(19) United States
(12) Patent Application Publication
(10) Pub. No.: US 2015/0093692 A1
(43) Pub. Date: Apr. 2, 2015

(54) PATTERN FORMING METHOD, ACTINIC RAY-SENSITIVE OR RADIATION-SENSITIVE RESIN COMPOSITION AND RESIST FILM USED THEREFOR, AND ELECTRONIC DEVICE MANUFACTURING METHOD AND ELECTRONIC DEVICE USING THE SAMEDEVICE MANUFACTURING METHOD AND ELECTRONIC DEVICE USING THE SAME

(71) Applicant: FUJIFILM CORPORATION, Tokyo (JP)

(72) Inventor: Shuhei YAMAGUCHI, Haibara-gun (JP)

(73) Assignee: FUJIFILM CORPORATION, Tokyo (JP)

(21) Appl. No.: 14/567,468

(22) Filed: Dec. 11, 2014

Related U.S. Application Data
(63) Continuation of application No. PCT/JP2013/066524, filed on Jun. 10, 2013.

(30) Foreign Application Priority Data
Jun. 13, 2012 (JP) 2012-134190

(51) Int. Cl. G03F 7/038; G03F 7/027; G03F 7/20

(52) U.S. Cl. CPC G03F 7/038; G03F 7/2041; G03F 7/027
USPC 430/18; 430/325; 430/311; 430/281.1

(57) ABSTRACT

There is provided a pattern forming method including: (a) forming a film by an actinic ray-sensitive or radiation-sensitive resin composition containing (A) to (C), (A) a resin capable of increasing polarity by the action of an acid to decrease solubility in a developer containing an organic solvent, (B) a compound capable of generating acid upon irradiation with an actinic ray or radiation, and (C) a salt having a conjugate base structure of an acid having a pKa of −2 or more in a molecule thereof and substantially not capable of decomposing by an actinic ray or radiation, (b) exposing the film, and (c) developing the exposed film using a developer containing an organic solvent to form a negative pattern.

### CROSS REFERENCE TO RELATED APPLICATION

This is a continuation of International Application No. PCT/JP2013/066524 filed on Jun. 10, 2013 and claims priority from Japanese Patent Application No. 2012-134190 filed on Jun. 13, 2012, the entire disclosures of which are incorporated herein by reference.

### TECHNICAL FIELD

The present invention relates to a pattern forming method, an actinic ray-sensitive or radiation-sensitive resin composition and a resist film used therefor, and an electronic device manufacturing method and an electronic device using the same. More particularly, the present invention relates to a pattern forming method suitable for a manufacturing process of a semiconductor such as an IC, a manufacturing process of a circuit board of a liquid crystal, a thermal head and the like, and other lithography processes of photofabrication, an actinic ray-sensitive or radiation-sensitive resin composition and a resist film used for the pattern forming method, and an electronic device manufacturing method and an electronic device using the same. In particular, the present invention relates to a pattern forming method suitable for exposure in an ArF exposure apparatus or an ArF immersion (liquid immersion) projection exposure apparatus which uses far-ultraviolet rays having a wavelength of 300 nm or less as a light source, an actinic ray-sensitive or radiation-sensitive resin composition and a resist film used for the pattern forming method, and a method of manufacturing an electronic device and an electronic device.

### BACKGROUND ART

Since a resist for a KrF excimer laser (248 nm) has been developed, a pattern forming method using chemical amplification has been used in order to compensate for desensitization caused by light absorption. For example, in a positive-type chemical amplification method, first, a photoacid-generating agent that is contained in an exposed portion decomposes upon irradiation with light and generates an acid.

Thereafter, in a process such as Post Exposure Bake (PEB) by the catalytic action of the generated acid, an alkali-insoluble group contained in the photosensitive composition is changed to an alkali-soluble group. Subsequently, development is performed using, for example, an alkaline solution. In this manner, the exposed portion is removed, and a desired pattern is obtained.

In the above method, various alkali developers have been suggested as an alkali developer. For example, as the alkali developer, an aqueous alkali developer such as 2.38% by mass of TMAH (aqueous tetramethylammonium hydroxide solution) is widely used.

Further, in order to make semiconductor elements finer, a wavelength of an exposure light source has been shortened and a projection lens with a high numerical aperture (high NA) has been used, and thus, an exposure machine using an ArF excimer laser having a wavelength of 193 nm as a light source has been currently developed. As a technique for further improving resolution, a method (that is, an immersion method) of filling a liquid having a high refractive index (hereinafter, also referred to as a “liquid for immersion”) between a projection lens and a sample has been proposed. In addition, EUV lithography that performs exposure with ultraviolet rays having a shorter wavelength (13.5 nm) has also been proposed.

For example, in the positive-type chemical amplification method, for the purpose of improving the performance of a resist composition used in forming a fine pattern, and more specifically, for the purpose of improving resolution and a pattern shape, a technique for using a weak acid salt has been suggested (see, for example, Japanese Patent Application Laid-Open No. 2005-17409, Japanese Patent Application Laid-Open No. 2009-276404, Japanese Patent Application Laid-Open No. 2010-160446, and Japanese Patent Application Laid-Open No. 2006-160447).

However, in the positive type image forming method, an isolated line or dot pattern may be formed well, but the shape of the pattern easily deteriorates when an isolated space or fine hole pattern is formed.

Further, recently, a pattern forming method using a developer containing an organic solvent (an organic-based developer) has also been developed (see, for example, Japanese Patent Application Laid-Open No. 2011-123469 (hereinafter referred to as JP-A-2011-123469) and International Publication No. WO2011/122336 (hereinafter referred to as WO 2011/122336)). For example, JP-A-2011-123469 and WO 2011/122336 disclose a pattern forming method including a process of coating, on a substrate, a resist composition of which solubility decreases with respect to an organic-based developer upon irradiation with an actinic ray or radiation, an exposure process, and a development process using the organic-based developer. According to this method, it is said that a fine pattern with high accuracy may be stably formed.

However, it has been possible to obtain a good pattern shape by the pattern forming method in the related art using a developer containing an organic solvent, but recently, for example, a need for making a hole pattern finer has sharply increased, and thus further performance improvement has been required even in the resist composition.

The present invention has been made in consideration of the above background, and an object of the present invention is to provide, in forming a fine pattern such as a hole pattern having a pore diameter of 45 nm or less by an organic-based developer, a pattern forming method having excellent uniformity of local pattern dimension (local CDU, nm) and exposure latitude (EL) and excellent reduction in scum generation, an actinic ray-sensitive or radiation-sensitive resin composition and a resist film used therefor, and an electronic device manufacturing method and an electronic device using the same.

### SUMMARY OF INVENTION

The present invention has the following configuration, and the problem of the present invention is accordingly solved.

[1] A pattern forming method including:

(a) forming a film by an actinic ray-sensitive or radiation-sensitive resin composition containing (A) to (C),
(A) a resin capable of increasing polarity by the action of an acid to decrease solubility in a developer containing an organic solvent, (B) a compound capable of generating acid upon irradiation with an actinic ray or radiation, and (C) a salt having a conjugate base structure of an acid having a pKa of −2 or more in a molecule thereof and substantially not capable of decomposing by an actinic ray or radiation,
(b) exposing the film, and
(c) developing the exposed film using a developer containing an organic solvent to form a negative pattern.

[2] The pattern forming method according to [1], wherein the salt (C) is represented by Formula (I):

A^{⊖}B^{⊕} (I)

wherein in Formula (I), A⁻ represents an organic anion having a conjugate base structure of an acid having a pKa of −2 or more, and B⁺ represents an organic cation, and A and B may be bonded to each other through a covalent bond.

[3] The pattern forming method according to [2], wherein the organic cation B⁺ is an organic cation having no aromatic structure.

[4] The pattern forming method according to [2] or [3], wherein the organic cation B⁺ is an ammonium cation or a sulfonium cation.

[5] The pattern forming method according to any one of [1] to [4], wherein the resin (A) is a resin capable of increasing polrality by generating an alcoholic hydroxyl group by the action of an acid so as to decrease solubility in a developer containing an organic solvent.

[6] The pattern forming method according to any one of [1] to [5], wherein the compound (B) is a compound capable of generating an organic acid represented by Formula (V) or Formula (VI) upon irradiation with an actinic ray or radiation:

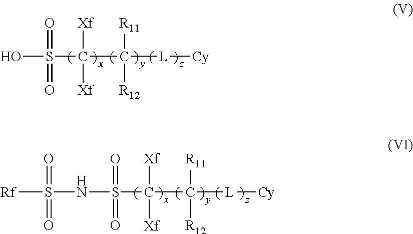

wherein a plurality of Xf each independently represents a fluorine atom or an alkyl group substituted with at least one fluorine atom, each of R₁₁ and R₁₂ independently represents a hydrogen atom, a fluorine atom or an alkyl group, L each independently represents a divalent linking group, Cy represents a cyclic organic group, Rf is a group including a fluorine atom, x represents an integer of 1 to 20, y represents an integer of 0 to 10, and z represents an integer of 0 to 10.

[7] The pattern forming method according to any one of [1] to [6], wherein the actinic ray-sensitive or radiation-sensitive resin composition further contains a hydrophobic resin (D) different from the resin (A).

[8] The pattern forming method according to any one of [1] to [7], wherein the developer is a developer containing at least one organic solvent selected from the group consisting of a ketone-based solvent, an ester-based solvent, an alcohol-based solvent, an amide-based solvent and an ether-based solvent.

[9] The pattern forming method according to any one of [1] to [8], wherein the exposure in the process (b) is immersion exposure.

[10] An actinic ray-sensitive or radiation-sensitive resin composition used in the pattern forming method according to any one of [1] to [9].

[11] A resist film formed by the actinic ray-sensitive or radiation-sensitive resin composition according to [10].

[12] An electronic device manufacturing method including the pattern forming method according to any one of [1] to [9].

[13] An electronic device manufactured by the electronic device manufacturing method according to [12].

It is also preferred that the present invention has the following constitution.

[14] The pattern forming method according to [7], in which the resin (D) is a resin containing a fluorine atom and/or a silicon atom.

[15] The pattern forming method according to [7], in which the resin (D) is a resin containing substantially no fluorine atom and silicon atom.

[16] The pattern forming method according to any one of [1] to [9], [14] and [15], in which the exposure in the process (b) is an ArF exposure.

[17] The pattern forming method according to any one of [1] to [9] and [14] to [16], further including (d) performing washing using an organic solvent-containing rinsing solution.

[18] The actinic ray-sensitive or radiation-sensitive resin composition according to [10], in which the composition is a chemical amplification type resist composition for organic solvent development.

[19] The actinic ray-sensitive or radiation-sensitive resin composition according to [10] and [18], in which the composition is for immersion exposure.

### DESCRIPTION OF EMBODIMENTS

Hereinafter, exemplary embodiments of the present invention will be described in detail.

In representation of a group (atomic group) in the present specification, the representation which does not specify substitution and non-substitution includes a representation having a substituent along with a representation having no substituent. For example, “an alkyl group” also includes an alkyl group having no substituent (an unsubstituted alkyl group) and an alkyl group having a substituent (a substituted alkyl group).

The term “actinic ray” or “radiation” in the present specification refers to, for example, a bright line spectrum of a mercury lamp and the like, far-ultraviolet rays represented by an excimer laser, extreme ultraviolet rays (EUV light), X-rays, an electron beam (EB) and the like. Further, the term “light” in the present invention refers to an actinic ray or radiation.

In addition, unless otherwise specifically indicated, the term “exposure” in the present specification includes not only the exposure performed using a mercury lamp, far-ultraviolet rays represented by an excimer laser, extreme-ultraviolet rays, X-rays, EUV light and the like, but also drawing performed by a particle beam such as an electron beam and an ion beam.

The pattern forming method of the present invention includes

(a) forming a film by an actinic ray-sensitive or radiation-sensitive resin composition containing the following (A) to (C),
(A) a resin capable of increasing the polarity by the action of an acid to decrease the solubility in a developer containing an organic solvent,
(B) a compound capable of generating acid upon irradiation with an actinic ray or radiation, and
(C) a salt having a conjugate base structure of an acid having a pKa of −2 or more in a molecule thereof and substantially not capable of decomposing by an actinic ray or radiation,

(b) exposing the film, and

(c) developing the exposed film using a developer containing an organic solvent to form a negative pattern.

In forming a fine pattern such as a hole pattern and the like having a pore diameter of 45 nm or less by an organic-based developer by the above-described pattern forming method of the present invention, the reason that uniformity of local pattern dimension and exposure latitude are excellent and reduction in scum generation is excellent, is not clear, but is presumed as follows.

In general, the negative pattern forming method using a developer containing an organic solvent has a low dissolution contrast of an exposed portion and an unexposed portion against the developer and a pattern boundary portion is partially dissolved, and thus uniformity of local pattern dimension and exposure latitude easily deteriorate.

When an acid generated from the exposed portion is diffused into the unexposed portion and reaction between the resin and the acid occurs even in the unexposed portion, the dissolution contrast is decreased, and thus a chemical amplification type resist composition usually contains a basic compound in order to capture an acid in the unexposed portion.

However, the basic compound generally has high volatility, and in particular, after a film is manufactured, the basic compound present in an outermost layer of the resist film is easily lost by volatilization due to a preheating process (prebake) and the like before the exposure process, and thus the acid in the unexposed portion of the outermost layer is not sufficiently captured and uniformity of local pattern dimension and exposure latitude easily deteriorate. Further, the solubility of the resist film in an organic-based developer in the vicinity of the outermost layer deteriorates, and thus scum is easily generated.

In contrast, the salt (C) in the present invention has low volatility, such that it is difficult for the salt (C) to be lost due to volatilization even in the outermost layer, and thus it is thought that it is possible to maintain the uniformity of local pattern dimension and exposure latitude fairly well and suppress the generation of scum.

Meanwhile, the salt (C) is a salt that has a conjugate base structure of an acid having a pKa of −2 or more in a molecule thereof, and thus a function of capturing an acid generated from the compound (B) may be exhibited by a buffering action.

By the way, as described above, when a fine hole pattern is formed by the positive type image forming method, the shape of the pattern easily deteriorates, and thus it is substantially impossible to form an ultrafine (for example, the space width or pore diameter is 45 nm or less) pattern. This is because when such a fine pattern is formed by the positive type image forming method, a region on which a space portion or hole portion is to be formed becomes an exposed portion, and it is optically almost impossible to expose and resolve the ultrafine region.

It is preferred that the pattern forming method of the present invention further includes (d) performing washing using a rinsing solution containing an organic solvent.

It is preferred that the rinsing solution is a rinsing solution containing at least one organic solvent selected from the group consisting of a hydrocarbon-based solvent, a ketone-based solvent, an ester-based solvent, an alcohol-based solvent, an amide-based solvent, and an ether-based solvent.

It is preferred that the pattern forming method of the present invention includes (e) a heating process after (b) the exposure process.

Further, the resin (A) is also a resin capable of increasing the polarity by the action of an acid to increase the solubility in the alkali developer. Accordingly, the pattern forming method of the present invention may further include (f) developing the film using an alkali developer.

The pattern forming method of the present invention may include several times of (b) the exposure process.

The pattern forming method of the present invention may include several times of (e) the heating process.

The resist film of the present invention is a film formed by the actinic ray-sensitive or radiation-sensitive resin composition, and for example, a film formed by applying the actinic ray-sensitive or radiation-sensitive resin composition on a substrate.

Hereinafter, an actinic ray-sensitive or radiation-sensitive resin composition that may be used in the present invention will be described.

In addition, the present invention also relates to the actinic ray-sensitive or radiation-sensitive resin composition that will be described below.

The actinic ray-sensitive or radiation-sensitive resin composition according to the present invention is used in a negative type development (development in which when a resist film is exposed, the solubility in the developer is decreased, and thus the exposed portion remains as a pattern and the unexposed portion is removed) particularly when a pattern having an ultrafine space width or pore diameter (for example, 45 nm or less) is formed on the resist film. That is, the actinic ray-sensitive or radiation-sensitive resin composition according to the present invention may be used as an actinic ray-sensitive or radiation-sensitive resin composition for organic solvent development, which is used for development using a developer containing an organic solvent. Here, the term, for organic solvent development refers to a use that is used in a process of developing a film using a developer containing at least an organic solvent.

It is preferred that the actinic ray-sensitive or radiation-sensitive resin composition of the present invention is typically a resist composition and a negative type resist composition (that is, a resist composition for organic solvent development), from the viewpoint of obtaining a particularly good effect. Further, the composition according to the present invention is typically a chemical amplification type resist composition.

[1] (A) Resin capable of increasing the polarity by the action of an acid to decrease the solubility in a developer containing an organic solvent

A resin capable of increasing the polarity by the action of an acid to decrease the solubility in a developer containing an organic solvent, which is used in the actinic ray-sensitive or radiation-sensitive resin composition of the present invention (hereinafter, also referred to as an “acid-decomposable resin” or “resin (A)”) is a resin having a structure protected with a leaving group capable of decomposing and leaving a polar group by the action of an acid (hereinafter, also referred to as an “acid-decomposable group”).

Examples of the resin (A) may include a resin having an acid-decomposable group at the main chain or side chain of the resin, or at both the main chain and the side chain.

Meanwhile, the resin (A) is also a resin capable of increasing the polarity by the action of an acid to increase the solubility in the alkali developer.

The polar group is not particularly limited as long as the polar group is a group that is sparingly soluble or insoluble in a developer containing an organic solvent, but examples thereof may include a phenolic hydroxyl group, a carboxyl group, a fluorinated alcohol group (preferably a hexafluoroisopropanol group), a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group and the like.

Examples of a preferred polar group may include a carboxyl group, a sulfonic acid group, an alcoholic hydroxyl group, and the like.

In the present invention, the alcoholic hydroxyl group (hereinafter, also referred to as an alcoholic hydroxyl group in some cases) is a hydroxyl group that is bonded to a hydrocarbon group, refers to a hydroxyl group other than a hydroxyl group (a phenolic hydroxyl group) that is directly bonded to an aromatic ring, or a hydroxyl group in an aliphatic alcohol in which an α-position carbon (a carbon atom to which a hydroxyl group is bonded) has been substituted with a fluorine atom, and typically represents a hydroxyl group having a pKa of 12 to 20.

In the present invention, it is preferred that the resin (A) is a resin capable of generating an alcoholic hydroxyl group and increasing the polarity by the action of an acid to decrease the solubility in a developer containing an organic solvent.

The structure protected with a leaving group capable of decomposing and leaving a polar group by the action of an acid is preferably:

(i) a structure capable of decomposing by the action of an acid to generate a carboxyl group and represented by the following Formula (a);

(ii) a structure capable of decomposing by the action of an acid to generate one alcoholic hydroxyl group and represented by the following Formula (b); or

(iii) a structure capable of decomposing by the action of an acid to generate two or three alcoholic hydroxyl groups and represented by the following Formula (c).

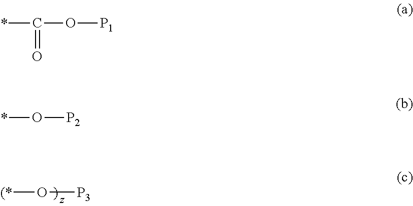

In the formulae, each of P₁ and P₂ independently represents a monovalent group capable of decomposing and leaving by the action of an acid.

P₃ represents a z-valent group capable of decomposing and leaving by the action of an acid. z represents 2 or 3.

* represents a bonding hand linked to the main chain or side chain of the resin.

It is preferred that the structure (i) is a group represented by the following Formula (a-1).

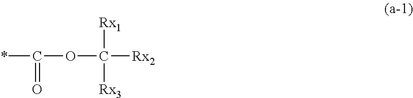

In the formula, each of Rx₁ to Rx₃ independently represents a monovalent organic group.

Rx₁ and Rx₂ may be bound with each other to form a ring.

* represents a bonding hand linked to the main chain or side chain of the resin.

The monovalent organic group as Rx₁ to Rx₃ is an alkyl group (straight or branched) or a cycloalkyl group (monocyclic or polycyclic).

The alkyl group of Rx₁ to Rx₃ is preferably an alkyl group having 1 to 4 carbon atoms, such as a methyl group, an ethyl group, a n-propyl group, an isopropyl group, a n-butyl group, an isobutyl group and a t-butyl group.

The cycloalkyl group of Rx₁ to Rx₃ is preferably a monocyclic cycloalkyl group having 3 to 20 carbon atoms, such as a cyclopentyl group and a cyclohexyl group, and a polycyclic cycloalkyl group having 4 to 20 carbon atoms, such as a norbornyl group, a tetracyclodecanyl group, a tetracyclododecanyl group and an adamantyl group.

The ring in which Rx₁ and Rx₂ are bound to form is preferably a cycloalkyl group (monocyclic or polycyclic). The cycloalkyl group is preferably a monocyclic cycloalkyl group such as a cyclopentyl group and a cyclohexyl group, and a polycyclic cycloalkyl group such as a norbornyl group, a tetracyclodecanyl group, a tetracyclododecanyl group and an adamantyl group. A monocyclic cycloalkyl group having 5 to 6 carbon atoms is more preferred, and a monocyclic cycloalkyl group having 5 carbon atoms is particularly preferred.

An aspect is preferred, in which Rx₁ is a methyl group or an ethyl group, and Rx₂ and Rx₃ are bound with each other to form the above-described cycloalkyl group.

Rx₁ to Rx₃ may have a substituent, and examples of the substituent may include an alkyl group (having 1 to 4 carbon atoms), a halogen atom, a hydroxyl group, an alkoxy group (having 1 to 4 carbon atoms), a carboxylic group, an alkoxycarbonyl group (having 2 to 6 carbon atoms), an aryl group (having 6 to 10 carbon atoms) and the like, and preferably a group having 8 or less carbon atoms.

The structure (ii) is preferably a group represented by the following Formula (b-1), (b-2), (b-3), or (b-4), and more preferably a group represented by the following Formula (b-1).

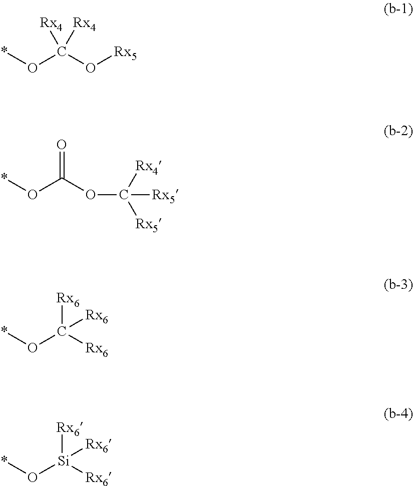

In Formula (b-1),

a plurality of Rx₄ each independently represent a hydrogen atom or a monovalent organic group. Rx₄'s may be bound with each other to form a ring.

Rx₅ represents a monovalent organic group. One of Rx₄'s and Rx₅ may be bound with each other to form a ring.

In Formula (b-2),

Rx₄′ represents a hydrogen atom, or a monovalent organic group.

a plurality of Rx₅′ independently represents a monovalent organic group. Rx₅′'s may be bound with each other to form a ring. Further, one of Rx₅′'s and Rx₄′ may be bound with each other to form a ring.

In Formula (b-3),

a plurality of Rx₆ independently represents a hydrogen atom, an alkyl group, a cycloalkyl group, an aryl group, an alkenyl group, or an alkynyl group. Two Rx₆'s may be bound with each other to form a ring. However, when one or two of the three Rx₆'s is or are a hydrogen atom(s), at least one of the other Rx₆'s represents an aryl group, an alkenyl group, or an alkynyl group.

In Formula (b-4),

a plurality of Rx₆′ independently represents a monovalent organic group. Two Rx₆′'s may be bound with each other to form a ring.

In Formulas (b-1) to (b-4), * represents a bonding hand linked to the main chain or side chain of the resin.

As described above, each of Rx₄ and Rx₄′ independently represents a hydrogen atom or a monovalent organic group. Each of Rx₄ and Rx₄′ is independently preferably a hydrogen atom, an alkyl group, or a cycloalkyl group, and more preferably a hydrogen atom, or an alkyl group.

The alkyl group of Rx₄ and Rx₄′ may be straight or branched. The carbon number of the alkyl group is preferably 1 to 10, and more preferably 1 to 3. Examples of the alkyl group of Rx₄ may include a methyl group, an ethyl group, an n-propyl group, an isopropyl group, and a n-butyl group.

The cycloalkyl group of Rx₄ and Rx₄′ may be monocyclic and polycyclic. The carbon number of the cycloalkyl group is preferably 3 to 10, and more preferably 4 to 8. Examples of the cycloalkyl group of Rx₄ may include a cyclopropyl group, a cyclobutyl group, a cyclopentyl group, a cyclohexyl group, a norbornyl group and an adamantyl group.

Further, in Formula (b-1), at least one of Rx₄'s is preferably a monovalent organic group. When the configuration is adopted, particularly high sensitivity may be achieved.

As Rx₄ and Rx₄′, the alkyl group and the cycloalkyl group may further have a substituent, and examples of the substituent may include a group which is the same as those described in the substituent that may be possessed by Rx₁ to Rx₃.

As described above, each of Rx₅ and Rx₅′ independently represents a monovalent organic group. Each of Rx₅ and Rx₅′ is independently preferably an alkyl group, or a cycloalkyl group, and more preferably an alkyl group. The alkyl group and the cycloalkyl group may further have a substituent, and examples of the substituent may include a group which is the same as those described in the substituent that may be possessed by Rx₁ to Rx₃.

It is preferred that the alkyl group of Rx₅ and Rx₅′ has no substituent, or one or more aryl groups and/or one or more silyl groups as the substituent. The carbon number of the unsubstituted alkyl group is preferably 1 to 20, and more preferably 1 to 10. The carbon number of the alkyl group moiety in the alkyl group substituted with one or more aryl groups is preferably 1 to 25.

Specific examples of the alkyl group of Rx₅ and Rx₅′ may similarly include those described as the specific examples of the alkyl group of Rx₄ and Rx₄. Further, the carbon number of the aryl group in the alkyl group substituted with one or more aryl groups is preferably 6 to 10, and examples thereof may include a phenyl group and a naphthyl group.

The carbon number of the alkyl group moiety in the alkyl group substituted with one or more silyl groups is preferably 1 to 30. Further, when the cycloalkyl group of Rx₅ and Rx₅′ has no substituent, the carbon number is preferably 3 to 20, and more preferably 3 to 15.

Specific examples of the cycloalkyl group of Rx₅ and Rx₅′ may similarly include those described as the specific examples of the cycloalkyl group of Rx₄ and Rx₄′.

Rx₆ represents a hydrogen atom, an alkyl group, a cycloalkyl group, an aryl group, an alkenyl group or an alkynyl group. However, when one or two of the three Rx₆'s is or are a hydrogen atom(s), at least one of the other Rx₆'s represents an aryl group, an alkenyl group or an alkynyl group. Rx₆ is preferably a hydrogen atom or an alkyl group.

As Rx₆, the alkyl group, the cycloalkyl group, the aryl group, the alkenyl group and the alkynyl group may further have a substituent, and examples of the substituent may include a group which is the same as those described in the substituent that may be possessed by Rx₁ to Rx₃.

Examples of the alkyl group and the cycloalkyl group as Rx₆ may similarly include those described in the alkyl group and the cycloalkyl group of Rx₄ and Rx₄′. In particular, when the alkyl group has no substituent, the carbon number thereof is preferably 1 to 6, and preferably 1 to 3.

Examples of the aryl group of Rx₆ may include an aryl group having 6 to 10 carbon atoms, such as a phenyl group and a naphthyl group.

Examples of the alkenyl group of Rx₆ may include an alkenyl group having 2 to 5 carbon atoms, such as a vinyl group, a propenyl group and an allyl group.

Examples of the alkynyl group of Rx₆ may include an alkynyl group having 2 to 5 carbon atoms, such as an ethynyl group, a propynyl group and a butynyl group.

Each Rx₆′ is independently preferably an alkyl group, a cycloalkyl group, or an aryl group, more preferably an alkyl group, or a cycloalkyl group, and still more preferably an alkyl group.

Specific examples and preferred examples of the alkyl group, the cycloalkyl group, and the aryl group with respect to Rx₆′ may include the alkyl group and the cycloalkyl group described above with respect to Rx₄ and Rx₄′ and the aryl group described above with respect to Rx₆.

The alkyl group, the cycloalkyl group, and the aryl group may further have a substituent, and examples of the substituent may include a group which is the same as those described in the substituent that may be possessed by Rx₁ to Rx₃.

It is preferred that the structure (iii) is a group represented by the following Formula (c-1), (c-2) or (c-3).

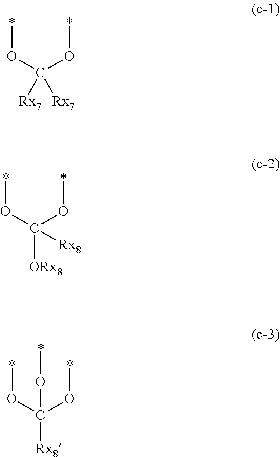

In Formula (c-1), a plurality of Rx₇ each independently represent a hydrogen atom, or a monovalent organic group.

Rx₇'s may be bound with each other to form a ring.

In Formula (c-2), a plurality of Rx₈ each independently represent a monovalent organic group.

Rx₈'s may be bound with each other to form a ring.

In Formula (c-3), Rx₈′ represents a monovalent organic group.

In Formulas (c-1) to (c-3), * represents a bonding hand linked to the main chain or side chain of the resin.

As described above, Rx₇ represents a hydrogen atom or a monovalent organic group. Rx₇ is preferably a hydrogen atom, an alkyl group or a cycloalkyl group, more preferably a hydrogen atom or an alkyl group, and still more preferably a hydrogen atom or an alkyl group having no substituent.

Rx₇ is preferably a hydrogen atom, or an alkyl group having 1 to 10 carbon atoms, and more preferably a hydrogen atom, or an alkyl group having 1 to 10 carbon atoms and no substituent.

The alkyl group and the cycloalkyl group as Rx₇ may further have a substituent, and examples of the substituent may include a group which is the same as those described in the substituent that may be possessed by Rx₁ to Rx₃.

Specific examples of the alkyl group and the cycloalkyl group of Rx₇ may similarly include those described as the specific examples of the alkyl group and the cycloalkyl group of Rx₄ and Rx₄′.

As described above, Rx₈ and Rx₈′ represent a hydrogen atom, or a monovalent organic group. Each of Rx₈ and Rx₈′ is independently preferably a hydrogen atom, an alkyl group or a cycloalkyl group, and more preferably a hydrogen atom or an alkyl group.

Examples of the alkyl group and the cycloalkyl group as Rx₈ and Rx₈′ may similarly include those described in the alkyl group and the cycloalkyl group of Rx₄ and Rx₄′.

The resin (A) has preferably a repeating unit (hereinafter, also referred to as an acid-decomposable repeating unit (a)) having the above-described structure protected with the leaving group capable of decomposing and leaving a polar group by the action of an acid, and more preferably a repeating unit having any one of the structures (i) to (iii).

Examples of the repeating unit having any one of the structures (i) to (iii) may include a repeating unit represented by the following Formula (I-1) or (I-2).

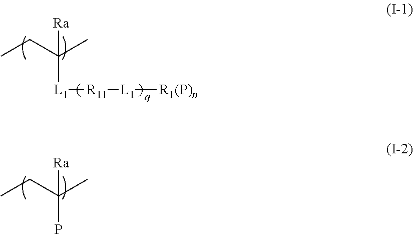

In the formula,

each Ra independently represents a hydrogen atom, an alkyl group, or a group represented by —CH₂—O—Ra₂. Here, Ra₂ represents a hydrogen atom, an alkyl group, or an acyl group.

P represents the structure (i) or (ii). When a plurality of P's is present, each P may be the same or different, and P's may be bound with each other to form a ring. When a plurality of P's is bound with each other to form a ring, the bound P may show the structure (iii), and in this case, * of Formula (c) in the structure (iii) represents a bonding hand linked to R₁.

R₁ represents a (n+1)-valent organic group.

R₁₁ represents a divalent organic group. When a plurality of R₁₁'s is present, each R₁₁ may be the same or different.

n represents an integer of 1 or more.

L₁ represents a linking group represented by —COO—, —OCO—, —CONH—, —O—, —Ar—, —SO₃— or —SO₂NH—. Here, Ar represents a divalent aromatic ring group. When a plurality of L₁'s is present, each L₁ may be the same or different.

q represents a repeating number of a group represented by —R₁₁-L₁-, and represents an integer of 0 to 3.

Ra represents a hydrogen atom, an alkyl group, or a group represented by —CH₂—O—Ra₂.

The carbon number of the alkyl group of Ra is preferably 6 or less, and the carbon number of the alkyl group and the acyl group of Ra₂ is preferably 5 or less. The alkyl group of Ra and the alkyl group and the acyl group of Ra₂ may have a substituent.

Ra is preferably a hydrogen atom, an alkyl group having 1 to 10 carbon atoms, or an alkoxyalkyl group having 1 to 10 carbon atoms, and specifically, preferably a hydrogen atom, a methyl group, a trifluoromethyl group or a hydroxymethyl group, and more preferably a hydrogen atom or a methyl group.

R₁ represents a (n+1)-valent organic group. R₁ is preferably a non-aromatic hydrocarbon group. In this case, R₁ may be a chain hydrocarbon group or an alicyclic hydrocarbon group. R₁ is more preferably an alicyclic hydrocarbon group.

The chain hydrocarbon group as R₁ may be straight or branched. In addition, the carbon number of the chain hydrocarbon group is preferably 1 to 8. For example, when the chain hydrocarbon group is an alkylene group, the alkylene group is preferably a methylene group, an ethylene group, a n-propylene group, an isopropylene group, a n-butylene group, an isobutylene group or a sec-butylene group.

The alicyclic hydrocarbon group as R₁ may be monocyclic or polycyclic. The alicyclic hydrocarbon group has, for example, a monocyclo, bicyclo, tricyclo or tetracyclo structure. The carbon number of the alicyclic hydrocarbon group is usually 5 or more, preferably 6 to 30, and more preferably 7 to 25.

Examples of the alicyclic hydrocarbon group may include those having a partial structure illustrated below. Each of these partial structures may have a substituent. Further, in each of these partial structures, the methylene group (—CH₂—) may be substituted with an oxygen atom (—O—), a sulfur atom (—S—), a carbonyl group [—C(═O)—], a sulfonyl group [—S(═O)₂—], a sulfinyl group [—S(═O)—] or an imino group [—N(R)—] (R is a hydrogen atom or an alkyl group).

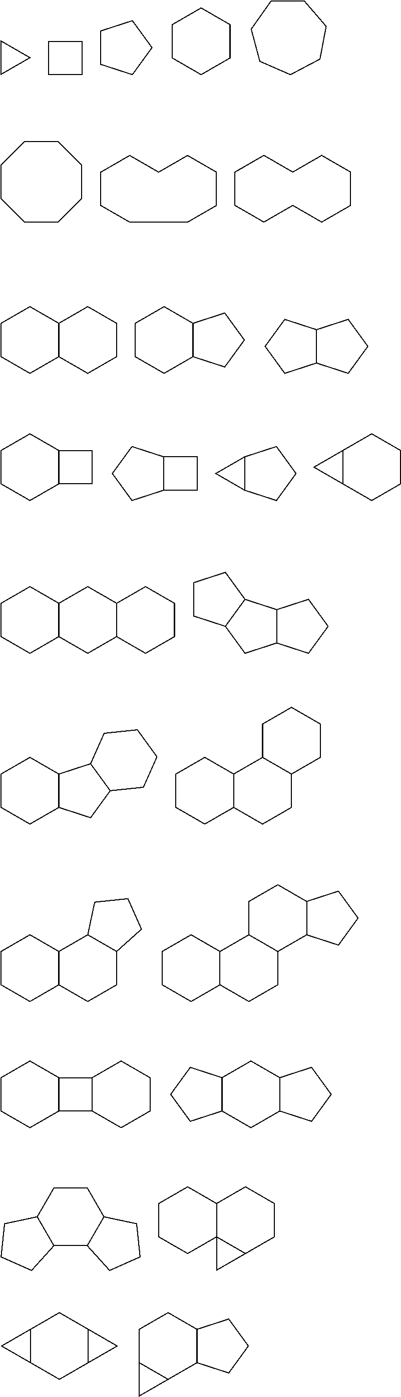

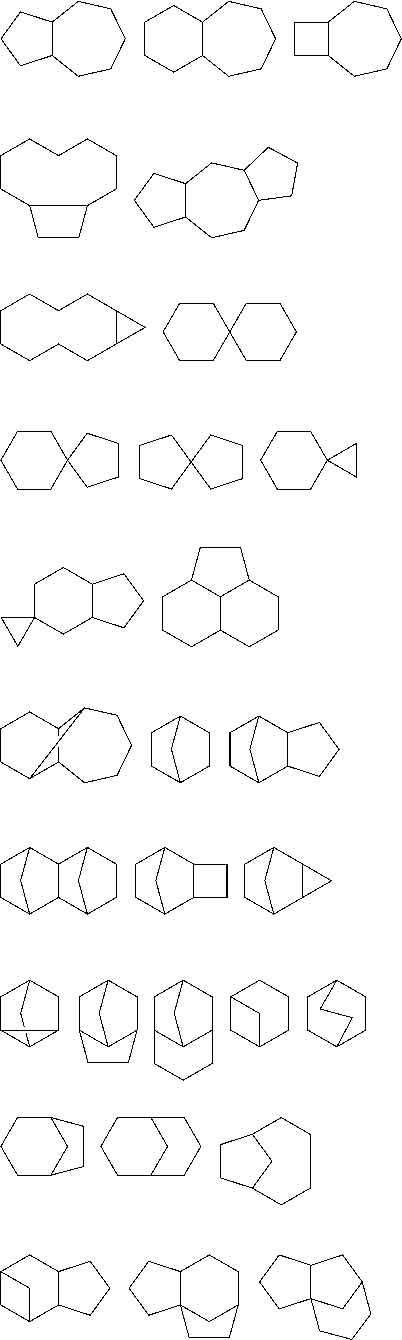

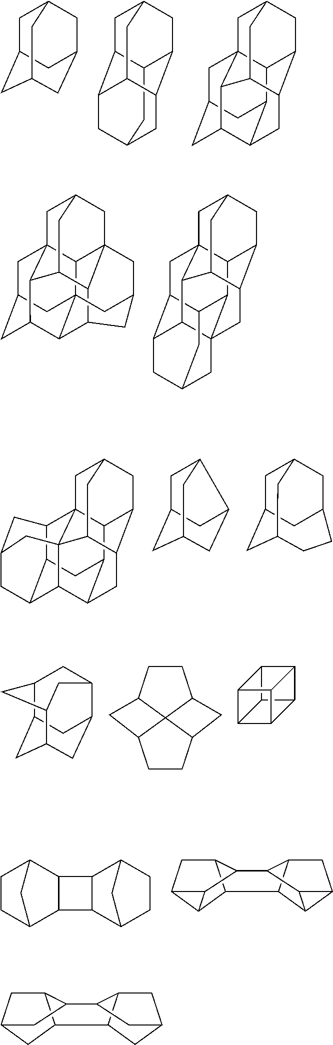

For example, when R₁ is a cycloalkylene group, R₁ is preferably an adamantylene group, a noradamantylene group, a decahydronaphthylene group, a tricyclodecanylene group, a tetracyclododecanylene group, a norbornylene group, a cyclopentylene group, a cyclohexylene group, a cycloheptylene group, a cyclooctylene group, a cyclodecanylene group or a cyclododecanylene group, and more preferably an adamantylene group, a norbornylene group, a cyclohexylene group, a cyclopentylene group, a tetracyclododecanylene group or a tricyclodecanylene group.

The non-aromatic hydrocarbon group of R₁ may have a substituent. Examples of the substituent may include an alkyl group having 1 to 4 carbon atoms, a halogen atom, a hydroxyl group, an alkoxy group having 1 to 4 carbon atoms, a carboxyl group and an alkoxycarbonyl group having 2 to 6 carbon atoms. The above-described alkyl group, alkoxy group and alkoxycarbonyl group may further have a substituent. Examples of the substituent may include a hydroxyl group, a halogen atom and an alkoxy group.

Details of the divalent organic group of R₁₁ are the same as the case where n=1 in the (n+1)-valent organic group as R₁, that is, the case where R₁ is a divalent organic group, and specific examples thereof are also the same.

L₁ represents a linking group represented by —COO—, —OCO—, —CONH—, —O—, —Ar—, —SO₃— or —SO₂NH— (“-” at the left side of these linking groups means connection to the main chain of the resin). Here, Ar represents a divalent aromatic ring group, and is preferably a divalent aromatic ring group having 6 to 10 carbon atoms, such as, for example, a phenylene group and a naphthylene group. L₁ is preferably a linking group represented by —COO—, —CONH— or —Ar—, and more preferably a linking group represented by —COO— or —CONH—.

n is an integer of 1 or more. n is preferably an integer of 1 to 3, and more preferably 1 or 2. Further, when n is an integer of 2 or more, it is possible to further enhance the dissolution contrast for an organic solvent-containing developer. Accordingly, the resolution may be further enhanced, and at the same time, LWR may be further reduced.

q represents a repeating number of a group represented by —R₁-L₁-, and represents an integer of 0 to 3. q is preferably an integer of 0 to 2, and more preferably 0 or 1.

Hereinafter, specific examples of the acid-decomposable repeating unit (a) will be described. Meanwhile, in the specific examples, Ra and P have the same meaning as Ra and P in Formula (I-1) or (I-2). P₁ has the same meaning as P₁ in Formula (a). P₃ has the same meaning as P₃ when z is 2 in Formula (c).

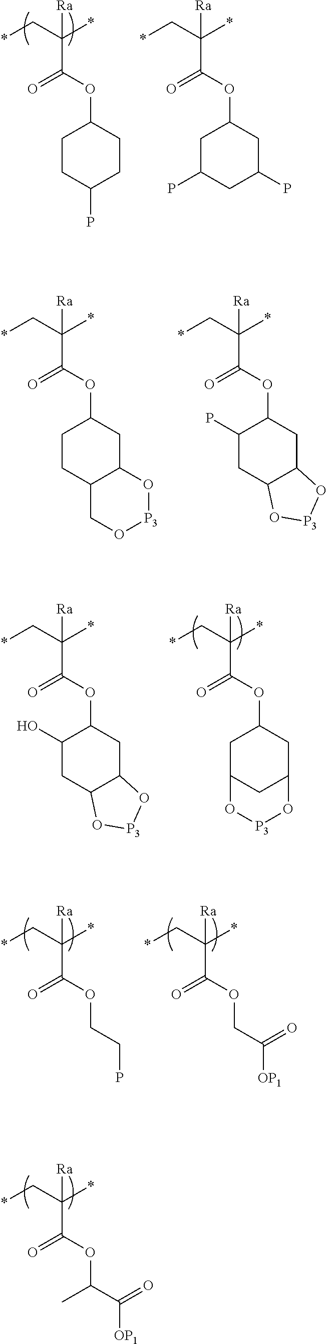

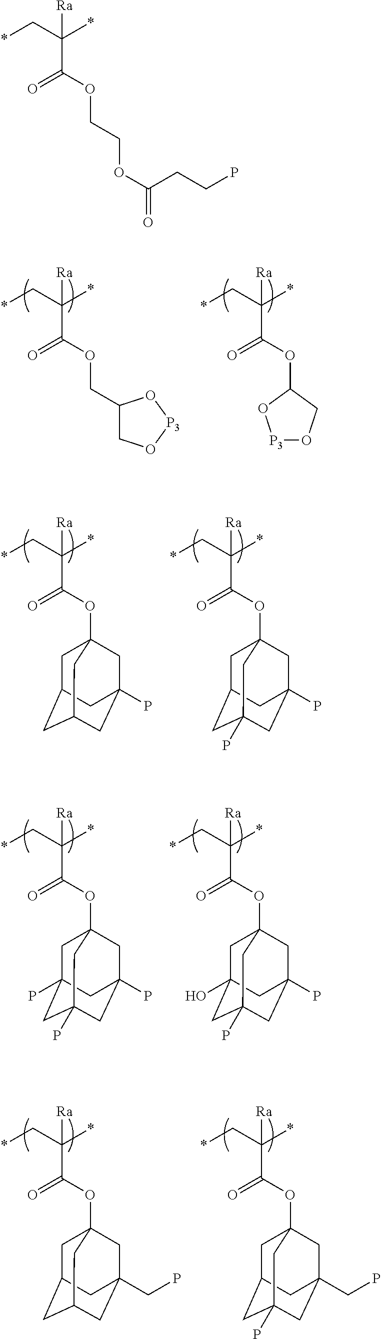

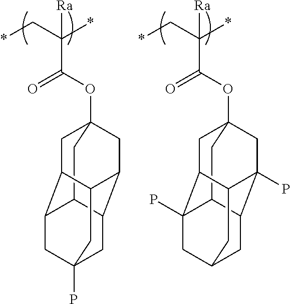

In the group capable of leaving by the action of an acid in the acid-decomposable repeating unit (a), appropriate examples thereof may also include —C(R₃₆)(R₃₇)(R₃₈), —C(R₃₆)(R₃₇)(OR₃₉), —C(R₀₁)(R₀₂)(OR₃₉) and the like.

In the Formula, each of R₃₆ to R₃₉ independently represents an alkyl group, a cycloalkyl group, an aryl group, an aralkyl group or an alkenyl group. R₃₆ and R₃₇ may be bound with each other to form a ring.

Each of R₀₁ and R₀₂ independently represents a hydrogen atom, an alkyl group, a cycloalkyl group, an aryl group, an aralkyl group or an alkenyl group.

The acid-decomposable group is preferably a cumyl ester group, an enol ester group, an acetal ester group, a tertiary alkyl ester group or the like. The group is more preferably a tertiary alkyl ester group.

The acid-decomposable repeating unit (a) that may be contained in the resin (A) is preferably a repeating unit represented by the following Formula (a1) or (a2).

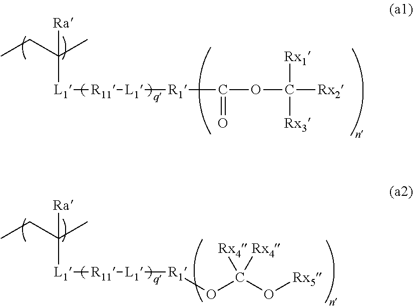

In Formulas (a1) and (2), each Ra′ independently represents a hydrogen atom, an alkyl group, or a group represented by —CH₂—O—Ra₂′. Here, Raₑ′ represents a hydrogen atom, an alkyl group or an acyl group.

R₁′ represents a (n′+1)-valent organic group.

R₁₁′ represents a divalent organic group. When a plurality of R₁₁′'s is present, each R₁₁′ may be the same or different.

L₁′ represents a linking group represented by —COO—, —CONH—, —O—, —Ar′—, —SO₃— or —SO₂NH—. Here, Ar′ represents a divalent aromatic ring group. When a plurality of L₁′'s is present, each L₁′ may be the same or different.

Each of Rx₁′ to Rx₃′ independently represents a monovalent organic group.

Rx₁′ and Rx₂′ may be bound with each other to form a ring.

q′ represents a repeating number of a group represented by —R₁₁′-L₁′-, and represents an integer of 0 to 3.

n′ represents an integer of 1 or more.

Rx₄″'s each independently represent a hydrogen atom or a monovalent organic group. Rx₄″'s may be bound with each other to form a ring.

Rx₅″ represents a monovalent organic group. One of Rx₄″'s and Rx₅″ may be bound with each other to form a ring.

Details of Ra′, Ra₂′, R₁′, R₁₁′, L₁′, Ar′, Rx₁′ to Rx₃′, Rx₄″, and Rx₅″ are the same as those described in Ra, Ra₂, R₁, R₁₁, L₁, and Ar in Formula (I-1), Rx₁ to Rx₃ in the Formula (a-1), and Rx₄ and Rx₅ in the Formula (b-1), respectively. In addition, preferred ranges of n′ and q′ are the same as the preferred ranges of n and q in Formula (I-1), respectively.

The resin (A) may include two or more types of the acid-decomposable repeating unit (a). When the configuration is adopted, it is possible to finely adjust reactivity and/or developability, thereby facilitating optimization of all the performances.

The total content of the acid-decomposable repeating unit (a) is preferably in a range of 20 mol % to 80 mol %, and more preferably in a range of 30 mol % to 70 mol %, based on all the repeating units of the resin (A).

Preferred specific examples of the acid-decomposable repeating unit (a) will be described below, but the present invention is not limited thereto.

In the specific examples, R¹, R¹⁰Rx, Xa and Xa₁ represent a hydrogen atom, CH₃, CF₃ or CH₂OH. Each of Rxa and Rxb represents an alkyl group having 1 to 4 carbon atoms. Z represents a substituent including a polar group, and when a plurality of Z's is present, each Z may be the same or different. p represents 0 or a positive integer. Specific examples and preferred examples of Z may include, for example, a hydroxyl group, a cyano group, an amino group, an alkyl amide group or a sulfonamide group as it is, or a straight or branched alkyl group and a cycloalkyl group having at least one thereof, and preferably an alkyl group having a hydroxyl group. The examples are more preferably a branched alkyl group having a hydroxyl group. The branched alkyl group is particularly preferably an isopropyl group. When a plurality of Z's is present, each Z may be the same or different.

Me represents a methyl group.

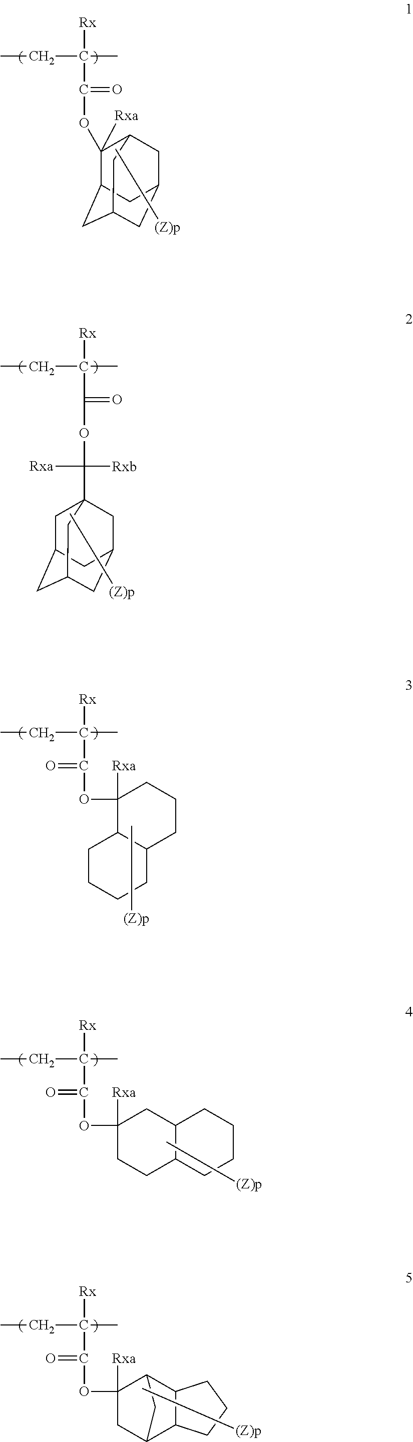

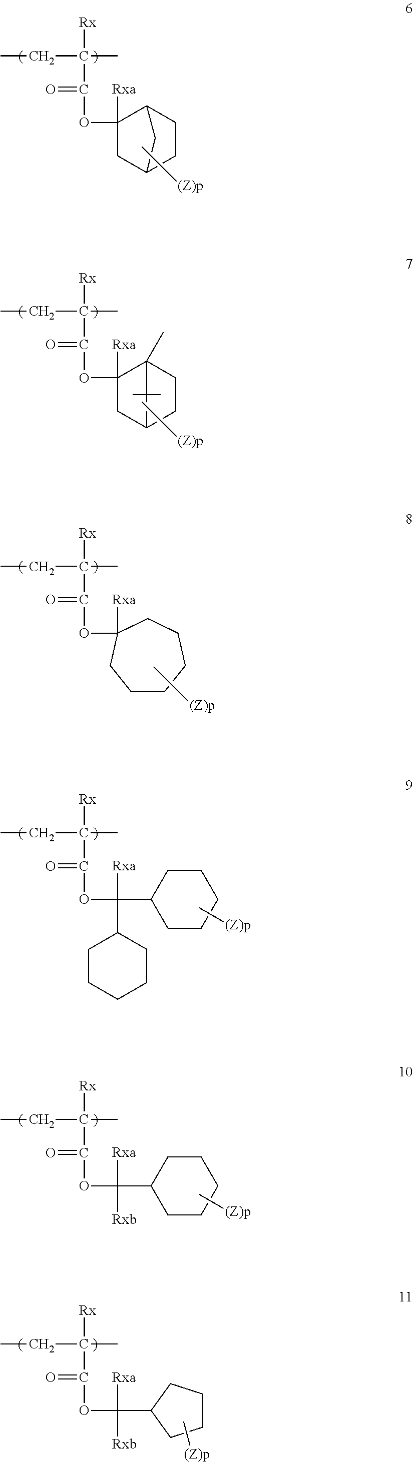

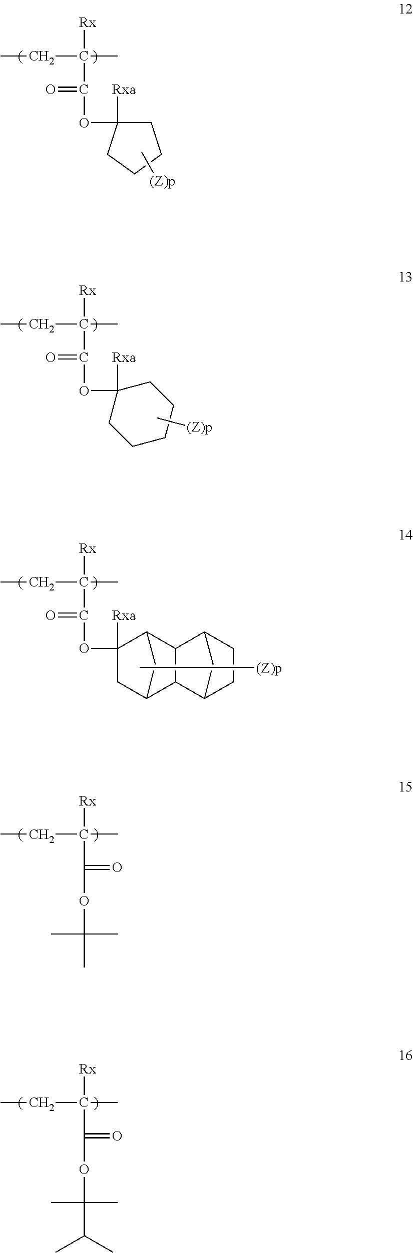

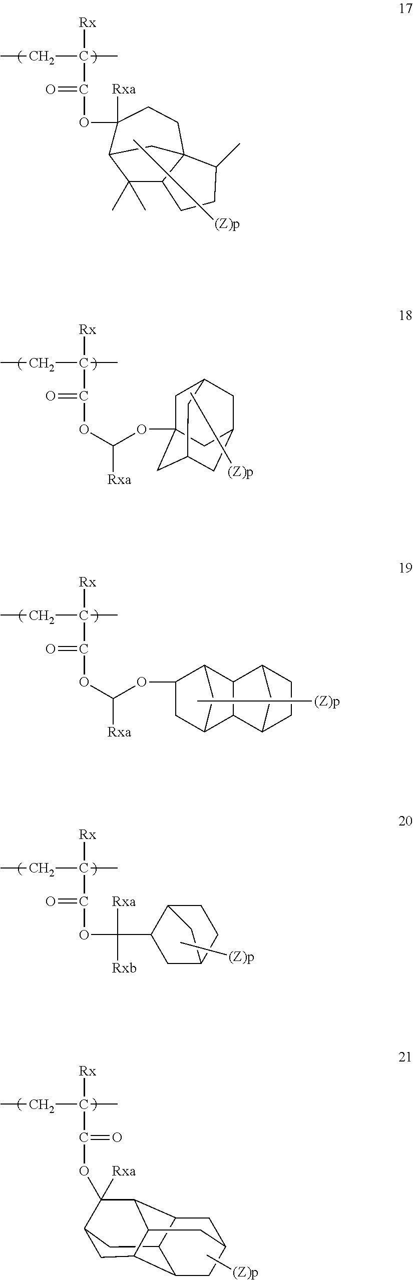

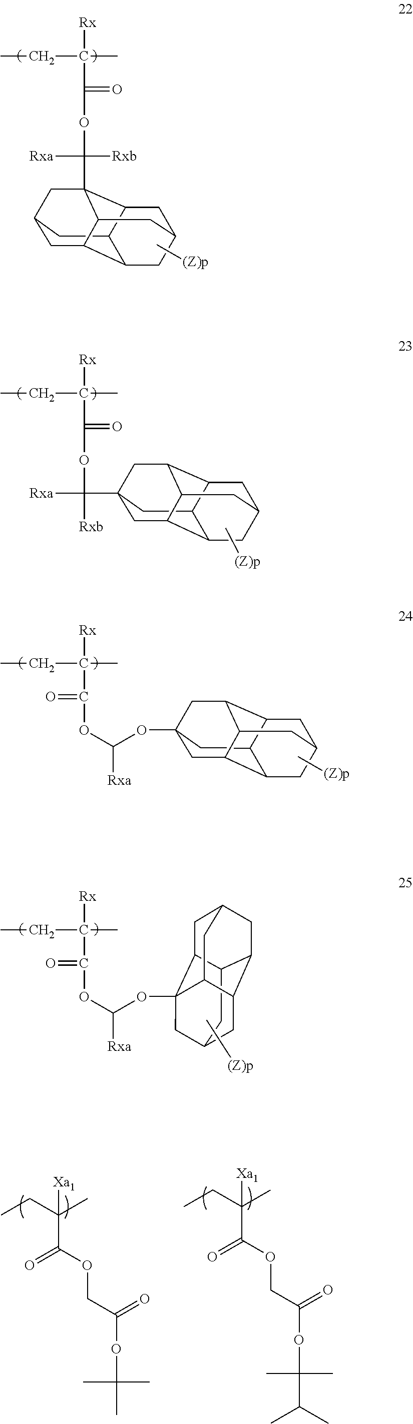

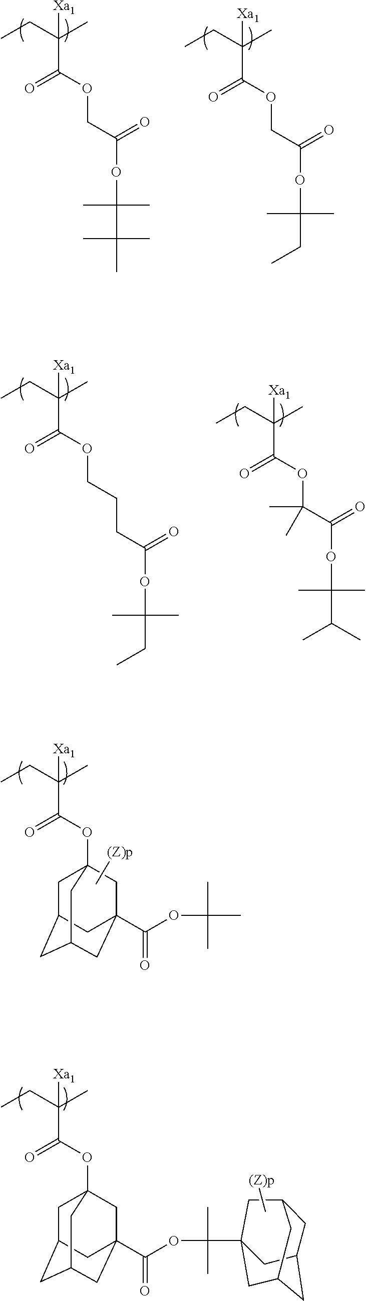

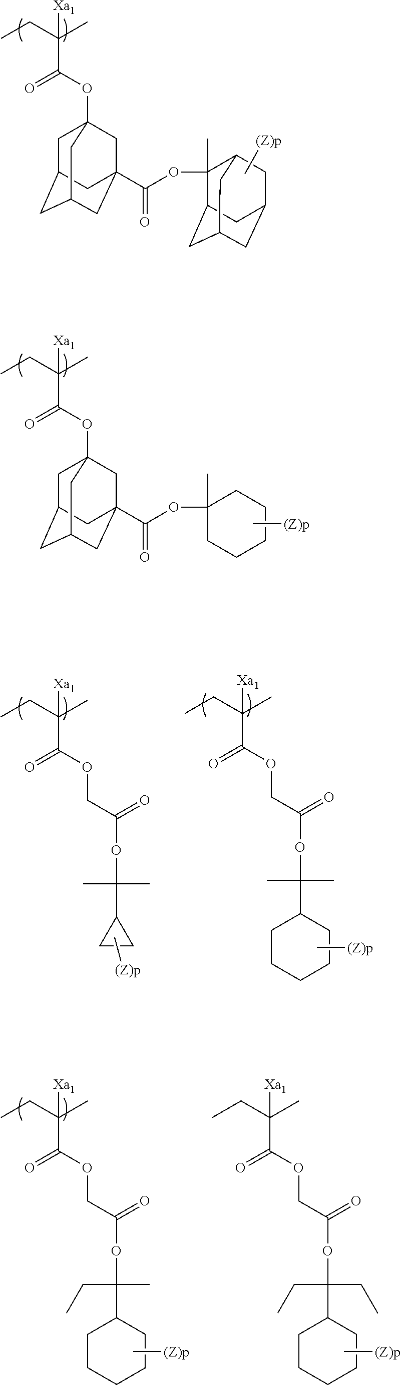

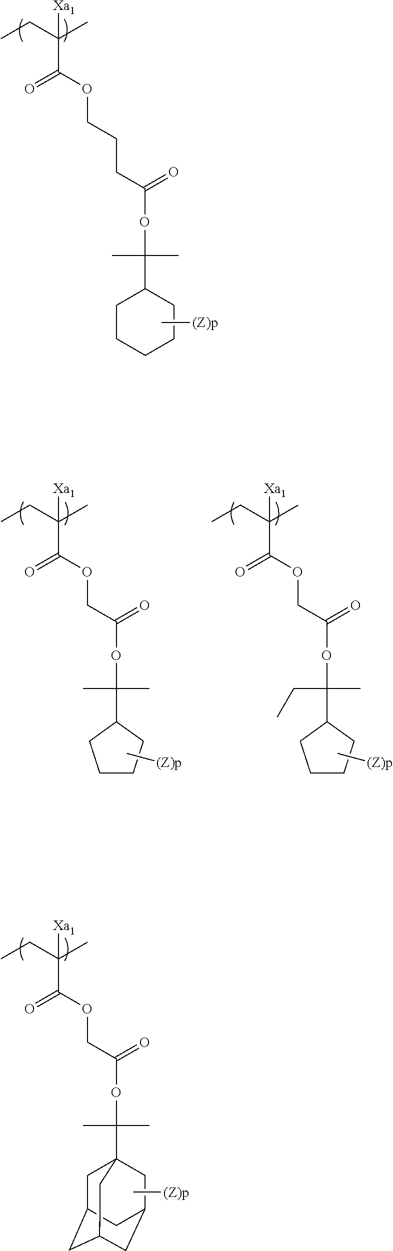

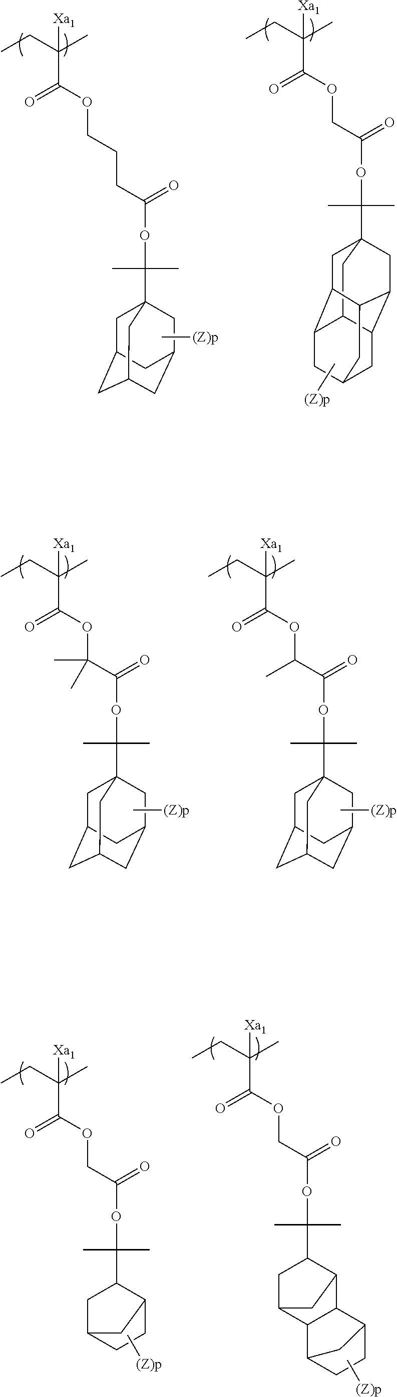

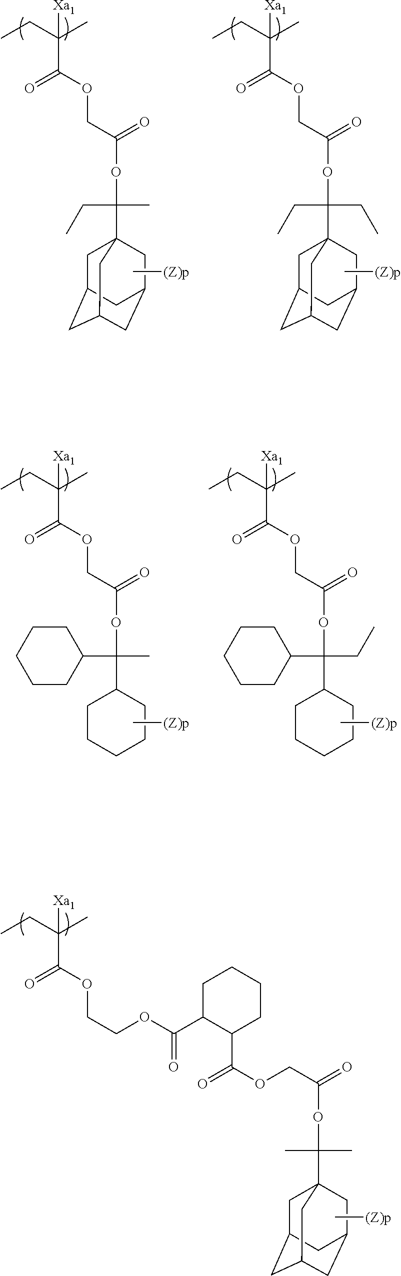

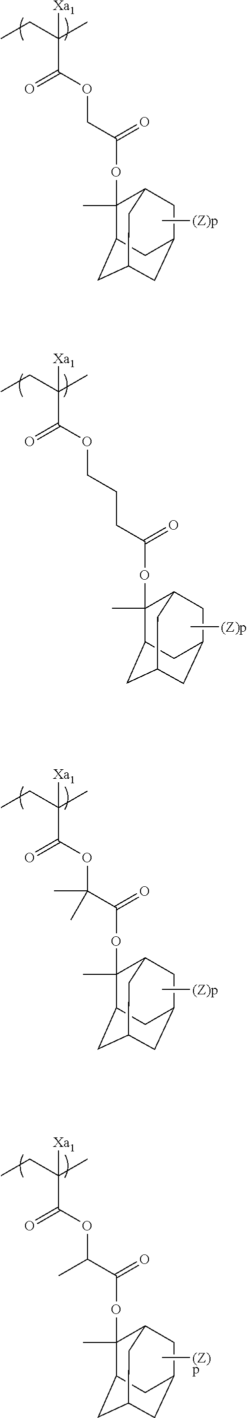

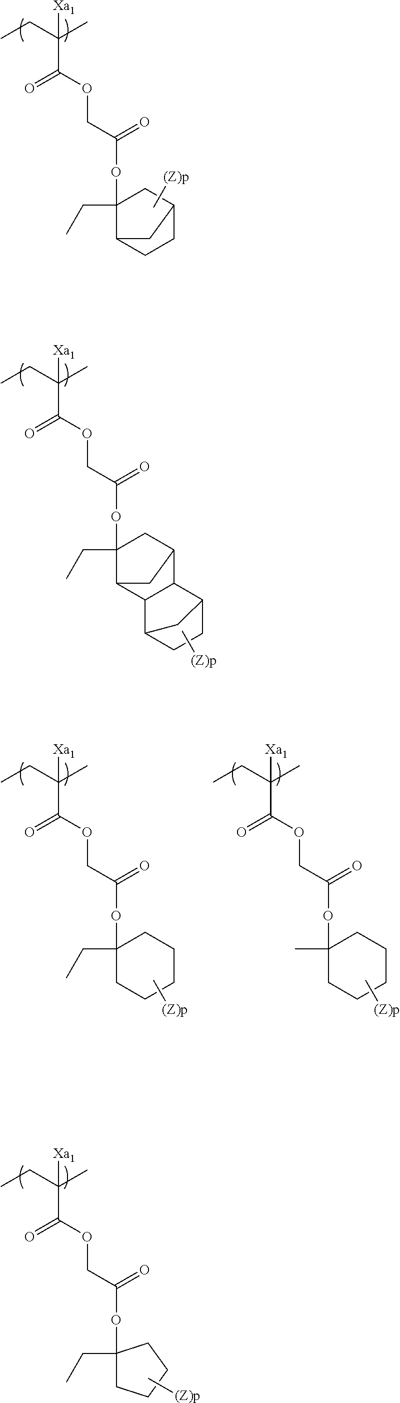

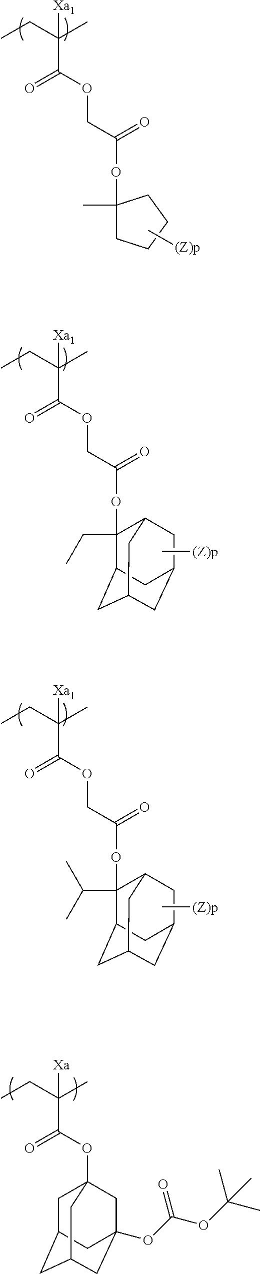

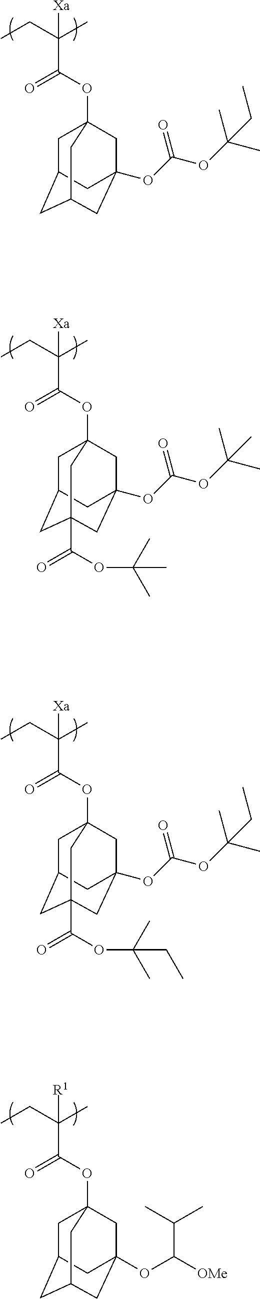

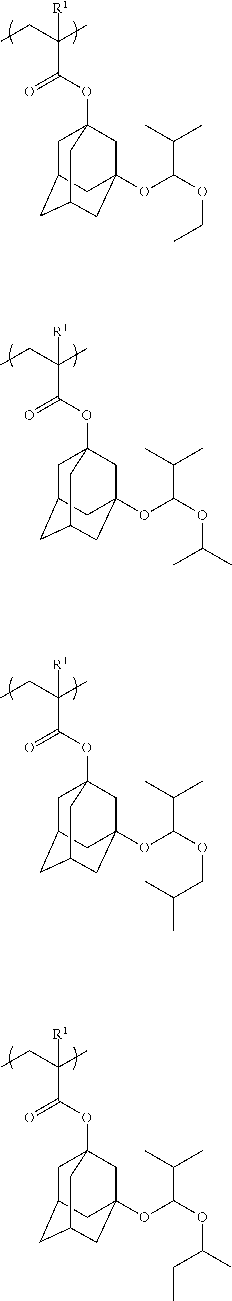

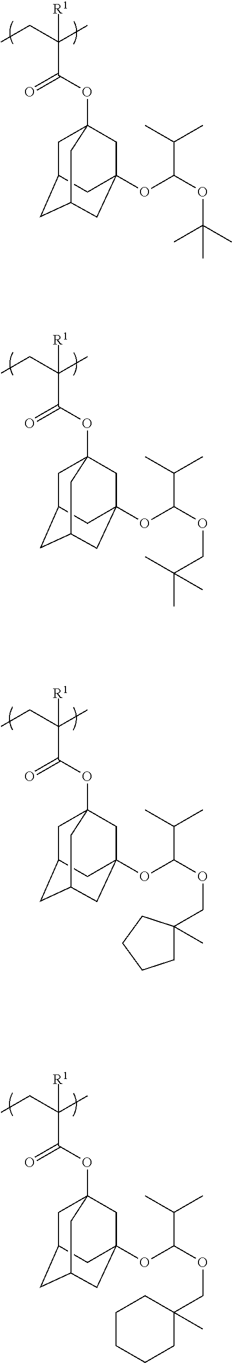

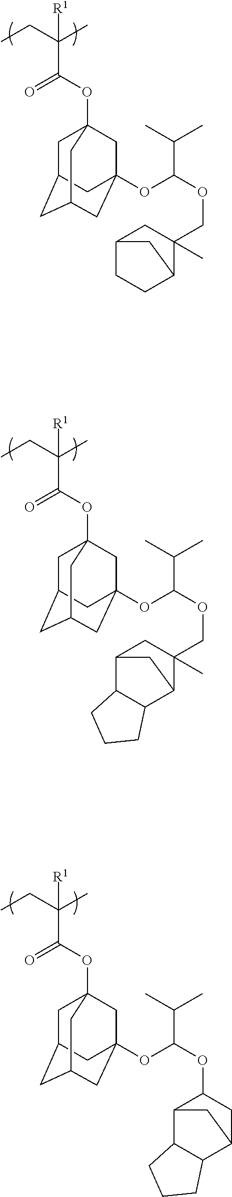

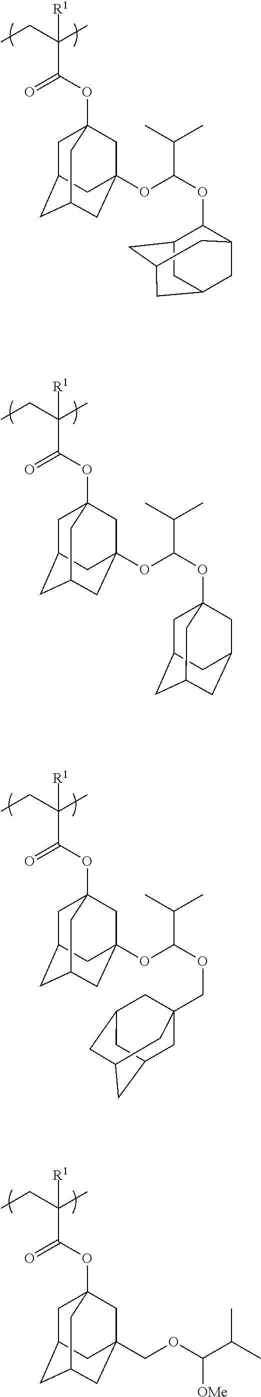

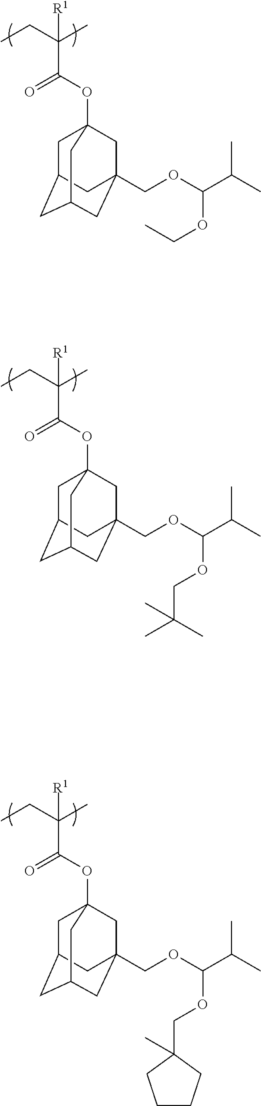

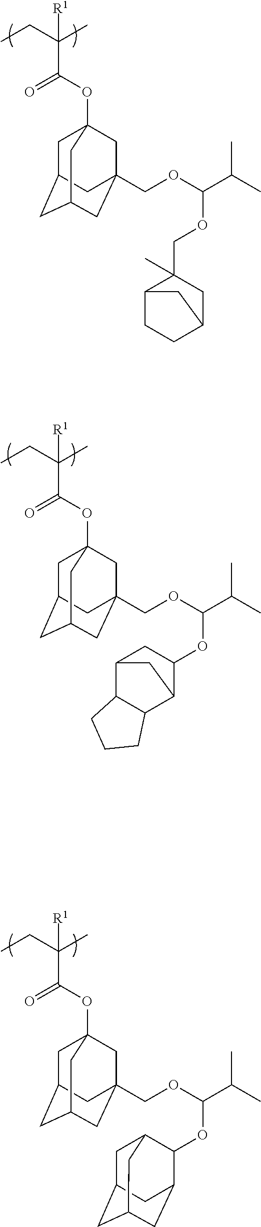

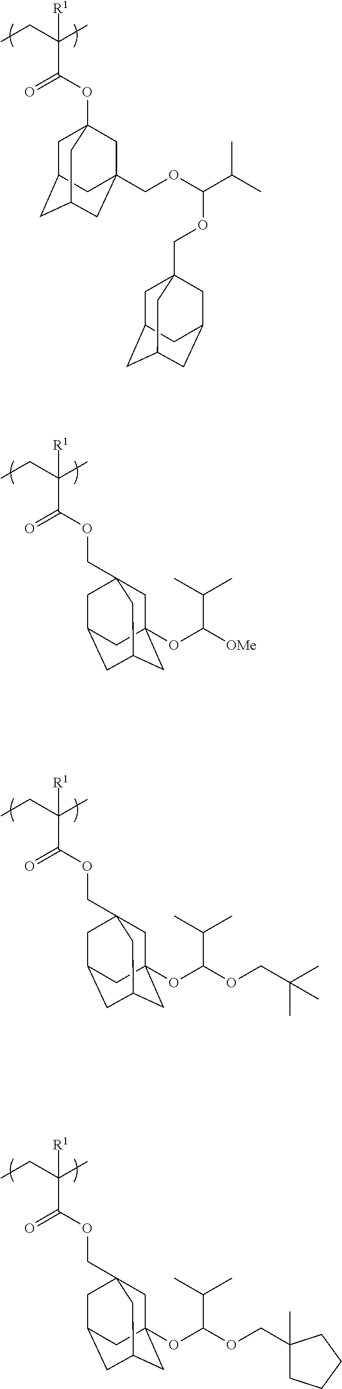

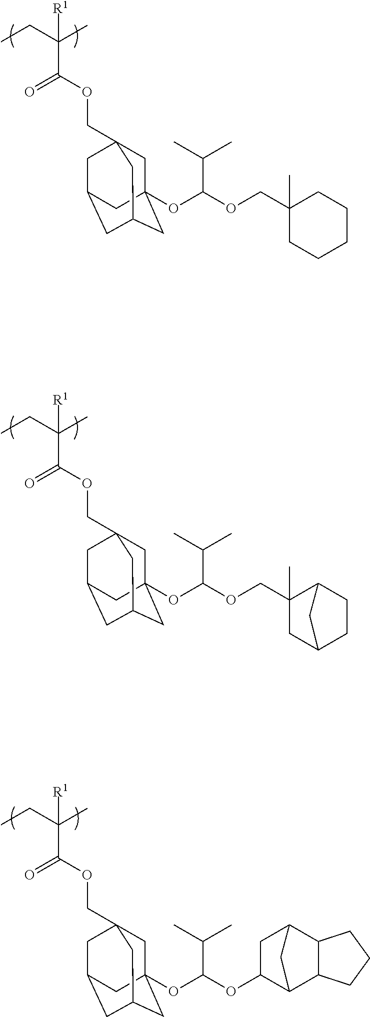

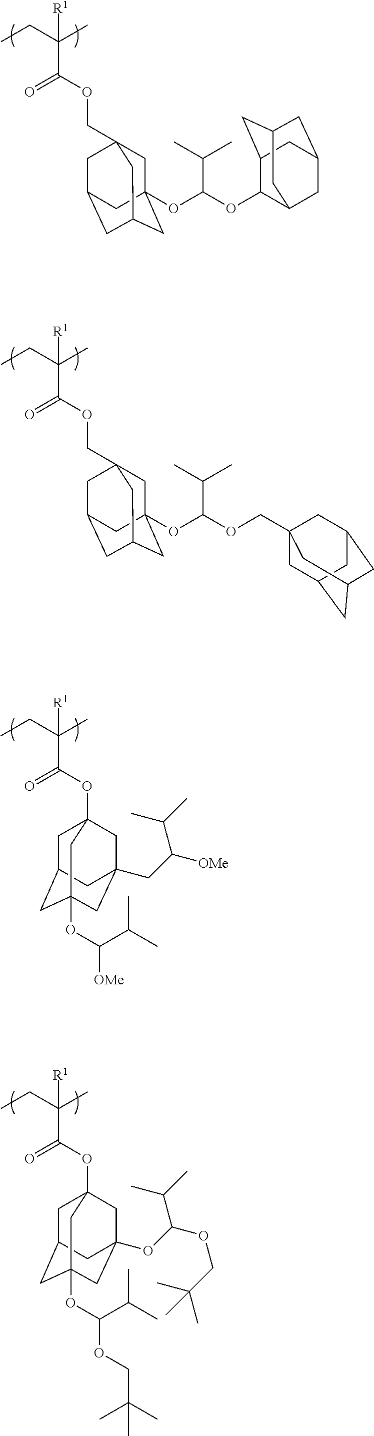

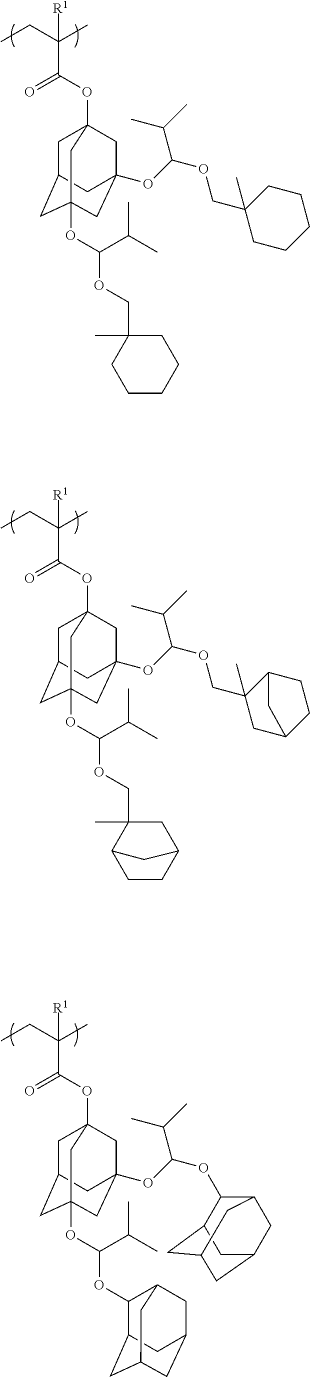

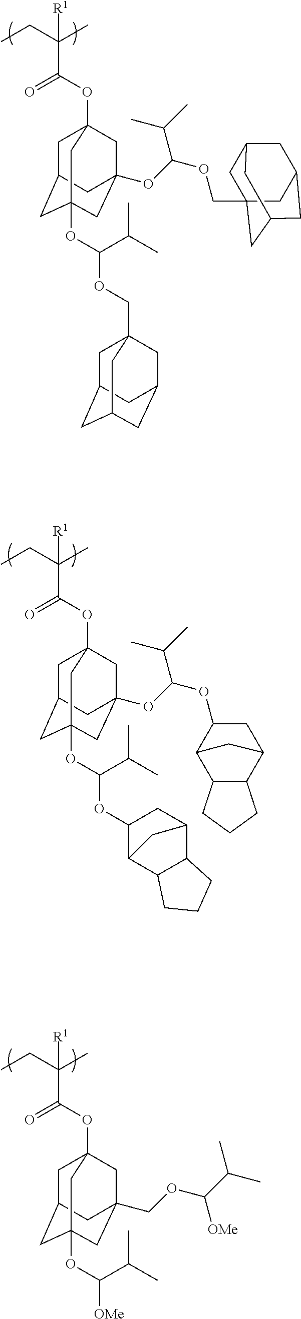

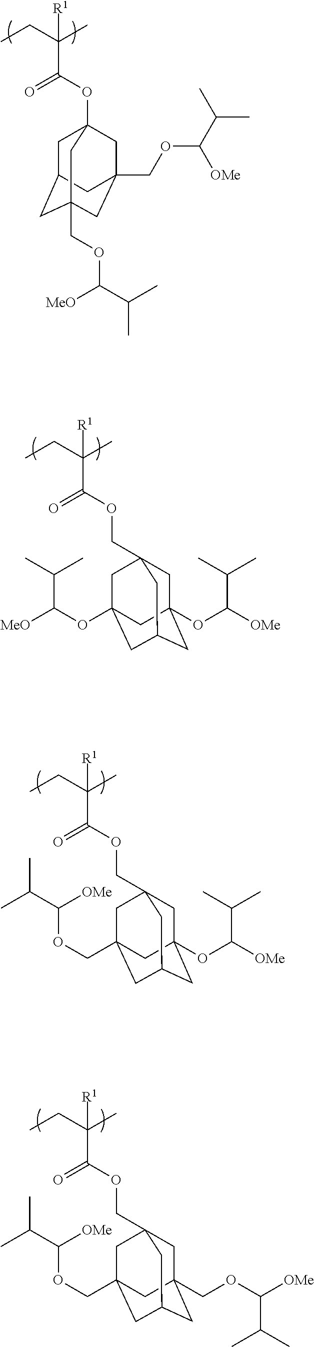

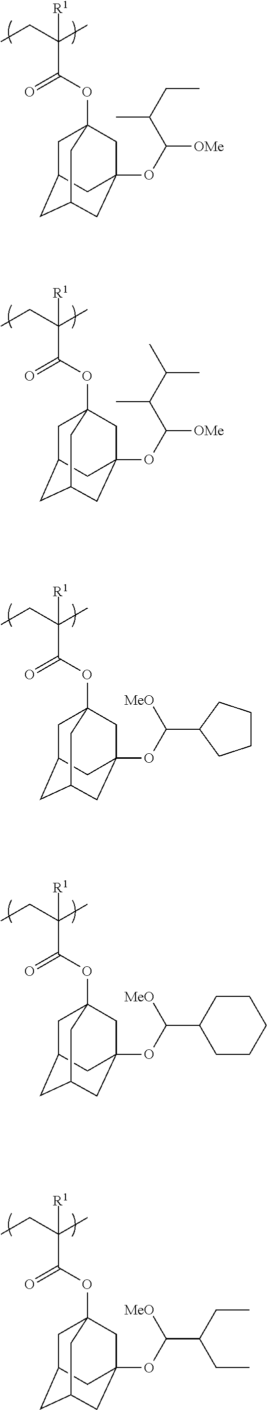

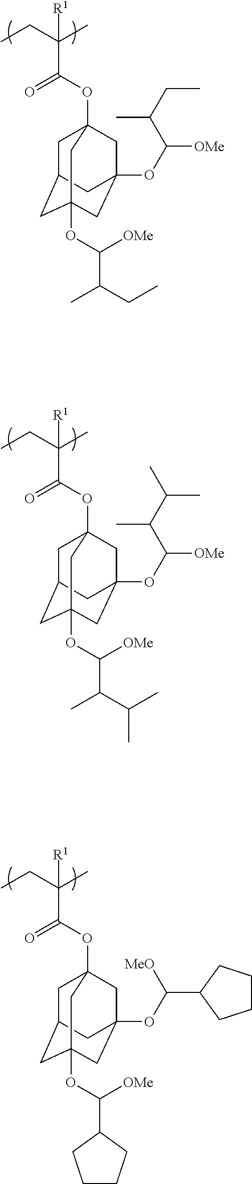

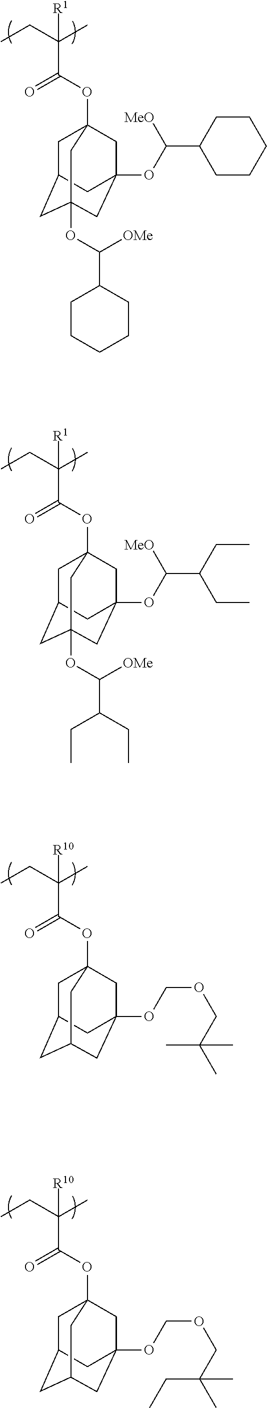

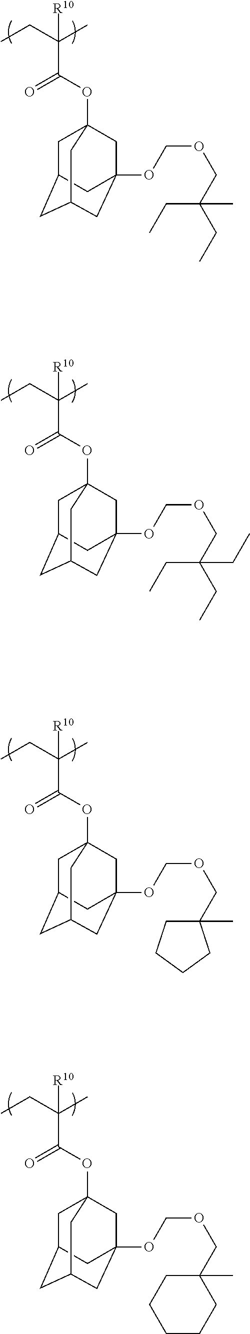

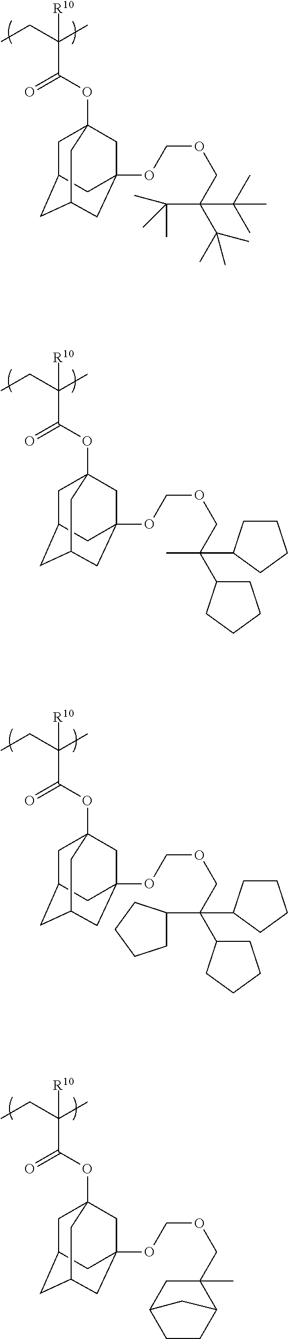

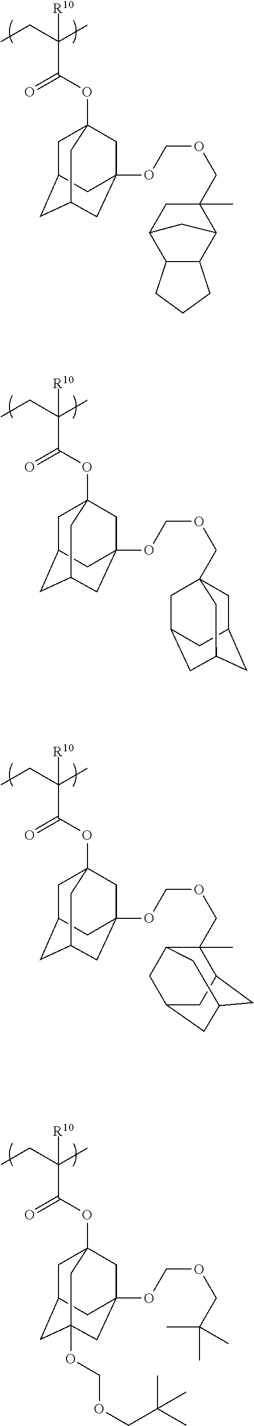

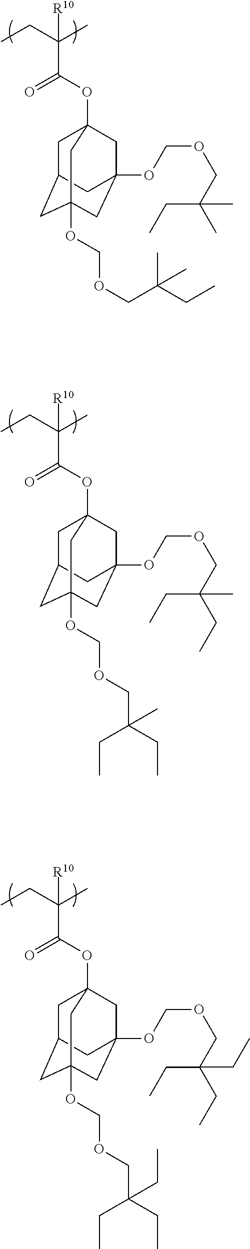

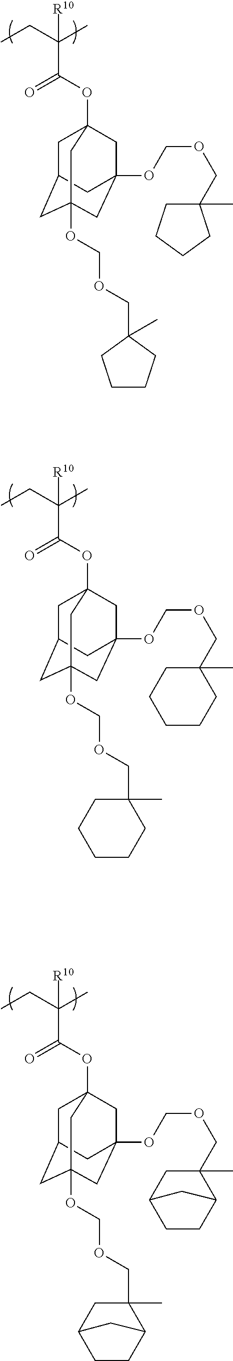

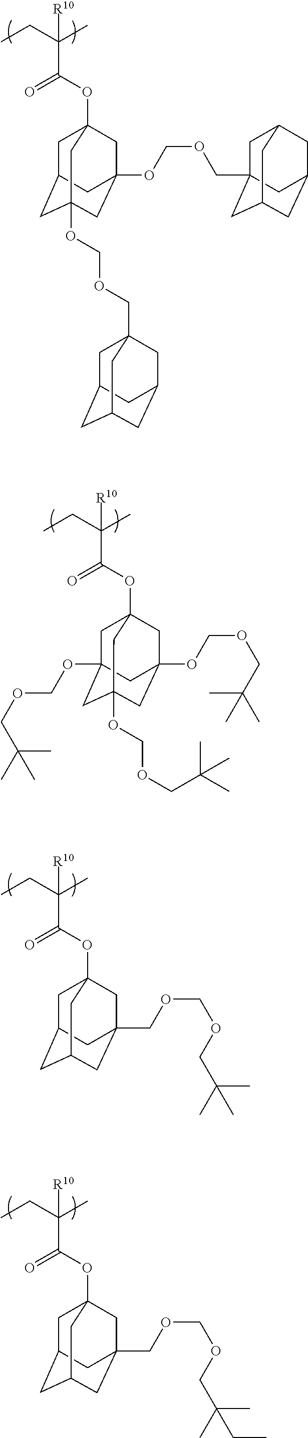

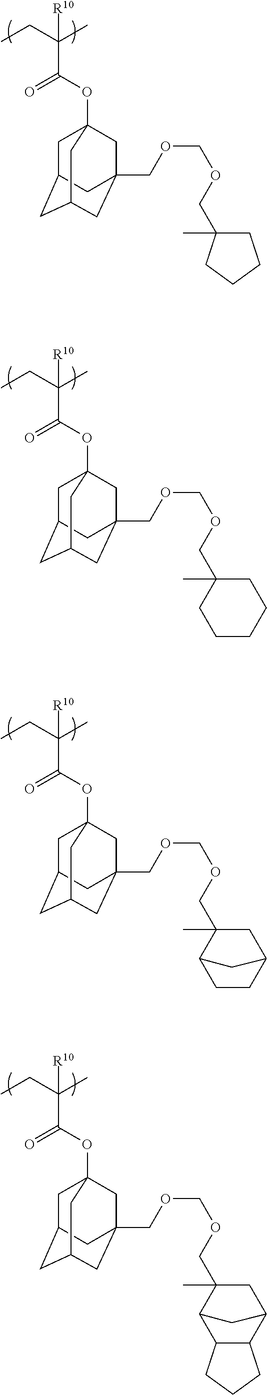

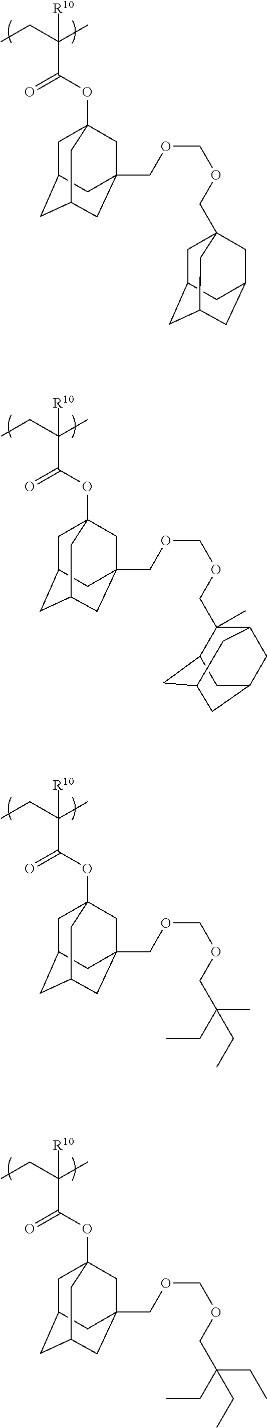

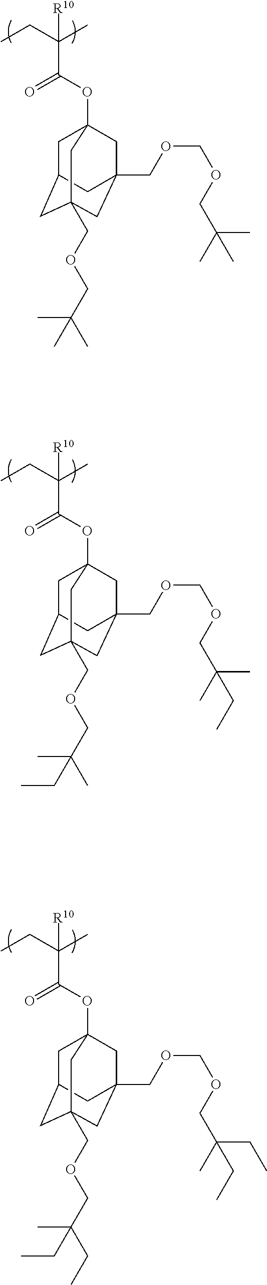

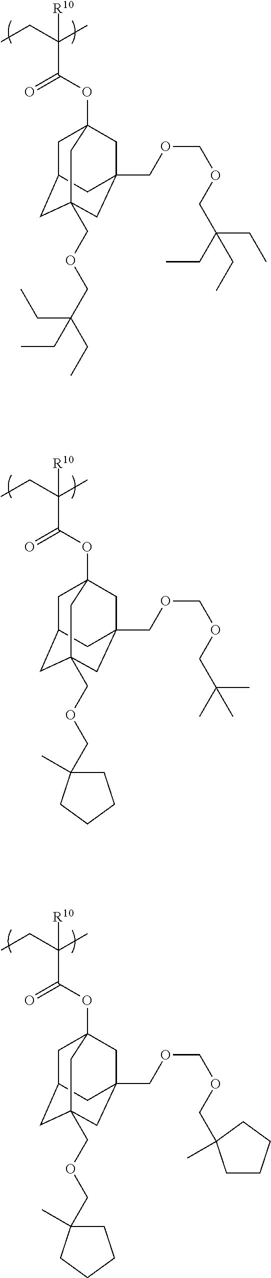

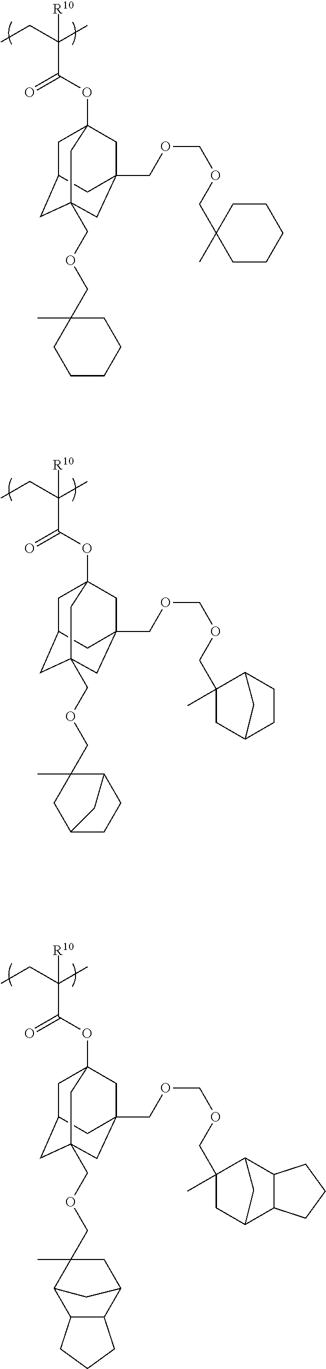

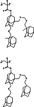

The resin (A) preferably contains a repeating unit having a polar group structure selected from a hydroxyl group, a cyano group, a carbonyl group, an ester group, an ether group, a lactone ring, a carboxyl group, a carboxylic acid anhydride, sulfonate ester, disulfonic acid and carbonate ester, and particularly preferably has a repeating unit having a structure of a lactone ring, a carboxyl group, a cyclic sulfonate ester and a cyclic carbonate ester.

As the lactone structure, any structure having a lactone structure may be used, but a 5- to 7-membered ring lactone structure is preferred, and it is preferred that another ring structure is condensed as a form in which a bicyclo or Spiro structure is formed in a 5- to 7-membered ring lactone structure. It is more preferred that the resin (A) has a repeating unit having a lactone structure represented by any one of the following Formulas (LC1-1) to (LC1-17). Further, the lactone structure may be bonded directly to the main chain. A preferred lactone structure is (LC1-1), (LC1-4), (LC1-5), (LC1-6), (LC1-13), (LC1-14), and (LC1-17), and a particularly preferred lactone structure is (LC 1-4). By using such a specific lactone structure, LWR and development defects are improved.

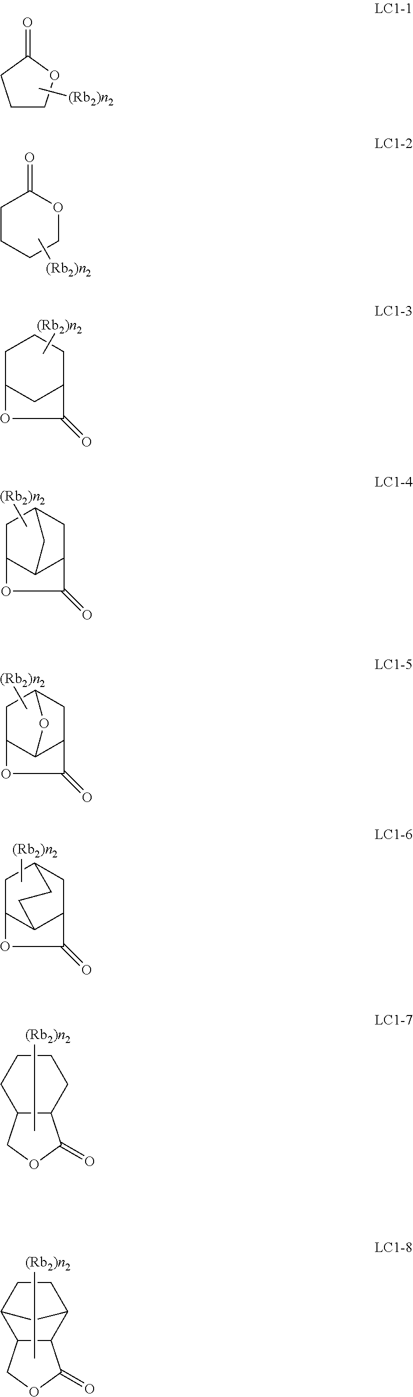

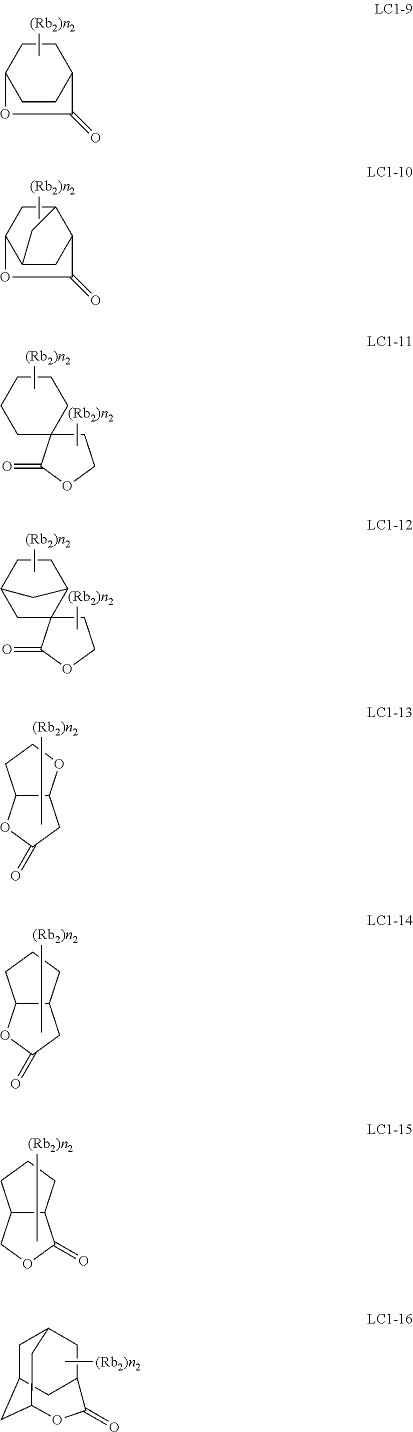

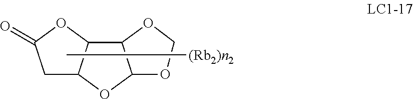

The lactone structure moiety may or may not have a substituent Rb₂. Preferred examples of the substituent Rb₂ may include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, an acid-decomposable group, and the like. An alkyl group having 1 to 4 carbon atoms, a cyano group, and an acid-decomposable group are more preferred. n₂ represents an integer of 0 to 4. When n₂ is 2 or more, substituent Rb₂'s may be the same or different. Further, a plurality of substituents Rb₂ may be bound with each other to form a ring.

The repeating unit having a lactone group usually has an optical isomer, but any optical isomer may be used. In addition, one kind of optical isomer may be used alone, or a plurality of optical isomers may be mixed and used. When one kind of optical isomer is mainly used, the optical purity (ee) is preferably 90% or more, and more preferably 95% or more.

The repeating unit having a lactone structure is preferably a unit represented by the following Formula (III).

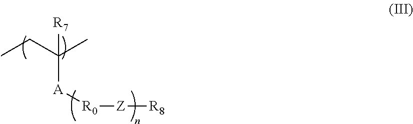

In Formula (III),

A represents an ester bond (a group represented by —COO—) or an amide bond (a group represented by —CONH—).

When a plurality of R₀s is present, each R₀ independently represents an alkylene group, a cycloalkylene group, or a combination thereof.

When a plurality of Z's is present, each Z independently represents a single bond, an ether bond, an ester bond, an amide bond or a urethane bond

(a group represented by

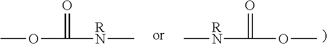

or an urea bond

(a group represented by

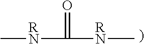

Here, a plurality of R each independently represents a hydrogen atom, an alkyl group, a cycloalkyl group or an aryl group.

R₈ represents a monovalent organic group having a lactone structure.

n is a repeating number of a structure represented by —R₀—Z—, represents an integer of 0 to 5, and is preferably 0 or 1, and more preferably 0. When n is 0, —R₀—Z— is not present, and the structure becomes a single bond.

R₇ represents a hydrogen atom, a halogen atom or an alkyl group.

The alkylene group and the cycloalkylene group of R₀ may have a substituent.

Z is preferably an ether bond or an ester bond, and particularly preferably an ester bond.

The alkyl group of R₇ is preferably an alkyl group having 1 to 4 carbon atoms, more preferably a methyl group and an ethyl group, and particularly preferably a methyl group.

Each of the alkylene group and the cycloalkylene group of R₀ and the alkyl group of R₇ may be substituted, and examples of the substituent may include a halogen atom such as a fluorine atom, a chlorine atom and a bromine atom, a mercapto group, a hydroxyl group, an alkoxy group such as a methoxy group, an ethoxy group, an isopropoxy group, a t-butoxy group and a benzyloxy group, and an acyloxy group such as an acetyloxy group and a propionyloxy group.

R₇ is preferably a hydrogen atom, a methyl group, a trifluoromethyl group and a hydroxymethyl group.

A preferred chain alkylene group in R₀ is preferably a chain alkylene having 1 to 10 carbon atoms, and more preferably 1 to 5 carbon atoms, and examples thereof may include a methylene group, an ethylene group, a propylene group, and the like. A preferred cycloalkylene group is a cycloalkylene group having 3 to 20 carbon atoms, and examples thereof may include a cyclohexylene group, a cyclopentylene group, a norbornylene group, an adamantylene group and the like. In order to exhibit effects of the present invention, a chain alkylene group is more preferred, and a methylene group is particularly preferred.

The monovalent organic group having a lactone structure represented by R₈ is not limited as long as the organic group has a lactone structure, specific examples thereof may include a lactone structure represented by Formulas (LC1-1) to (LC1-17), and among them, a structure represented by (LC1-4) is particularly preferred. Further, n₂ in (LC1-1) to (LC1-17) is more preferably 2 or less.

In addition, R₈ is preferably a monovalent organic group having an unsubstituted lactone structure, or a monovalent organic group having a lactone structure having a methyl group, a cyano group, or an alkoxycarbonyl group as a substituent, and more preferably a monovalent organic group having a lactone structure having a cyano group as a substituent (cyanolactone).

Hereinafter, specific examples of the repeating unit having a group having a lactone structure will be described, but the present is not limited thereto.

(In Formula, Rx represents H, CH₃, CH₂OH or CF₃)

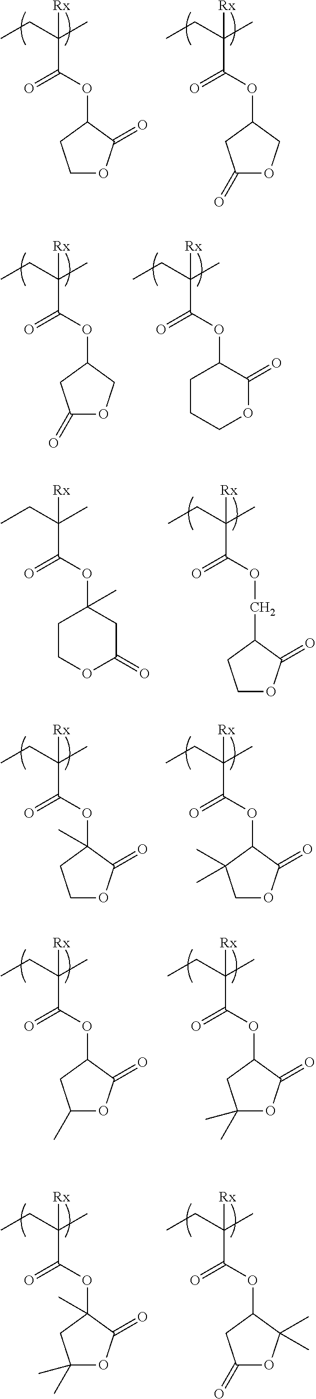

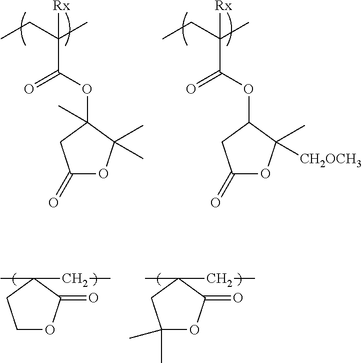

(In Formula, Rx represents H, CH₃, CH₂OH or CF₃)

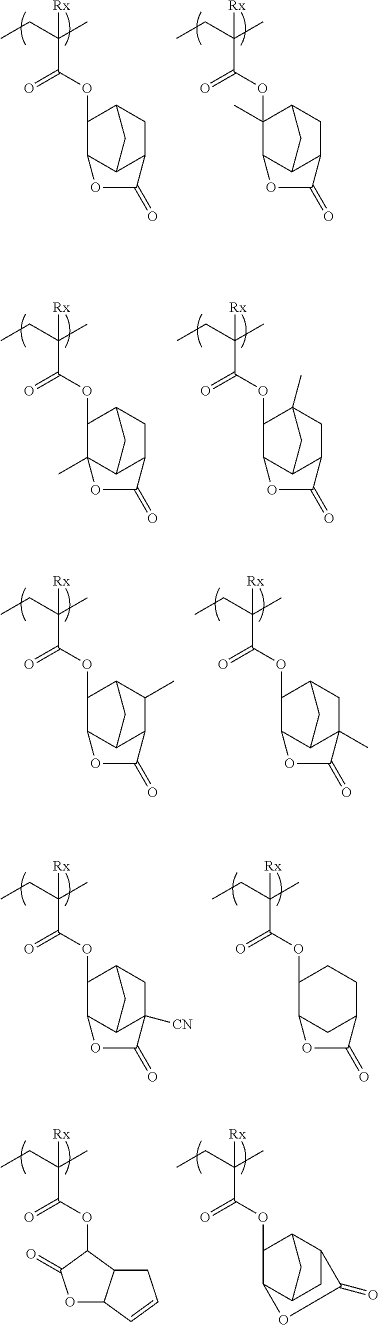

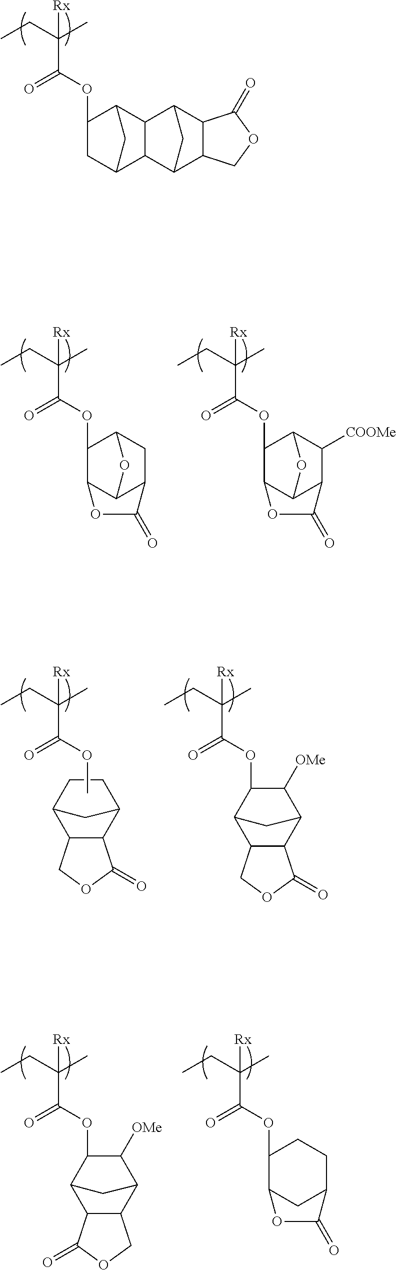

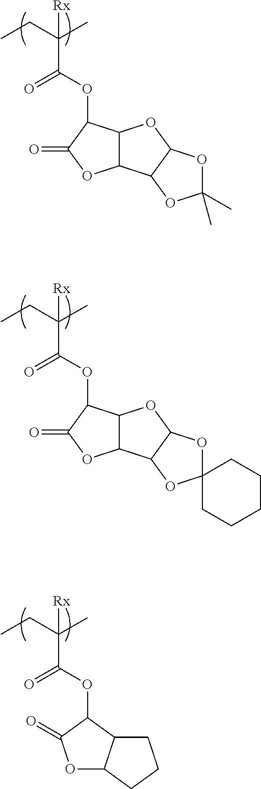

(In Formula, Rx represents H, CH₃, CH₂OH or CF₃)

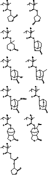

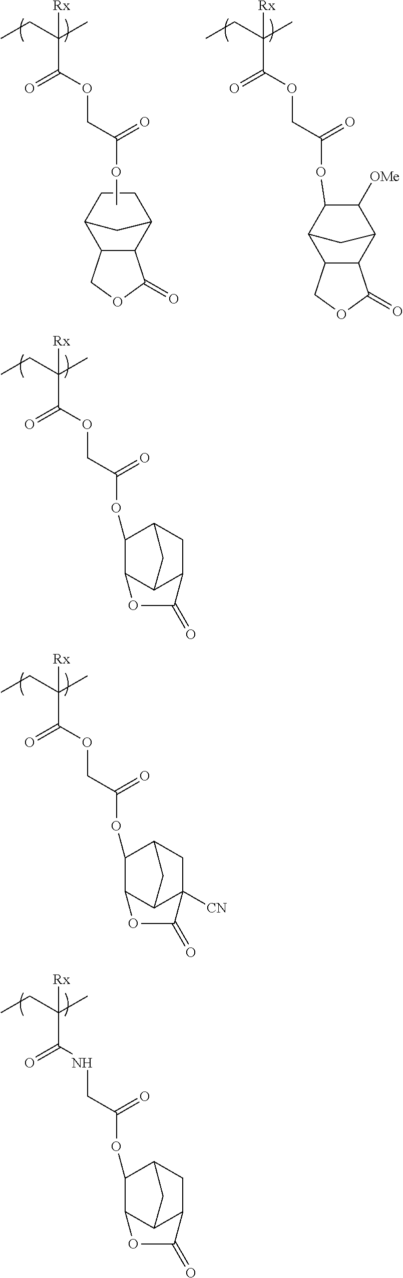

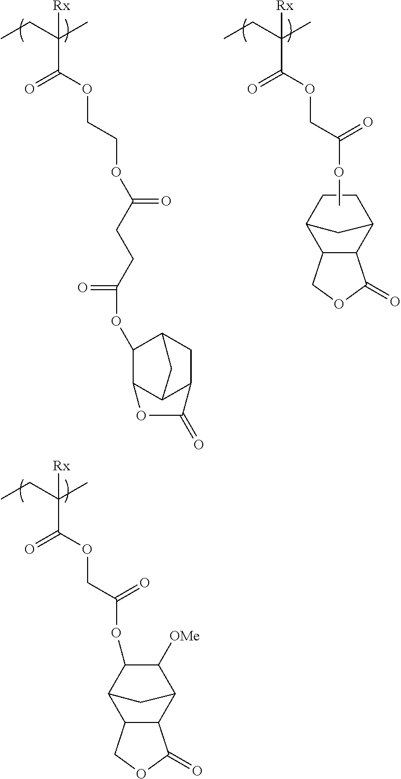

Hereinafter, specific examples of the repeating unit having a carboxyl group will be described, but the present invention is not limited thereto.

Among the following specific examples, Xa represents a hydrogen atom, an alkyl group that may have a substituent, or a halogen atom, and preferably represents a hydrogen atom, a methyl group, a hydroxymethyl group and an acetyloxymethyl group.

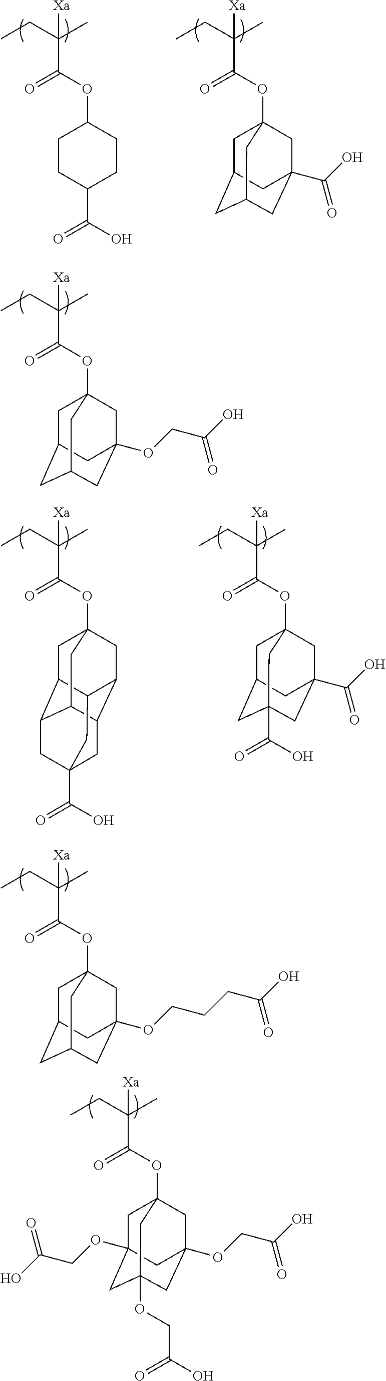

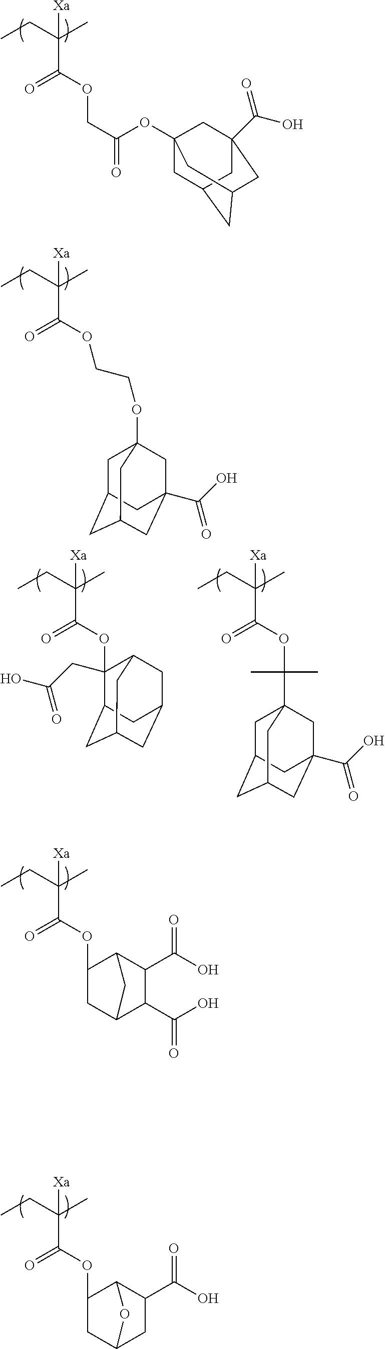

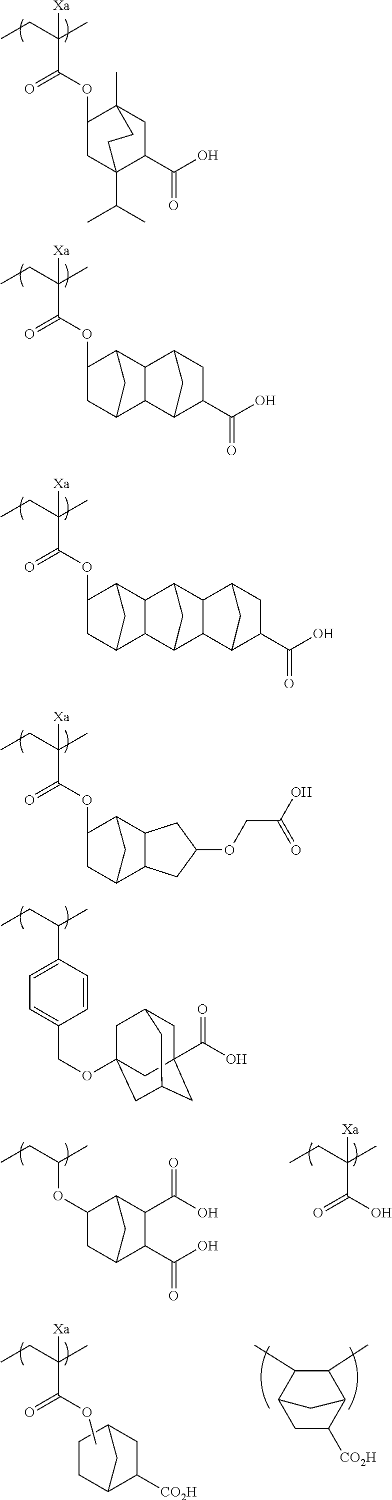

Examples of the cyclic sulfonate ester structure may include a structure represented by the following Formula (S-1) or (S-2).

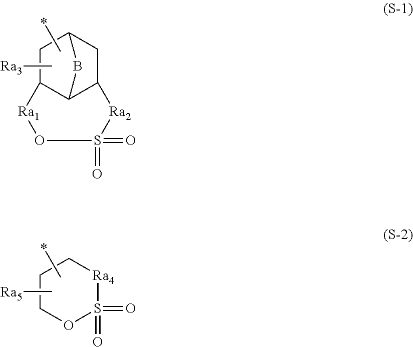

In the formula,

each of Ra₁, Ra₂ and Ra₄ independently represents a single bond, or an alkylene group having 1 to 3 carbon atoms, each of Ra₁ and Ra₅ independently represents a hydrogen atom, an alkyl group, an alkoxy group, a halogenated alkyl group, a hydroxyl group, —COOR″, —OC(═O)R″, a hydroxyalkyl group or a cyano group, and R″ represents a hydrogen atom or an alkyl group.

B represents an alkylene group having 1 to 5 carbon atoms which may contain an oxygen atom (—O—) or a sulfur atom (—S—), an oxygen atom, or a sulfur atom.

The alkylene group having 1 to 5 carbon atoms in B is preferably a straight or branched alkylene group, and examples thereof may include a methylene group, an ethylene group, an n-propylene group, an isopropylene group, and the like.

When the alkylene group includes an oxygen atom or a sulfur atom, specific examples thereof may include a group in which —O— or —S— is interposed at the end of the alkylene group or between carbon atoms, and for example, —O—CH₂—, —CH₂—O—CH₂—, —S—CH₂—, —CH₂—S—CH₂—, and the like.

The repeating unit having a cyclic sulfonate ester structure is preferably a repeating unit represented by the following Formula (IV).

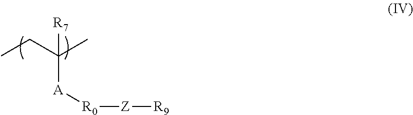

In Formula (IV),

A represents an ester bond (a group represented by —COO—) or an amide bond (a group represented by —CONH—).

R₀ represents an alkylene group, a cycloalkylene group or a combination thereof.

Z represents a single bond, an ether bond, an ester bond, an amide bond, a urethane bond

(a group represented by

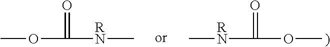

or an urea bond

(a group represented by

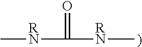

Here, a plurality of R each independently represents a hydrogen atom, an alkyl group, a cycloakyl group or an aryl group.

R₇ represents a hydrogen atom, a halogen atom or an alkyl group.

R₇ is preferably a hydrogen atom, a methyl group, a trifluoromethyl group or a hydroxymethyl group.

R₉ represents a monovalent organic group having a cyclic sulfonate ester structure.

Hereinafter, specific examples of the repeating unit having a cyclic sulfonate ester structure will be described, but the present invention is not limited thereto.

Among the following specific examples, Xa represents a hydrogen atom, an alkyl group that may have a substituent or a halogen atom, and preferably represents a hydrogen atom, a methyl group, a hydroxymethyl group and an acetyloxymethyl group.

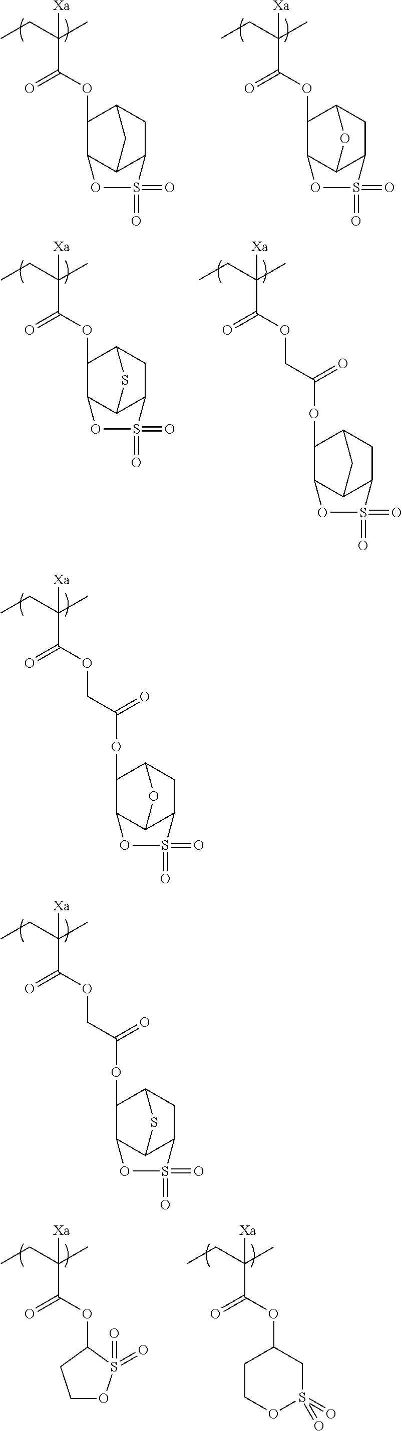

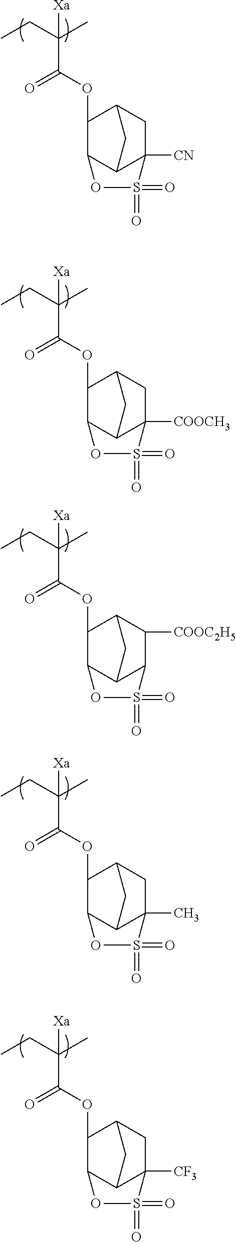

Examples of a group having a cyclic carbonate ester structure may include a group represented by Formula (1-7a) or (1-7b), and the like.

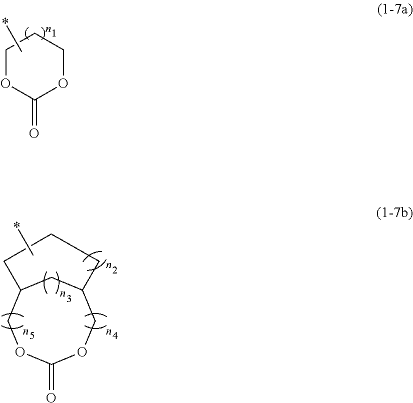

In Formula (1-7a), n₁ represents an integer of 0 to 2.

In Formula (1-7b), each of n₂ to n₅ independently represents an integer of 0 to 2.

In Formulas (1-7a) and (1-7b), “*” represents a bonding hand. In addition, the groups represented by Formulas (1-7a) and (1-7b) may have a substituent.

Preferred examples of the group represented by Formula (1-7a) or (1-7b) may include those represented by the following Formula (1-7aa) or (1-7bb).

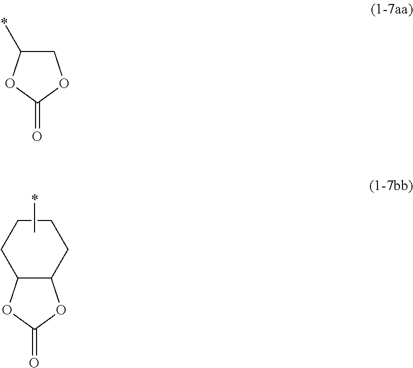

In Formulas (1-7aa) and (1-7bb), “*” represents a bonding hand.

Specific examples of the repeating unit having a cyclic carbonate ester structure will be described, but the present invention is not limited thereto.

Among the following specific examples, Xa represents a hydrogen atom, an alkyl group that may have a substituent or a halogen atom, and preferably represents a hydrogen atom, a methyl group, a hydroxymethyl group or an acetyloxymethyl group.

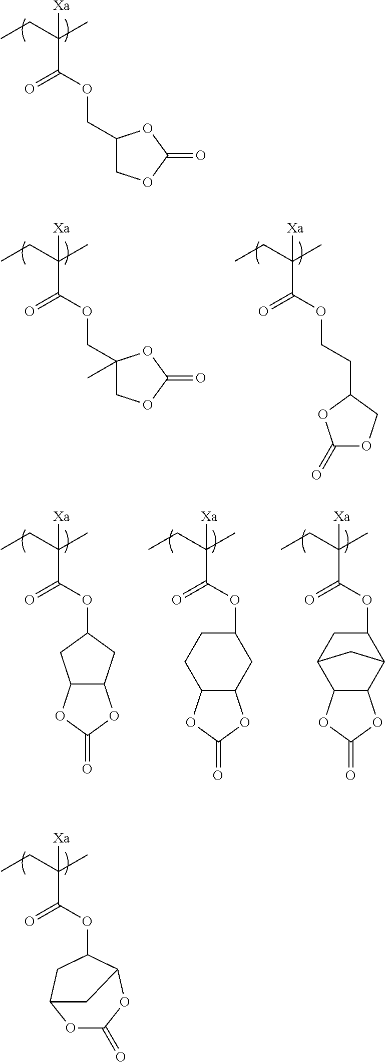

The content of the repeating unit having the polar group structure is preferably 10 mol % to 65 mol %, more preferably 15 mol % to 60 mol %, and still more preferably 20 mol % to 55 mol %, based on all the repeating units in the resin (A).

The resin (A) may have a repeating unit having a hydroxyl group or a cyano group other than the repeating unit represented by Formula (III). Accordingly, adhesion to substrate and affinity for developer are improved. The repeating unit having a hydroxyl group or a cyano group is preferably a repeating unit having an alicyclic hydrocarbon structure substituted with a hydroxyl group or a cyano group, and preferably has no acid-decomposable group. In the alicyclic hydrocarbon structure substituted with a hydroxyl group or a cyano group, the alicyclic hydrocarbon structure is preferably an adamantyl group, a diamantyl group and a norbornane group. A preferred alicyclic hydrocarbon structure substituted with a hydroxyl group or a cyano group is preferably a partial structure represented by the following Formulas (VIIa) to (VIId).

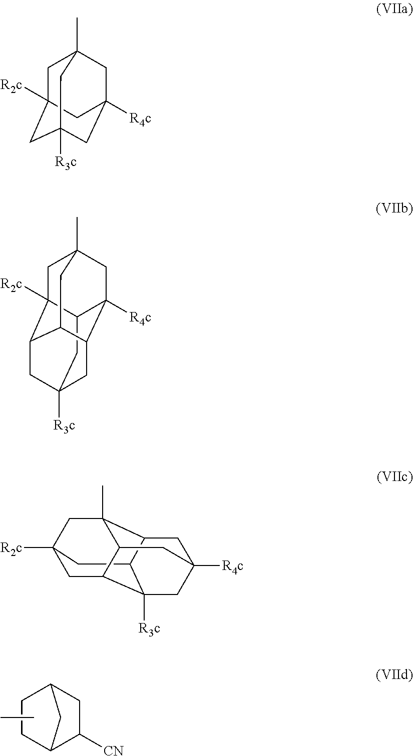

In Formulas (VIIa) to (VIIc),

each of R_{2c} to R_{4c} independently represents a hydrogen atom, a hydroxyl group or a cyano group, provided that at least one of R_{2c} to R_{4c} represents a hydroxyl group or a cyano group. It is preferred that one or two of R_{2c} to R_{4c} are a hydroxyl group with the remaining being a hydrogen atom. In Formula (VIIa), it is more preferred that two of R_{2c} to R_{4c} are a hydroxyl group with the remaining being a hydrogen atom.

Examples of the repeating unit having a partial structure represented by Formulas (VIIa) to (VIId) may include a repeating unit represented by the following Formulas (AIIa) to (AIId).

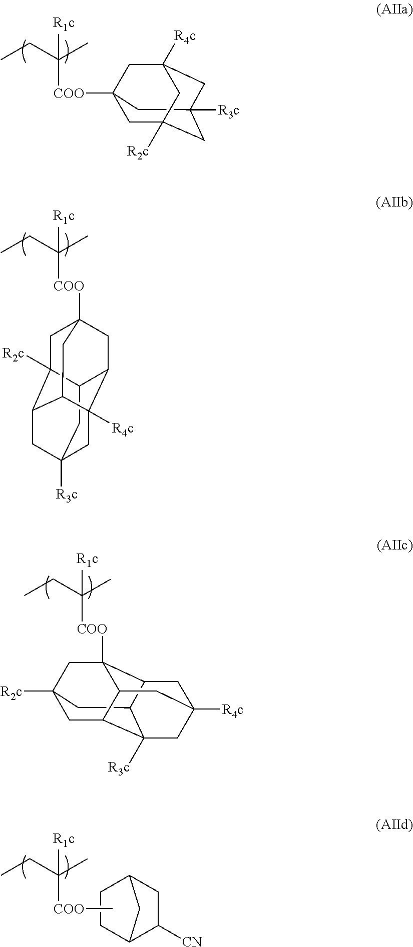

In Formulas (AIIa) to (AIId),

R_{1c} represents a hydrogen atom, a methyl group, a trifluoromethyl group or a hydroxymethyl group.

R_{2c} to R_{4c} have the same meaning as R_{2c} to R_{4c} in Formulas (VIIa) to (VIIc).

When the resin (A) contains a repeating having a hydroxyl group or a cyano group, the content of the repeating unit having a hydroxyl group or a cyano group is preferably 5 mol % to 40 mol %, more preferably 5 mol % to 30 mol %, and still more preferably 10 mol % to 30 mol %, based on all the repeating units in the resin (A).

Specific examples of the repeating unit having a hydroxyl group or a cyano group will be described below, but the present invention is not limited thereto.

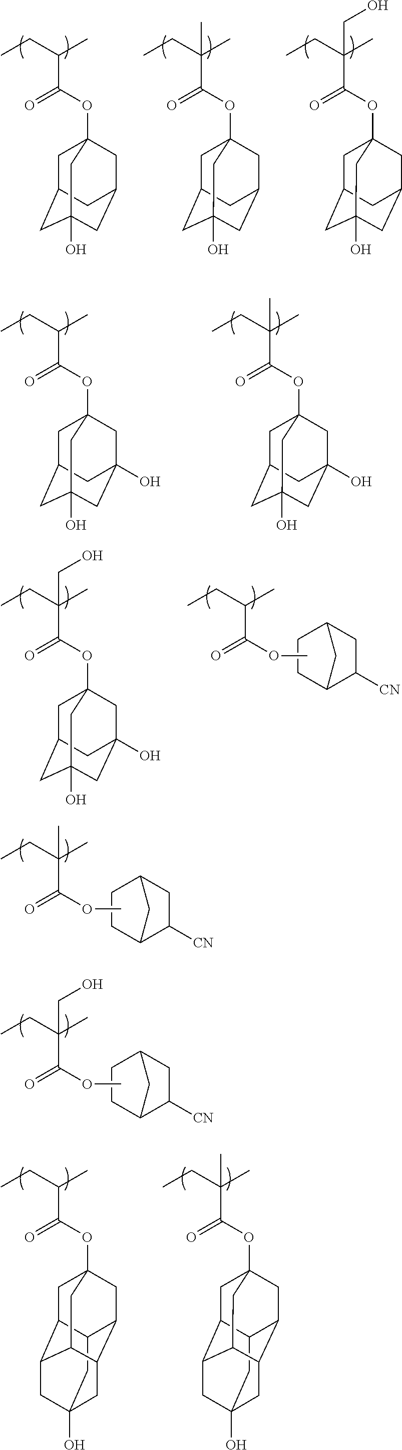

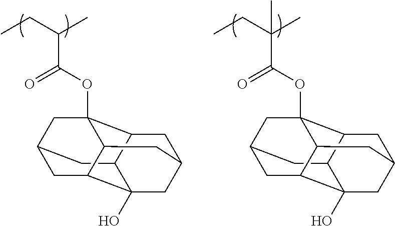

The resin (A) may have a repeating unit having an acid group. Examples of the acid group may includes a carboxyl group, a sulfonamide group, a sulfonylimide group, a bissulfonylimide group and an aliphatic alcohol which is substituted with an electron-withdrawing group at an α-position (for example, a hexafluoroisopropanol group), and it is more preferred that the resin has a repeating unit having a carboxyl group. By containing a repeating unit having an acid group, the resolution increases in the usage of contact holes. As for the repeating unit having an acid group, a repeating unit in which the acid group is directly bonded to the main chain of the resin, such as repeating unit by an acrylic acid or a methacrylic acid or a repeating unit in which the acid group is bonded to the main chain of the resin through a linking group, and a repeating unit which is introduced into the end of the polymer chain by using a polymerization initiator having an acid group or a chain transfer agent at the time of polymerization are all preferred, and the linking group may have a monocyclic or polycyclic cyclic hydrocarbon structure. A repeating unit by an acrylic acid or a methacrylic acid is particularly preferred.

The resin (A) may or may not contain a repeating unit having an acid group, but in the case of containing a repeating unit having an acid group, the content of the repeating unit having an acid group is preferably 25 mol % or less, and more preferably 20 mol % or less, based on all the repeating units in the resin (A). When the resin (A) contains a repeating unit having an acid group, the content of the repeating unit having an acid group in the resin (A) is usually 1 mol % or more.

Specific examples of the repeating unit having an acid group will be described below, but the present invention is not limited thereto.

In the specific examples, Rx represents H, CH₃, CH₂OH or CF₃.

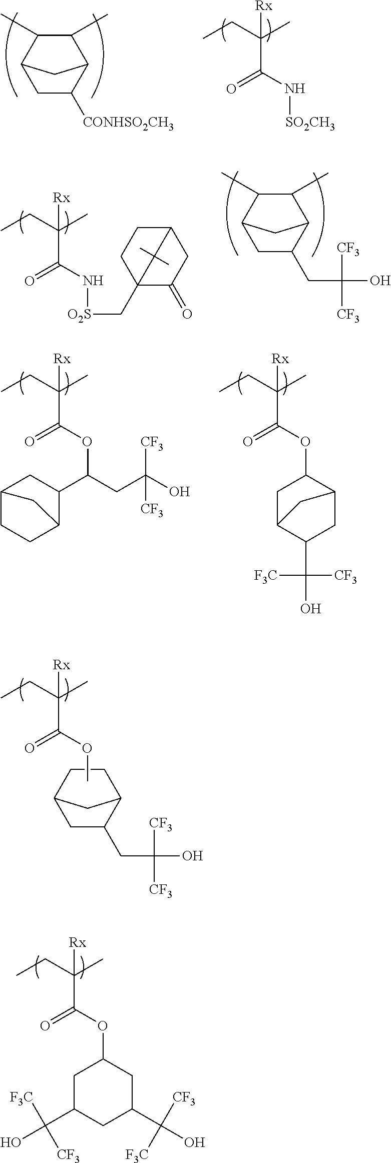

The resin (A) of the present invention may have a repeating unit having an alicyclic hydrocarbon structure having no polar group (for example, the acid group, the hydroxyl group, and the cyano group) and not exhibiting acid decomposability. Accordingly, elution of low molecular components from the resist film into the liquid for immersion during the immersion exposure may be reduced, and further, the solubility of the resin during the development using a developer containing an organic solvent may be appropriately adjusted. Examples of the repeating unit may include a repeating unit represented by Formula (IV).

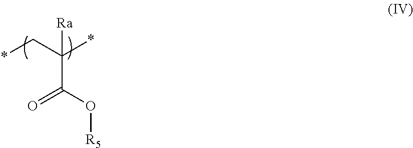

In Formula (IV), R₅ represents a hydrocarbon group having at least one cyclic structure and having no polar group.

Ra represents a hydrogen atom, an alkyl group or a —CH₂—O—Ra₂ group. In the formula, Ra₂ represents a hydrogen atom, an alkyl group or an acyl group. Ra is preferably a hydrogen atom, a methyl group, a hydroxymethyl group and a trifluoromethyl group, and particularly preferably a hydrogen atom and a methyl group.

The cyclic structure that R₅ has includes a monocyclic hydrocarbon group and a polycyclic hydrocarbon group. Examples of the monocyclic hydrocarbon group may include a cycloalkyl group having 3 to 12 carbon atoms, such as a cyclopentyl group, a cyclohexyl group, a cycloheptyl group and a cyclooctyl group, and a cycloalkenyl group having 3 to 12 carbon atoms, such as a cyclohexenyl group. The monocyclic hydrocarbon group is preferably a monocyclic hydrocarbon group having 3 to 7 carbon atoms, and more preferably a cyclopentyl group or a cyclohexyl group.

The polycyclic hydrocarbon group includes a ring assembly hydrocarbon group and a crosslinked cyclic hydrocarbon group, and examples of the ring assembly hydrocarbon group may include a bicyclohexyl group, a perhydronaphthalenyl group and the like. Examples of the crosslinked cyclic hydrocarbon ring may include a bicyclic hydrocarbon ring such as a pinane ring, a bornane ring, a norpinane ring, a norbornane ring and a bicyclooctane ring (a bicyclo[2.2.2]octane ring, a bicyclo[3.2.1]octane ring and the like), a tricyclicydrocarbon ring such as a homobledane ring, an adamantine ring, a tricyclo[5.2.1.0^{2,6}]decane ring and a tricyclo[4.3.1.1^{2,5}]undecane ring, a tetracyclic hydrocarbon ring such as a tetracyclo[4.4.0.1^{2,5}.1^{7,10}]dodecane ring and a perhydro-1,4-methano-5,8-methanonaphthalene ring, and the like. Further, the crosslinked cyclic hydrocarbon ring also includes a condensed cyclic hydrocarbon ring, for example, a condensed ring obtained by condensing a plurality of 5- to 8-membered cycloalkane rings, such as a perhydronaphthalene (decalin) ring, a perhydroanthracene ring, a perhydrophenanthrene ring, a perhydroacenaphthene ring, a perhydrofluorene ring, a perhydroindene ring and a perhydrophenalene ring.

Preferred examples of the crosslinked cyclic hydrocarbon ring may include a norbornyl group, an adamantyl group, a bicyclooctanyl group, a tricyclo[5,2,1,0^{2,6}]decanyl group and the like. More preferred examples of the crosslinked cyclic hydrocarbon ring may include a norbornyl group and an adamantyl group.

The alicyclic hydrocarbon groups may have a substituent, and preferred examples of the substituent may include a halogen atom, an alkyl group, a hydroxyl group with a hydrogen atom being substituted, an amino group with a hydrogen atom being substituted and the like. Preferred examples of the halogen atom may include a bromine atom, a chlorine atom and a fluorine atom, and preferred examples of the alkyl group may include a methyl group, an ethyl group, a n-butyl group and a t-butyl group. The above-described alkyl group may further have a substituent, and examples of the substituent, which the alkyl group may further have, may include a halogen atom, an alkyl group, a hydroxyl group with a hydrogen atom being substituted, and an amino group with a hydrogen atom being substituted.

Examples of the substituent for hydrogen atom may include an alkyl group, a cycloalkyl group, an aralkyl group, a substituted methyl group, a substituted ethyl group, an alkoxycarbonyl group, and an aralkyloxycarbonyl group. Preferred examples of the alkyl group may include an alkyl group having 1 to 4 carbon atoms, preferred examples of the substituted methyl group may include a methoxymethyl group, a methoxythiomethyl group, a benzyloxymethyl group, a t-butoxymethyl group, and a 2-methoxyethoxymethyl group, examples of the substituted ethyl group may include a 1-ethoxy ethyl group and a 1-methyl-1-methoxyethyl group, preferred examples of the acyl group may include an aliphatic acyl group having 1 to 6 carbon atoms, such as a formyl group, an acetyl group, a propionyl group, a butyryl group, an isobutyryl group, a valeryl group and a pivaloyl group, and examples of the alkoxycarbonyl group may include an alkoxycarbonyl group having 1 to 4 carbon atoms and the like.

The resin (A) may or may not contain a repeating unit having a polar group-free alicyclic hydrocarbon structure and not exhibiting acid decomposability, but in the case of containing the repeating unit, the content ratio of the repeating unit is preferably 1 mol % to 50 mol %, and more preferably 10 mol % to 50 mol %, based on all the repeating units in the resin (A).

Specific examples of the repeating unit having a polar group-free alicyclic hydrocarbon structure and not exhibiting acid decomposability will be described below, but the present invention is not limited thereto. In the formula, Ra represents H, CH₃, CH₂OH or CF₃.

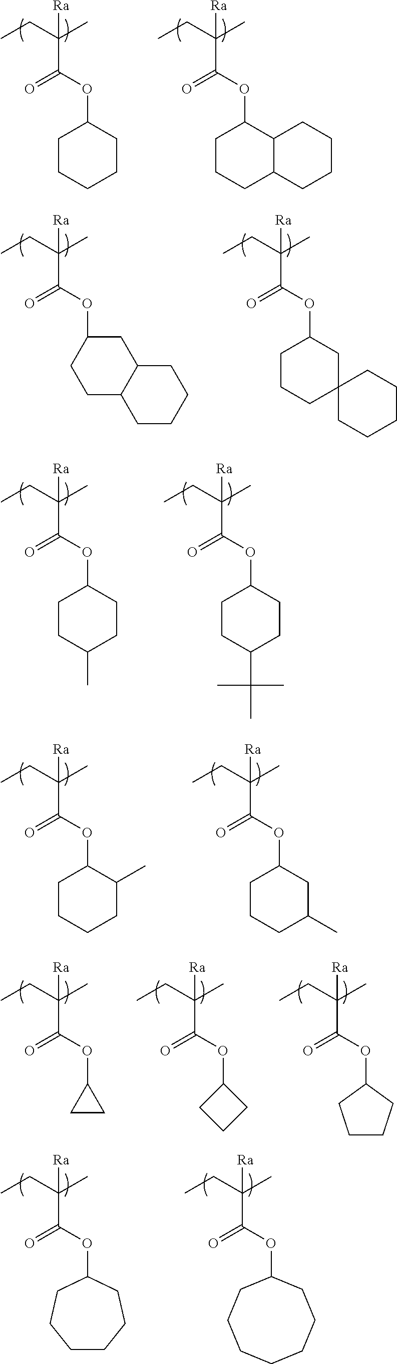

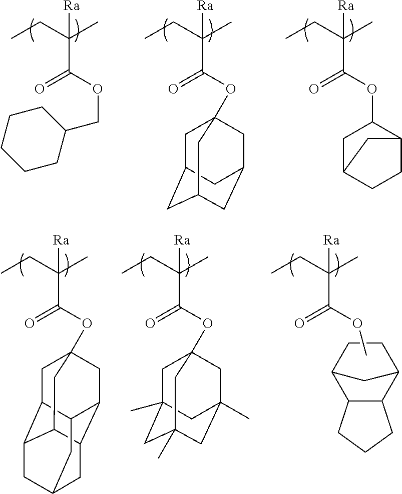

The resin (A) used in the composition of the present invention may have, in addition to the above-described repeating structural units, various repeating structural units for the purpose of controlling the dry etching resistance, suitability for a standard developer, adhesion to a substrate, and resist profile, and further, resolution, heat resistance, sensitivity and the like, which are properties generally required for an actinic ray-sensitive or radiation-sensitive resin composition.

Examples of the repeating structural units may include repeating structural units corresponding to the monomers described below, but are not limited thereto.

Accordingly, the performance required for the resin used in the composition of the present invention, particularly

(1) solubility for a coating solvent,

(2) film-forming property (glass transition temperature),

(3) alkali developability,

(4) film reduction (selection of a hydrophilic, hydrophobic or alkali-soluble group),

(5) adhesion of unexposed portion to substrate, and

(6) dry etching resistance, and the like may be finely adjusted.

Examples of the monomer may include a compound having one addition-polymerizable unsaturated bond selected from acrylate esters, methacrylate esters, acrylamides, methacrylamides, allyl compounds, vinyl ethers, vinyl esters and the like, and the like.

Other than these, an addition-polymerizable unsaturated compound that is copolymerizable with the monomers corresponding to the above-described various repeating structural units may be copolymerized.

In the resin (A) used in the composition of the present invention, the molar ratio of respective repeating structural units contained is appropriately set in order to control dry etching resistance, suitability for a standard developer, adhesion to a substrate, and resist profile of the actinic ray-sensitive or radiation-sensitive resin composition, and further, resolution, heat resistance, sensitivity and the like which are performances generally required for the actinic ray-sensitive or radiation-sensitive resin composition.

When the composition of the present invention is for ArF exposure, from the viewpoint of transparency to ArF light, the resin (A) used in the composition of the present invention preferably has substantially no aromatic ring (specifically, the ratio of a repeating unit having an aromatic group in the resin is preferably 5 mol % or less, more preferably 3 mol % or less, and ideally 0 mol %, that is, the resin does not have an aromatic group), and the resin (A) preferably has a monocyclic or polycyclic alicyclic hydrocarbon structure.

The form of the resin (A) in the present invention may be any form of a random type, a block type, a comb type, and a star type. The resin (A) may be synthesized, for example, by polymerization of radicals, cations, or anions of an unsaturated monomer, corresponding to each structure. Further, it is also possible to obtain a target resin by using an unsaturated monomer corresponding to a precursor of each structure to perform polymerization, and then performing a polymer reaction.

When the composition of the present invention is for ArF exposure, from the viewpoint of transparency to ArF light, the resin (A) used in the composition of the present invention preferably has substantially no aromatic ring (specifically, the ratio of a repeating unit having an aromatic group in the resin is preferably 5 mol % or less, more preferably 3 mol % or less, and ideally 0 mol %, that is, the resin does not have an aromatic group), and the resin (A) preferably has a monocyclic or polycyclic alicyclic hydrocarbon structure.

When the composition of the present invention includes a resin (D) to be described below, the resin (A) preferably contains no fluorine atom and no silicon atom from the viewpoint of compatibility with the resin (D).

The resin (A) used in the composition of the present invention is preferably a resin in which all the repeating units consist of a (meth)acrylate-based repeating unit. In this case, all repeating units may be used as any one of a methacrylate-based repeating unit, an acrylate-based repeating unit, and a methacrylate-based repeating unit and an acrylate-based repeating unit, but the acrylate-based repeating unit is present in an amount of preferably 50 mol % or less based on all the repeating units.

When KrF excimer laser light, electron beam, X-ray or high-energy beam having a wavelength of 50 nm or less (EUV and the like) is irradiated on the composition of the present invention, the resin (A) preferably further has a hydroxystyrene-based repeating unit. The resin (A) has more preferably a hydroxystyrene-based repeating unit and an acid-decomposable repeating unit such as a hydroxystyrene-based repeating unit protected by an acid-decomposable group and (meth)acrylic acid tertiary alkyl ester.

Preferred examples of the hydroxystyrene-based repeating unit having an acid-decomposable group may include repeating units consisting of t-butoxycarbonyloxystyrene, 1-alkoxyethoxystyrene, (meth)acrylic acid tertiary alkyl ester, and the like, and repeating units consisting of 2-alkyl-2-adamantyl(meth)acrylate and dialkyl(1-adamantyl)methyl (meth)acrylate are more preferred.

The resin (A) in the present invention may be synthesized by a typical method (for example, radical polymerization). Examples of a general synthesis method may include a batch polymerization method of dissolving monomer species and an initiator in a solvent and heating the solution to perform the polymerization, a dropping polymerization method of adding dropwise a solution containing monomer species and an initiator to a heated solvent over 1 to 10 hours, and the like, and a dropping polymerization method is preferred. Examples of a reaction solvent may include tetrahydrofuran, 1,4-dioxane, ethers such as diisopropyl ether, ketones such as methyl ethyl ketone and methyl isobutyl ketone, an ester solvent such as ethyl acetate, an amide solvent such as dimethylformamide, dimethylacetamide, and a solvent capable of dissolving the composition of the present invention described below, such as propylene glycol monomethyl ether acetate, propylene glycol monomethyl ether and cyclohexanone. The polymerization is more preferably performed by using the same solvent as the solvent used in the photosensitive composition of the present invention. Accordingly, generation of particles during storage may be suppressed.

The polymerization reaction is preferably performed under an inert gas atmosphere such as nitrogen and argon. As for the polymerization initiator, the polymerization is initiated by using a commercially available radical initiator (azo-based initiator, peroxide and the like). The radical initiator is preferably an azo-based initiator, and an azo-based initiator having an ester group, a cyano group or a carboxyl group is preferred. Preferred examples of the initiator may include azobisisobutyronitrile, azobisdimethylvaleronitrile, dimethyl 2,2′-azobis(2-methylpropionate) and the like. The initiator is added additionally or in parts, if desired, and after the completion of reaction, the reaction product is poured in a solvent, and a desired polymer is recovered by a powder or solid recovery method, or the like. The reaction concentration is 5% by mass to 50% by mass, and preferably 10% by mass to 30% by mass. The reaction temperature is usually 10° C. to 150° C., preferably 30° C. to 120° C., and more preferably 60° C. to 100° C.

After the completion of reaction, the reaction solution is allowed to cool to room temperature and purified. The purification may be performed by a typical method, such as a liquid-liquid extraction method of applying water-washing or combining water-washing with an appropriate solvent to remove residual monomers or oligomer components, a purification method in a solution state, such as ultrafiltration of removing only polymers having a molecular weight not more than a specific molecular weight by virtue of extraction, a reprecipitation method of adding dropwise a resin solution in a poor solvent to solidify the resin in the poor solvent to remove residual monomers and the like, a purification method in a solid state, such as washing of the resin slurry separated by filtration with a poor solvent and the like, and the like. For example, the resin is precipitated as a solid by contacting the reaction solution with a solvent (poor solvent) in which the resin is sparingly soluble or insoluble and which is in a volumetric amount of 10 times or less and preferably 10 to 5 times the reaction solution.

The solvent (precipitation or reprecipitation solvent) used at the time of operation of precipitation or reprecipitation from the polymer solution may be sufficient if the solvent is a poor solvent for the polymer, and the solvent may be appropriately selected from a hydrocarbon, a halogenated hydrocarbon, a nitro compound, ether, ketone, ester, carbonate, alcohol, carboxylic acid, water, and a mixed solvent including these solvents, according to the kind of the polymer, and may be used. Among these solvents, a solvent including at least alcohol (particularly, methanol or the like) or water is preferred as the precipitation or reprecipitation solvent.

The amount of the precipitation or reprecipitation solvent used may be appropriately selected by considering the efficiency, yield and the like, but in general, the amount is 100 parts by mass to 10,000 parts by mass, preferably 200 by parts by mass to 2,000 parts by mass, and more preferably 300 parts by mass to 1,000 parts by mass, based on 100 parts by mass of the polymer solution.

The temperature during the precipitation or reprecipitation may be appropriately selected by considering the efficiency or operability but is usually 0 to 50° C., and preferably in the vicinity of room temperature (for example, approximately 20° C. to 35° C.). The precipitation or reprecipitation operation may be performed by a known method such as batch system and continuous system using a commonly employed mixing vessel such as stirring tank.

The precipitated or reprecipitated polymer is usually subjected to commonly employed solid-liquid separation such as filtration and centrifugation, then dried and used. The filtration is performed by using a solvent-resistant filter element, and preferably under pressure. The drying is performed under atmospheric pressure or reduced pressure (preferably under reduced pressure) at a temperature of approximately 30° C. to 100° C. and preferably at a temperature of approximately 30° C. to 50° C.

Meanwhile, after the resin is once precipitated and separated, the resin may be dissolved in a solvent again and then brought into contact with a solvent in which the resin is sparingly soluble or insoluble. That is, there may be used a method including, after the completion of radical polymerization reaction, bringing the polymer into contact with a solvent in which the polymer is sparingly soluble or insoluble, to precipitate a resin (process a), separating the resin from the solution (process b), dissolving the resin in a solvent again to prepare a resin solution A (process c), and then bringing the resin solution A into contact with a solvent in which the resin is sparingly soluble or insoluble and which is in a volumetric amount of less than 10 times (volumetric amount of preferably 5 times or less) the resin solution A, to precipitate a resin solid (process d), and separating the precipitated resin (process e).

In addition, for suppressing the resin after preparation of the composition from aggregation or the like, as described in, for example, Japanese Patent Application Laid-Open No. 2009-037108, a process of dissolving the synthesized resin in a solvent to prepare a solution, and heating the solution at approximately 30° C. to 90° C. for approximately 30 minutes to 4 hours may be added.

The weight average molecular weight of the resin (A) in the present invention is preferably 1,000 to 200,000, more preferably 2,000 to 50,000, still more preferably 3,000 to 40,000, and particularly preferably 3,000 to 30,000, in terms of polystyrene by the GPC method. By setting the weight average molecular weight within 1,000 to 200,000, it is possible to prevent deterioration in the heat resistance or dry etching resistance and prevent the film-forming property from deteriorating due to impaired developability or increased viscosity.

The polydispersity (molecular weight distribution) is usually in a range of 1.0 to 3.0, preferably 1.0 to 2.6, more preferably 1.0 to 2.0, and particularly preferably 1.4 to 2.0. The smaller the molecular weight distribution is, the better the resolution and resist shape are, and the smoother the side wall of the resist pattern is, and thus roughness is excellent.

In the actinic ray-sensitive or radiation-sensitive resin composition of the present invention, the blending ratio of the resin (A) in the entire composition is preferably 30% by mass to 99% by mass, and more preferably 60% by mass to 95% by mass, based on the total solid content of the composition of the resin (A). In this specification, mass ratio is equal to weight ratio.

Further, in the present invention, the resin (A) may be used either alone or in combination of a plurality thereof.

[2] (B) Compound capable of generating an acid upon irradiation with an actinic ray or radiation

The composition in the present invention also contains (B) a compound capable of generating an acid upon irradiation with an actinic ray or radiation (hereinafter, also referred to as an “acid generator”). The compound (B) capable of generating an acid upon irradiation with an actinic ray or radiation is preferably a compound capable of generating an organic acid upon irradiation with an actinic ray or radiation.

The acid generator may be appropriately selected from a photo-initiator for cationic photopolymerization, a photo-initiator for radical photopolymerization, a photodecoloring agent for dyes, a photodiscoloring agent, or a known compound capable of generating an acid upon irradiation with an actinic ray or radiation, which is used for microresist or the like, and a mixture thereof, and be used.

Examples thereof may include a diazonium salt, a phosphonium salt, a sulfonium salt, an iodonium salt, imidosulfonate, oxime sulfonate, diazodisulfone, disulfone, and o-nitrobenzyl sulfonate.

Among the acid generators, preferred compounds include compounds represented by the following Formulas (ZI), (ZII), and (ZIII).

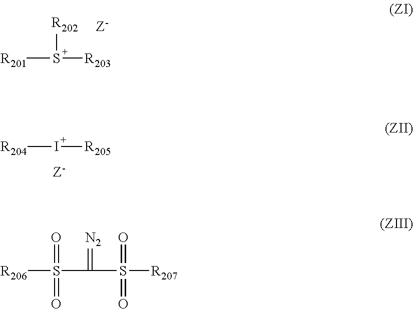

In Formula (ZI),

each of R₂₀₁, R₂₀₂ and R₂₀₃ independently represents an organic group.

The carbon number of the organic group as R₂₀₁, R₂₀₂ and R₂₀₃ is generally 1 to 30, and preferably 1 to 20.

Further, two of R₂₀₁ to R₂₀₃ may be bound with each other to form a ring structure, and the ring may include an oxygen atom, a sulfur atom, an ester bond, an amide bond or a carbonyl group in the ring. Examples of the group in which two of R₂₀₁ to R₂₀₃ are bound to form may include an alkylene group (for example, a butylene group and a pentylene group).

Z⁻ represents a non-nucleophilic anion.

Examples of the non-nucleophilic anion as Z⁻ may include sulfonate anion, carboxylate anion, sulfonylimide anion, bis(alkylsulfonyl)imide anion, tris(alkylsulfonyl)methyl anion and the like.

The non-nucleophilic anion is an anion having an extremely low ability of causing a nucleophilic reaction and capable of suppressing the decomposition with time due to an intramolecular nucleophilic reaction. Accordingly, the stability of the resist composition with time is improved.

Examples of the sulfonate anion may include an aliphatic sulfonate anion, an aromatic sulfonate anion, a camphorsulfonate anion and the like.

Examples of the carboxylate anion may include an aliphatic carboxylate anion, an aromatic carboxylate anion, an aralkylcarboxylate anion and the like.

The aliphatic moiety in the aliphatic sulfonate anion and the aliphatic carboxylate anion may be an alkyl group or a cycloalkyl group and is preferably an alkyl group having 1 to 30 carbon atoms and a cycloalkyl group having 3 to 30 carbon atoms, and examples thereof may include a methyl group, an ethyl group, a propyl group, an isopropyl group, a n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, a bornyl group, and the like.

The aromatic group in the aromatic sulfonate anion and the aromatic carboxylate anion is preferably an aryl group having 6 to 14 carbon atoms, and examples thereof may include a phenyl group, a tolyl group, a naphthyl group, and the like.

The alkyl group, the cycloalkyl group and the aryl group in the aliphatic sulfonate anion and the aromatic sulfonate anion may have a substituent. Examples of the substituent of the alkyl group, the cycloalkyl group and the aryl group in the aliphatic sulfonate anion and the aromatic sulfonate anion may include a nitro group, a halogen atom (a fluorine atom, a chlorine atom, a bromine atom and an iodine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), a cycloalkylalkyloxyalkyloxy group (preferably having 8 to 20 carbon atoms) and the like. Examples of the aryl group and the ring structure that each group may further include, as the substituent, an alkyl group (preferably having 1 to 15 carbon atoms) and a cycloalkyl group (preferably having 3 to 15 carbon atoms).

The aralkyl group in the aralkylcarboxylate anion is preferably an aralkyl group having 7 to 12 carbon atoms, and examples thereof may include a benzyl group, a phenethyl group, a naphthylmethyl group, a naphthylethyl group, a naphthylbutyl group and the like.

The alkyl group, the cycloalkyl group, the aryl group and the aralkyl group in the aliphatic carboxylate anion, the aromatic carboxylate anion and the aralkylcarboxylate anion may have a substituent. Examples of the substituent may include the same halogen atom, alkyl group, cycloalkyl group, alkoxy group, alkylthio group and the like as those in the aromatic sulfonate anion.

Examples of the sulfonylimide anion may include saccharin anion.

The alkyl group in the bis(alkylsulfonyl)imide anion and the tris(alkylsulfonyl)methide anion is preferably an alkyl group having 1 to 5 carbon atoms, and examples thereof may include a methyl group, an ethyl group, a propyl group, an isopropyl group, a n-butyl group, an isobutyl group, a sec-butyl group, a pentyl group, a neopentyl group and the like.

Two alkyl groups in the bis(alkylsulfonyl)imide anion may be linked to each other to form an alkylene group (preferably having 2 to 4 carbon atoms), and the alkylene group may be bound with an imide group and two sulfonyl groups to form a ring. Examples of a substituent which may be possessed by an alkylene group formed by linking two alkyl groups in the alkyl group and the bis(alkylsulfonyl)imide anion with each other may include a halogen atom, an alkyl group substituted with a halogen atom, an alkoxy group, an alkylthio group, an alkyloxysulfonyl group, an aryloxysulfonyl group, a cycloalkylaryloxysulfonyl group and the like, and an alkyl group substituted with a fluorine atom is preferred.

Examples of the other non-nucleophilic anions may include fluorinated phosphate (for example, PF₆⁻), fluorinated boron (for example, BF₄⁻), fluorinated antimony (for example, SbF₆⁻) and the like.

The non-nucleophilic anion of Z⁻ is preferably an aliphatic sulfonate anion in which at least an α-position of sulfonic acid is substituted with a fluorine atom, an aromatic sulfonate anion substituted with a fluorine atom or a group having a fluorine atom, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonate anion having 4 to 8 carbon atoms and a benzenesulfonate anion having a fluorine atom, and still more preferably a nonafluorobutanesulfonate anion, a perfluorooctanesulfonate anion, a pentafluorobenzenesulfonate anion and a 3,5-bis(trifluoromethyl)benzenesulfonate anion.

The acid generator is preferably a compound capable of generating an acid represented by the following Formula (V) or (VI) upon irradiation with an actinic ray or radiation. By the compound capable of generating an acid represented by the following Formula (V) or (VI), the compound has a cyclic organic group, and thus the resolution and roughness performance may be excellent.

The non-nucleophilic anion may be an anion capable of generating an organic acid represented by the following Formula (V) or (VI).

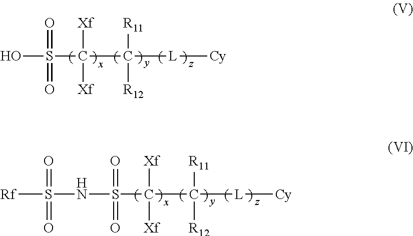

In the formula,

a plurality of Xf each independently represents a fluorine atom or an alkyl group substituted with at least one fluorine atom.

Each of R₁₁ and R₁₂ independently represents a hydrogen atom, a fluorine atom or an alkyl group.

L each independently represents a divalent linking group.

Cy represents a cyclic organic group.

Rf is a group including a fluorine atom.

x represents an integer of 1 to 20.

y represents an integer of 0 to 10.

z represents an integer of 0 to 10.

Xf represents a fluorine atom or an alkyl group substituted with at least one fluorine atom. The carbon number of the alkyl group is preferably 1 to 10, and more preferably 1 to 4. In addition, the alkyl group substituted with at least one fluorine atom is preferably a perfluoroalkyl group.

Xf is preferably a fluorine atom or a perfluoroalkyl group having 1 to 4 carbon atoms. More specifically, Xf is preferably a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉, and more preferably a fluorine atom or CF₃. In particular, it is preferred that both Xf's are a fluorine atom.

Each of R₁₁ and R₁₂ independently represents a hydrogen atom, a fluorine atom or an alkyl group. The alkyl group may have a substituent (preferably a fluorine atom) and preferably has 1 to 4 carbon atoms. The alkyl group is more preferably a perfluoroalkyl group having 1 to 4 carbon atoms. Specific examples of the alkyl group having a substituent of R₁₁ and R₁₂ may include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ and CH₂CH₂C₄F₉, and among them, CF₃ is preferred.

L represents a divalent linking group. Examples of the divalent linking group may include —COO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms) or a divalent linking group formed by combining a plurality of these, and the like. Among them, —COO—, —CONH—, —NHCO—, —CO—, —O—, —SO₂—, —COO-an alkylene group-, —OCO-an alkylene group-, —CONH-an alkylene group- or —NHCO-an alkylene group- is preferred, and alkylene group- or —OCO-an alkylene group- is more preferred.

Cy represents a cyclic organic group. Examples of the cyclic organic group may include an alicyclic group, an aryl group and a heterocyclic group.

The alicyclic group may be monocyclic or polycyclic. Examples of the monocyclic alicyclic group may include a monocyclic cycloalkyl group such as a cyclopentyl group, a cylohexyl group and a cyclooctyl group. Examples of the polycyclic alicyclic group may include a polycyclic cycloalkyl group such as a norbornyl group, a tricyclodecanyl group, a tetracyclodecanyl group, a tetracyclododecanyl group and an adamantyl group. Among them, an alicyclic group having a bulky structure with 7 or more carbon atoms, such as a norbornyl group, a tricyclodecanyl group, a tetracyclodecanyl group, a tetracyclododecanyl group and an adamantyl group, is preferred from the viewpoint of suppressing diffusion in film during a PEB (post-exposure baking) process and improving the MEEF (mask error enhancement factor).

The aryl group may be monocyclic or polycyclic. Examples of the aryl group may include a phenyl group, a naphthyl group, a phenanthryl group and an anthryl group. Among them, a naphthyl group having relatively low light absorbance at 193 nm is preferred.

The heterocyclic group may be monocyclic or polycyclic, but a polycyclic heterocyclic group may suppress the diffusion of an acid more efficiently. Further, the heterocyclic group may have aromaticity or may not have aromaticity. Examples of the heterocyclic ring having aromaticity may include a furan ring, a thiophene ring, a benzofuran ring, a benzothiophene ring, a dibenzofuran ring, a dibenzothiophene ring and a pyridine ring. Examples of the heterocyclic ring having no aromaticity may include a tetrahydropyran ring, a lactone ring, a sultone ring and a decahydroisoquinoline ring. The heterocyclic ring in the heterocyclic group is particularly preferably a furan ring, a thiophene ring, a pyridine ring or a decahydroisoquinoline ring. Further, examples of the lactone ring or the sultone ring may include a lactone structure or a sultone structure exemplified in the above-described resin (A).

The cyclic organic group may have a substituent. Examples of the substituent may include an alkyl group (may be straight or branched, and preferably has 1 to 12 carbon atoms), a cycloalkyl group (may be monocyclic, polycyclic or spirocyclic, and preferably has 3 to 20 carbon atoms), an aryl group (preferably has 6 to 14 carbon atoms), a hydroxyl group, an alkoxy group, an ester group, an amide group, a urethane group, a ureido group, a thioether group, a sulfonamide group and a sulfonate ester group. Meanwhile, the carbon constituting the cyclic organic group (the carbon contributing to ring formation) may be carbonyl carbon.

x is preferably 1 to 8, and among them, more preferably 1 to 4, and particularly preferably 1. y is preferably 0 to 4, and more preferably 0. z is preferably 0 to 8, and among them, preferably 0 to 4.

Examples of the group having a fluorine atom represented by Rf may include an alkyl group having at least one fluorine atom, a cycloalkyl group having at least one fluorine atom, and an aryl group having at least one fluorine atom.

The alkyl group, the cycloalkyl group and the aryl group may be substituted with a fluorine atom, or may be substituted with another substituent including a fluorine atom. When Rf is a cycloalkyl group having at least one fluorine atom or an aryl group having at least one fluorine atom, examples of another substituent including a fluorine atom may include an alkyl group substituted with at least one fluorine atom.

Further, the alkyl group, the cycloalkyl group and the aryl group may also be further substituted with a substituent including no fluorine atom. Examples of the substituent may include those including no fluorine atom among those described above for CY.

Examples of the alkyl group having at least one fluorine atom represented by Rf may include the same as those described above as the alkyl group substituted with at least one fluorine atom represented by Xf. Examples of the cycloalkyl group having at least one fluorine atom represented by Rf may include a perfluorocyclopentyl group and a perfluorocyclohexyl group. Examples of the aryl group having at least one fluorine atom represented by Rf may include a perfluorophenyl group.

Examples of the organic group represented by R₂₀₁, R₂₀₂ and R₂₀₃ may include corresponding groups in compounds (ZI-1), (ZI-2), (ZI-3) and (ZI-4) described below.

Meanwhile, a compound having a plurality of structures represented by Formula (ZI) may be used. For example, it is possible to use a compound having a structure in which at least one of R₂₀₁ to R₂₀₃ in a compound represented by Formula (ZI) is bonded to at least one of R₂₀₁ to R₂₀₃ in another compound represented by Formula (ZI) through a single bond or a linking group.

Examples of a more preferred (ZI) component may include compounds (ZI-1), (ZI-2), (ZI-3) and (ZI-4) described below.

Compound (ZI-1) is an arylsulfonium compound in which at least one of R₂₀₁ to R₂₀₃ in Formula (ZI) is an aryl group, that is, a compound having arylsulfonium as a cation.

In the arylsulfonium compound, all of R₂₀₁ to R₂₀₃ may be an aryl group or a part of R₂₀₁ to R₂₀₃ may be an aryl group, with the remaining being an alkyl group or a cycloalkyl group.

Examples of the arylsulfonium compound may include a triarylsulfonium compound, a diarylalkylsulfonium compound, an aryldialkylsulfonium compound, a diarylcycloalkylsulfonium compound and an aryldicycloalkylsulfonium compound.

The aryl group in the arylsulfonium compound is preferably a phenyl group and a naphthyl group, and more preferably a phenyl group. The aryl group may be an aryl group having a heterocyclic structure having an oxygen atom, a nitrogen atom, a sulfur atom or the like. Examples of the heterocyclic structure may include a pyrrole residue, a furan residue, a thiophene residue, an indole residue, a benzofuran residue, a benzothiophene residue and the like. When the arylsulfonium compound has two or more aryl groups, each aryl group may be the same or different.

The alkyl group or the cycloalkyl group, which the arylsulfonium compound has, if necessary, is preferably a straight or branched alkyl group having 1 to 15 carbon atoms and a cycloalkyl group having 3 to 15 carbon atoms, and examples thereof may include a methyl group, an ethyl group, a propyl group, a n-butyl group, a sec-butyl group, a t-butyl group, a cyclopropyl group, a cyclobutyl group, a cyclohexyl group and the like.

The aryl group, the alkyl group and the cycloalkyl group of R₂₀₁ to R₂₀₃ may have, as a substituent, an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxyl group or a phenylthio group. The substituent is preferably a straight or branched alkyl group having 1 to 12 carbon atoms, a cycloalkyl group having 3 to 12 carbon atoms, and a straight, branched or cyclic alkoxy group having 1 to 12 carbon atoms, and more preferably an alkyl group having 1 to 4 carbon atoms and an alkoxy group having 1 to 4 carbon atoms. The substituent may be substituted with any one of three R₂₀₁ to R₂₀₃ or may be substituted with all of the three. Further, when R₂₀₁ to R₂₀₃ are an aryl group, the substituent is preferably substituted at the p-position of the aryl group.

Subsequently, compound (ZI-2) will be described below.

Compound (ZI-2) is a compound in which each of R₂₀₁ to R₂₀₃ in Formula (ZI) independently represents an organic group having no aromatic ring. Here, the aromatic ring also includes an aromatic ring containing a hetero atom.

The organic group containing no aromatic ring as R₂₀₁ to R₂₀₃ has generally 1 to 30 carbon atoms, and preferably 1 to 20 carbon atoms.

Each of R₂₀₁ to R₂₀₃ independently represents preferably an alkyl group, a cycloalkyl group, an allyl group or a vinyl group, more preferably a straight or branched 2-oxoalkyl group, a 2-oxocycloalkyl group and an alkoxycarbonylmethyl group, and particularly preferably a straight or branched 2-oxoalkyl group.

The alkyl group and the cycloalkyl group of R₂₀₁ to R₂₀₃ are preferably a straight or branched alkyl group having 1 to 10 carbon atoms (for example, a methyl group, an ethyl group, a propyl group, a butyl group and a pentyl group) and a cycloalkyl group having 3 to 10 carbon atoms (a cyclopentyl group, a cyclohexyl group and a norbornyl group). The alkyl group is more preferably a 2-oxoalkyl group and an alkoxycarbonylmethyl group. The cycloalkyl group is more preferably a 2-oxocycloalkyl group.

The 2-oxoalkyl group may be either straight or branched and is preferably a group having >C═O at the 2-position of the above-described alkyl group.

The 2-oxocycloalkyl group is preferably a group having >C═O at the 2-position of the above-described cycloalkyl group.

The alkoxy group in the alkoxycarbonylmethyl group is preferably an alkoxy group having 1 to 5 carbon atoms (a methoxy group, an ethoxy group, a propoxy group, a butoxy group and a pentoxy group).

R₂₀₁ to R₂₀₃ may be further substituted with a halogen atom, an alkoxy group (for example, having 1 to 5 carbon atoms), a hydroxyl group, a cyano group or a nitro group.

Subsequently, compound (ZI-3) will be described.

Compound (ZI-3) is a compound represented by the following Formula (ZI-3), and a compound having a phenacylsulfonium salt structure.

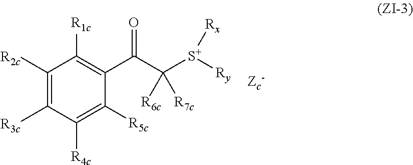

In Formula (ZI-3),

each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

Each of R_{6c} and R_{7c} independently represents a hydrogen atom, an alkyl group, a cycloalkyl group, a halogen atom, a cyano group or an aryl group.

Each of Rₓ and R_{y} independently represents an alkyl group, a cycloalkyl group, a 2-oxoalkyl group, a 2-oxocycloalkyl group, an alkoxycarbonylalkyl group, an allyl group or a vinyl group.

Any two or more of R_{1c} to R_{5c}, R_{5c} and R_{6c}, R_{6c} and R_{7c}, R_{5c} and Rₓ, and Rₓ and R_{y} may be bound with each other to form a ring structure, respectively, and the ring structure may include an oxygen atom, a sulfur atom, a nitrogen atom, a ketone group or an ester bond.

The nitrogen atom that may be included in the ring structure may further have an alkylsulfonyl group or an acyl group.

Examples of the ring structure may includes an aromatic or non-aromatic hydrocarbon ring, an aromatic or non-aromatic heterocyclic ring, and a polycyclic condensed ring formed by combining two or more of these rings. The ring structure includes a 3- to 10-membered ring and is preferably a 4- to 8-membered ring, and more preferably a 5- or 6-membered ring.

Examples of the group in which any two or more of R_{1c} to R_{5c}, R_{6c} and R_{7c}, and Rₓ and R_{y} are bound to form may include a butylene group, a pentylene group and the like.

The group in which R_{5c} and R_{6c} and R_{5c} and Rₓ are bound to form is preferably a single bond or an alkylene group, and examples of the alkylene group may include a methylene group, an ethylene group and the like.

Zc⁻ represents a non-nucleophilic anion, and examples thereof may include the non-nucleophilic anion such as T in Formula (ZI).

The alkyl group as R_{1c} to R_{7c} may be either straight or branched and examples thereof may include an alkyl group having 1 to 20 carbon atoms, and preferably a straight or branched alkyl group having 1 to 12 carbon atoms (for example, a methyl group, an ethyl group, a straight or branched propyl group, a straight or branched butyl group and a straight or branched pentyl group), and examples of the cycloalkyl group may include a cycloalkyl group having 3 to 10 carbon atoms (for example, a cyclopentyl group and a cyclohexyl group).

The aryl group as R_{1c} to R_{5c} preferably has 5 to 15 carbon atoms, and examples thereof may include a phenyl group and a naphthyl group.

The alkoxy group as R_{1c} to R_{5c} may be straight, branched or cyclic and examples thereof may include an alkoxy group having 1 to 10 carbon atoms, preferably a straight or branched alkoxy group having 1 to 5 carbon atoms (for example, a methoxy group, an ethoxy group, a straight or branched propoxy group, a straight or branched butoxy group, and a straight or branched pentoxy group), and a cyclic alkoxy group having 3 to 10 carbon atoms (for example, a cyclopentyloxy group and a cyclohexyloxy group).

Specific examples of the alkoxy group in the alkoxycarbonyl group as R_{1c} to R_{5c} are the same as the specific examples of the alkoxy group as R_{1c} to R_{5c}.

Specific examples of the alkyl group in the alkylcarbonyloxy group and the alkylthio group as R_{1c} to R_{5c} are the same as the specific examples of the alkyl group as R_{1c} to R_{5c}.

Specific examples of the cycloalkyl group in the cycloalkylcarbonyloxy group as R_{1c} to R_{5c} are the same as the specific examples of the cycloalkyl group as R_{1c} to R_{5c}.

Specific examples of the aryl group in the aryloxy group and the arylthio group as R_{1c} to R_{5c} are the same as the specific examples of the aryl group as R_{1c} to R_{5c}.

Any one of R_{1c} to R_{5c} is preferably a straight or branched alkyl group, a cycloalkyl group, or a straight, branched or cyclic alkoxy group, and the sum of carbon numbers of R_{1c} to R_{5c} is more preferably 2 to 15. Accordingly, the solvent solubility is further enhanced, and thus generation of particles during storage is suppressed.

Examples of the ring structure in which any two or more of R_{1c} to R_{5c} may be bound with each other to form may include preferably a 5- or 6-membered ring, and particularly preferably a 6-membered ring (for example, a phenyl ring).

Examples of the ring structure in which R_{5c} and R_{6c} may be bound with each other to form may include a 4-membered or greater ring (particularly preferably a 5- or 6-membered ring) formed together with the carbonyl carbon atom and the carbon atom in Formula (I) by combining R_{5c} and R_{6c} with each other to constitute a single bond or an alkylene group (a methylene group, an ethylene group or the like).

The aryl group as R_{6c} to R_{7c} preferably has 5 to 15 carbon atoms, and examples thereof may include a phenyl group and a naphthyl group.

An aspect in which both R_{6c} and R_{7c} are an alkyl group is preferred. In particular, an aspect in which each of R_{6c} and R_{7c} is a straight or branched alkyl group having 1 to 4 carbon atoms is preferred, and an aspect in which both are a methyl group is particularly preferred.

Further, when R_{6c} and R_{7c} are bound with each other to form a ring, the group in which R_{6c} and R_{7c} are bound to form is preferably an alkylene group having 2 to 10 carbon atoms, and examples thereof may include an ethylene group, a propylene group, a butylene group, a pentylene group, a hexylene group and the like. In addition, the ring in which R_{6c} and R_{7c} are bound to form may have a heteroatom such as an oxygen atom in the ring.

Examples of the alkyl group and the cycloalkyl group as Rₓ and R_{y} are the same as those of the alkyl group and the cycloalkyl group in R_{1c} to R_{7c}.

Examples of the 2-oxoalkyl group and the 2-oxocycloalkyl group as Rₓ and R_{y} may include a group having >C═O at the 2-position of the alkyl group and the cycloalkyl group as R_{1c} to R_{7c}.

Examples of the alkoxy group in the alkoxycarbonylalkyl group as Rₓ and R_{y} are the same as those of the alkoxy group in R_{1c} to R_{5c}, and examples of the alkyl group may include an alkyl group having 1 to 12 carbon atoms, and preferably a straight alkyl group having 1 to 5 carbon atoms (for example, a methyl group and an ethyl group).

The allyl group as Rₓ and R_{y} is not particularly limited, but is preferably an unsubstituted allyl group, or an allyl group substituted with a monocyclic or polycyclic cycloalkyl group (preferably a cycloalkyl group having 3 to 10 carbon atoms).

The vinyl group as Rₓ and R_{y} is not particularly limited, but is preferably an unsubstituted vinyl group, or a vinyl group substituted with a monocyclic or polycyclic cycloalkyl group (preferably a cycloalkyl group having 3 to 10 carbon atoms).

Examples of the ring structure in which R_{5c} and Rₓ may be bound with each other to form may include a 5-membered or greater ring (particularly preferably a 5-membered ring) formed together with a sulfur atom and a carbonyl carbon atom in Formula (ZI-3) by combining R_{5c} and Rₓ with each other to constitute a single bond or an alkylene group (a methylene group, an ethylene group or the like).

Examples of the ring structure in which Rₓ and R_{y} may be bound with each other to form may include a 5- or 6-membered ring formed together with a sulfur atom in Formula (ZI-3) by divalent Rₓ and R_{y} (for example, a methylene group, an ethylene group, a propylene group and the like), and the 5-membered ring is preferably a tetrahydrothiophene ring. The 6-membered ring formed together with a sulfur atom in Formula (ZI-3) is preferably a 6-membered ring containing an oxygen atom, a sulfur atom, a nitrogen atom or a ketone group in the ring structure.

Each of Rₓ and R_{y} is an alkyl group or a cycloalkyl group having preferably 4 or more carbon atoms, more preferably 6 or more carbon atoms, and still more preferably 8 or more carbon atoms.

Each of R_{1c} to R_{7c} and Rₓ and R_{y} may further have a substituent, and examples of the substituent may include a halogen atom (for example, a fluorine atom), a hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, an aryloxycarbonyloxy group and the like.

In Formula (ZI-3), it is more preferred that each of R_{1c}, R_{2c}, R_{4c} and R_{5c} independently represents a hydrogen atom and R_{3c} represents a group other than a hydrogen atom, that is, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

A cation of the compound represented by Formula (ZI-2) or (ZI-3) in the present invention includes the following specific examples.

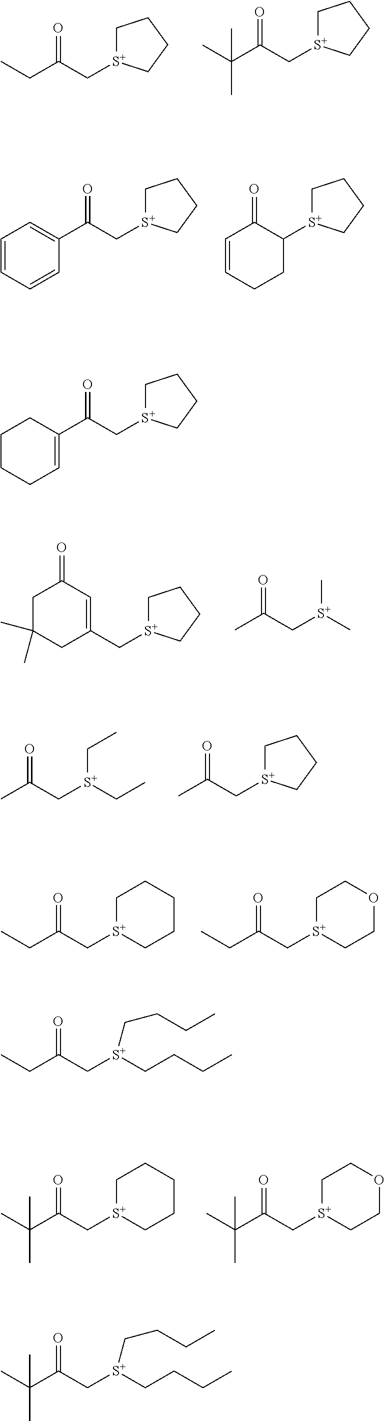

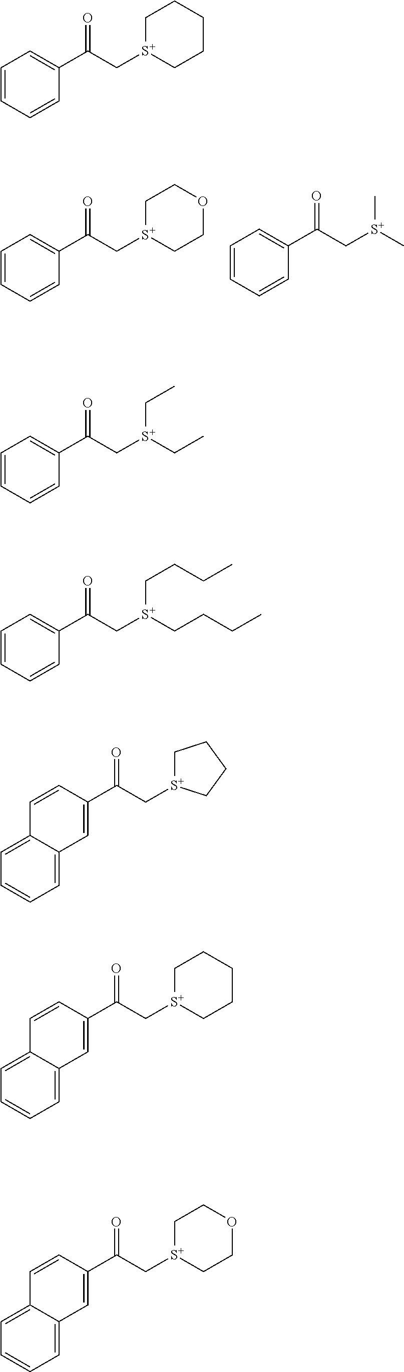

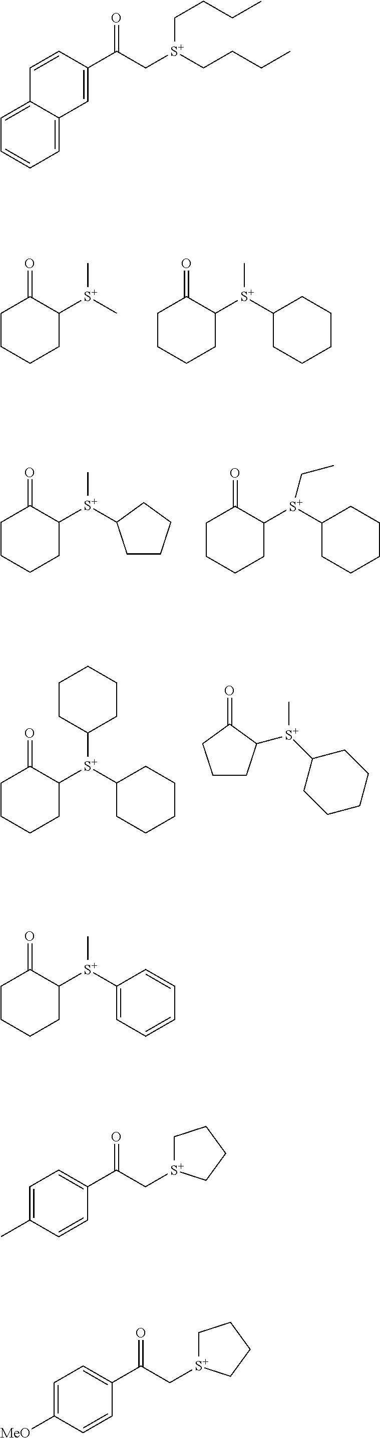

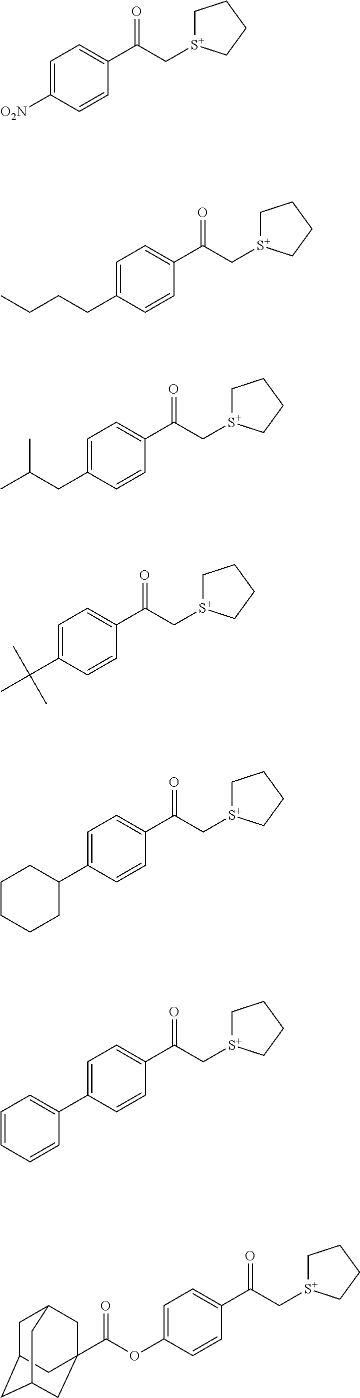

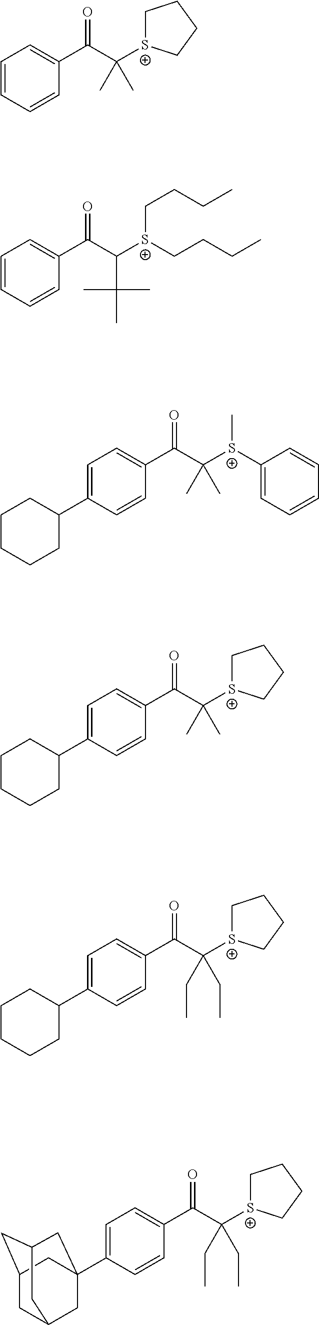 [SMILES: CC(C)(C(=O)c1ccccc1)[S+]1CCCC1 ; CCCC[S+](CCCC)C(C(=O)c1ccccc1)C(C)(C)C ; C[S+](c1ccccc1)C(C)(C)C(=O)c1ccc(C2CCCCC2)cc1 ; CC(C)(C(=O)c1ccc(C2CCCCC2)cc1)[S+]1CCCC1 ; CCC(CC)(C(=O)c1ccc(C2CCCCC2)cc1)[S+]1CCCC1 ; CCC(CC)(C(=O)c1ccc(C23CC4CC(CC(C4)C2)C3)cc1)[S+]1CCCC1]

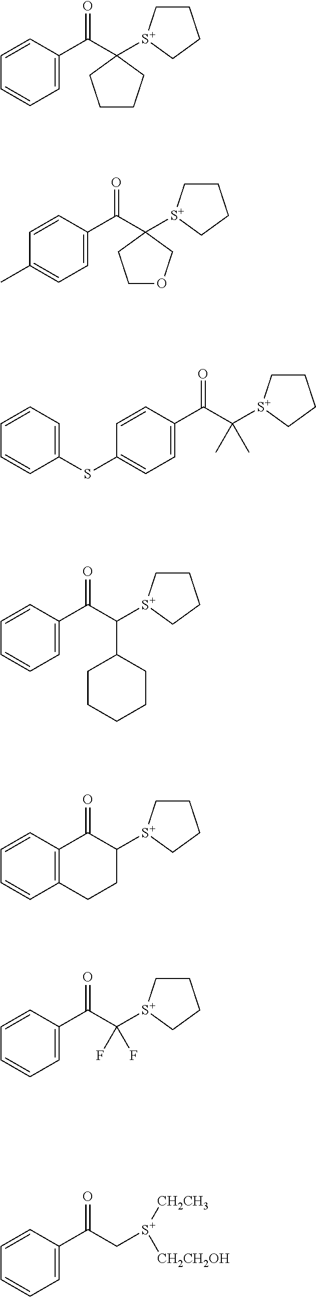

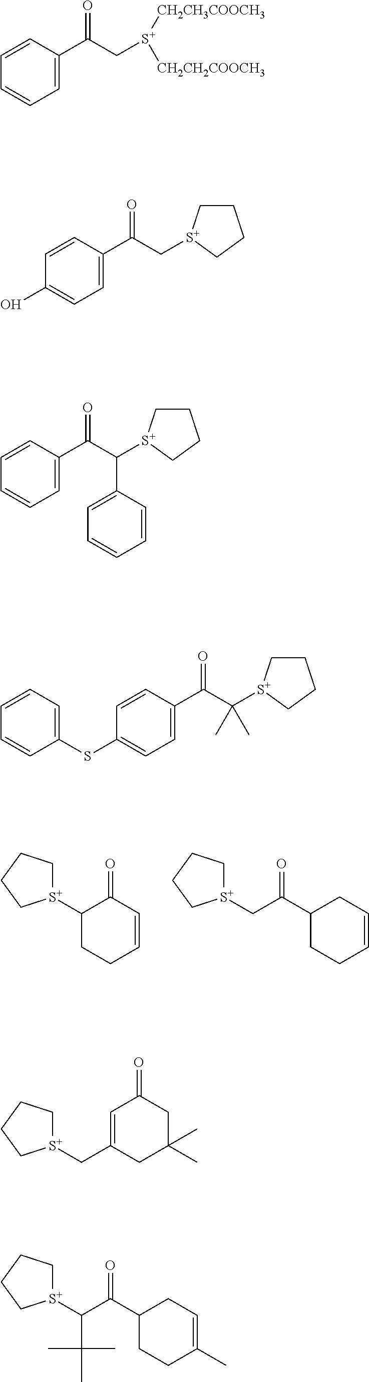

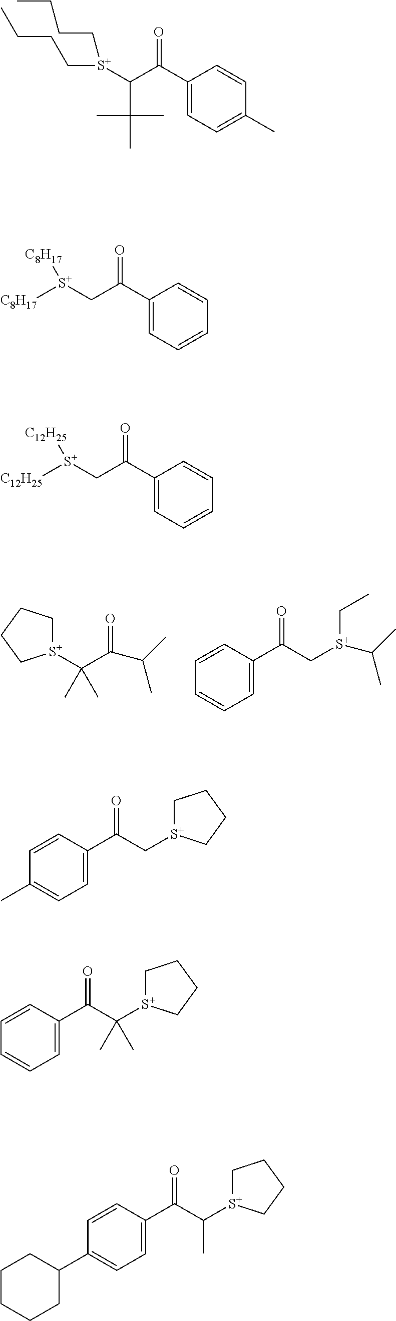

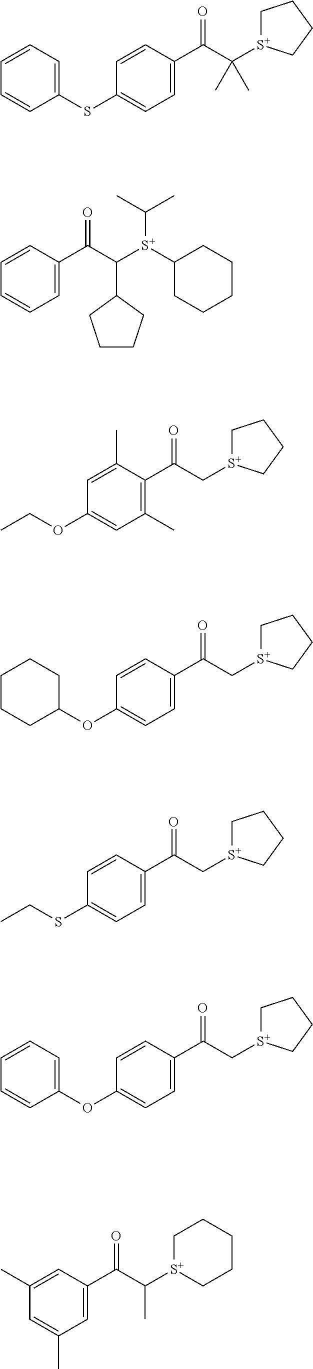

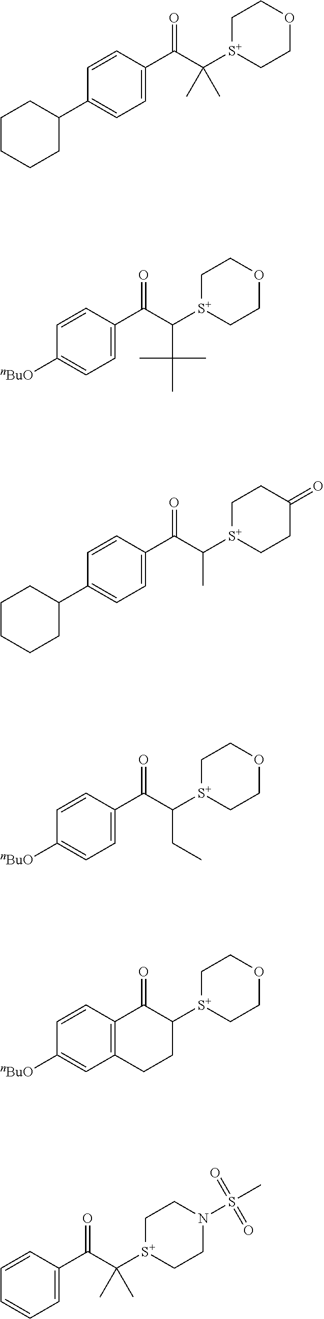

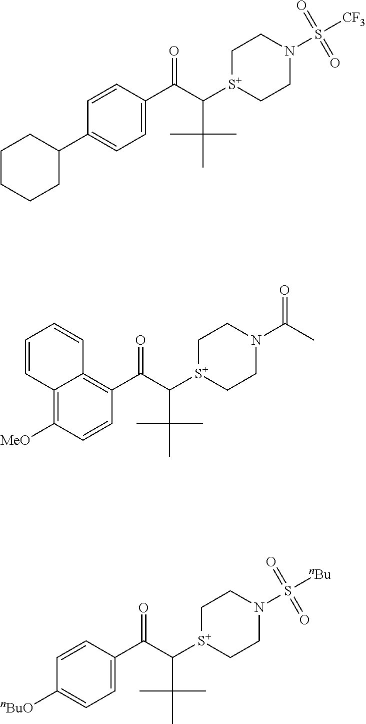

Subsequently, compound (ZI-4) will be described.

Compound (ZI-4) is represented by the following Formula (ZI-4).

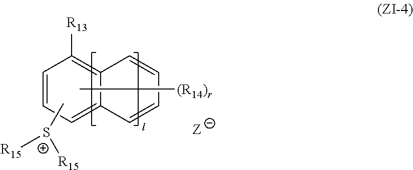

In Formula (ZI-4),

R₁₃ represents a hydrogen atom, a fluorine atom, a hydroxyl group, an alkyl group, a cycloalkyl group, an alkoxy group, an alkoxycarbonyl group or a group having a cycloalkyl group. These groups may have a substituent.

When a plurality of R₁₄ is present, each R₁₄ independently represents a hydroxyl group, an alkyl group, a cycloalkyl group, an alkoxy group, an alkoxycarbonyl group, an alkylcarbonyl group, an alkylsulfonyl group, a cycloalkylsulfonyl group or a group having a cycloalkyl group. These groups may have a substituent.

Each of R₁₅'s independently represents an alkyl group, a cycloalkyl group or a naphthyl group. Two of R₁₅ may be bound with each other to form a ring. These groups may have a substituent.

1 represents an integer of 0 to 2.

r represents an integer of 0 to 8.

Z⁻ represents a non-nucleophilic anion, and examples thereof may include the non-nucleophilic anion such as Z⁻ in Formula (ZI).

In Formula (ZI-4), the alkyl group of R₁₃, R₁₄ and R₁₅ is preferably a straight or branched alkyl group having 1 to 10 carbon atoms, and preferred examples thereof may include a methyl group, an ethyl group, a n-butyl group, a t-butyl group and the like.

Examples of the cycloalkyl group of R₁₃, R₁₄ and R₁₅ may include a monocyclic or polycyclic cycloalkyl group (preferably a cycloalkyl group having 3 to 20 carbon atoms), and cyclopropyl, cyclopentyl, cyclohexyl, cycloheptyl and cyclooctyl are particularly preferred.

The alkoxy group of R₁₃ and R₁₄ is preferably a straight or branched alkoxy group having 1 to 10 carbon atoms, and preferred examples thereof may include a methoxy group, an ethoxy group, an n-propoxy group, an n-butoxy group and the like.

The alkoxycarbonyl group of R₁₃ and R₁₄ is preferably a straight or branched alkoxycarbonyl group having 2 to 11 carbon atoms, and preferred examples thereof may include a methoxycarbonyl group, an ethoxycarbonyl group, a n-butoxycarbonyl group and the like.

Examples of the group having a cycloalkyl group of R₁₃ and R₁₄ may include a monocyclic or polycyclic cycloalkyl group (preferably a cycloalkyl group having 3 to 20 carbon atoms), and examples thereof may include a monocyclic or polycyclic cycloalkyloxy group and an alkoxy group having a monocyclic or polycyclic cycloalkyl group. These groups may further have a substituent.

The monocyclic or polycyclic cycloalkyloxy group of R₁₃ and R₁₄ has a total carbon number of preferably 7 or more, and more preferably 7 to 15, and preferably has a monocyclic cycloalkyl group. The monocyclic cycloalkyloxy group having a total carbon number of 7 or more represents a monocyclic cycloalkyloxy group in which a cycloalkyloxy group such as a cyclopropyloxy group, a cyclobutyloxy group, a cyclopentyloxy group, a cyclohexyloxy group, a cycloheptyloxy group, a cyclooctyloxy group or a cyclododecanyloxy group arbitrarily has a substituent such as an alkyl group such as a methyl group, an ethyl group, a propyl group, a butyl group, a pentyl group, a hexyl group, a heptyl group, an octyl group, a dodecyl group, a 2-ethylhexyl group, an isopropyl group, a sec-butyl group, a t-butyl group and an iso-amyl group, a hydroxyl group, halogen atom (fluorine, chlorine, bromine and iodine), a nitro group, a cyano group, an amide group, a sulfonamide group, an alkoxy group such as a methoxy group, an ethoxy group, a hydroxyethoxy group, a propoxy group, a hydroxypropoxy group and a butoxy group, an alkoxycarbonyl group such as a methoxycarbonyl group and an ethoxycarbonyl group, an acyl group such as a formyl group, an acetyl group and a benzoyl group, an acyloxy group such as an acetoxy group and a butyryloxy group, and a carboxyl group, and in which the total carbon number inclusive of the carbon number of an arbitrary substituent on the cycloalkyl group is 7 or more.

Further, examples of the polycyclic cycloalkyloxy group having a total carbon number of 7 or more may include a norbornyloxy group, a tricyclodecanyloxy group, a tetracyclodecanyloxy group, an adamantyloxy group and the like.

The alkoxy group having a monocyclic or polycyclic cycloalkyl group of R₁₃ and R₁₄ has preferably a total carbon number of 7 or more, and more preferably a total carbon number 7 to 15, and is preferably an alkoxy group having a monocyclic cycloalkyl group. The alkoxy group having a total carbon number of 7 or more and having a monocyclic cycloalkyl group represents an alkoxy group in which an alkoxy group such as methoxy, ethoxy, propoxy, butoxy, pentyloxy, hexyloxy, heptoxy, octyloxy, dodecyloxy, 2-ethylhexyloxy, isopropoxy, sec-butoxy, t-butoxy and iso-amyloxy is substituted with the above-described monocyclic cycloalkyl group which may have a substituent, and in which the total carbon number inclusive of the carbon number of the substituent is 7 or more. Examples thereof may include a cyclohexylmethoxy group, a cyclopentylethoxy group and a cyclohexylethoxy group, and a cyclohexylmethoxy group is preferred.

Further, examples of the alkoxy group having a total carbon number of 7 or more and having a polycyclic cycloalkyl group may include a norbornylmethoxy group, norbornylethoxy group, a tricyclodecanylmethoxy group, a tricyclodecanylethoxy group, a tetracyclodecanylmethoxy group, a tetracyclodecanylethoxy group, an adamantylmethoxy group, an adamantylethoxy group and the like, and a norbornylmethoxy group, a norbornylethoxy group and the like are preferred.

Specific examples of the alkyl group in the alkylcarbonyl group of R₁₄ are the same as those of the above-described alkyl group as R₁₃ to R₁₅.

It is preferred that the alkylsulfonyl group and the cycloalkylsulfonyl group of R₁₄ are preferably straight, branched or cyclic and have 1 to 10 carbon atoms, and preferred examples thereof may include a methanesulfonyl group, an ethanesulfonyl group, a n-propanesulfonyl group, a n-butanesulfonyl group, a cyclopentanesulfonyl group, a cyclohexanesulfonyl group and the like.

Examples of the substituent which each of the groups may have may include a halogen atom (for example, a fluorine atom), a hydroxyl group, a carboxyl group, a cyano group, a nitro group, an alkoxy group, an alkoxyalkyl group, an alkoxycarbonyl group, an alkoxycarbonyloxy group and the like.

Examples of the alkoxy group may include a straight, branched or cyclic alkoxy group having 1 to 20 carbon atoms, and the like, such as a methoxy group, an ethoxy group, a n-propoxy group, an i-propoxy group, a n-butoxy group, a 2-methylpropoxy group, a 1-methylpropoxy group, a t-butoxy group, a cyclopentyloxy group and a cyclohexyloxy group.

Examples of the alkoxyalkyl group may include a straight, branched or cyclic alkoxyalkyl group having 2 to 21 carbon atoms, such as a methoxymethyl group, an ethoxymethyl group, a 1-methoxyethyl group, a 2-methoxyethyl group, a 1-ethoxyethyl group and a 2-ethoxyethyl group.

Examples of the alkoxycarbonyl group may include a straight, branched or cyclic alkoxycarbonyl group having 2 to 21 carbon atoms and the like, such as a methoxycarbonyl group, an ethoxycarbonyl group, a n-propoxycarbonyl group, an i-propoxycarbonyl group, a n-butoxycarbonyl group, a 2-methylpropoxycarbonyl group, a 1-methylpropoxycarbonyl group, a t-butoxycarbonyl group, a cyclopentyloxycarbonyl group and a cyclohexyloxycarbonyl group.

Examples of the alkoxycarbonyloxy group may include a straight, branched or cyclic alkoxycarbonyloxy group having 2 to 21 carbon atoms, and the like, such as a methoxycarbonyloxy group, an ethoxycarbonyloxy group, a n-propoxycarbonyloxy group, an i-propoxycarbonyloxy group, a n-butoxycarbonyloxy group, a t-butoxycarbonyloxy group, a cyclopentyloxycarbonyloxy group and a cyclohexyloxycarbonyloxy group.

Examples of the ring structure in which two R₁₅s are bound with each other to form may include a 5- or 6-membered ring formed together with the sulfur atom in Formula (ZI-4) by two R₁₅s, and particularly preferably a 5-membered ring (that is, a tetrahydrothiophene ring), and may be condensed with an aryl group or a cycloalkyl group. The divalent R₁₅ may have a substituent, and examples of the substituent may include a hydroxyl group, a carboxyl group, a cyano group, a nitro group, an alkyl group, a cycloalkyl group, an alkoxy group, an alkoxyalkyl group, an alkoxycarbonyl group, an alkoxycarbonyloxy group and the like. As for the substituent on the ring structure, a plurality of substituents may be present, and the substituents may be bound with each other to form a ring (an aromatic or non-aromatic hydrocarbon ring, an aromatic or non-aromatic heterocyclic ring, a polycyclic condensed ring formed by combining two or more of these rings or the like).

In Formula (ZI-4), R₁₅ is preferably a methyl group, an ethyl group, a naphthyl group, a divalent group capable of forming a tetrahydrothiophene ring structure together with the sulfur atom by combining two R₁₅s with each other, and the like.

The substituent that R₁₃ and R₁₄ may have is preferably a hydroxyl group, an alkoxy group, an alkoxycarbonyl group or a halogen atom (particularly a fluorine atom).

l is preferably 0 or 1, and more preferably 1.

r is preferably 0 to 2.

A cation of the compound represented by Formula (ZI-4) in the present invention may include the following specific examples.

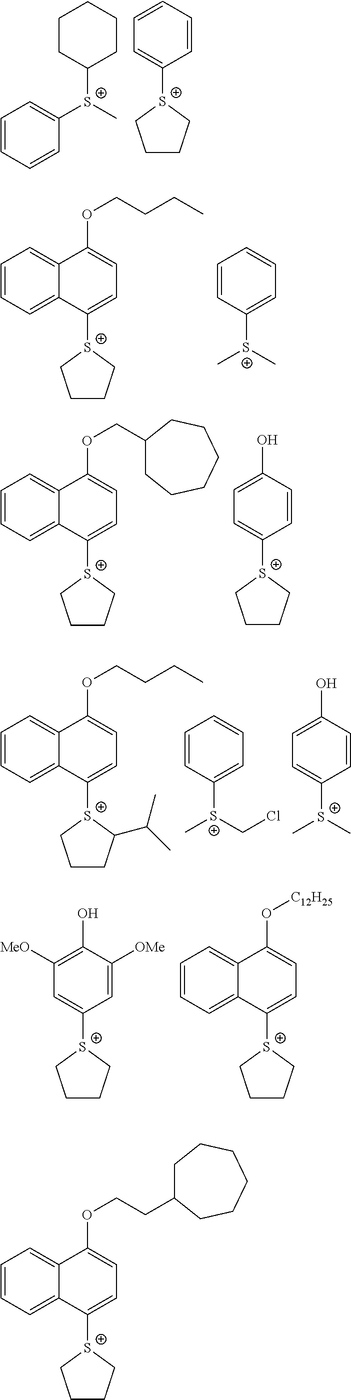

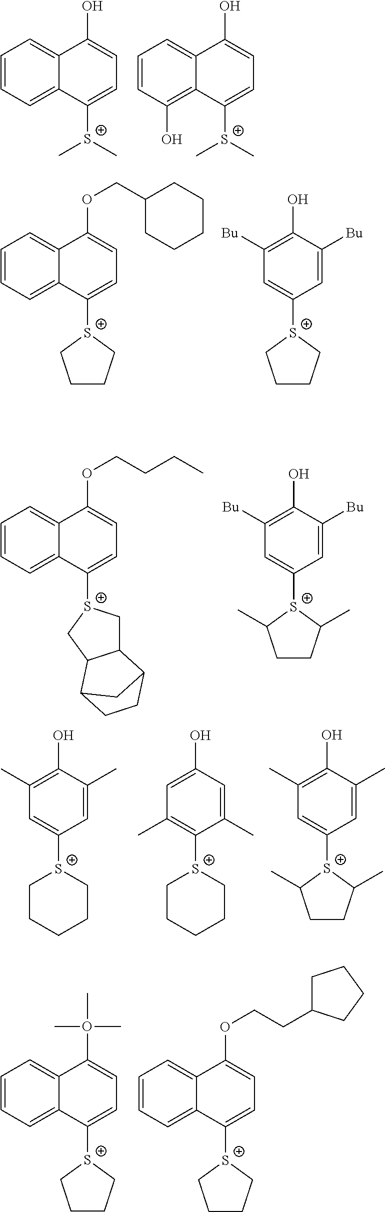

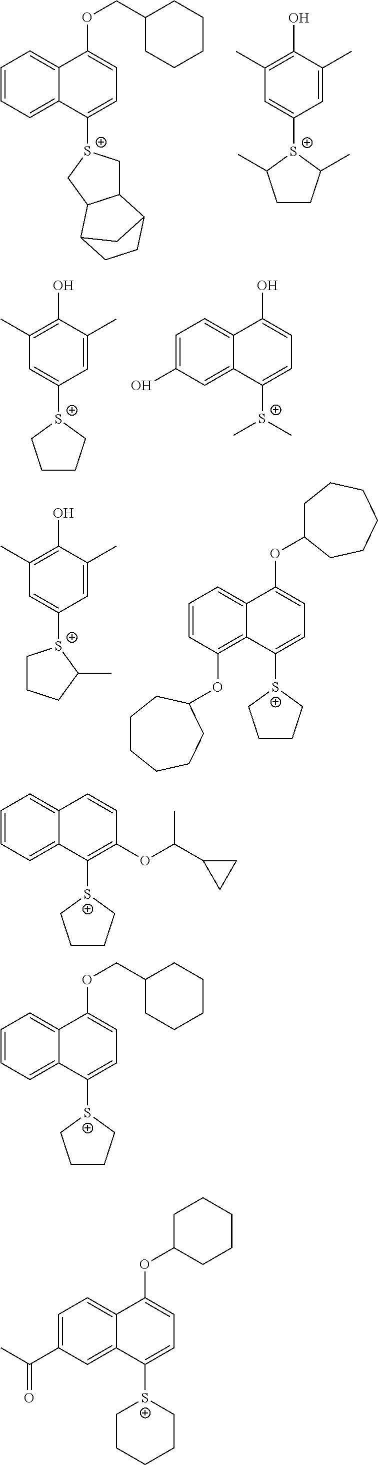

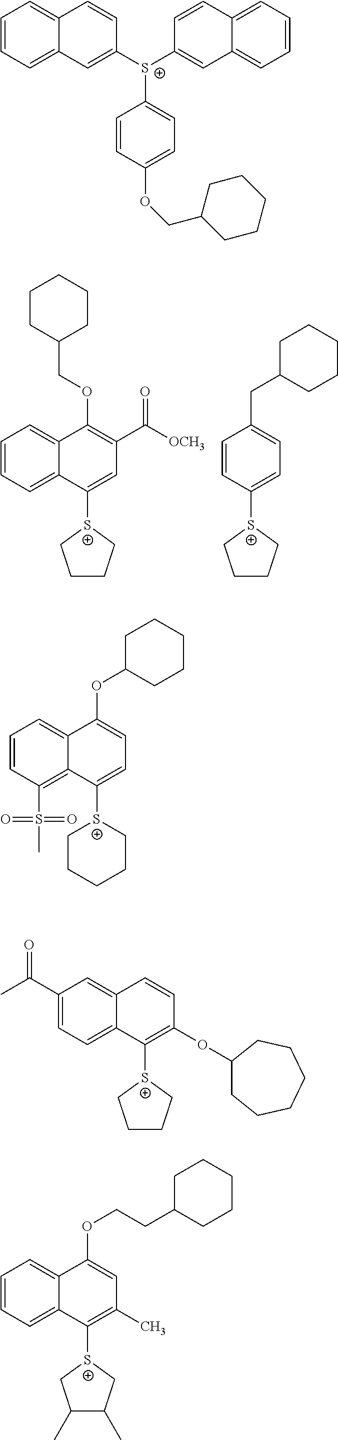 [SMILES: c1ccc2cc([S+](c3ccc(OCC4CCCCC4)cc3)c3ccc4ccccc4c3)ccc2c1 ; COC(=O)c1cc([S+]2CCCC2)c2ccccc2c1OCC1CCCCC1 ; c1cc([S+]2CCCC2)ccc1CC1CCCCC1 ; CS(=O)(=O)c1cccc2c(OC3CCCCC3)ccc([S+]3CCCCC3)c12 ; CC(=O)c1ccc2c([S+]3CCCC3)c(OC3CCCCCC3)ccc2c1 ; Cc1cc(OCCC2CCCCC2)c2ccccc2c1[S+]1CC(C)C(C)C1]

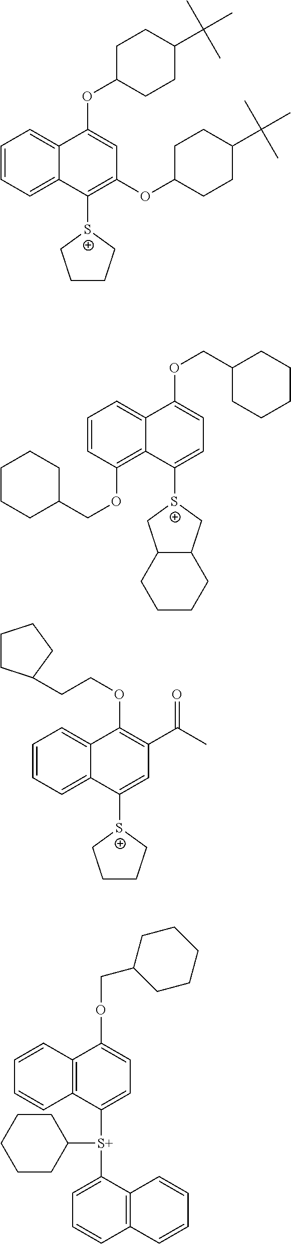 [SMILES: CC(C)(C)C1CCC(Oc2cc(OC3CCC(C(C)(C)C)CC3)c3ccccc3c2[S+]2CCCC2)CC1 ; c1cc(OCC2CCCCC2)c2c([S+]3CC4CCCCC4C3)ccc(OCC3CCCCC3)c2c1 ; CC(=O)c1cc([S+]2CCCC2)c2ccccc2c1OCCC1CCCC1 ; c1ccc2c([S+](c3ccc(OCC4CCCCC4)c4ccccc34)C3CCCCC3)cccc2c1]

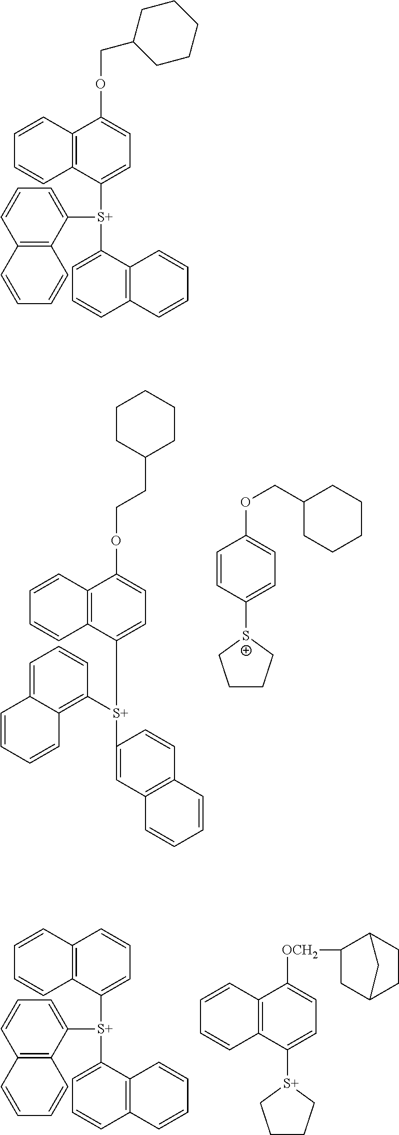

Subsequently, Formulas (ZII) and (ZIII) will be described.

In Formulas (ZII) and (ZIII),

each of R₂₀₄ to R₂₀₇ independently represents an aryl group, an alkyl group or a cycloalkyl group.

The aryl group of R₂₀₄ to R₂₀₇ is preferably a phenyl group or a naphthyl group, and more preferably a phenyl group. The aryl group of R₂₀₄ to R₂₀₇ may be an aryl group having a heterocyclic structure having an oxygen atom, a nitrogen atom, a sulfur atom or the like. Examples of the structure of the aryl group having a heterocyclic structure may include pyrrole, furan, thiophene, indole, benzofuran, benzothiophene and the like.

The alkyl group and the cycloalkyl group in R₂₀₄ to R₂₀₇ are preferably a straight or branched alkyl group having 1 to 10 carbon atoms (for example, a methyl group, an ethyl group, a propyl group, a butyl group and a pentyl group) and a cycloalkyl group having 3 to 10 carbon atoms (a cyclopentyl group, a cyclohexyl group and a norbornyl group), respectively.

The aryl group, the alkyl group and the cycloalkyl group of R₂₀₄ to R₂₀₇ may have a substituent. Examples of the substituent that the aryl group, the alkyl group and the cycloalkyl group of R₂₀₄ to R₂₀₇ may have may include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, a phenylthio group and the like.

Z⁻ represents a non-nucleophilic anion, and examples thereof are the same as those of the non-nucleophilic anion of Z⁻ in Formula (ZI).

Examples of the acid generator may further include compounds represented by the following Formulas (ZIV), (ZV) and (ZVI).

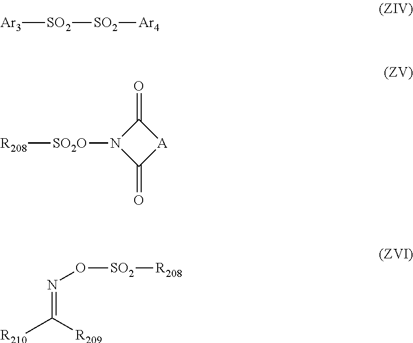

In Formulas (ZIV) to (ZVI),

each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

Specific examples of the aryl group of Ar₃, Ar₄, R₂₀₈, R₂₀₉ and R₂₁₀ are the same as the specific examples of the aryl group as R₂₀₁, R₂₀₂ and R₂₀₃ in Formula (ZI-1).

Specific examples of the alkyl group and the cycloalkyl group of R₂₀₈, R₂₀₉ and R₂₁₀ are the same as the specific examples of the alkyl group and the cycloalkyl group as R₂₀₁, R₂₀₂ and R₂₀₃ in Formula (ZI-2).

Examples of the alkylene group of A may include an alkylene group having 1 to 12 carbon atoms (for example, a methylene group, an ethylene group, a propylene group, an isopropylene group, a butylene group, an isobutylene group and the like), examples of the alkenylene group of A may include an alkenylene group having 2 to 12 carbon atoms (for example, an ethenylene group, a propenylene group, a butenylene group and the like), and examples of the arylene group of A may include an arylene group having 6 to 10 carbon atoms (for example, a phenylene group, a tolylene group, a naphthylene group and the like).

Among the acid generators, the compounds represented by Formulas (ZI) to (ZIII) are more preferred.

Further, the acid generator is preferably a compound capable of generating an acid having either a sulfonic acid group or an imide group.

The pKa of an acid that the acid generator in the present invention generates is preferably −2.5 to −20.0 and more preferably −3.0 to −16.0 from the viewpoint that the the acid may be more certainly captured by “(C) a salt having a conjugate base structure of an acid having a pKa of −2 or more in a molecule thereof and substantially not capable of decomposing by an actinic ray or radiation” to be described below.

The acid generator is more preferably a compound capable of generating a monovalent perfluoroalkanesulfonic acid, a compound capable of generating an aromatic sulfonic acid substituted with a monovalent fluorine atom or a fluorine atom-containing group, or a compound capable of generating an imide acid substituted with a monovalent fluorine atom or a fluorine atom-containing group, and still more preferably a sulfonium salt of fluoro-substituted alkanesulfonic acid, fluorine-substituted benzenesulfonic acid, fluorine-substituted imide acid or fluorine-substituted methide acid. The usable acid generator is particularly preferably a fluoro-substituted alkanesulfonic acid, a fluoro-substituted benzenesulfonic acid, or a fluoro-substituted imide acid, in which the acid generated has a pKa of −2.5 or less, and the sensitivity is enhanced.

Among the acid generators, particularly preferable examples will be described below.

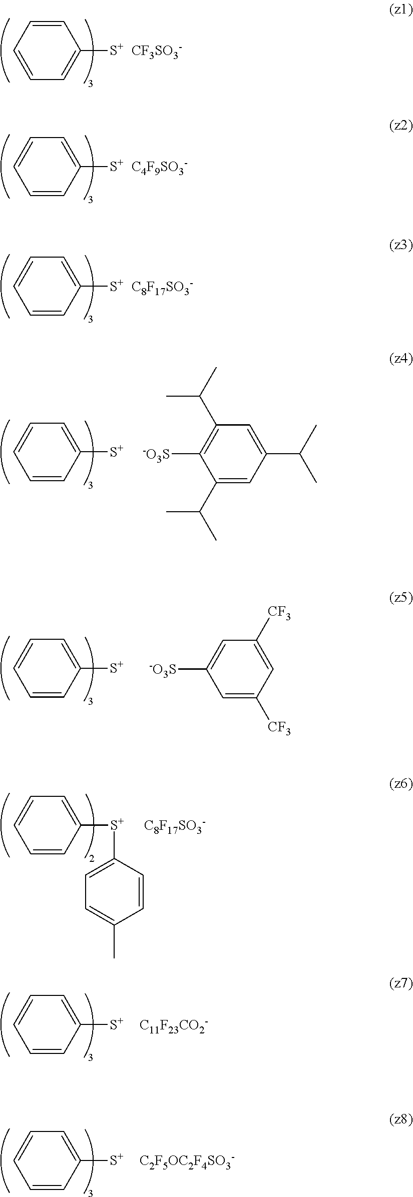

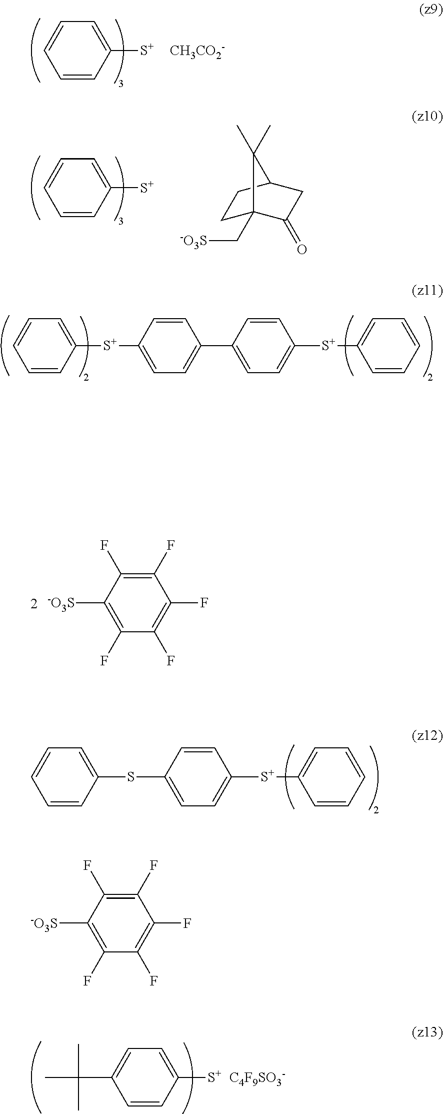

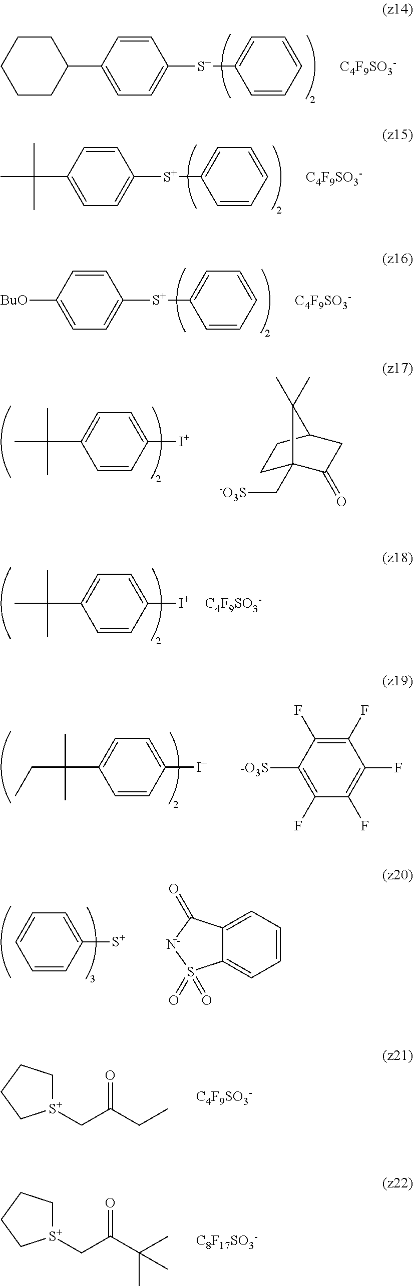

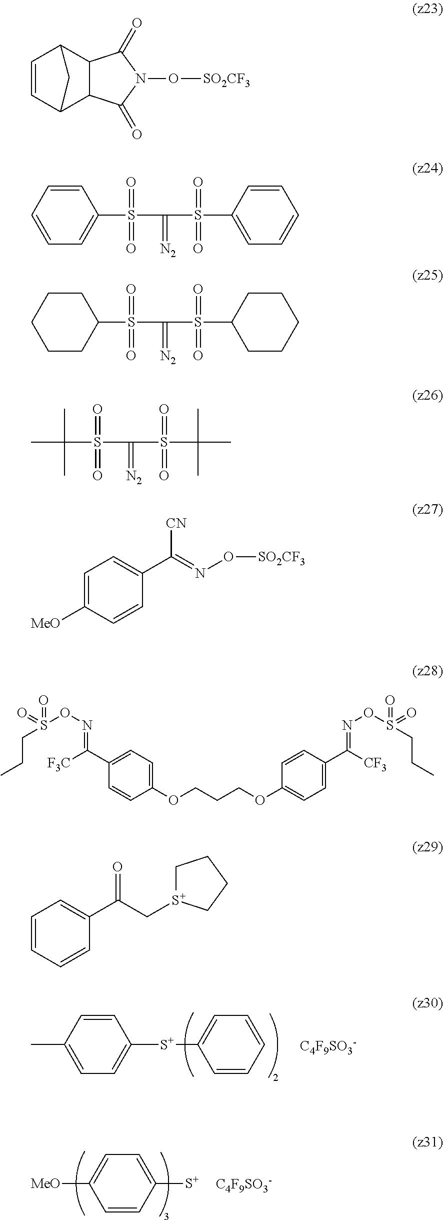

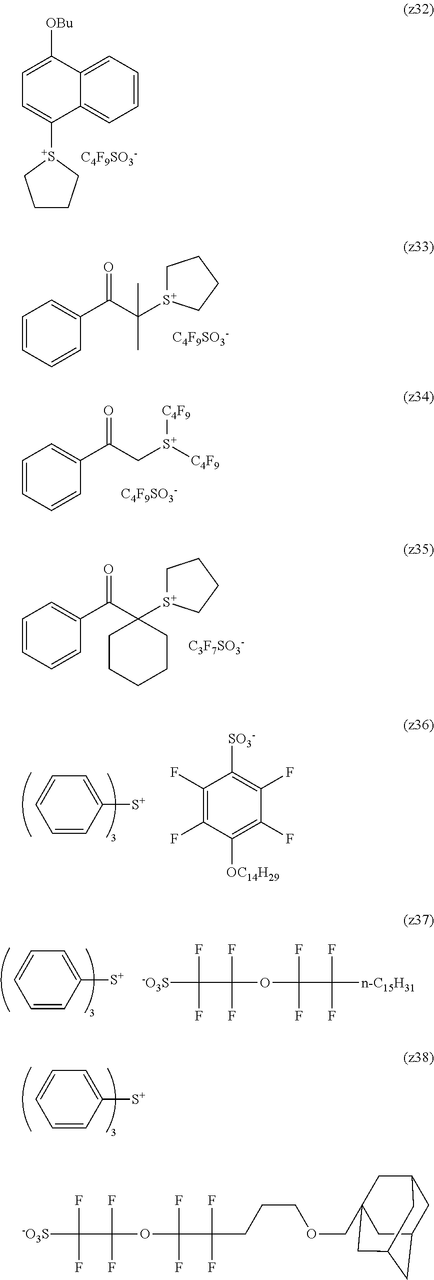

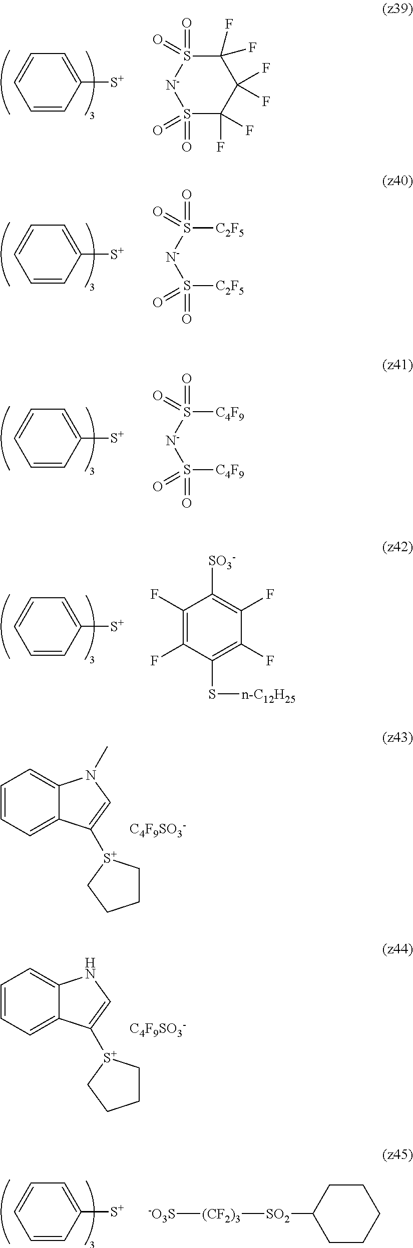

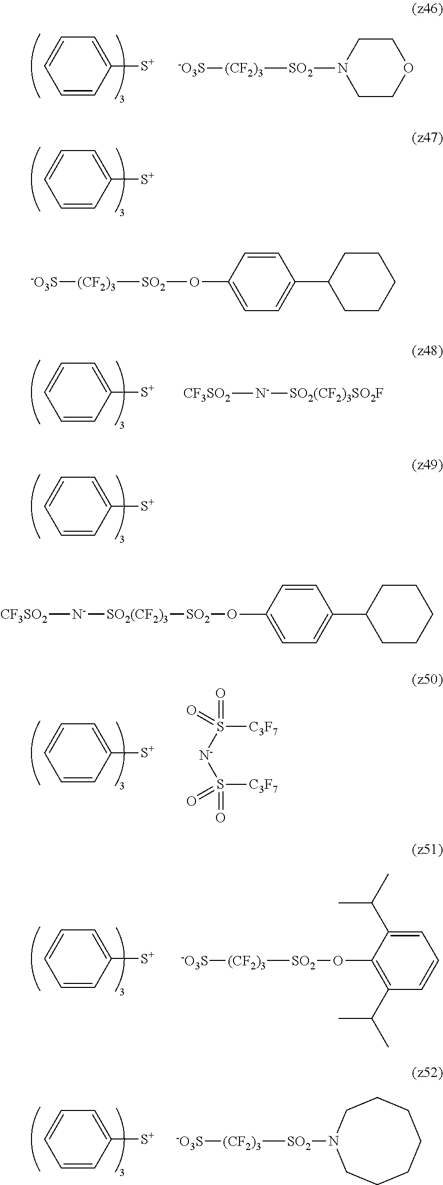

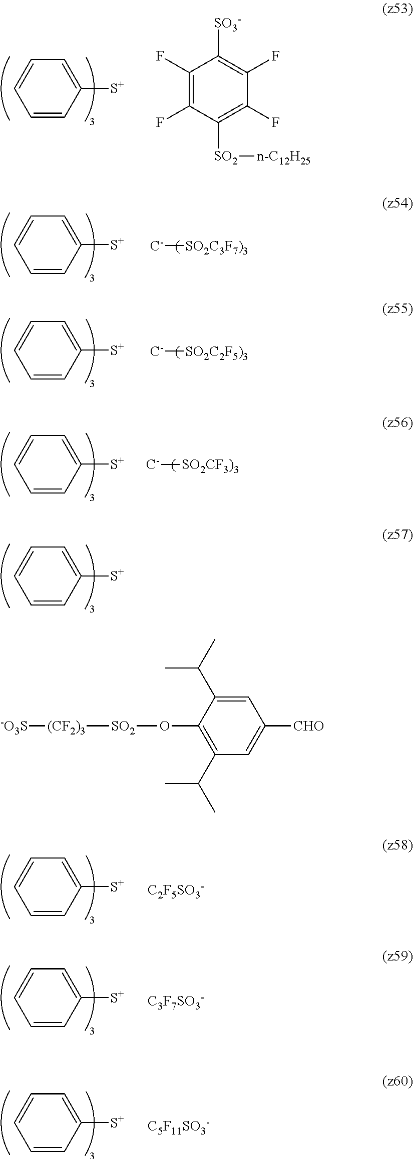

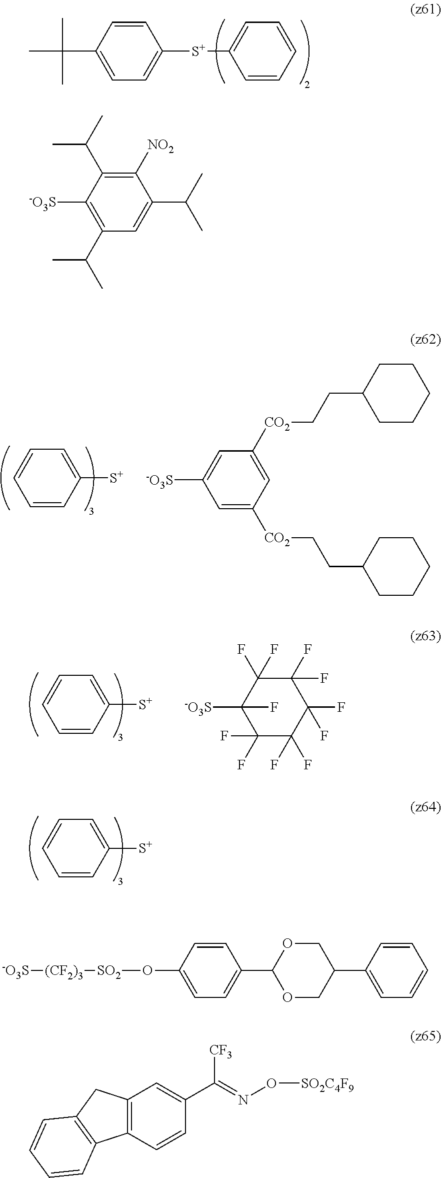

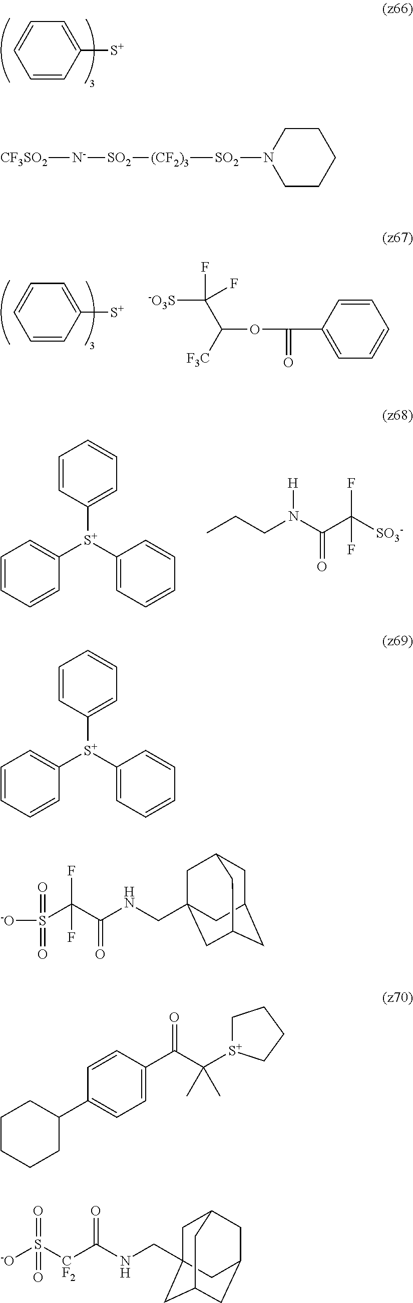

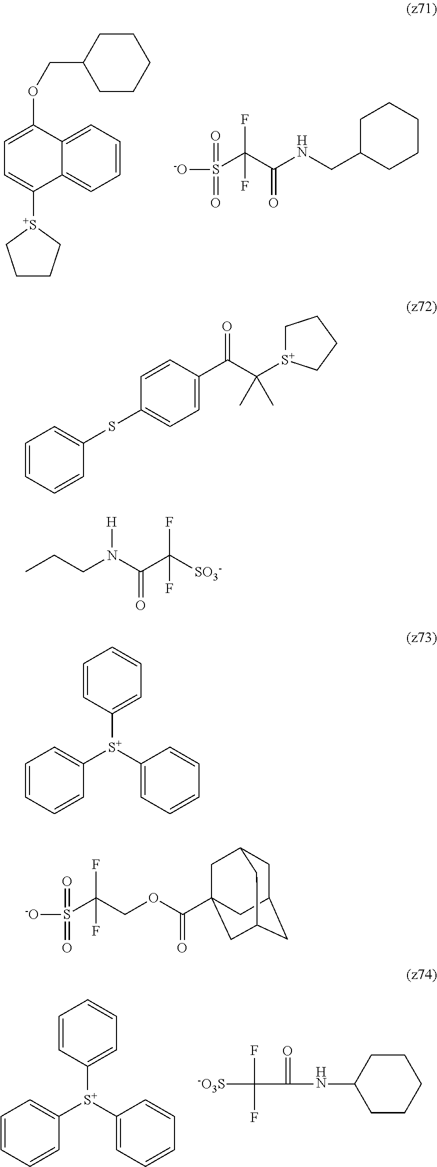

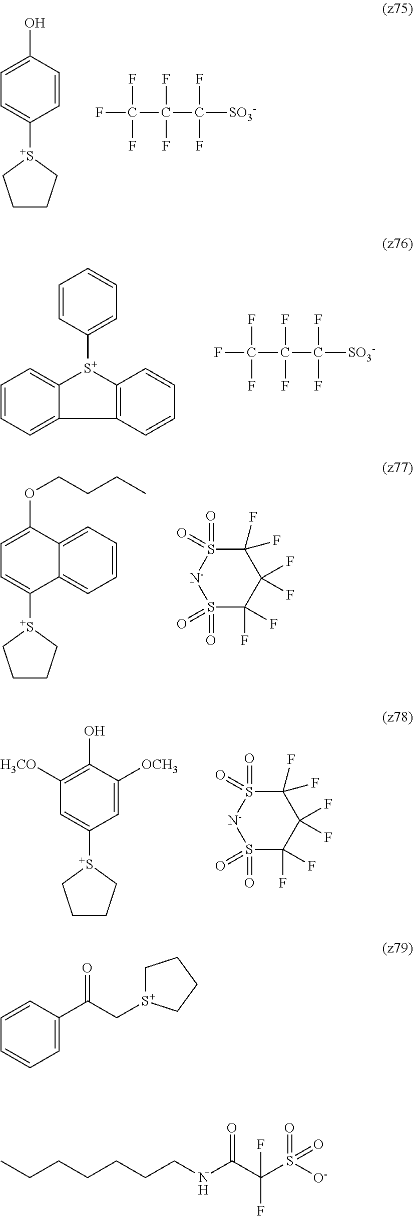

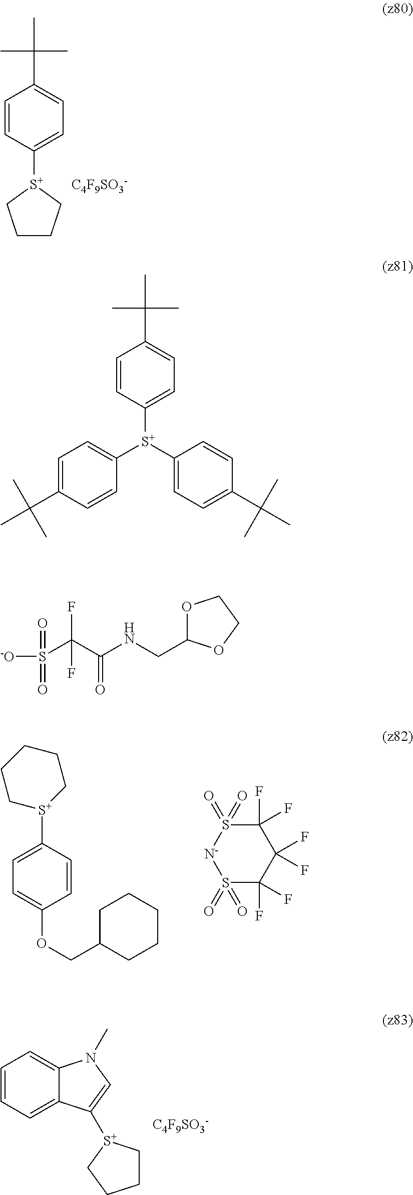

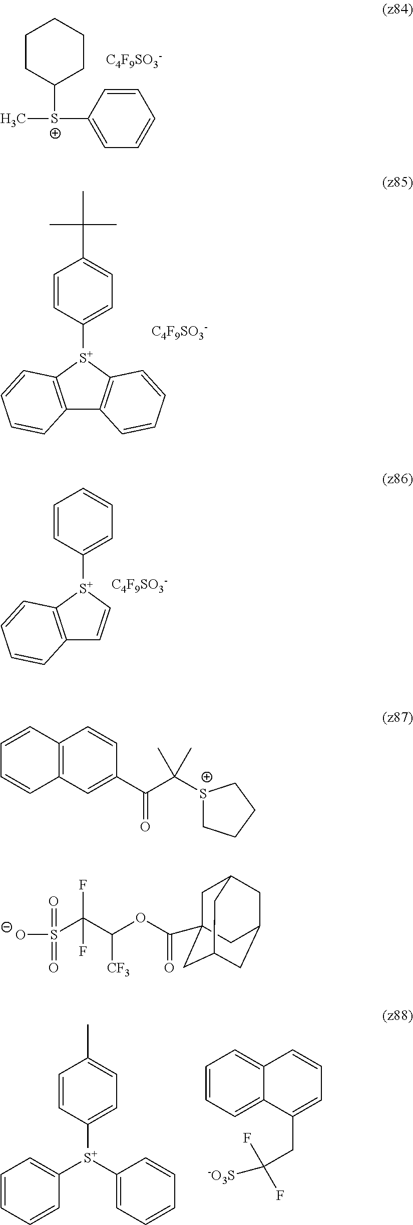

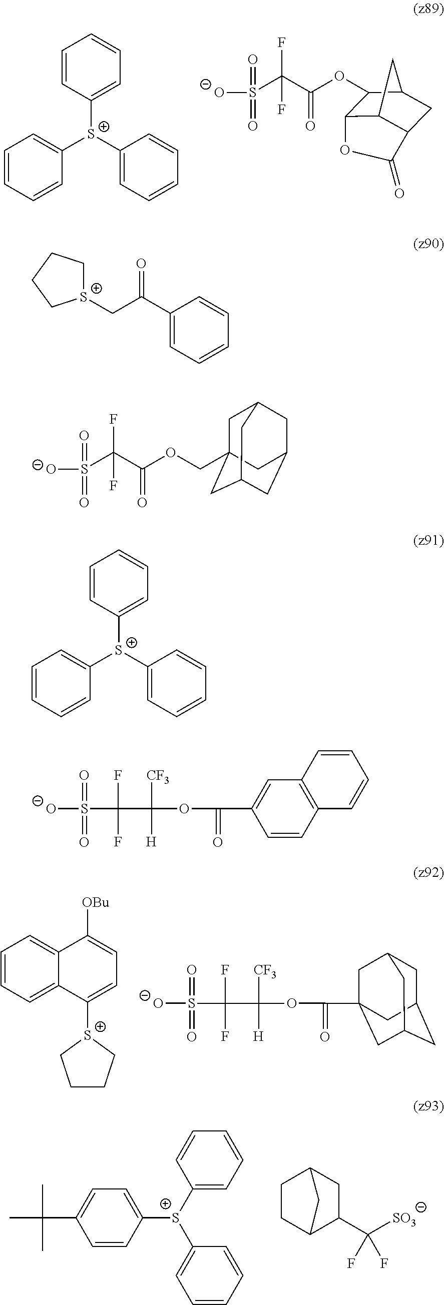

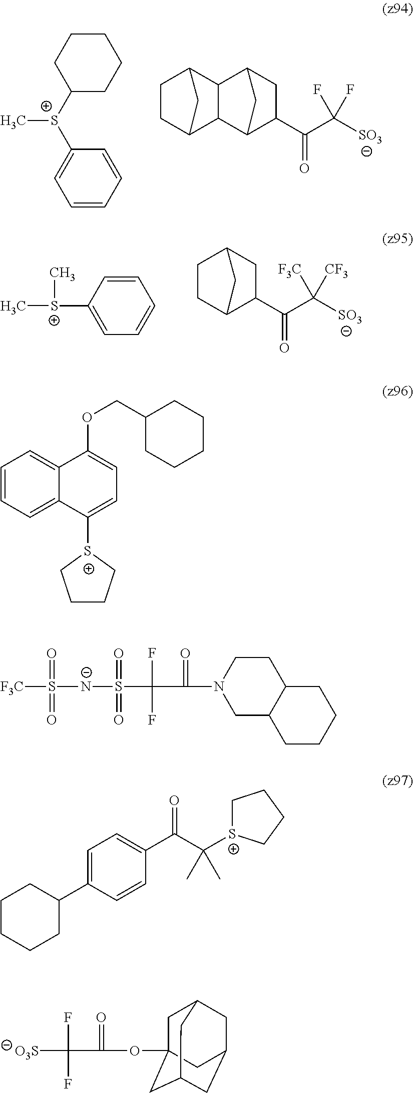

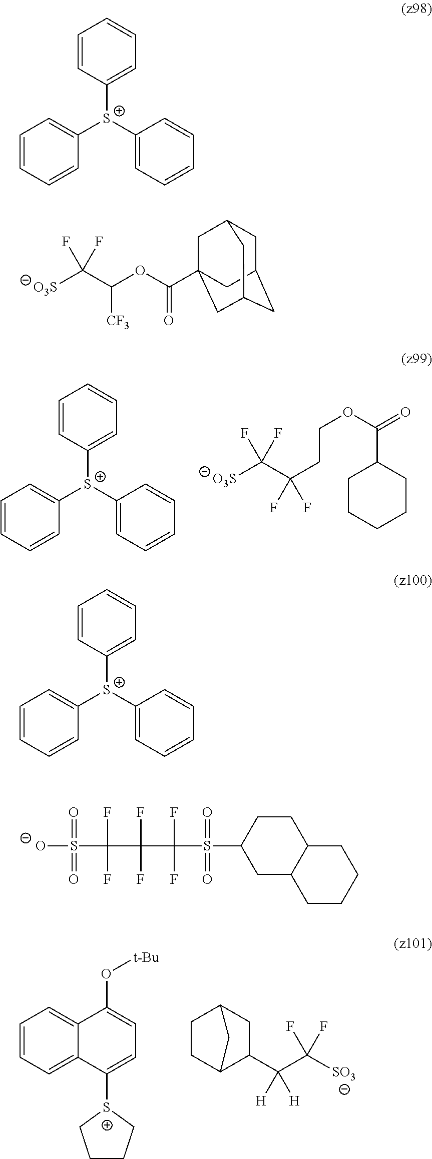

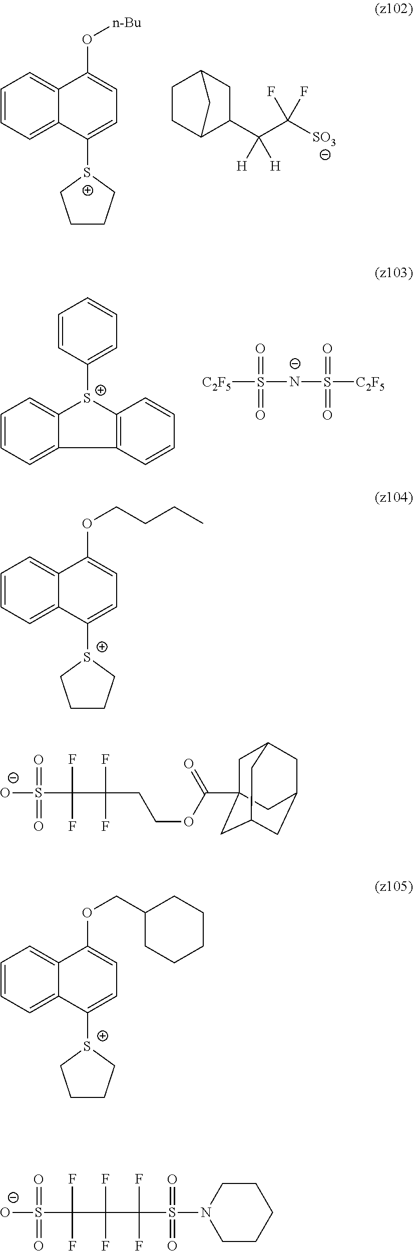

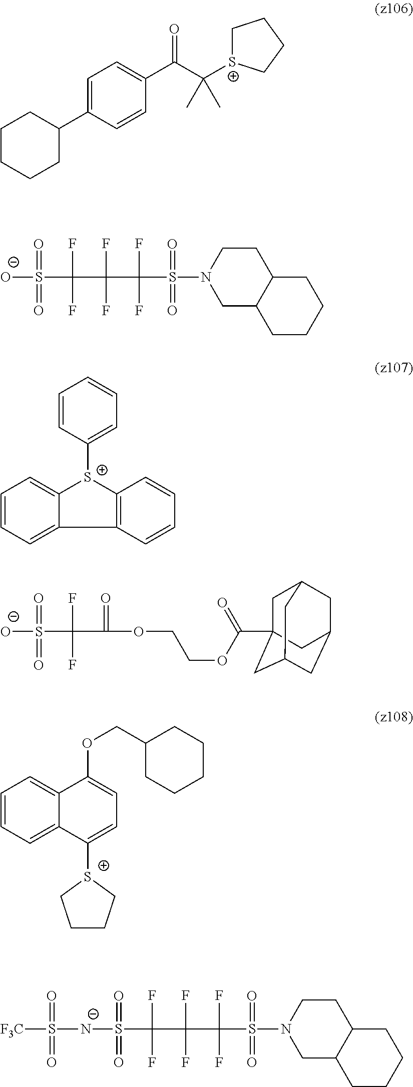 [SMILES: CC(C)(C(=O)c1ccc(C2CCCCC2)cc1)[S+]1CCCC1 ; O=S(=O)([O-])C(F)(F)C(F)(F)C(F)(F)S(=O)(=O)N1CCC2CCCCC2C1 ; c1ccc(-[s+]2c3ccccc3c3ccccc32)cc1 ; O=C(OCCOC(=O)C(F)(F)S(=O)(=O)[O-])C12CC3CC(CC(C3)C1)C2 ; c1ccc2c([S+]3CCCC3)ccc(OCC3CCCCC3)c2c1 ; O=S(=O)([N-]S(=O)(=O)C(F)(F)C(F)(F)C(F)(F)S(=O)(=O)N1CCC2CCCCC2C1)C(F)(F)F]

The acid generator may be synthesized by a known method, and may be synthesized in accordance with the method described in, for example, Japanese Patent Application Laid-Open No. 2007-161707.

The acid generator may be used either alone or in combination of two or more thereof

The content of the compound capable of generating an acid upon irradiation with an actinic ray or radiation (except for the case represented by Formula (ZI-3) or (ZI-4)) in the composition is preferably 0.1% by mass to 30% by mass, more preferably 0.5% by mass to 25% by mass, still more preferably 3% by mass to 20% by mass, and particularly preferably 3% by mass to 15% by mass, based on the total solid content of the actinic ray-sensitive or radiation-sensitive resin composition.

Further, when the acid generator is represented by Formula (ZI-3) or (ZI-4), the content thereof is preferably 5% by mass to 35% by mass, more preferably 8% by mass to 30% by mass, still more preferably 9% by mass to 30% by mass, and particularly preferably 9% by mass to 25% by mass, based on the total solid content of the composition.

(C) Salt having a conjugate base structure of an acid having a pKa of −2 or more in a molecule thereof and substantially not capable of decomposing by an actinic ray or radiation

The actinic ray-sensitive or radiation-sensitive resin composition in the present invention contains a salt (C) (hereinafter, simply referred to as “salt (C)” in some cases) having a conjugate base structure of an acid having a pKa of −2 or more, which is different from the above-described compound (B), in a molecule thereof and substantially not capable of decomposing by an actinic ray or radiation.

Further, as described below, the salt (C) is also different from a basic compound or an ammonium salt compound (N) in which basicity decreases upon irradiation with an actinic ray or radiation.

The salt (C) is a salt that has a conjugate base structure of an acid having a pKa of −2 or more in a molecule thereof, and thus a function of capturing an acid generated from the compound (B) by a buffering action may be exhibited. In addition, the salt (C) does not substantially decompose by an actinic ray or radiation, and thus may become a salt of which the function of capturing an acid generated is not substantially damaged during the exposure process in forming a pattern.

The pKa of the acid is not particularly limited as long as the pKa is −2 or more, but is preferably −2 to 16, more preferably −1.5 to 13, and particularly preferably −1 to 10 from the aforementioned viewpoint that the acid generated from the compound (B) by a buffering action is captured more certainly.

In the present invention, the pKa is one of indices for quantitatively representing the strength of acid, and has the same meaning as an acidity constant. Considering a dissociative reaction in which hydrogen ions are emitted from acid, the equilibrium constant Ka is indicated by a negative common logarithm pKa thereof. A smaller pKa indicates that the acid is stronger. For example, it is possible to use a value calculated by using ACD/Labs (manufactured by Advanced Chemistry Development, Inc.) and the like.

In the present invention, the salt (C) is preferably a compound represented by the following Formula (I).

A^{⊖}B^{⊕} (I)

In Formula (I), A⁻ represents an organic anion having a conjugate base structure of an acid having a pKa of −2 or more, and B⁺ represents an organic cation. A⁻ and B⁺ may be bonded to each other through a covalent bond.

The conjugate base structure of an acid having a pKa of −2 or more in the organic anion A⁻ is not particularly limited, and examples thereof may include a conjugate base structure such as a hydroxyl group, a mercapto group, a carboxylic acid group, a sulfonic acid group, an imide group, a sulfonamide group, a sulfonimide group, a methylene compound (a malonic acid derivative, an acetoacetic acid derivative, a cyanoacetic acid derivative, a malononitrile derivative, a cyclopentadiene derivative, a bissulfonylmethane derivative and the like) and a nitrogen-containing aromatic compound (an imidazole derivative, an indole derivative, an isocyanuric acid derivative and the like).

Hereinafter, specific examples of the conjugate base structure represented by an organic anion A″ will be described, but the present invention is not limited thereto.

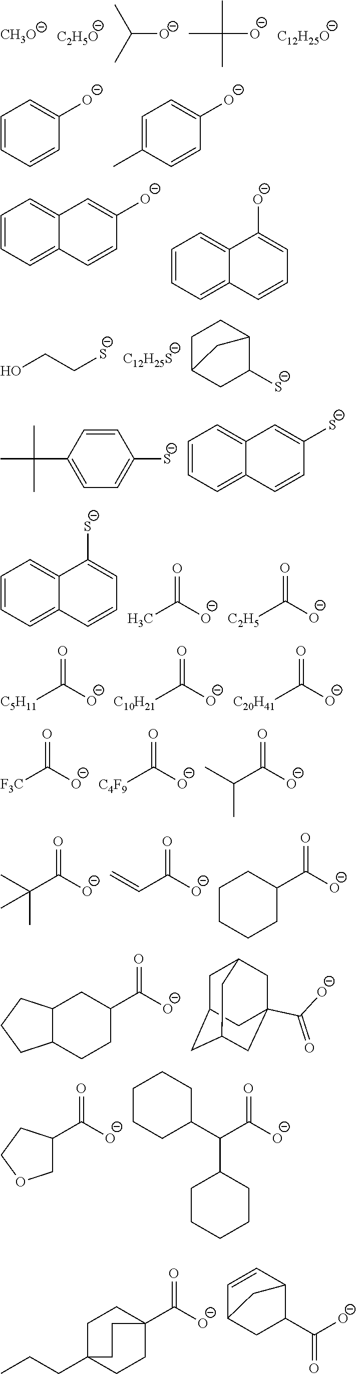

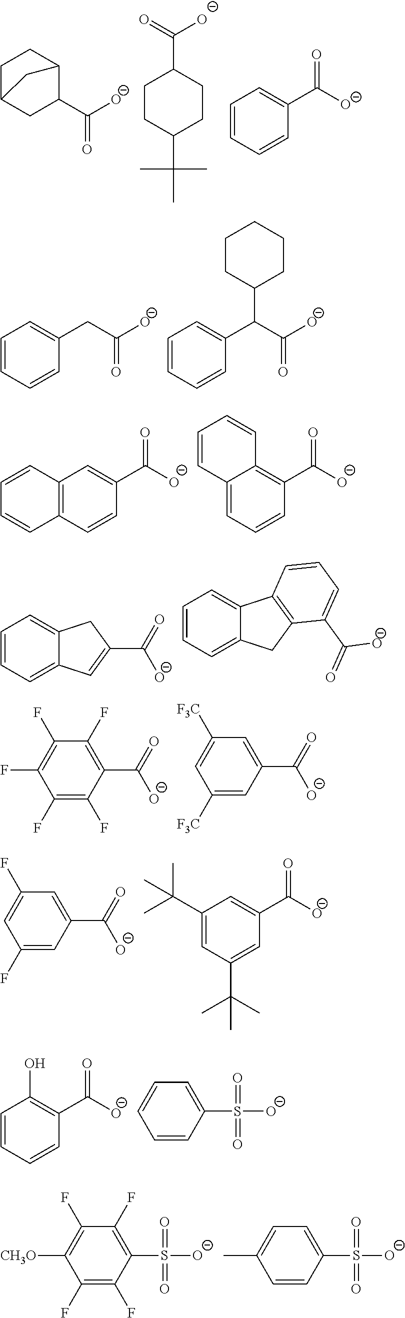

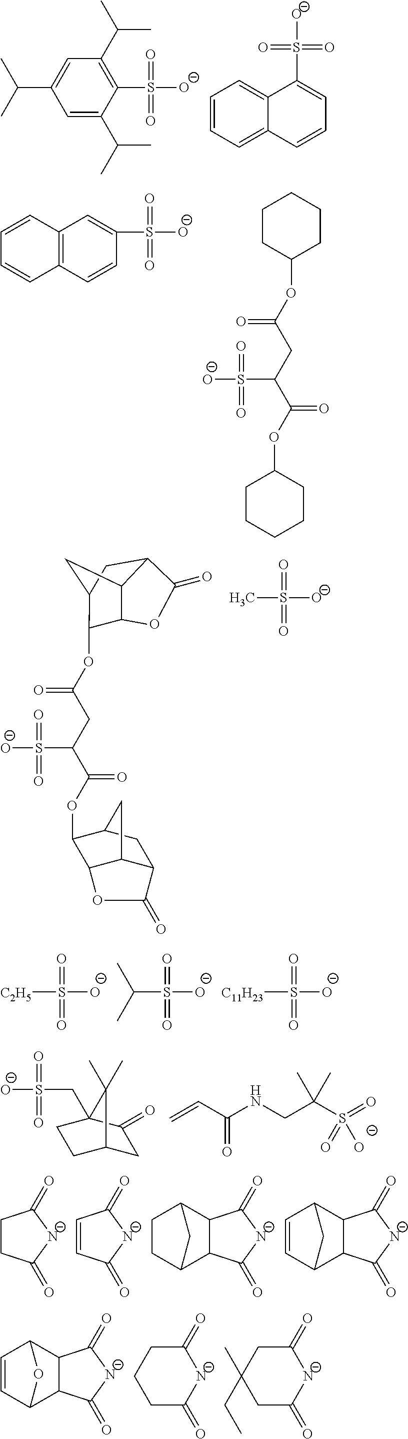

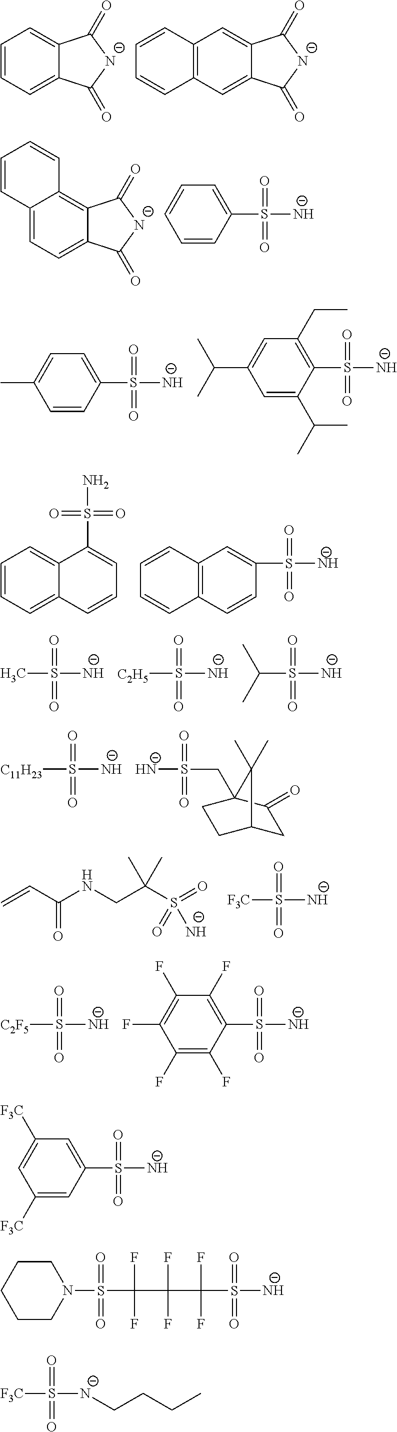

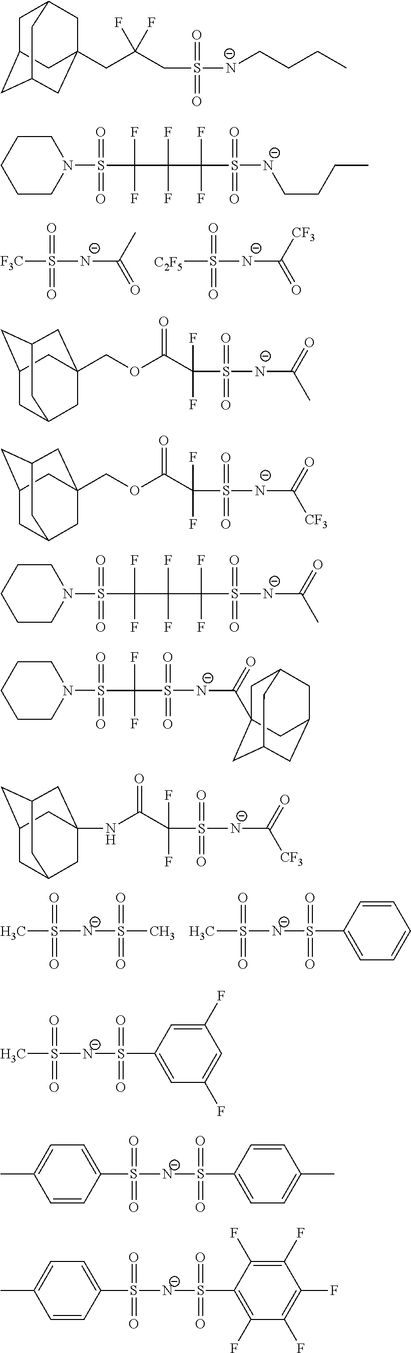

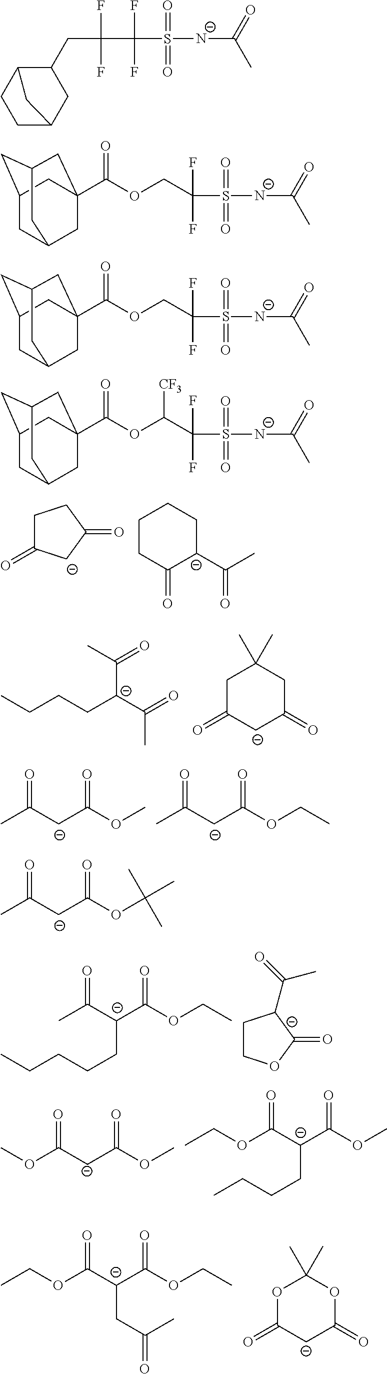

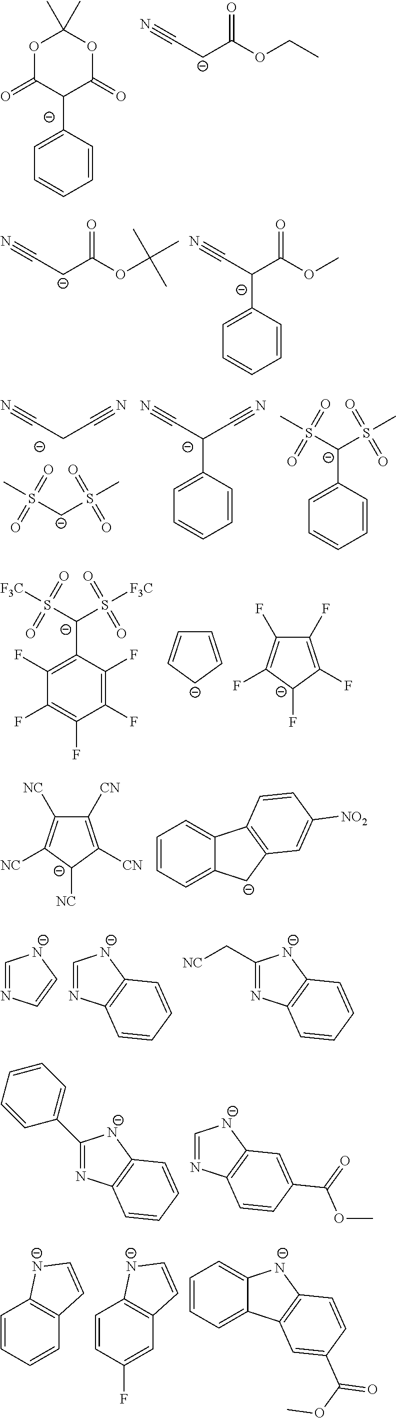

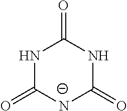

The organic cation B⁺ is not particularly limited, but it is preferred that the organic cation B+ does not decompose by an actinic-ray or radiation (more specifically an ArF excimer laser light) from the aforementioned viewpoint that the acid generated from the compound (B) is more certainly captured by a buffering action.

The structure of the organic cation B+ is not particularly limited, but examples thereof may include an ammonium cation, a sulfonium cation, a phosphonium cation and the like, and among them, an ammonium cation or a sulfonium cation is preferred, and an ammonium cation is particularly preferred. Further, it is preferred that the organic cation does not have an aromatic structure or backbone.

Hereinafter, specific examples of the organic cation represented by B⁺ will be described, but the present invention is not limited thereto.

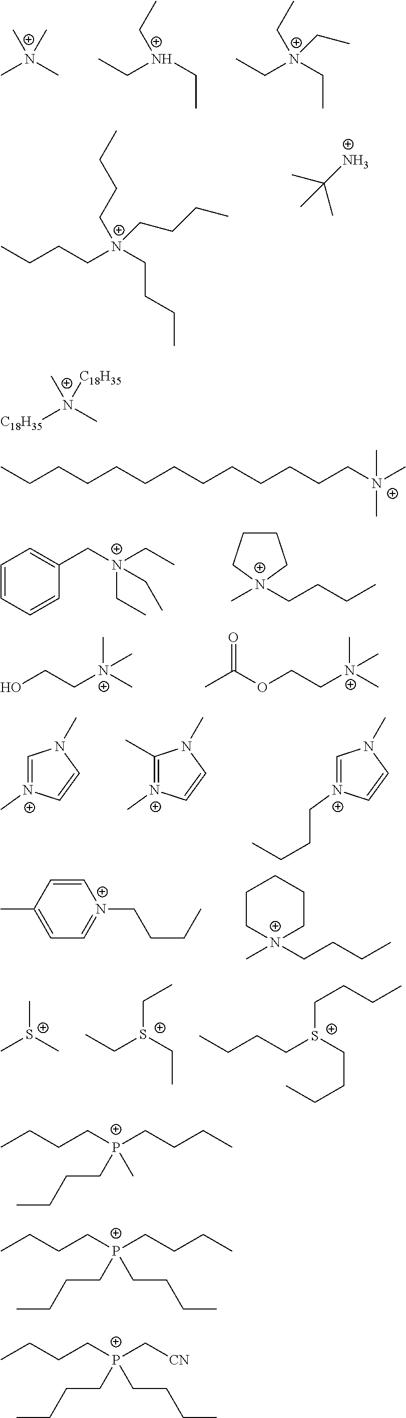

In Formula (I), A⁻ and B⁺ may be linked to each other through a covalent bond. Hereinafter, specific examples of a salt structure in which A⁻ and B⁺ are linked to each other will be described, but the present invention is not limited thereto.

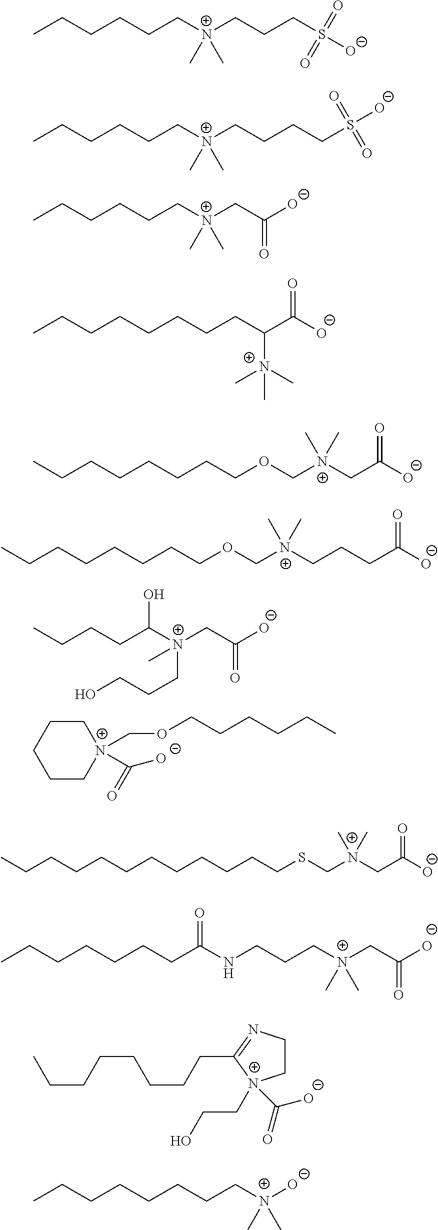

The salt (C) having a conjugate base structure of an acid having a pKa of −2 or more in a molecule thereof and (substantially not capable of decomposing by an actinic ray or radiation may be synthesized by a known method, and may be synthesized in accordance with methods described in, for example, “Hiroshi Horiguchi, Synthetic Surfactants <augmented edition>, Sankyo Publishing Co., Ltd., 1969”, “Surfactant Evaluation•Test Method Editorial Committee, Surfactant Evaluation•Test Method, Gihodo Shuppan Co., Ltd., 2002” and the like.

In the present invention, the use amount of the salt (C) having a conjugate base structure of an acid having a pKa of −2 or more in a molecule thereof and substantially not capable of decomposing by an actinic ray or radiation is preferably 0.001% by mass to 10% by mass, and more preferably 0.01% by mass to 5% by mass, based on the solid content of the actinic ray-sensitive or radiation-sensitive resin composition.

The use ratio of the acid generator and the salt (C) in the composition is acid generator/salt (C) (molar ratio)=2.5 to 300. That is, the molar ratio is preferably 2.5 or more from the viewpoint of sensitivity and resolution, and preferably 300 or less from the viewpoint that as time elapses from exposure until a heating treatment, a reduction in resolution caused by thickening of the resist pattern is suppressed. The acid generator/salt (C) (molar ratio) is more preferably 5.0 to 200, and still more preferably 7.0 to 150.

[4] (D) Hydrophobic resin different from resin (A)

Particularly when applied to immersion exposure, the actinic ray-sensitive or radiation-sensitive resin composition according to the present invention may contain a hydrophobic resin different from the resin (A) (hereinafter, also referred to as “hydrophobic resin (D) or simply referred to as “resin (D)).

Accordingly, when the hydrophobic resin (D) is unevenly distributed on the film top layer and the immersion medium is water, the static/dynamic contact angle of the resist film surface against water may be improved, thereby improving an immersion liquid follow-up property.

It is preferred that the hydrophobic resin (D) is designed to be unevenly distributed at the interface as described above, but unlike a surfactant, the hydrophobic resin (D) does not necessarily have a hydrophilic group in the molecule thereof, and may not contribute to the mixing of polar/non-polar materials homogeneously.

From the viewpoint of uneven distribution on the film top layer, the hydrophobic resin (D) has preferably one or more of “a fluorine atom”, “a silicon atom” and “a CH₃ partial structure contained in a side chain moiety of a resin”, and more preferably two or more thereof.

When the hydrophobic resin (D) includes a fluorine atom and/or a silicon atom, the fluorine atom and/or the silicon atom in the hydrophobic resin (D) may be included in the main chain of the resin, and may be included in the side chain thereof.

When hydrophobic resin (D) includes a fluorine atom, a resin having an alkyl group having a fluorine atom, a cycloalkyl group having a fluorine atom, or an aryl group having a fluorine atom is preferred as a partial structure having a fluorine atom.

The alkyl group (having preferably 1 to 10 carbon atoms, and more preferably 1 to 4 carbon atoms) having a fluorine atom is a straight or branched alkyl group in which at least one hydrogen atom is substituted with a fluorine atom, and may further have a substituent other than a fluorine atom.

The cycloalkyl group having a fluorine atom is a monocyclic or polycyclic cycloalkyl group in which at least one hydrogen atom is substituted with a fluorine atom and may further have a substituent other than a fluorine atom.

The aryl group having a fluorine atom is an aryl group in which at least one hydrogen atom in an aryl group such as a phenyl group and a naphthyl group is substituted with a fluorine atom and may further have a substituent other than a fluorine atom.

Preferred examples of the alkyl group having a fluorine atom, the cycloalkyl group having a fluorine atom and the aryl group having a fluorine atom may include groups represented by the following Formulas (F2) to (F4), but the present invention is not limited thereto.

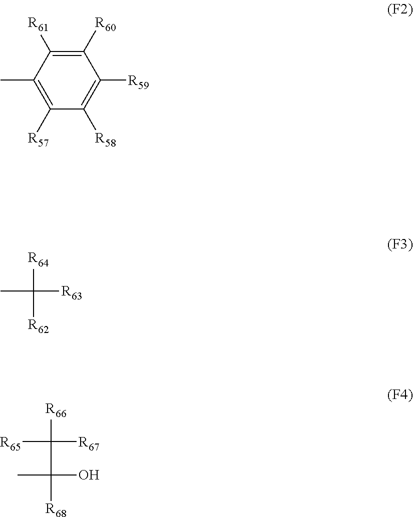

In Formulas (F2) to (F4),

each of R₅₇ to R₆₈ independently represents a hydrogen atom, a fluorine atom or an alkyl group (straight or branched), provided that each of at least one of R₅₇ to R₆₁, at least one of R₆₂ to R₆₄ and at least one of R₆₅ to R₆₈ independently represents a fluorine atom or an alkyl group (preferably having 1 to 4 carbon atoms) in which at least one hydrogen atom is substituted with a fluorine atom.

All of R₅₇ to R₆₁ and R₆₅ to R₆₇ are preferably a fluorine atom. R₆₂, R₆₃ and R₆₈ are preferably an alkyl group (preferably having 1 to 4 carbon atoms) in which at least one hydrogen atom is substituted with a fluorine atom, and more preferably a perfluoroalkyl group having 1 to 4 carbon atoms. R₆₂ and R₆₃ may be bound with each other to form a ring.

Specific examples of the group represented by Formula (F2) may include a p-fluorophenyl group, a pentafluorophenyl group, a 3,5-di(trifluoromethyl)phenyl group and the like.

Specific examples of the group represented by Formula (F3) may include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group and the like. A hexafluoroisopropyl group, a heptafluoroisopropyl group, a hexafluoro(2-methyl)isopropyl group, an octafluoroisobutyl group, a nonafluoro-t-butyl group and a perfluoroisopentyl group are preferred, and a hexafluoroisopropyl group and a heptafluoroisopropyl group are more preferred.

Specific examples of the group represented by Formula (F4) may include —C(CF₃)₂OH, —C(C₂F₅)₂OH, —C(CF₃)(CH₃)OH, —CH(CF₃)OH and the like, and —C(CF₃)₂OH is preferred.

The partial structure including a fluorine atom may be bonded directly to the main chain or may be further bonded to the main chain through a group selected from the group consisting of an alkylene group, a phenylene group, an ether bond, a thioether bond, a carbonyl group, an ester bond, an amide bond, a urethane bond and a ureylene bond, or a group formed by combining two or more thereof.

Hereinafter, specific examples of the repeating unit having a fluorine atom will be described, but the present invention is not limited thereto.

In the specific examples, X₁ represents a hydrogen atom, —CH₃, —F, or —CF₃. X₂ represents —F or —CF₃.

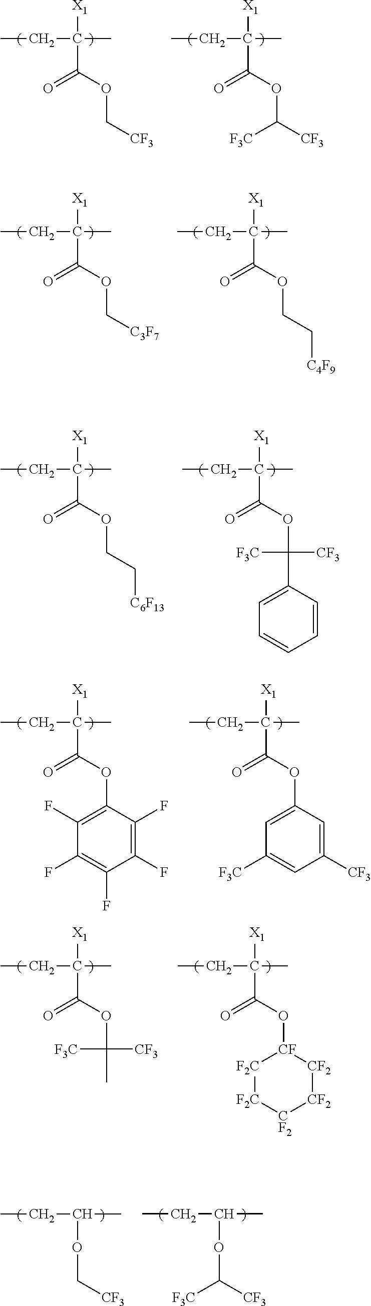

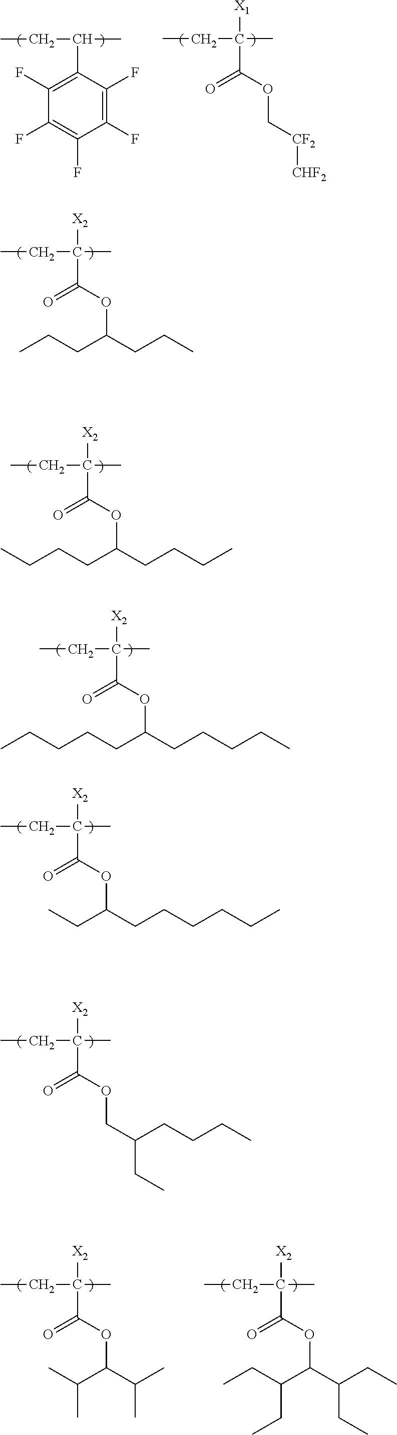

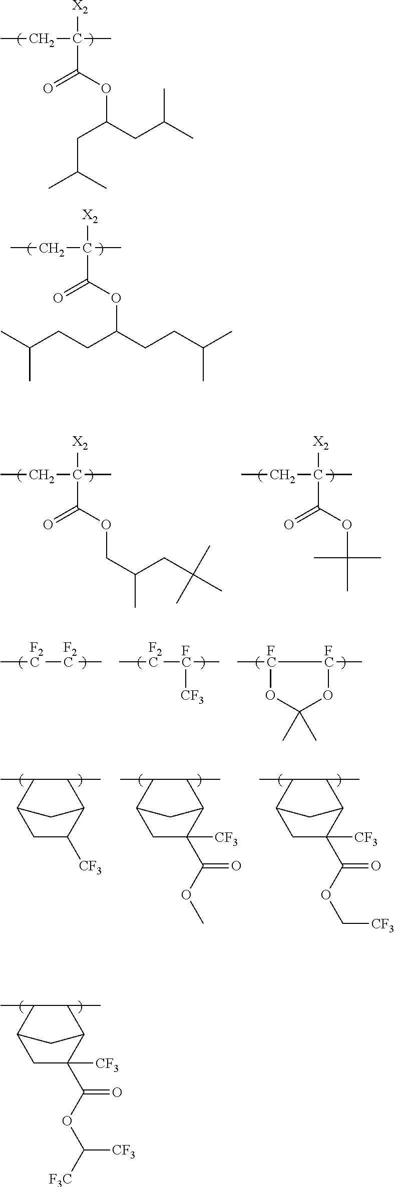

The hydrophobic resin (D) may contain a silicon atom. As a partial structure having a silicon atom, a resin having an alkylsilyl structure (preferably a trialkylsilyl group) or a cyclic siloxane structure is preferred.

Specific examples of the alkylsilyl structure or the cyclic siloxane structure may include groups represented by the following Formulas (CS-1) to (CS-3), and the like.

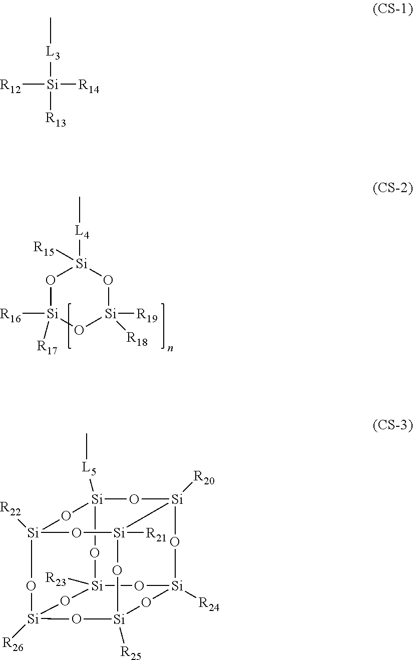

In Formulas (CS-1) to (CS-3), each of R₁₂ to R₂₆ independently represents a straight or branched alkyl group (preferably having 1 to 20 carbon atoms) or a cycloalkyl group (preferably having 3 to 20 carbon atoms).

Each of L₃ to L₅ represents a single bond or a divalent linking group. Examples of the divalent linking group may include a sole member or a combination of two or more members (preferably having a total carbon number of 12 or less), selected from the group consisting of an alkylene group, a phenylene group, an ether bond, a thioether bond, a carbonyl group, an ester bond, an amide bond, a urethane bond and a urea bond.

n represents an integer of 1 to 5. n is preferably an integer of 2 to 4.

Hereinafter, specific examples of the repeating unit having a group represented by Formulas (CS-1) to (CS-3) will be described, but the present invention is not limited thereto. Meanwhile, in the specific examples, X₁ represents a hydrogen atom, —CH₃, —F or —CF₃.

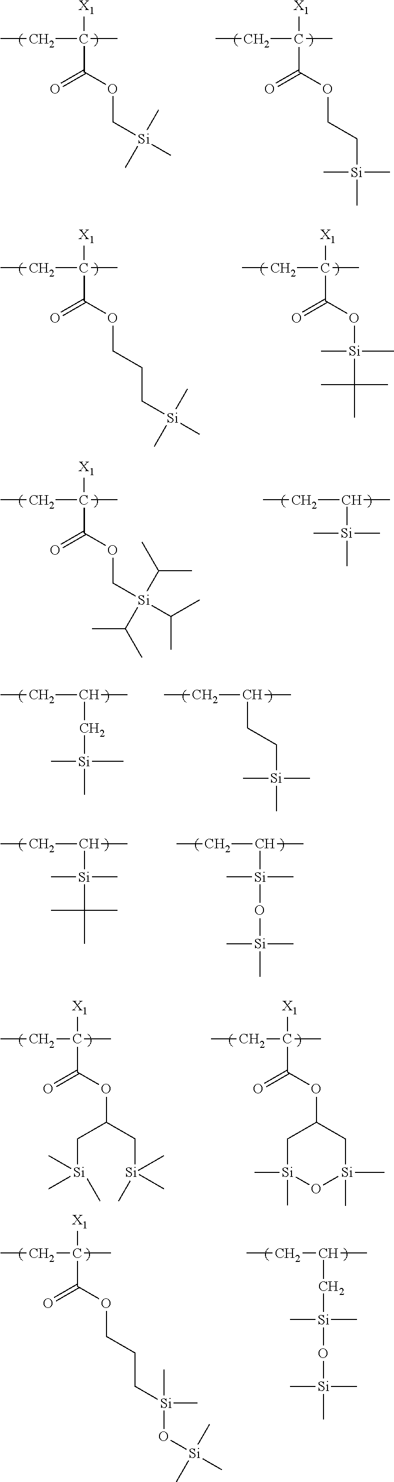

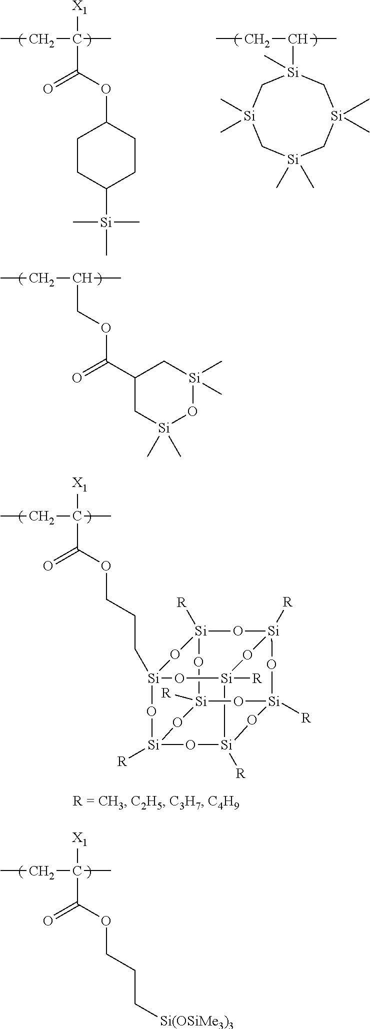

The hydrophobic resin (D) may contain a repeating unit having a sulfonic acid amine salt structure. Hereinafter, the repeating unit having a sulfonic acid amine salt structure will be exemplified, but the present invention is not limited thereto.

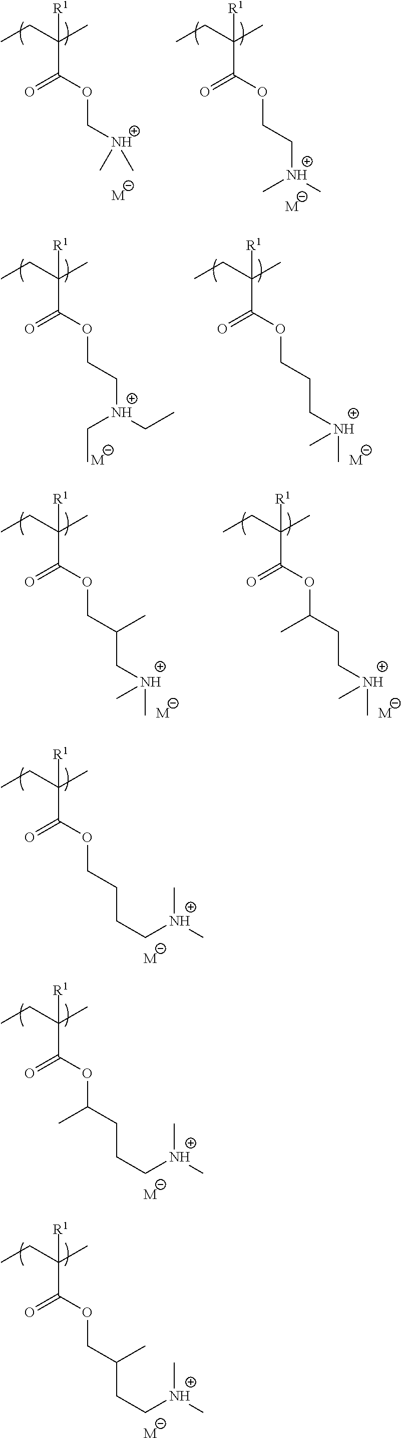

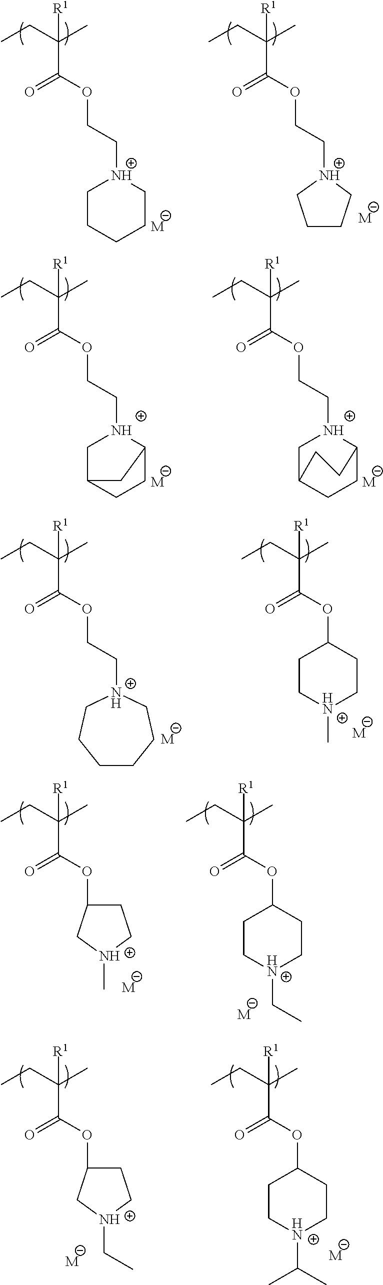

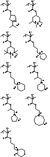

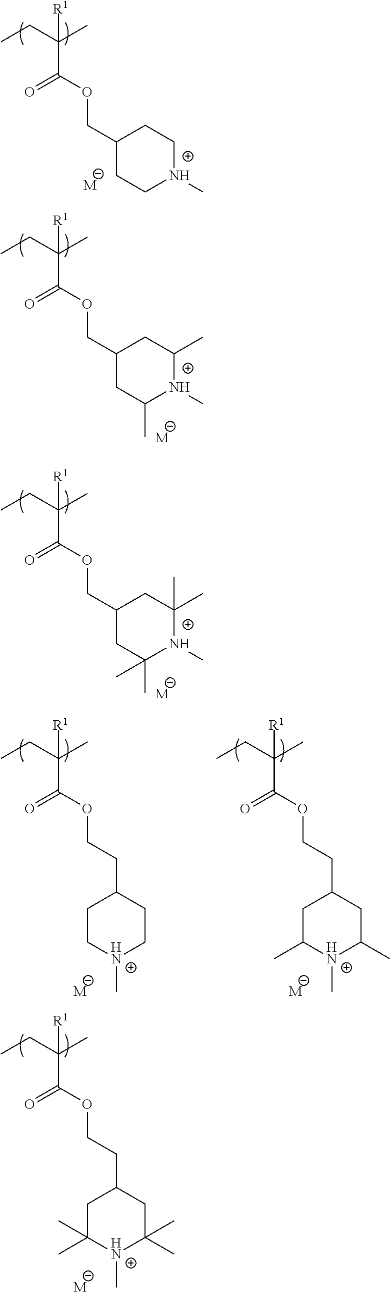

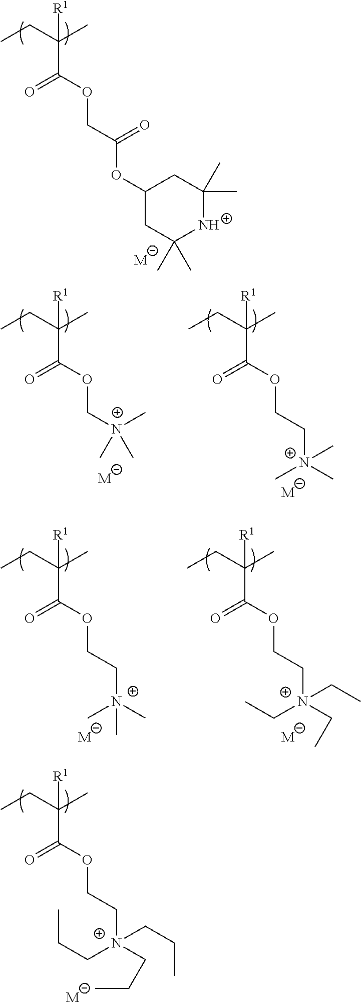

In each formula, R¹ represents a hydrogen atom or an alkyl group. M⁻ represents a sulfonic acid ion, and is preferably an aryl sulfonate such as tosylate, benzene sulfonate, 4-fluorobenzene sulfonate, 1,2,3,4,5-pentafluoro benzene sulfonate, mesythylene sulfonate, 2,4,6-triisopropyl benzene sulfonate, naphthyl sulfonate and pyrene sulfonate, and a sulfonic acid ion such as mesylate and butane sulfonate.

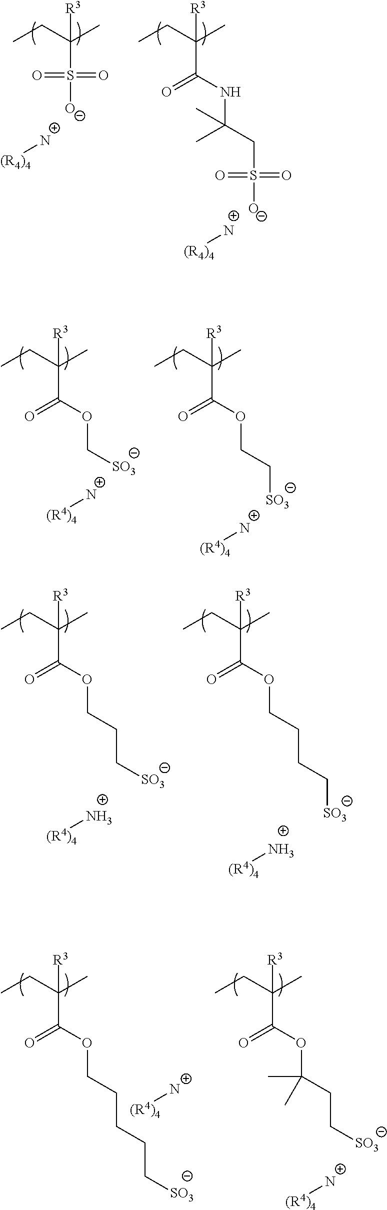

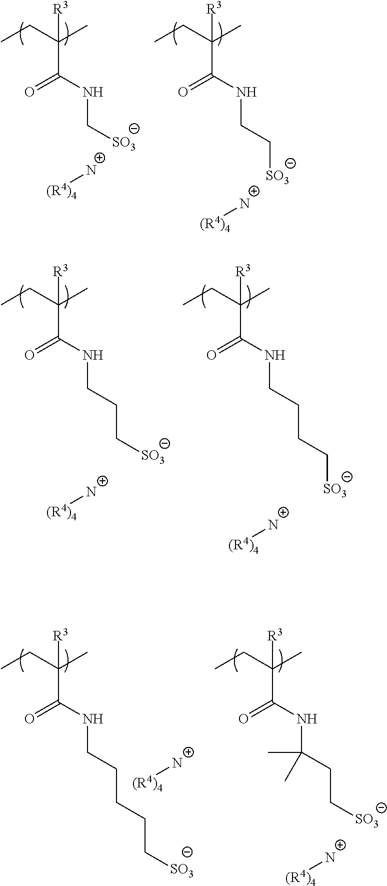

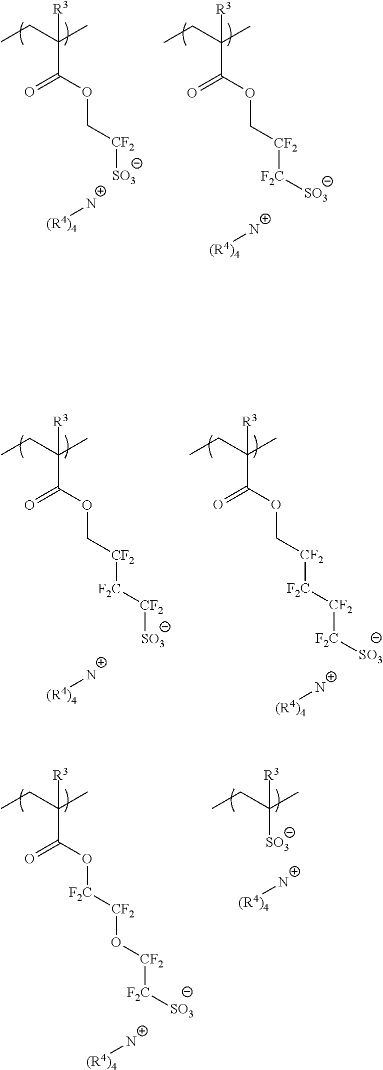

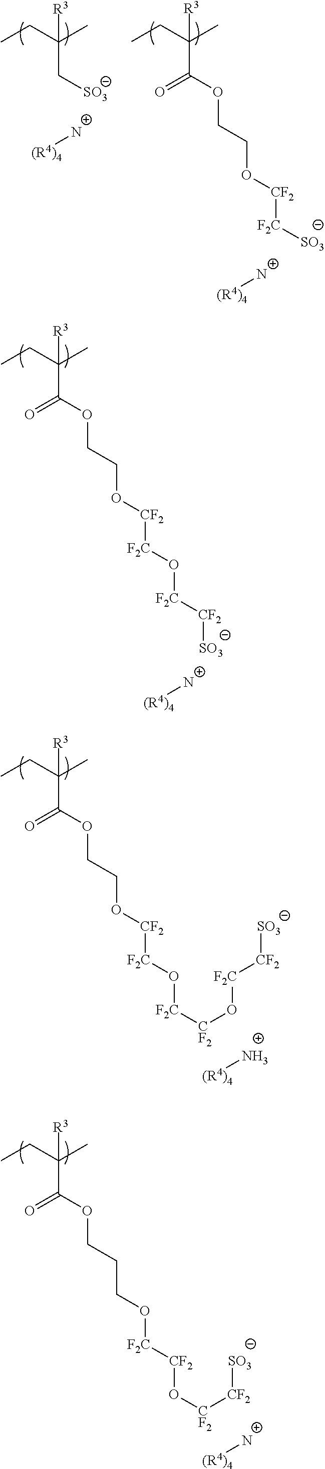

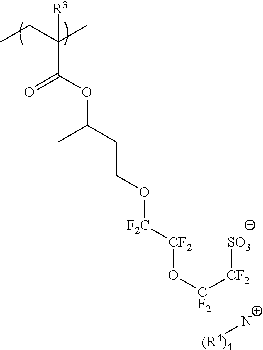

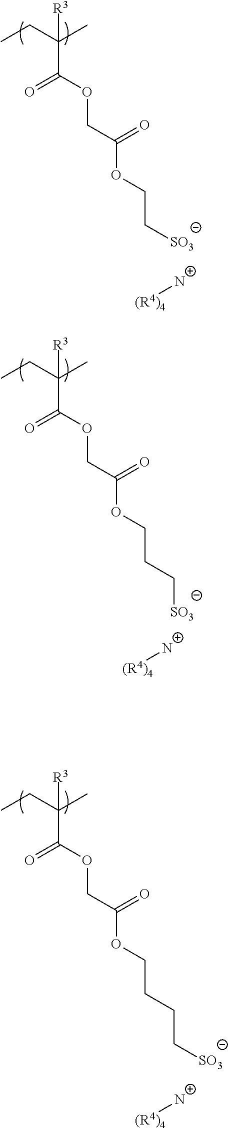

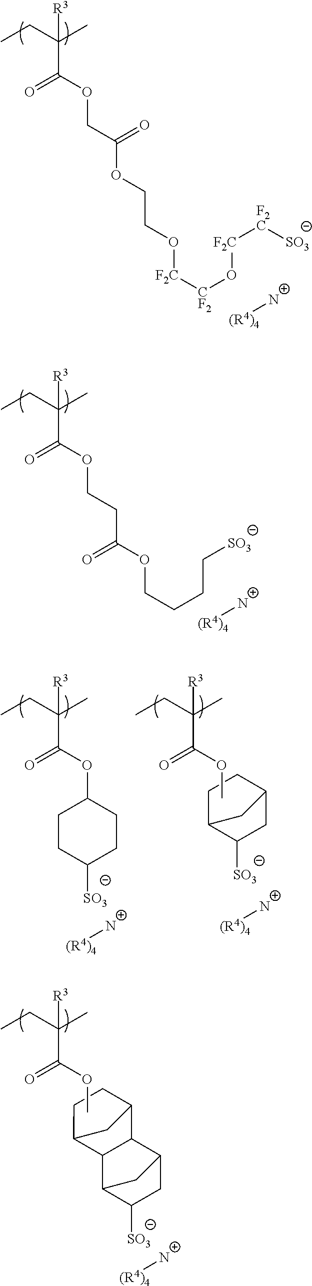

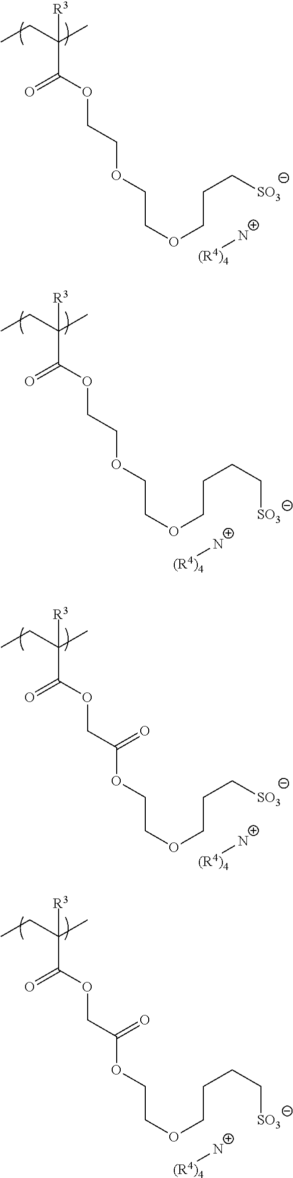

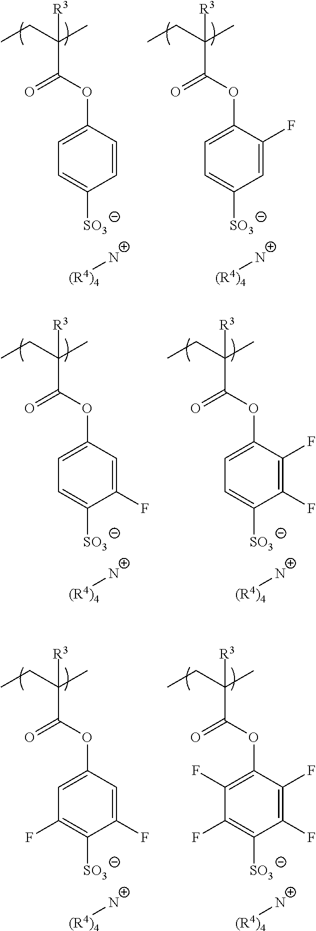

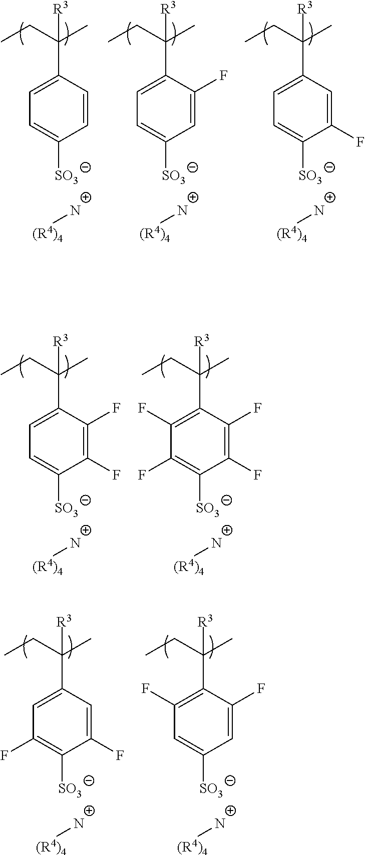

In each formula, R³ represents a hydrogen atom or an alkyl group.

Each R⁴ independently represents a hydrogen atom, a straight, branched or cyclic alkyl group having 1 to 20 carbon atoms, an alkenyl group having 2 to 20 carbon atoms, or an aryl group having 6 to 10 carbon atoms. The straight, branched or cyclic alkyl group having 1 to 20 carbon atoms and the alkenyl group having 2 to 20 carbon atoms for R⁴ may have a hydroxyl group, an ether bond, an ester bond, a cyano group, an amino group, a double bond or a halogen atom. Two to four les may be bound with each other to form a ring having 3 to 20 carbon atoms.

The hydrophobic resin (D) may contain a repeating unit having a carboxylic acid amine salt structure. Hereinafter, the repeating unit having a carboxylic acid amine salt structure will be exemplified, but the present invention is not limited thereto.

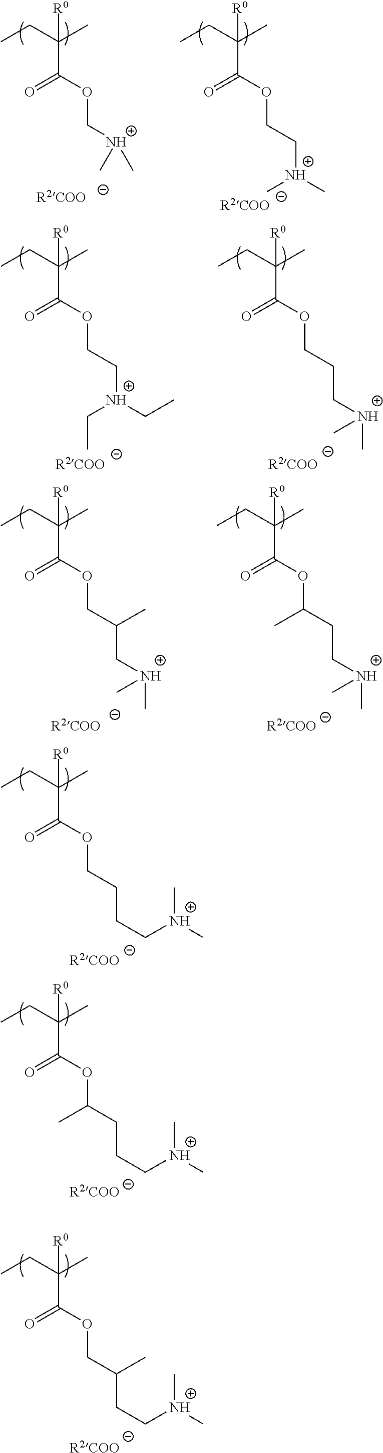

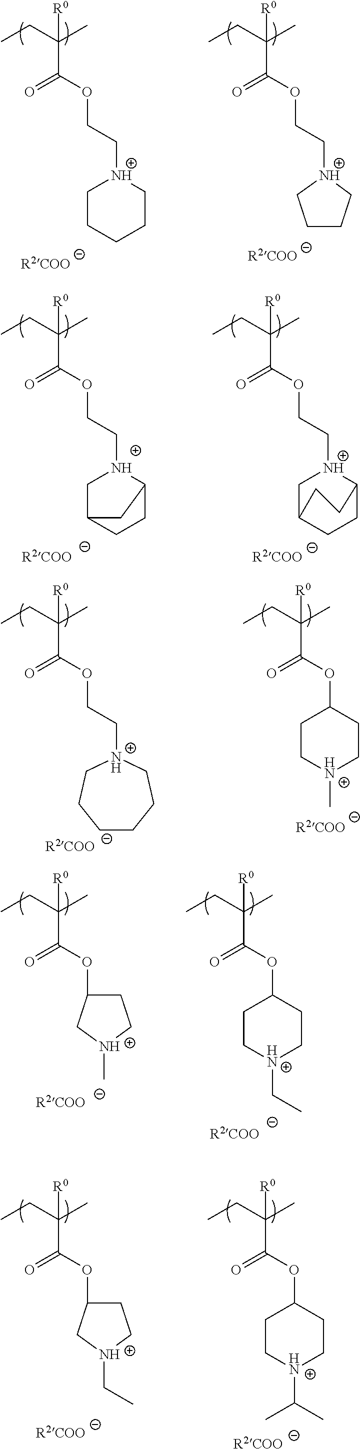

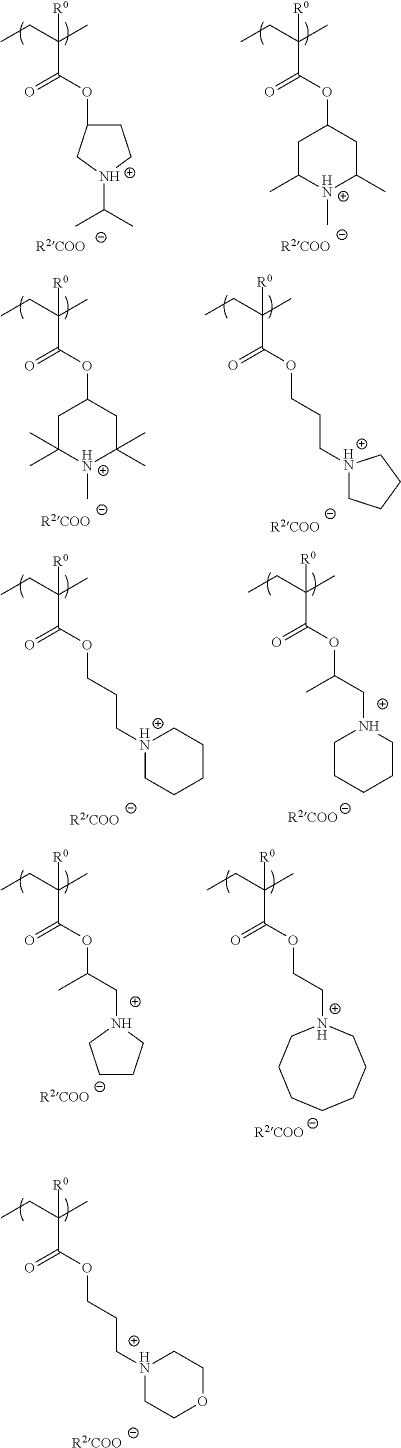

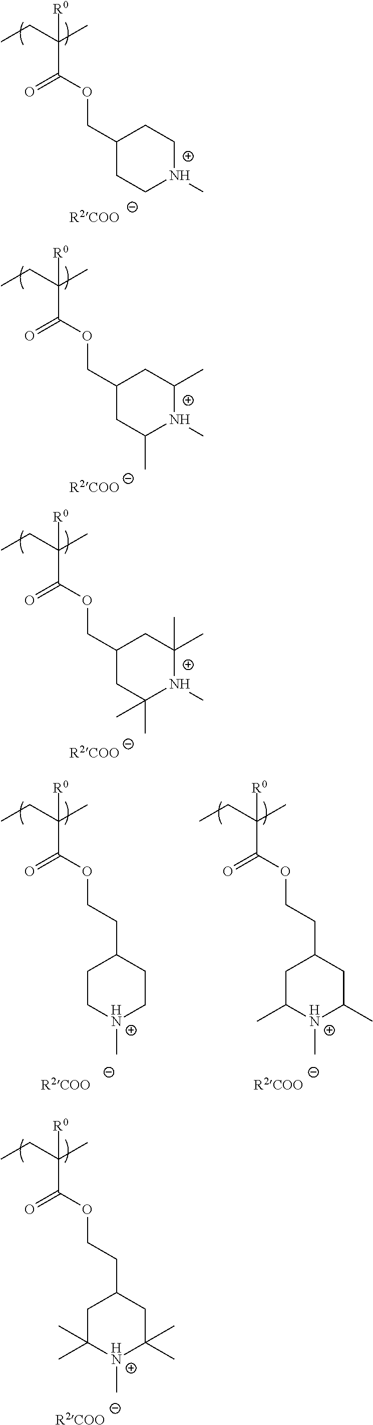

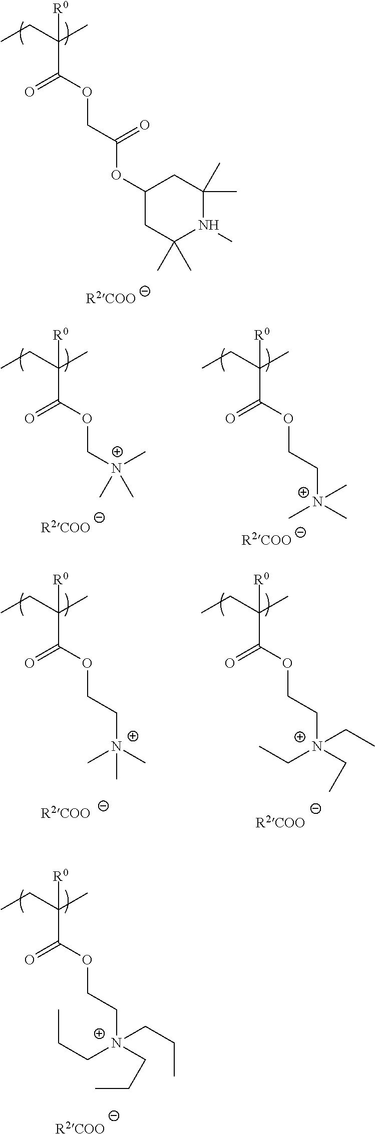

In each formula, R⁰ represents a hydrogen atom or an alkyl group.

Specific examples of a carboxylic acid anion represented by R²COO— may include formic acid anion, acetic acid anion, propionic acid anion, butyric acid anion, isobutyric acid anion, valeric acid anion, isovaleric acid anion, pivalic acid anion, hexanoic acid anion, octanoic acid anion, cyclohexanecarboxylic acid anion, cyclohexylacetic acid anion, lauric acid anion, myristic acid anion, palmitic acid anion, stearic acid anion, phenylacetic acid anion, diphenylacetic acid anion, phenoxyacetic acid anion, mandelic acid anion, benzoylformic acid anion, cinnamic acid anion, dihydrocinnamic acid anion, benzoic acid anion, methylbenzoic acid anion, salicylic acid anion, naphthalenecarboxylic acid anion, anthracenecarboxylic acid anion, anthraquinonecarboxylic acid anion, hydroxyacetic acid anion, pivalic acid anion, lactic acid anion, methoxyacetic acid anion, 2-(2-methoxyethoxyl)acetic acid anion, 2-(2-(2-methoxyethoxyl)ethoxy)acetic acid anion, diphenolic acid anion, monochloroacetic acid anion, dichloroacetic acid anion, trichloroacetic acid anion, trifluoroacetic acid anion, pentafluoropropionic acid anion, heptafluorobutyric acid anion and the like, and monoanions of dicarboxylic acids such as succinic acid, tartaric acid, glutaric acid, pimelic acid, sebacic acid, phthalic acid, isophthalic acid, terephthalic acid, naphthalenedicarboxylic acid, cyclohexanedicarboxylic acid and cyclohexenedicarboxylic acid.

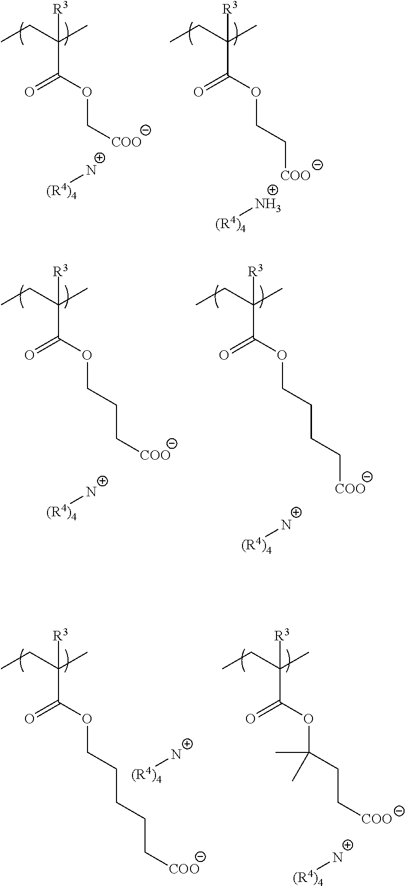

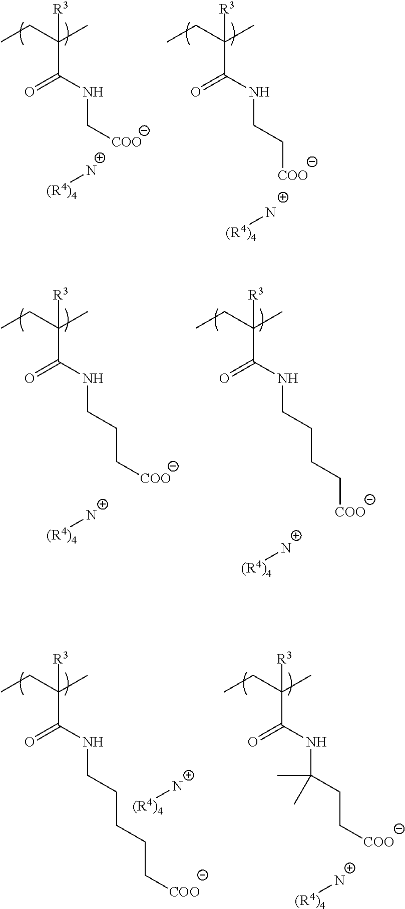

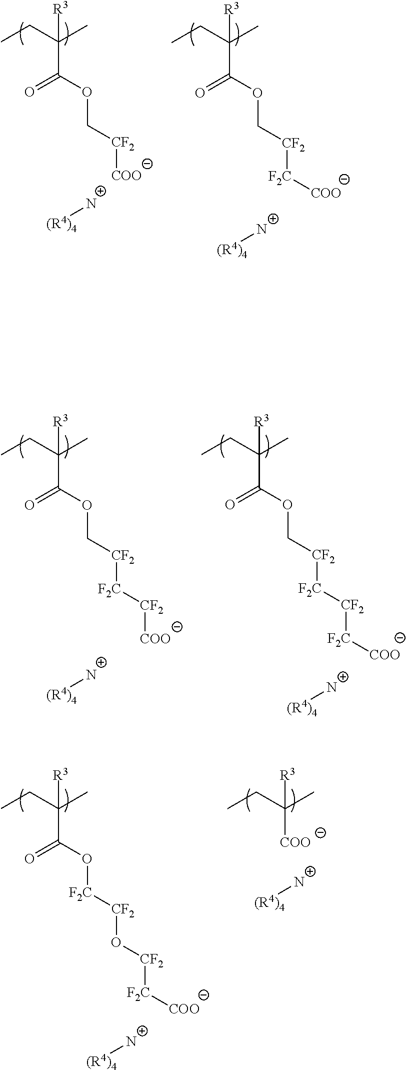

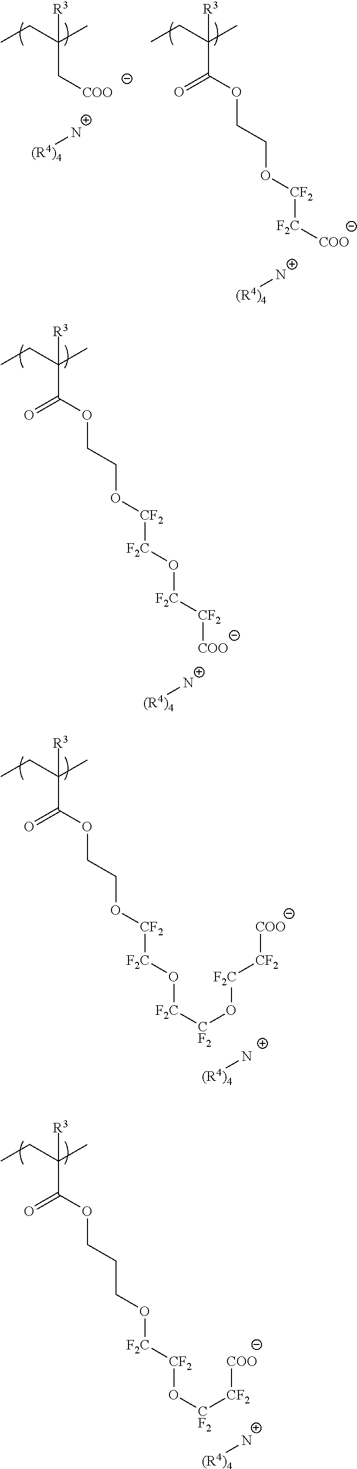

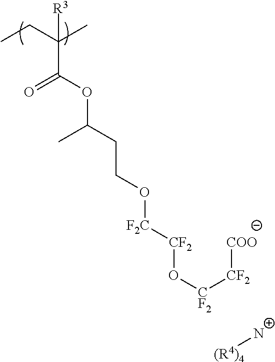

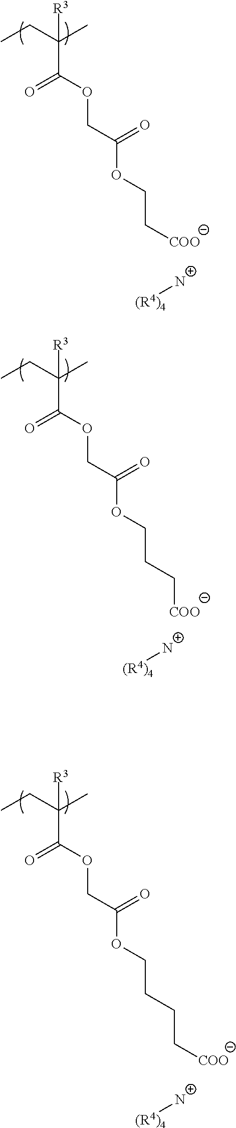

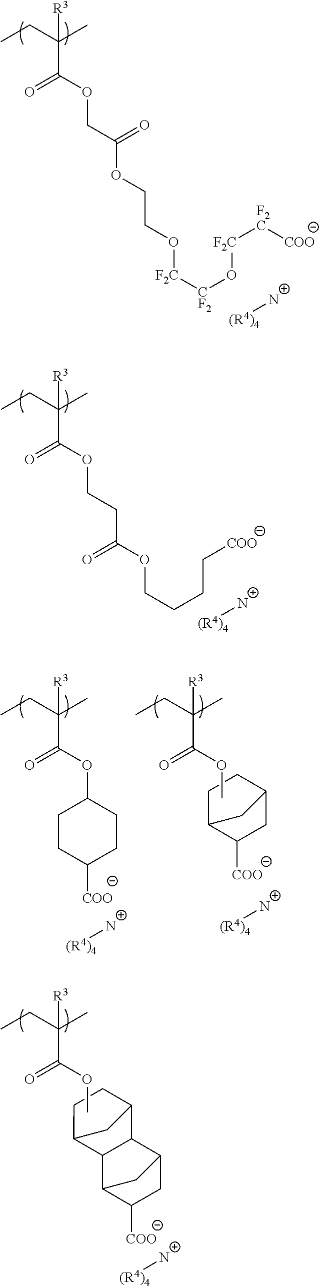

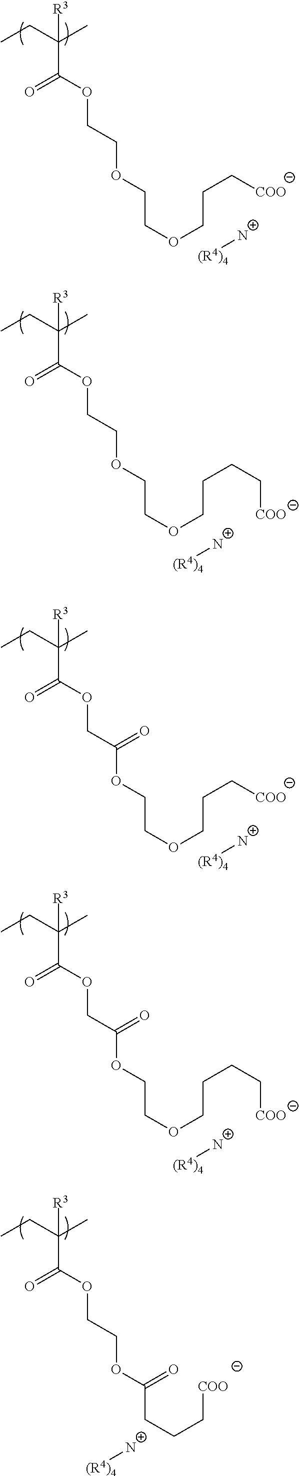

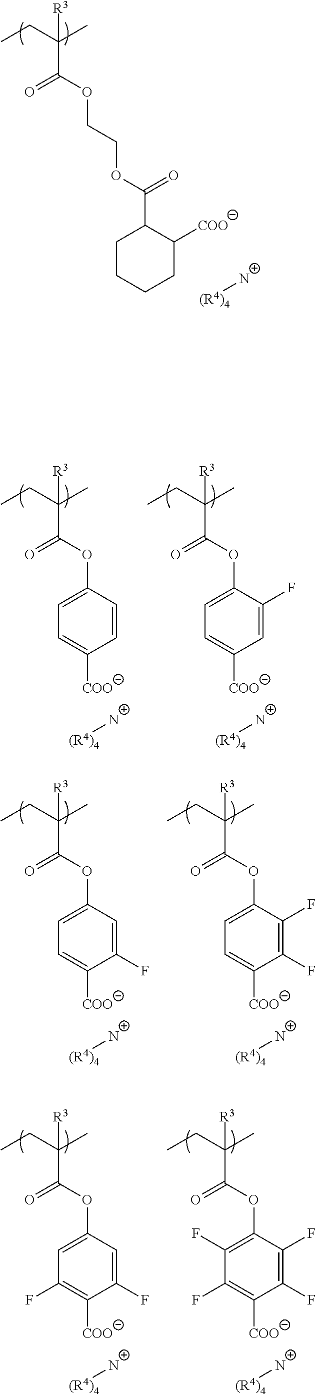

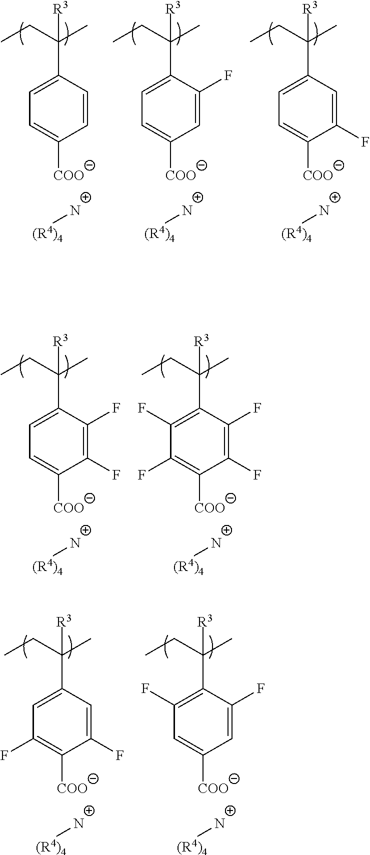

In each formula, R³ represents a hydrogen atom or an alkyl group.

Each R⁴ independently represents a hydrogen atom, a straight, branched or cyclic alkyl group having 1 to 20 carbon atoms, an alkenyl group having 2 to 20 carbon atoms, or an aryl group having 6 to 10 carbon atoms. The straight, branched or cyclic alkyl group having 1 to 20 carbon atoms and the alkenyl group having 2 to 20 carbon atoms for R⁴ may have a hydroxyl group, an ether bond, an ester bond, a cyano group, an amino group, a double bond or a halogen atom. Two to four R⁴s may be bound with each other to form a ring having 3 to 20 carbon atoms.

The hydrophobic resin (D) may contain a repeating unit having an amine structure.

Hereinafter, the repeating unit having an amine structure will be exemplified, but the present invention is not limited thereto.

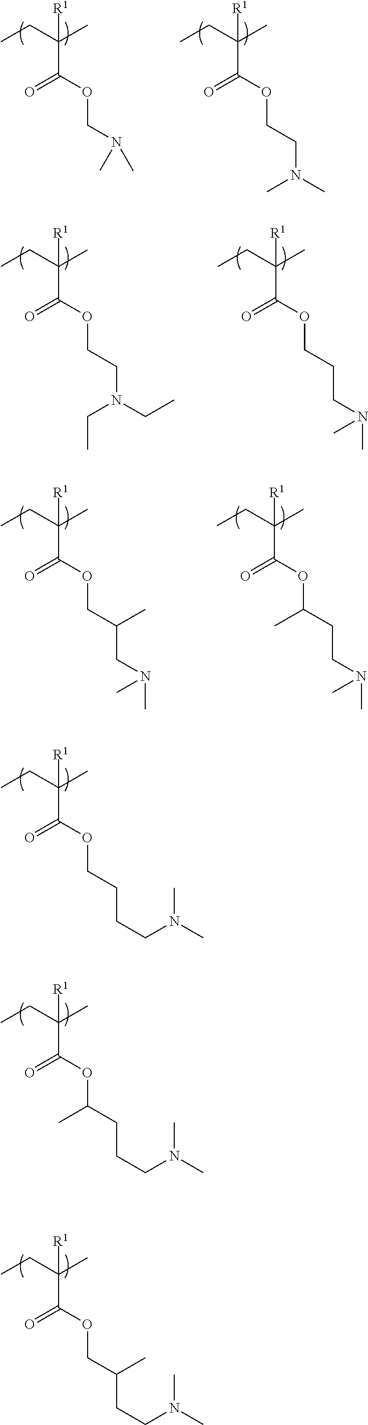

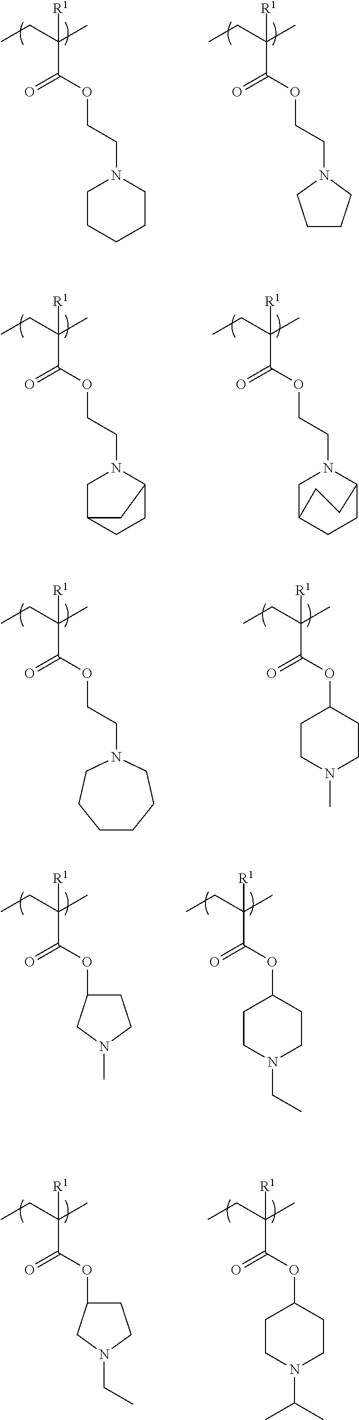

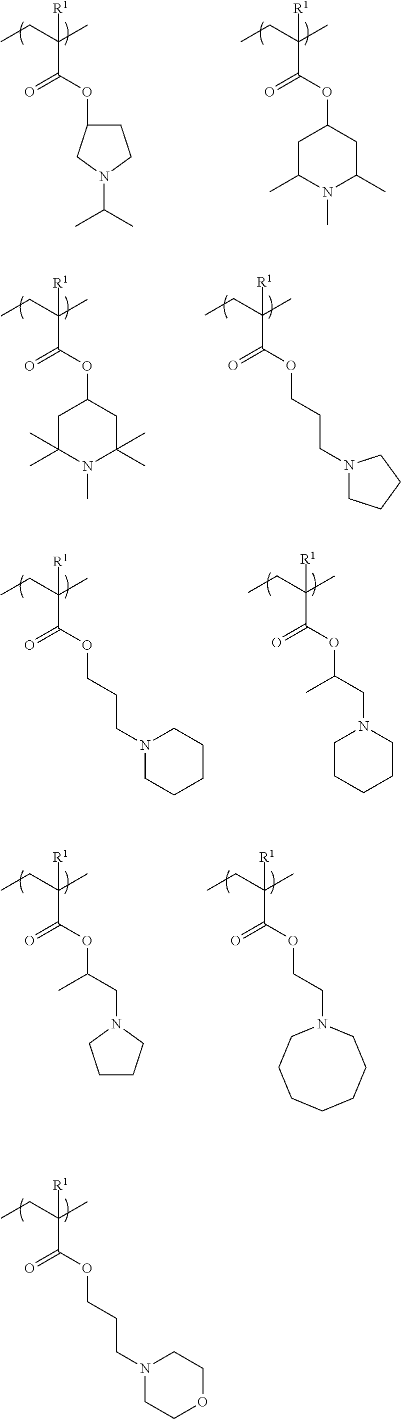

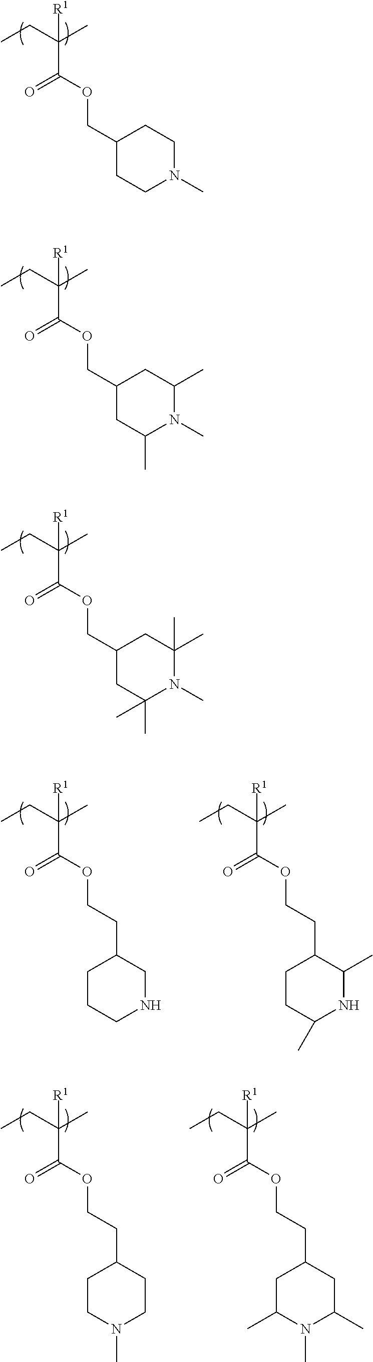

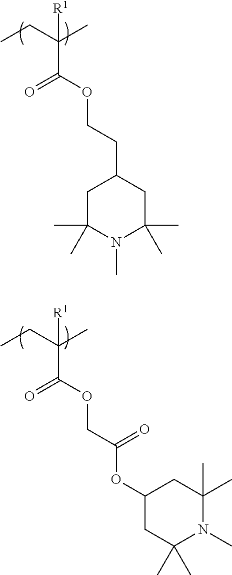

In each formula, R¹ represents a hydrogen atom or an alkyl group.

In the present invention, when the hydrophobic resin (D) contains a repeating unit having a sulfonic acid amine salt structure, a repeating unit having a carboxylic acid amine salt structure or a repeating unit having an amine structure, each of the contents of the repeating unit having a sulfonic acid amine salt structure, the repeating unit having a carboxylic acid amine salt structure or the repeating unit having an amine structure in the hydrophobic resin (D) is preferably 0 mol % to 30 mol %, more preferably 0 mol % to 20 mol %, and particularly preferably 0 mol % to 10 mol %, based on all the repeating units of the hydrophobic resin (D).

Further, as described above, it is preferred that the hydrophobic resin (D) also includes a CH₃ partial structure in the side chain moiety thereof

Here, the CH₃ partial structure (hereinafter, simply referred to as a “side chain CH₃ partial structure” in some cases) that the side chain moiety in the resin (D) has includes a CH₃ partial structure that an ethyl group, a propyl group and the like have.

Meanwhile, a methyl group (for example, an α-methyl group of the repeating unit having a methacrylic acid structure) directly bonded to the main chain of the resin (D) slightly contributes to the surface uneven distribution of the resin (D) due to the effects of the main chain and thus is not included in the CH₃ partial structure in the present invention.

More specifically, when the resin (D) includes a repeating unit derived from a monomer having a polymerizable moiety having a carbon-carbon double bond, such as, for example, a repeating unit and the like represented by the following Formula (M) and when R₁₁ to R₁₄ are a CH₃ “as it is”, the CH₃ is not included in the CH₃ partial structure in the present invention that the side chain moiety has.

Meanwhile, the CH₃ partial structure present through any atom from the C—C main chain corresponds to a CH₃ partial structure in the present invention. For example, when R₁₁ is an ethyl group (CH₂CH₃), R₁₁ is assumed to have “one” of the CH₃ partial structure in the present invention.

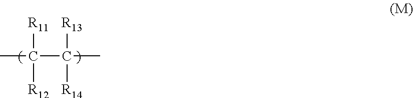

In Formula (M),

each of R₁₁ to R₁₄ independently represents a side chain moiety.

Examples of R₁ to R₁₄ in the side chain moiety may include a hydrogen atom, a monovalent organic group and the like.

Examples of the monovalent organic group for R₁₁ to R₁₄ may include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, an arylaminocarbonyl group and the like, and these groups may further have a substituent.

The hydrophobic resin (D) is preferably a resin having a repeating unit having a CH₃ partial structure at the side chain moiety thereof, and more preferably has at least one repeating unit (x) of a repeating unit represented by the following Formula (II) and a repeating unit represented by the following Formula (III) as the repeating unit.

Hereinafter, the repeating unit represented by Formula (II) will be described in detail.

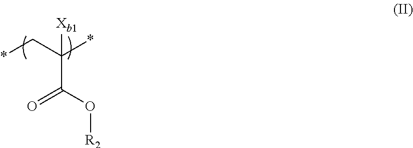

In Formula (II), X_{b1} represents a hydrogen atom, an alkyl group, a cyano group or a halogen atom, and R₂ represents an organic group which is stable against an acid and has one or more CH₃ partial structures. Here, more specifically, the organic group which is stable against an acid is preferably an organic group not having “a group capable of decomposing by the action of an acid to generate a polar group” described in the resin (A).

The alkyl group of X_{b1} is preferably an alkyl group having 1 to 4 carbon atoms, and examples thereof may include a methyl group, an ethyl group, a propyl group, a hydroxymethyl group, a trifluoromethyl group or the like, but a methyl group is preferred.

X_{b1} is preferably a hydrogen atom or a methyl group.

Examples of R₂ may include an alkyl group, a cycloalkyl group, an alkenyl group, a cycloalkenyl group, an aryl group and an aralkyl group, which have one or more CH₃ partial structures. The above-described cycloalkyl group, alkenyl group, cycloalkenyl group, aryl group and aralkyl group may further have an alkyl group as a substituent.

R₂ is preferably an alkyl group or an alkyl-substituted cycloalkyl group, which has one or more CH₃ partial structures.

The organic group, which has one or more CH₃ partial structures and is stable against an acid as R₂, preferably has 2 to 10 CH₃ partial structures, and more preferably 2 to 8 CH₃ partial structures.

The alkyl group having one or more CH₃ partial structures in R₂ is preferably a branched alkyl group having 3 to 20 carbon atoms. Specific examples of the preferred alkyl group may include an isopropyl group, an isobutyl group, a 3-pentyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group and the like. An isobutyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group and a 2,3,5,7-tetramethyl-4-heptyl group are more preferred.

The cycloalkyl group having one or more CH₃ partial structures in R₂ may be monocyclic or polycyclic. Specific examples thereof may include groups having a monocyclo, bicyclo, tricyclo and tetracyclo structure having 5 or more carbon atoms, and the like. The carbon number thereof is preferably 6 to 30, and particularly preferably 7 to 25. Preferred examples of the cycloalkyl group may include an adamantyl group, a noradamantyl group, a decalin residue, a tricyclodecanyl group, a tetracyclododecanyl group, a norbornyl group, a cedrol group, a cyclopentyl group, a cyclohexyl group, a cycloheptyl group, a cyclooctyl group, a cyclodecanyl group and a cyclododecanyl group. More preferred examples thereof may include an adamantyl group, a norbornyl group, a cyclohexyl group, a cyclopentyl group, a tetracyclododecanyl group and a tricyclodecanyl group. A norbornyl group, a cyclopentyl group and a cyclohexyl group are more preferred.

The alkenyl group having one or more CH₃ partial structures in R₂ is preferably a straight or branched alkenyl group having 1 to 20 carbons, and more preferably a branched alkenyl group.

The aryl group having one or more CH₃ partial structures in R₂ is preferably an aryl group having 6 to 20 carbon atoms, examples thereof may include a phenyl group and a naphthyl group, and a phenyl group is preferred.

The aralkyl group having one or more CH₃ partial structures in R₂ is preferably an aralkyl group having 7 to 12 carbon atoms, and examples thereof may include a benzyl group, a phenethyl group and a naphthylmethyl group.

Specific examples of a hydrocarbon group having two or more CH₃ partial structures in R₂ may include an isopropyl group, an isobutyl group, a t-butyl group, a 3-pentyl group, a 2-methyl-3-butyl group, a 3-hexyl group, a 2,3-dimethyl-2-butyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, a 3,5-dimethylcyclohexyl group, a 4-isopropylcyclohexyl group, a 4-t-butylcyclohexyl group, an isobornyl group and the like. More preferred are an isopropyl group, a t-butyl group, a 2-methyl-3-butyl group, a 2,3-dimethyl-2-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, a 3,5-dimethylcyclohexyl group, a 3,5-di-tert-butylcyclohexyl group, a 4-isopropylcyclohexyl group, a 4-t-butylcyclohexyl group, an isobornyl group and the like.

Preferred specific examples of the repeating unit represented by Formula (II) will be described below. However, the present invention is not limited thereto.

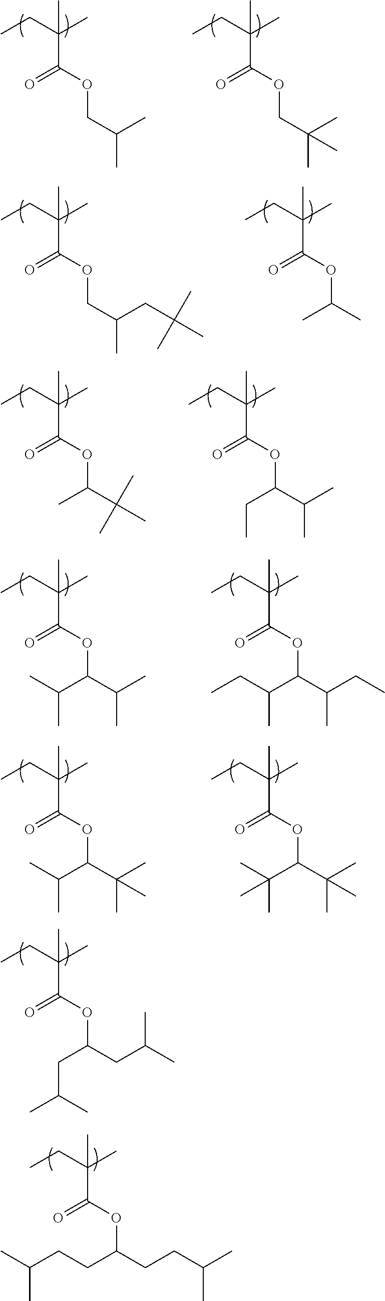

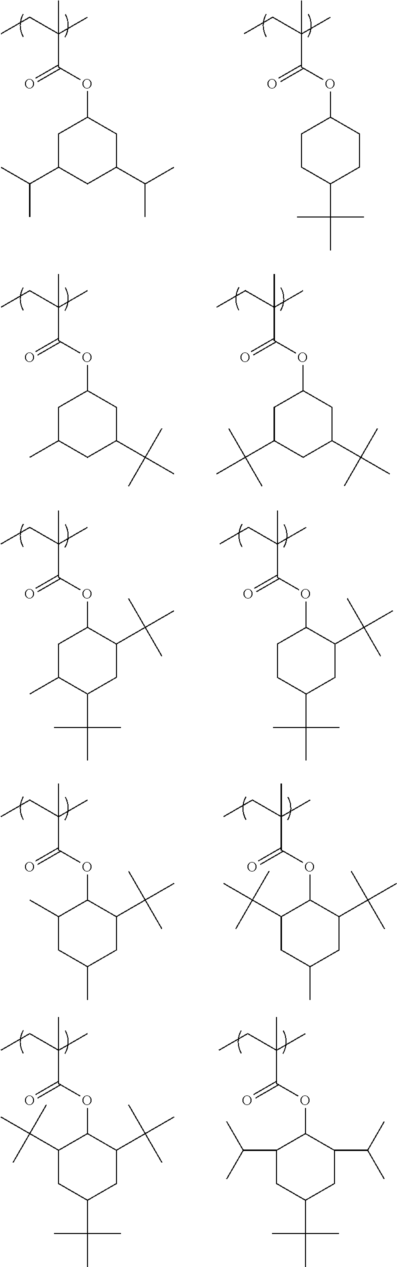

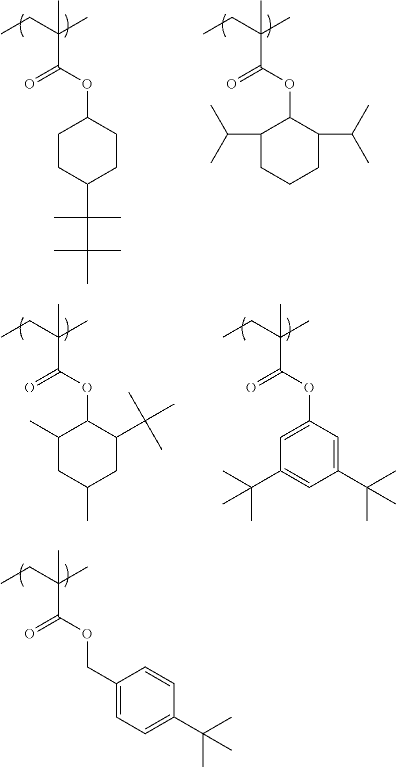

The repeating unit represented by Formula (II) is preferably a repeating unit that is stable against an acid (non-acid-decomposable), and specifically, a repeating unit having no group capable of decomposing by the action of an acid to generate a polar group is preferred.

Hereinafter, the repeating unit represented by Formula (III) will be described in detail.

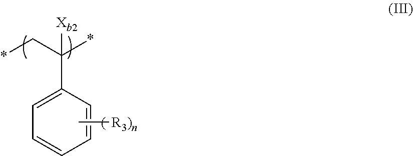

In Formula (III), X_{b2} represents a hydrogen atom, an alkyl group, a cyano group or a halogen atom, R₃ represents an organic group which is stable against an acid and has one or more CH₃ partial structures, and n represents an integer of 1 to 5.

The alkyl group of X_{b2} is preferably an alkyl group having 1 to 4 carbon atoms, and examples thereof may include a methyl group, an ethyl group, a propyl group, a hydroxymethyl group, a trifluoromethyl group or the like, but a hydrogen atom is preferred.

X_{b2} is preferably a hydrogen atom.

Since R₃ is an organic group which is stable against an acid, more specifically, R₃ is preferably an organic group not having “a group capable of decomposing by the action of an acid to generate a polar group” described in the resin (A).

Examples of R₃ may include an alkyl group having one or more CH₃ partial structures.

The organic group, which has one or more CH₃ partial structures and is stable against an acid as R₃, preferably has 1 to 10 CH₃ partial structures, more preferably 1 to 8 CH₃ partial structures, and still more preferably 1 to 4 CH₃ partial structures.

The alkyl group having one or more CH₃ partial structures in R₃ is preferably a branched alkyl group having 3 to 20 carbon atoms. Specific examples of the preferred alkyl group may include an isopropyl group, an isobutyl group, a 3-pentyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group and the like. Examples of the more preferred alkyl group may include an isobutyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group and a 2,3,5,7-tetramethyl-4-heptyl group.

Specific examples of the alkyl group having two or more CH₃ partial structures in R₃ may include an isopropyl group, an isobutyl group, a t-butyl group, a 3-pentyl group, a 2,3-dimethylbutyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group and the like. More preferably, those having 5 to 20 carbon atoms are more preferred, and examples thereof may include an isopropyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group and a 2,6-dimethylheptyl group.

n represents an integer of 1 to 5, more preferably an integer of 1 to 3, and still more preferably 1 or 2.

Preferred specific examples of the repeating unit represented by Formula (III) will be described below. However, the present invention is not limited thereto.

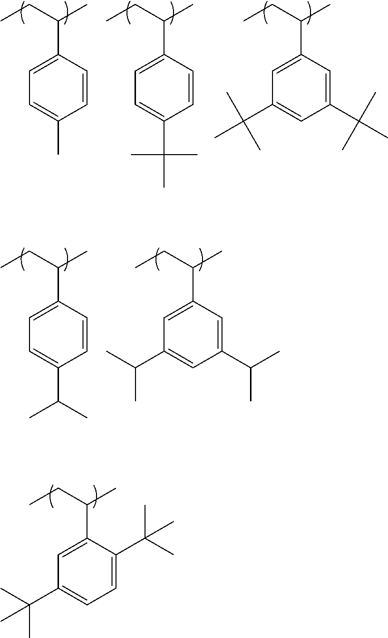

The repeating unit represented by Formula (III) is preferably a repeating unit that is stable against an acid (non-acid-decomposable), and specifically, a repeating unit having no group capable of decomposing by the action of an acid to generate a polar group is preferred.

When the resin (D) includes a CH₃ partial structure in the side chain moiety thereof and particularly has no fluorine atom and silicon atom, a content of at least one repeating unit (x) of the repeating unit represented by Formula (II) and the repeating unit represented by Formula (III) is preferably 90 mol % or more, and more preferably 95 mol % or more, based on all the repeating units of the resin (C). The content is usually 100 mol % or less based on all the repeating units of the resin (C).

The resin (D) contains at least one repeating unit (x) of the repeating unit represented by Formula (II) and the repeating unit represented by Formula (III) in an amount of 90 mol % or more based on all the repeating units of the resin (D), thereby increasing the surface free energy of the resin (C). As a result, it is difficult for the resin (D) to be unevenly distributed on the surface of the resist film, and thus the static/dynamic contact angle of the resist film against water may be certainly improved, thereby improving an immersion liquid follow-up property.

Further, even when the hydrophobic resin (D) includes (i) a fluorine atom and/or a silicon atom and even when the hydrophobic resin (D) includes (ii) a CH₃ partial structure in the side chain moiety thereof, the hydrophobic resin (D) may have at least one group selected from the group of following (x) to (z).

(x) an acid group

(y) a group having a lactone structure, an acid anhydride group or an acid imide group, and

(z) a group capable of decomposing by the action of an acid

Examples of the acid group (x) may include a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group and the like.

Preferred examples of the acid group may include a fluorinated alcohol group (preferably hexafluoroisopropanol), a sulfonimide group and a bis(alkylcarbonyl)methylene group.

Examples of the repeating unit having the acid group (x) may include a repeating unit, in which the acid group is directly bonded to the main chain of the resin, such as repeating unit by an acrylic acid or a methacrylic acid, a repeating unit in which the acid group is bonded to the main chain of the resin through a linking group or the like. Further, the repeating unit may also be introduced into the end of the polymer chain by using a polymerization initiator having an acid group or a chain transfer agent at the time of polymerization, and all of these cases are preferred. The repeating unit having the acid group (x) may have at least one of a fluorine atom and a silicon atom.

The content of the repeating unit having the acid group (x) is preferably 1 mol % to 50 mol %, more preferably 3 mol % to 35 mol %, and still more preferably 5 mol % to 20 mol %, based on all the repeating units in the hydrophobic resin (D).

Specific examples of the repeating unit having the acid group (x) will be described below, but the present invention is not limited thereto. In the formulas, Rₓ represents a hydrogen atom, CH₃, CF₃ or CH₂OH.

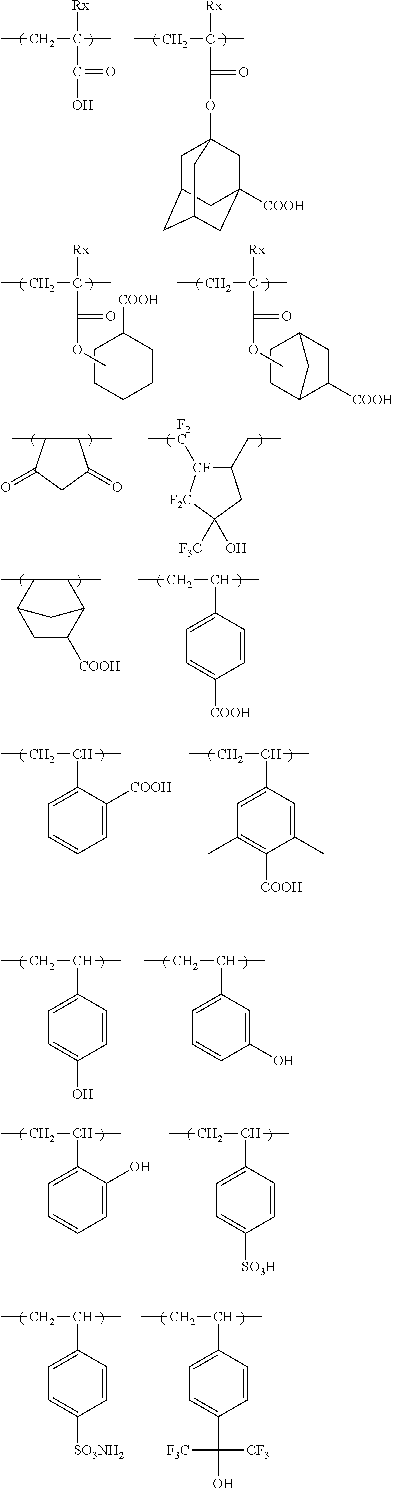

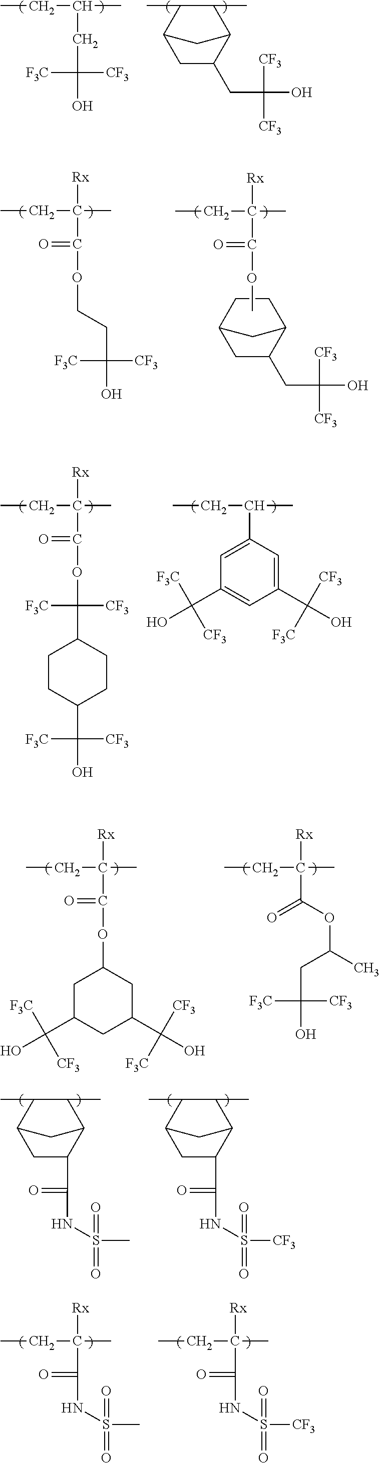

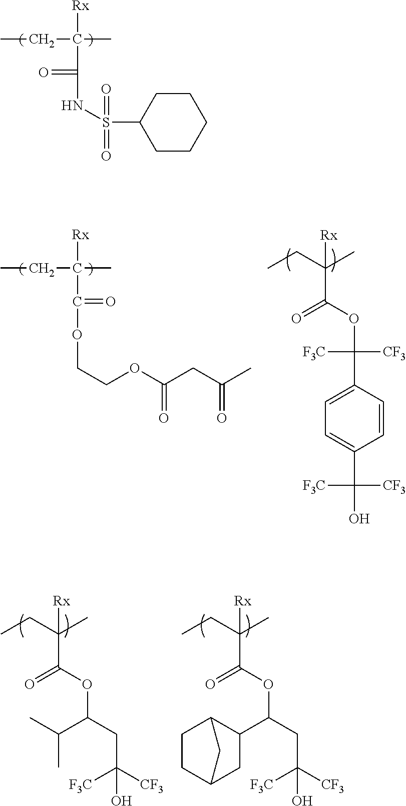

As (y) the group having a lactone structure, the acid anhydride group or the acid imide group, a group having a lactone structure is particularly preferred.

Examples of the repeating unit including these groups may include a repeating unit in which the group is directly bonded to the main chain of the resin, such as a repeating unit by an acrylate ester or a methacrylate ester. Further, the repeating unit may be a repeating unit in which the group is bonded to the main chain of the resin through a linking group. In addition, the repeating unit may be introduced into the end of the resin by using a polymerization initiator or a chain transfer agent having the group at the time of polymerization.

Examples of the repeating unit having a group having a lactone structure are the same as those of the repeating unit having a lactone structure described in the paragraph of acid-decomposable resin (A).

The content of the repeating unit having a group having a lactone structure, an acid anhydride group or an acid imide group is preferably 1 mol % to 100 mol %, more preferably 3 mol % to 98 mol %, and still more preferably 5 mol % to 95 mol %, based on all the repeating units in the hydrophobic resin (D).

Examples of the repeating unit having (z) a group capable of decomposing by the action of an acid in the hydrophobic resin (D) are the same as those of the repeating unit having an acid-decomposable group exemplified in the resin (A). The repeating unit having (z) a group capable of decomposing by the action of an acid may have at least one of a fluorine atom and a silicon atom. In the hydrophobic resin (D), the content of the repeating unit having (z) a group capable of decomposing by the action of an acid is preferably 1 mol % to 80 mol %, more preferably 10 mol % to 80 mol %, and still more preferably 20 mol % to 60 mol %, based on all the repeating units in the resin (D).

The hydrophobic resin (D) may further have a repeating unit represented by the following Formula (III).

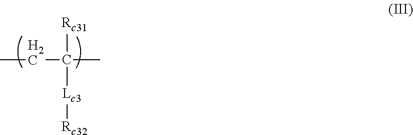

In Formula (III),

R_{c31} represents a hydrogen atom, an alkyl group (which may be substituted with a fluorine atom or the like), a cyano group or a —CH₂—O-Rac₂ group. In the formula, Raₑ represents a hydrogen atom, an alkyl group or an acyl group. R_{c31} is preferably a hydrogen atom, a methyl group, a hydroxymethyl group and a trifluoromethyl group, and particularly preferably a hydrogen atom and a methyl group.

R_{c32} represents a group having an alkyl group, a cycloalkyl group, an alkenyl group, a cycloalkenyl group or an aryl group. These groups may be substituted with a group including a fluorine atom or a silicon atom.

L_{c3} represents a single bond or a divalent linking group.

In Formula (III), the alkyl group of R_{c2} is preferably a straight or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably an aryl group having 6 to 20 carbon atoms, and more preferably a phenyl group or a naphthyl group, and these groups may have a substituent. R_{c32} is preferably an unsubstituted alkyl group or an alkyl group substituted with a fluorine atom.

The divalent linking group of Lₒ is preferably an alkylene group (preferably having 1 to 5 carbon atoms), an ether bond, a phenylene group or an ester bond (a group represented by —COO—).

The content of the repeating unit represented by Formula (III) is preferably 1 mol % to 100 mol %, more preferably 10 mol % to 90 mol %, and still more preferably 30 mol % to 70 mol %, based on all the repeating units in the hydrophobic resin.

It is also preferred that the hydrophobic resin (D) further has a repeating unit represented by the following Formula (CII-AB).

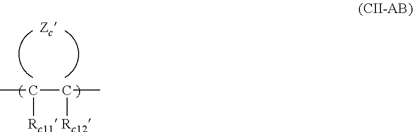

In Formula (CII-AB),

each of R_{c11}′ and R_{c12}′ independently represents a hydrogen atom, a cyano group, a halogen atom or an alkyl group.

Z_{c}′ includes two carbon atoms (C—C) to which Z_{c}′ is bonded and represents an atomic group for forming an alicyclic structure.

The content of the repeating unit represented by Formula (CII-AB) is preferably 1 mol % to 100 mol %, more preferably 10 mol % to 90 mol %, and still more preferably 30 mol % to 70 mol %, based on all the repeating units in the hydrophobic resin.

Hereinafter, specific examples of the repeating units represented by Formulas (III) and (CII-AB) will be described below, but the present invention is not limited thereto. In the formulas, Ra represents H, CH₃, CH₂OH, CF₃ or CN.

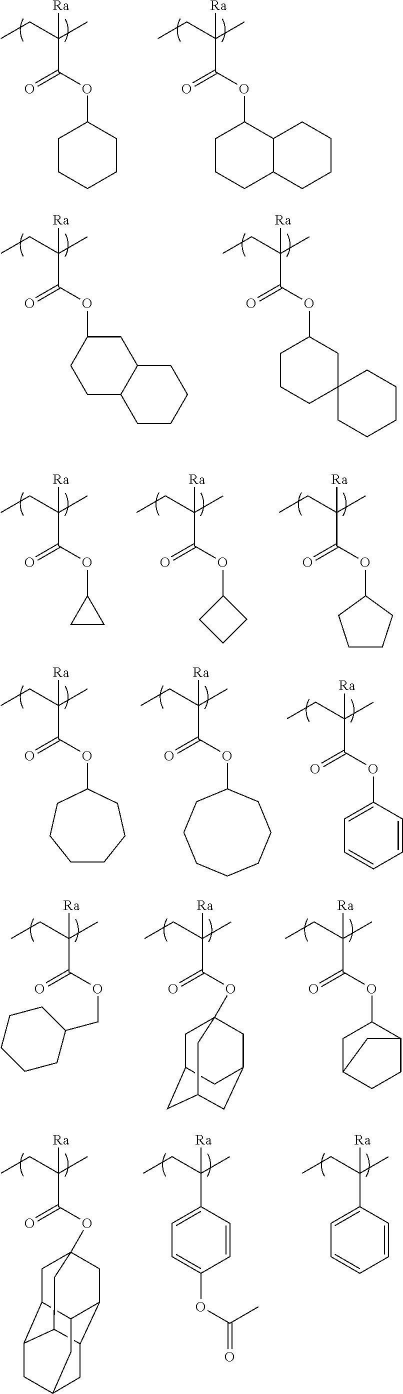

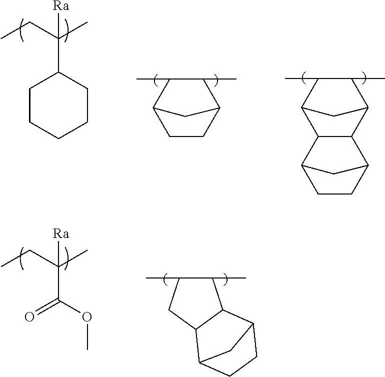

When the hydrophobic resin (D) has a fluorine atom, the content of the fluorine atom is preferably 5% by mass to 80% by mass, and more preferably 10% by mass to 80% by mass, based on the weight average molecular weight of the hydrophobic resin (D). Further, the repeating unit including a fluorine atom is preferably 10 mol % to 100 mol %, and more preferably 30 mol % to 100 mol %, based on all the repeating units contained in the hydrophobic resin (D).

When the hydrophobic resin (D) has a silicon atom, the content of the silicon atom is preferably 2% by mass to 50% by mass, and more preferably 2% by mass to 30% by mass, based on the weight average molecular weight of the hydrophobic resin (D). Further, the repeating unit including a silicon atom is preferably 10 mol % to 100 mol %, and more preferably 20 mol % to 100 mol %, based on all the repeating units included in the hydrophobic resin (D).

Meanwhile, particularly when the resin (D) includes a CH₃ partial structure in the side chain moiety thereof, the form that the resin (D) contains substantially no fluorine atom and silicon atom is also preferred, and in this case, specifically, the content of the repeating unit having a fluorine atom or a silicon atom is preferably 5 mol % or less, more preferably 3 mol % or less, and still more preferably 1 mol % or less, based on all the repeating units in the resin (D), and is ideally 0 mol %, that is, containing no fluorine atom and silicon atom. Further, it is preferred that the resin (D) is substantially composed of only a repeating unit composed of only an atom selected from a carbon atom, an oxygen atom, a hydrogen atom, a nitrogen atom and a sulfur atom. More specifically, the repeating unit composed only of an atom selected from a carbon atom, an oxygen atom, a hydrogen atom, a nitrogen atom and a sulfur atom is present in an amount of preferably 95 mol % or more, more preferably 97 mol % or more, still more preferably 99 mol % or more, and ideally 100 mol %, based on all the repeating units of the resin (D).

The weight average molecular weight of the hydrophobic resin (D) in terms of the standard polystyrene is preferably 1,000 to 100,000, more preferably 1,000 to 50,000, and still more preferably 2,000 to 15,000.

Further, the hydrophobic resin (D) may be used either alone or in combination of a plurality thereof.

The content of the hydrophobic resin (D) in the composition is preferably 0.01% by mass to 10% by mass, more preferably 0.05% by mass to 8% by mass, and still more preferably 0.1% by mass to 5% by mass, based on the total solid content in the composition of the present invention.

In the hydrophobic resin (D), similarly to the resin (A), it is natural that the content of impurities such as metal and the like is small, and the content of residual monomers or oligomer components is preferably 0.01% by mass to 5% by mass, more preferably 0.01% by mass to 3% by mass, and still more preferably 0.05% by mass to 1% by mass. Accordingly, it is possible to obtain an actinic ray-sensitive or radiation-sensitive resin composition free from extraneous substances in liquid and change in sensitivity and the like over time. Further, from the viewpoint of resolution, resist shape, side wall of resist pattern, roughness and the like, the molecular weight distribution (Mw/Mn, also referred to as polydispersity) is in a range of preferably 1 to 5, more preferably 1 to 3, and still more preferably 1 to 2.

As for the hydrophobic resin (D), various commercially available products may be used, and the hydrophobic resin (D) may be synthesized by a typical method (for example, radical polymerization). Examples of a general synthesis method may include a batch polymerization method of dissolving monomer species and an initiator in a solvent and heating the solution, thereby performing the polymerization, a dropping polymerization method of adding dropwise a solution containing monomer species and an initiator to a heated solvent over 1 to 10 hours, and the like, and a dropping polymerization method is preferred.

The reaction solvent, polymerization initiator, reaction conditions (temperature, concentration and the like) and purification method after reaction are the same as those described in the resin (A), but in the synthesis of the hydrophobic resin (D), the reaction concentration is preferably 30% by mass to 50% by mass.

Hereinafter, specific examples of the hydrophobic resin (D) will be described. In addition, the molar ratio (corresponding to each repeating unit sequentially from the left), the weight average molecular weight and the polydispersity of the repeating unit in each resin are shown in the following Table.

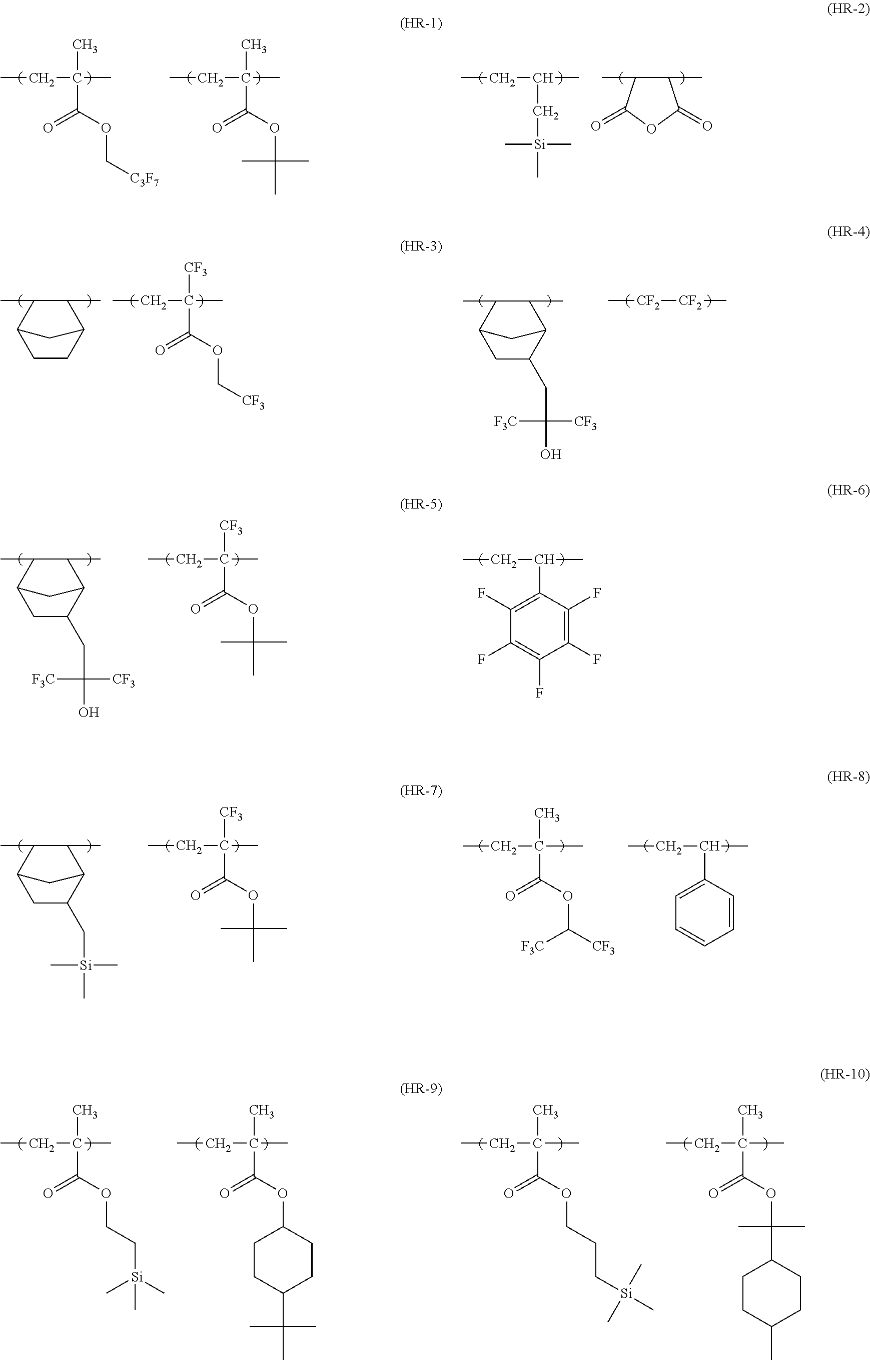

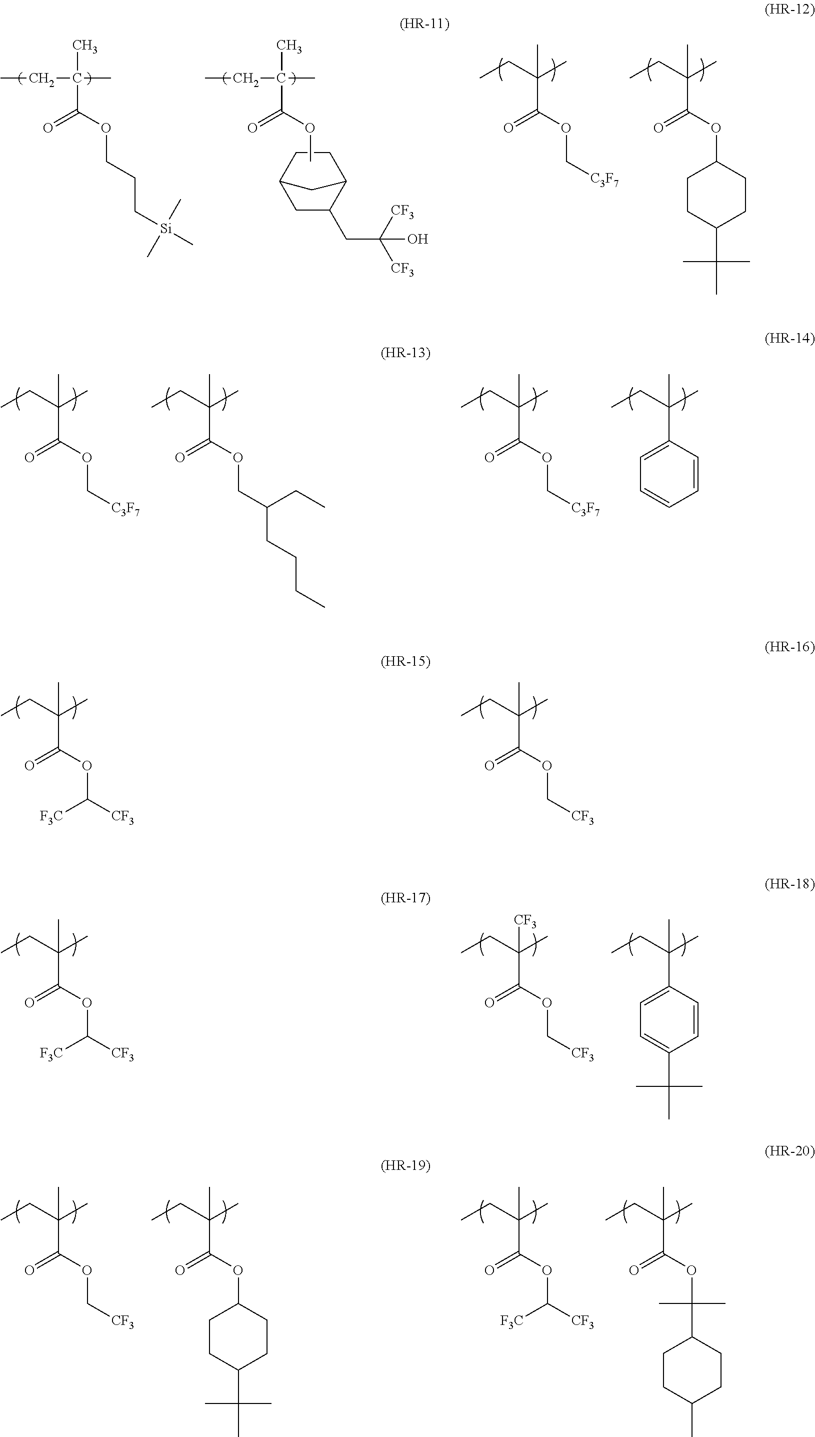

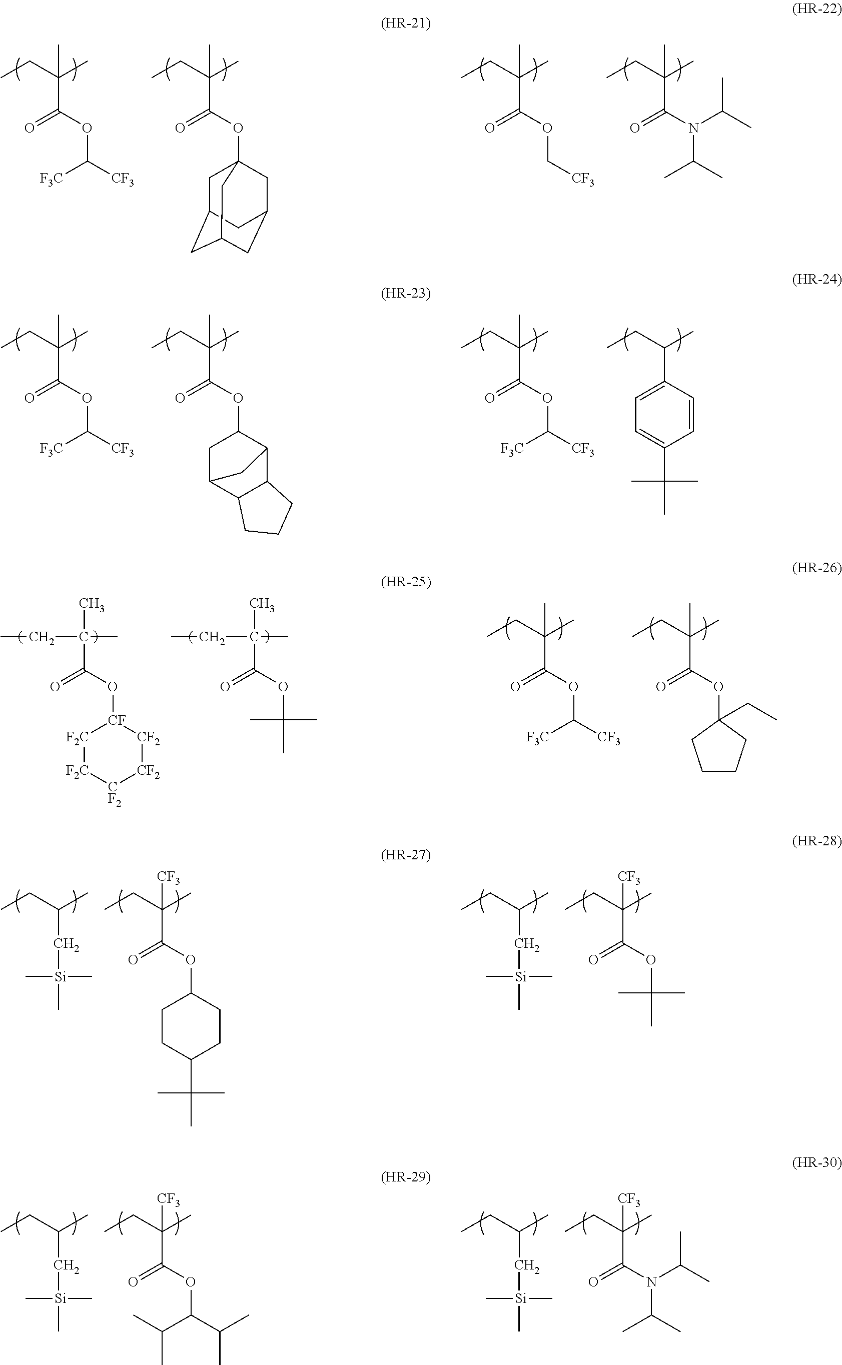

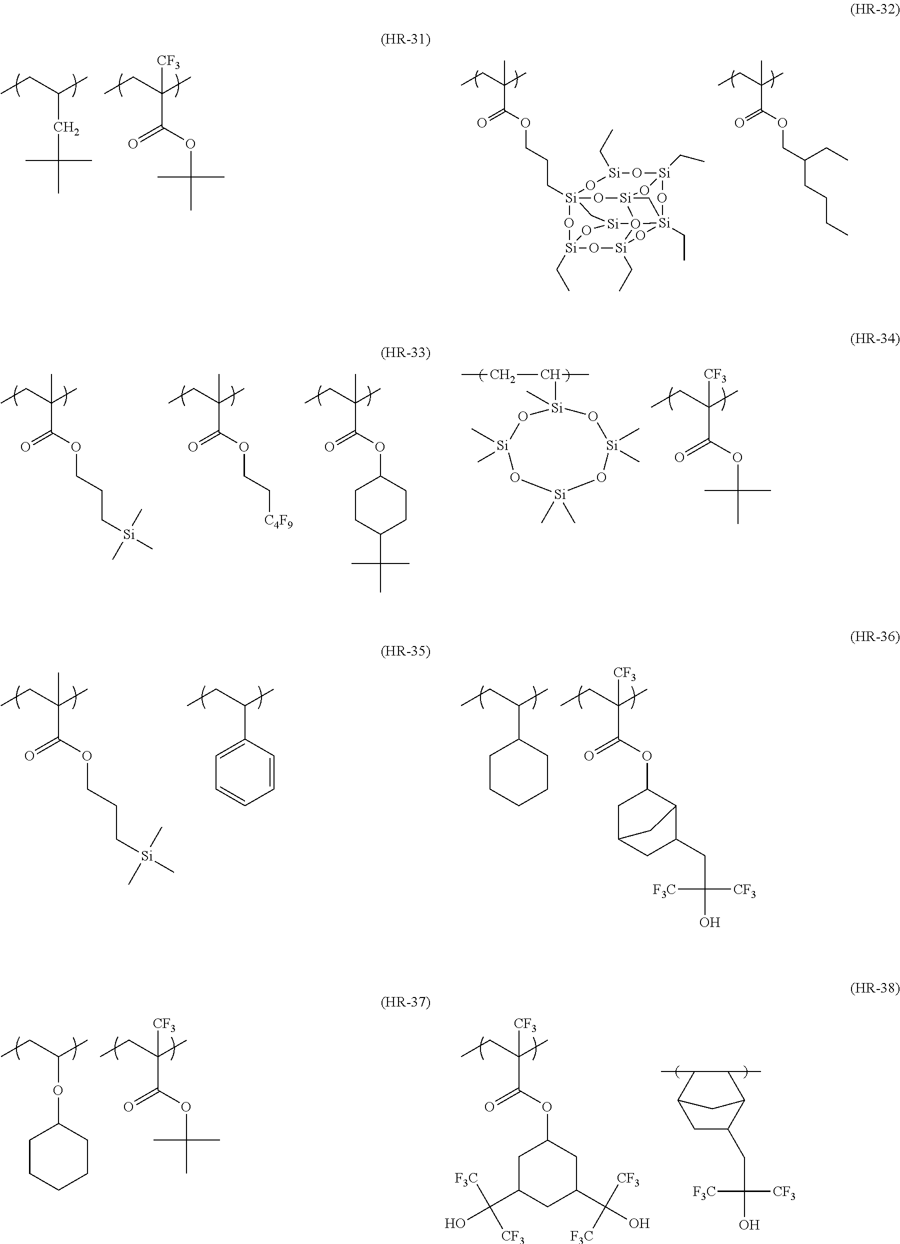

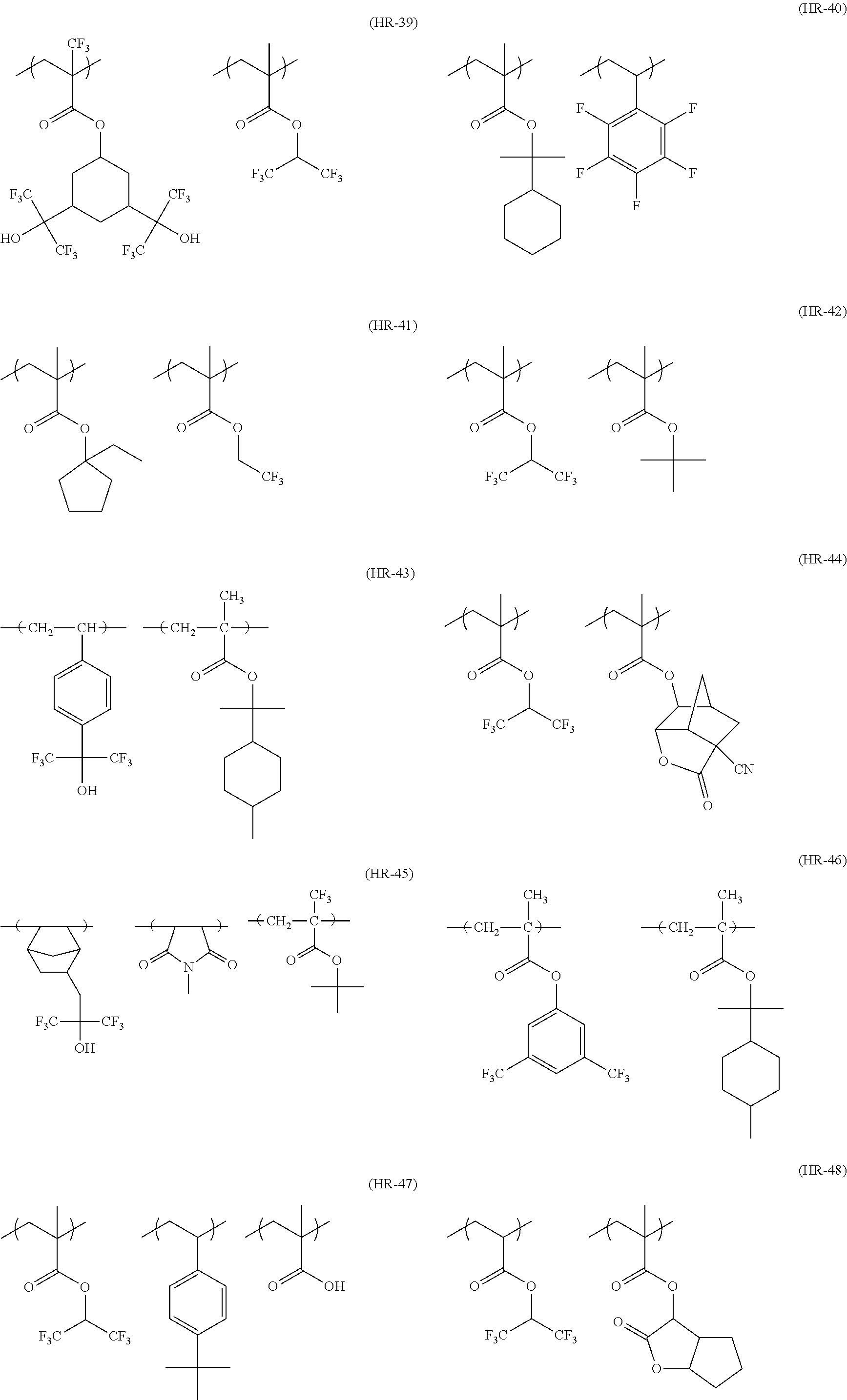

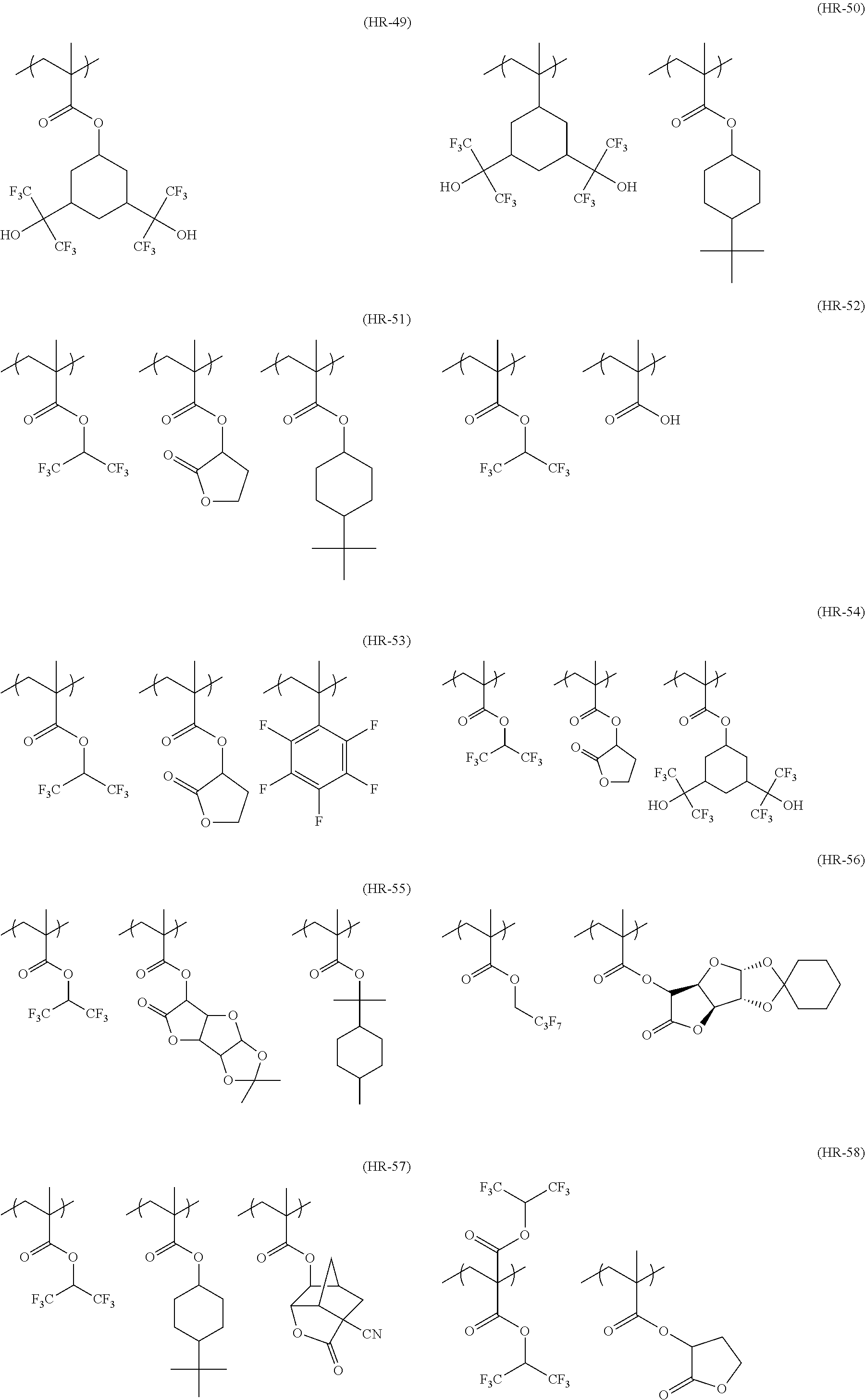

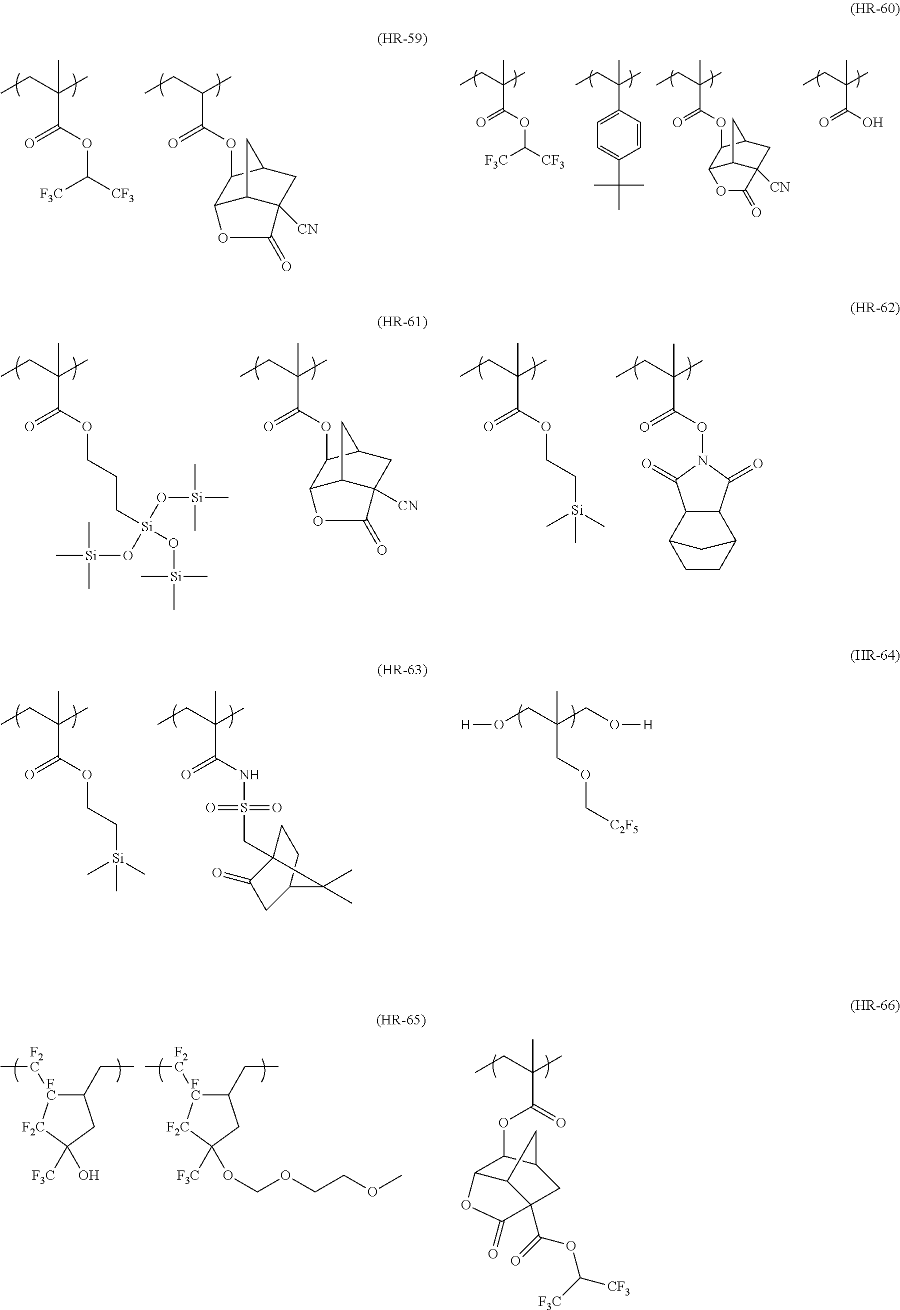

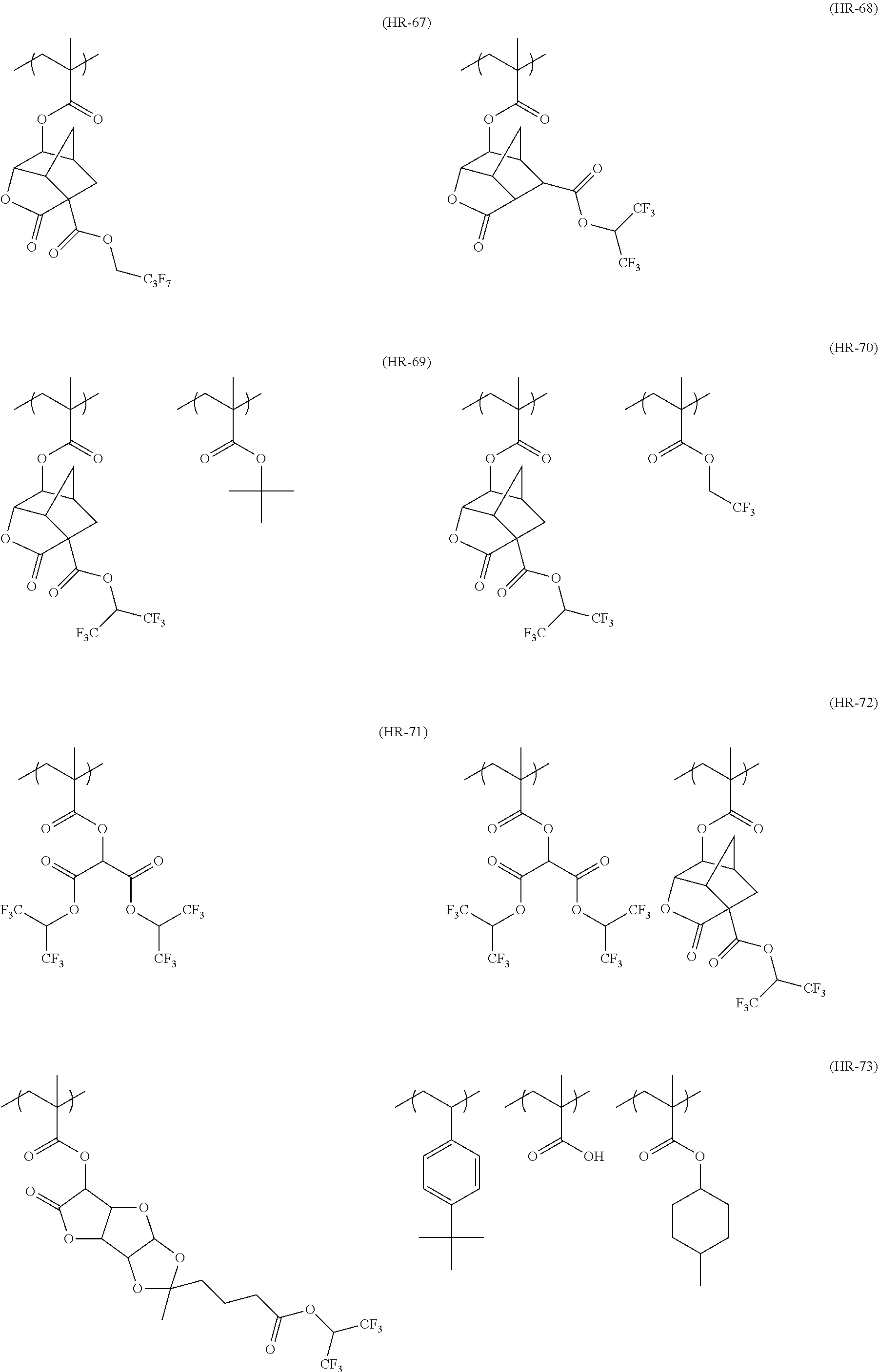

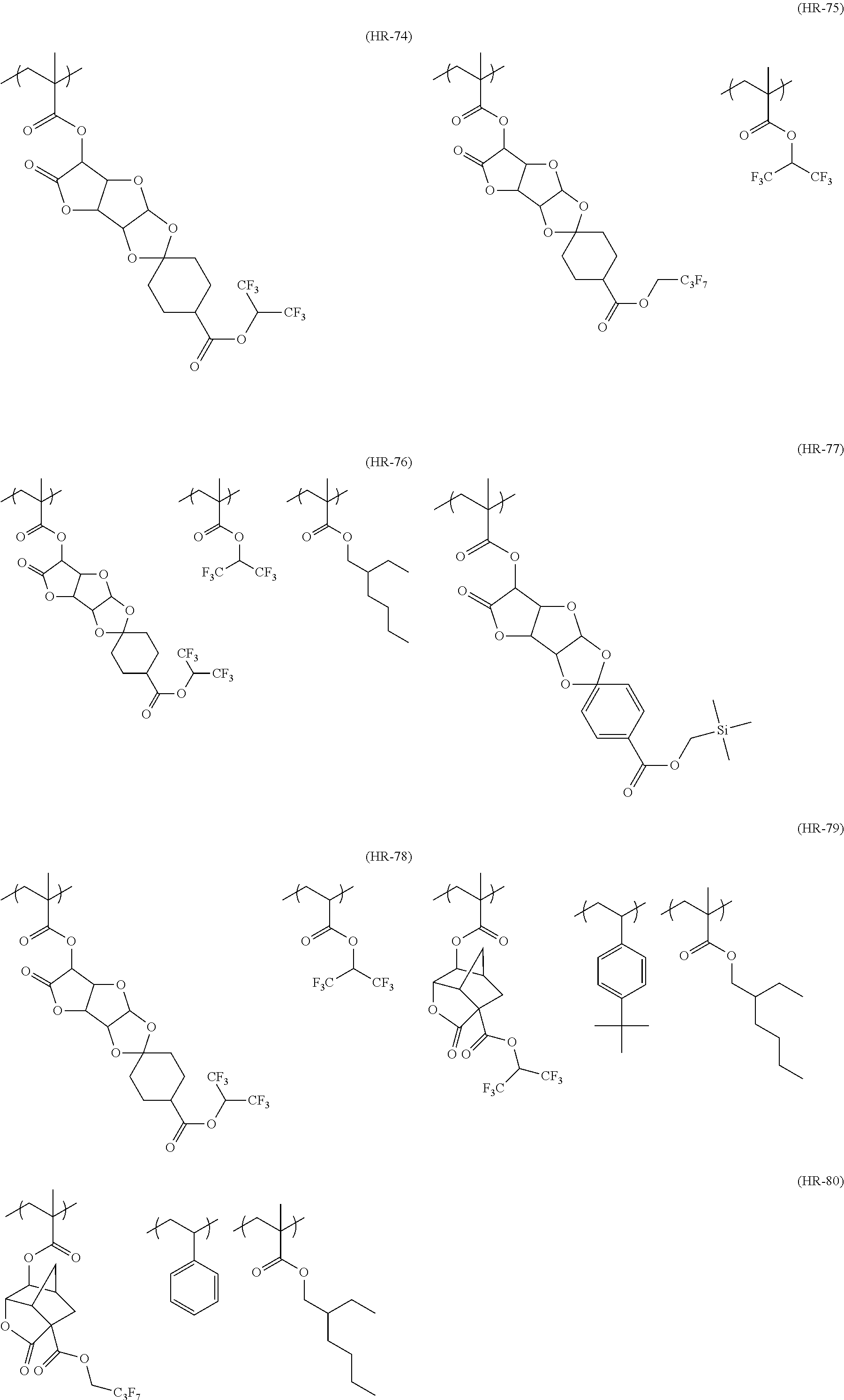

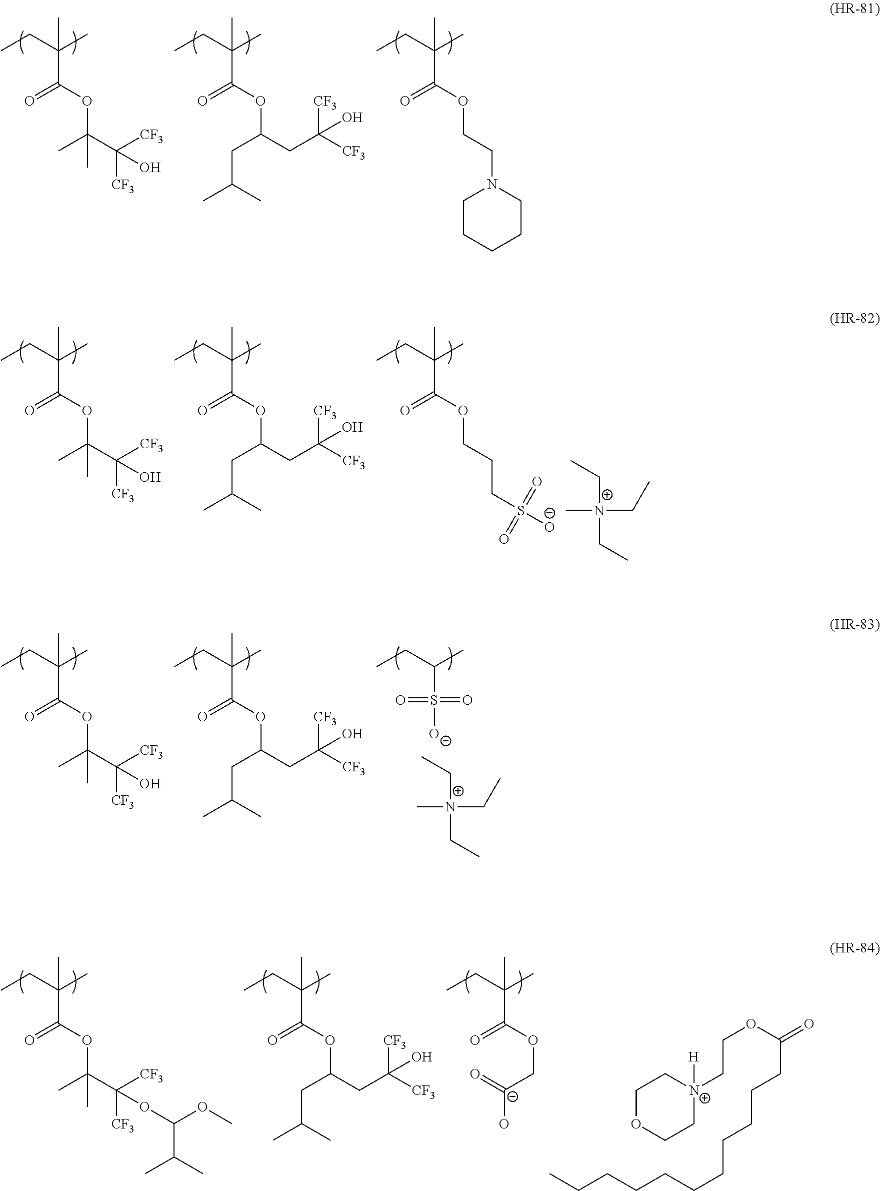

TABLE 1

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

TABLE 2

| Resin | Composition | Mw | Mw/Mn |
|---|---|---|---|
| HR-66 | 100 | 6000 | 1.5 |
| HR-67 | 100 | 6000 | 1.4 |
| HR-68 | 100 | 9000 | 1.5 |
| HR-69 | 60/40 | 8000 | 1.3 |
| HR-70 | 80/20 | 5000 | 1.4 |
| HR-71 | 100 | 9500 | 1.5 |
| HR-72 | 40/60 | 8000 | 1.4 |
| HR-73 | 55/30/5/10 | 8000 | 1.3 |
| HR-74 | 100 | 13000 | 1.4 |
| HR-75 | 70/30 | 8000 | 1.3 |
| HR-76 | 50/40/10 | 9500 | 1.5 |
| HR-77 | 100 | 9000 | 1.6 |
| HR-78 | 80/20 | 3500 | 1.4 |
| HR-79 | 90/8/2 | 13000 | 1.5 |
| HR-80 | 85/10/5 | 5000 | 1.5 |

TABLE 3

| Resin | Composition | Mw | Mw/Mn |
|---|---|---|---|
| HR-81 | 35/60/5 | 8600 | 1.99 |
| HR-82 | 35/60/5 | 8700 | 1.71 |
| HR-83 | 35/60/5 | 8100 | 1.81 |
| HR-84 | 35/60/5 | 8900 | 1.89 |

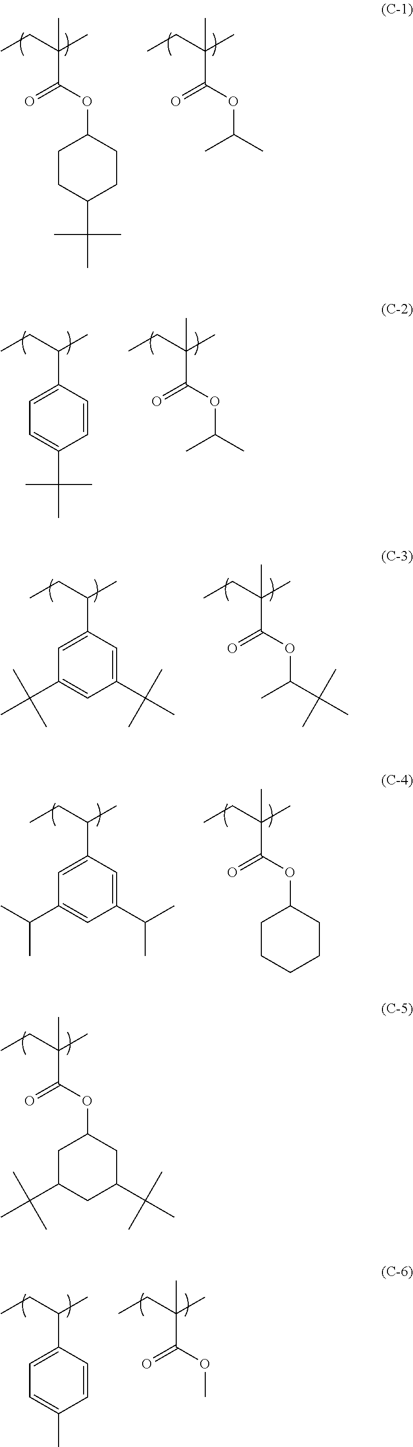

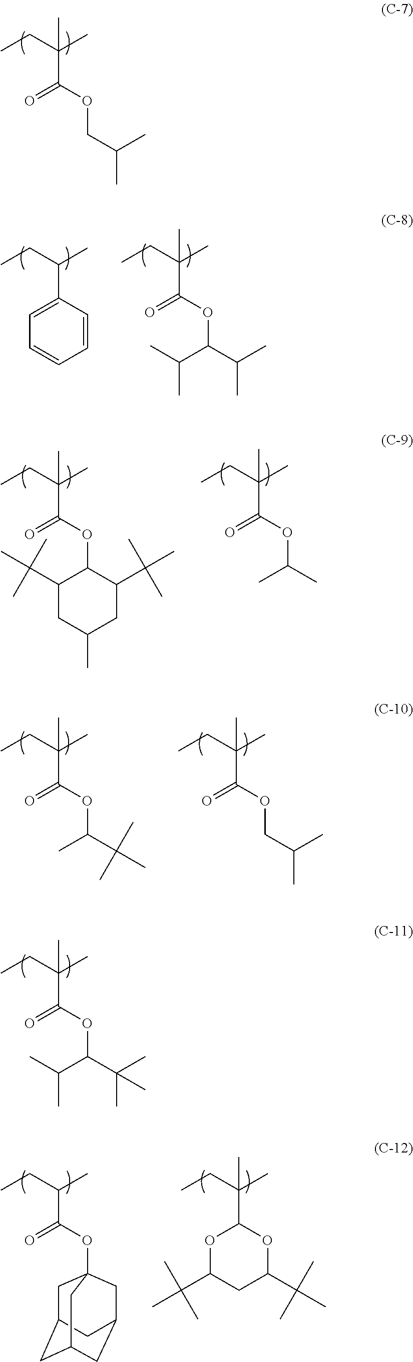

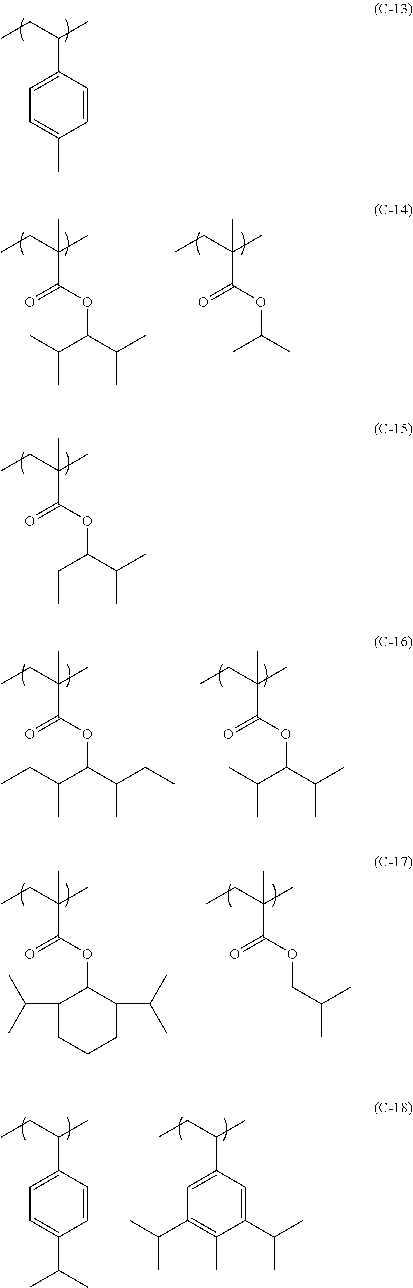

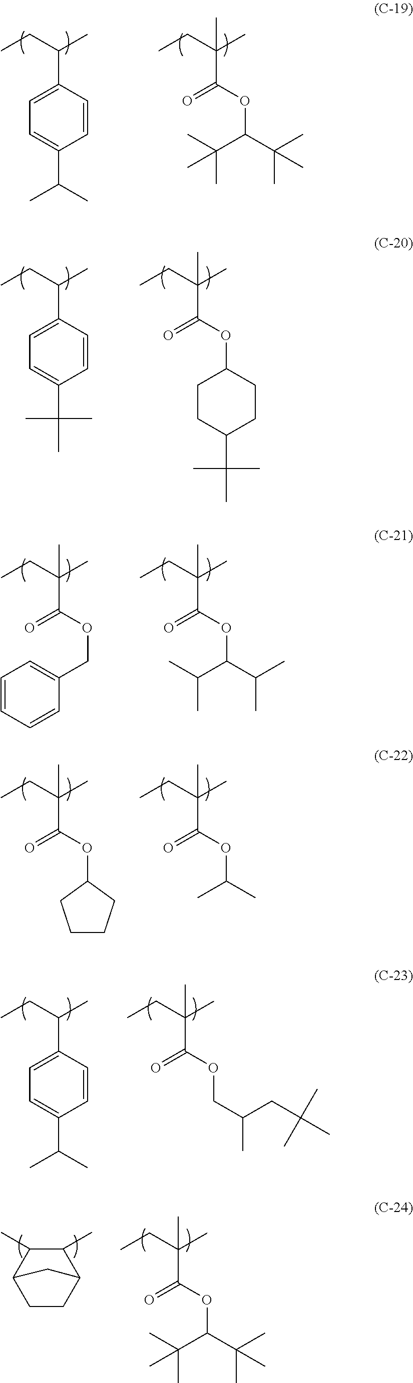

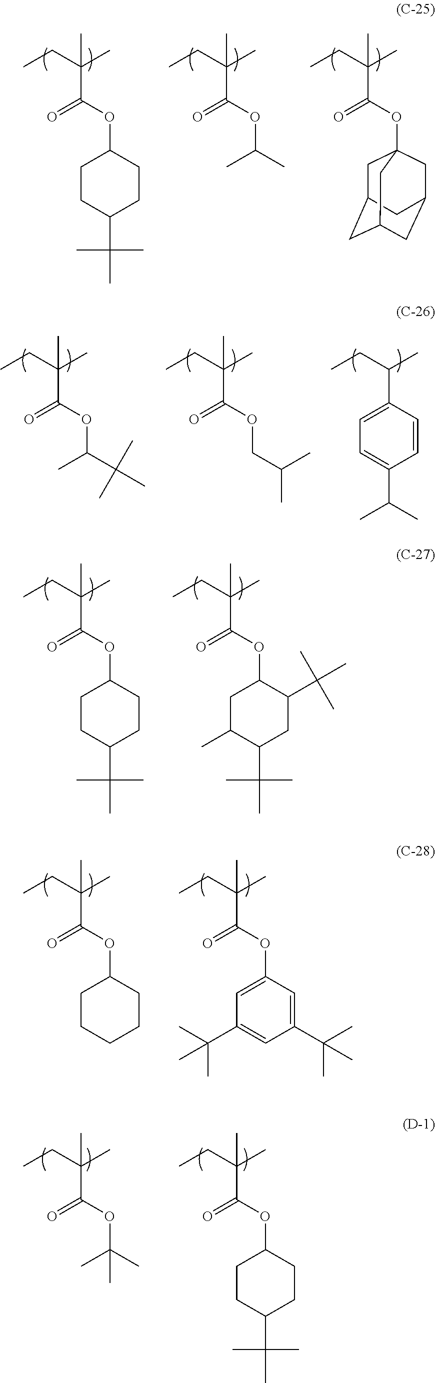

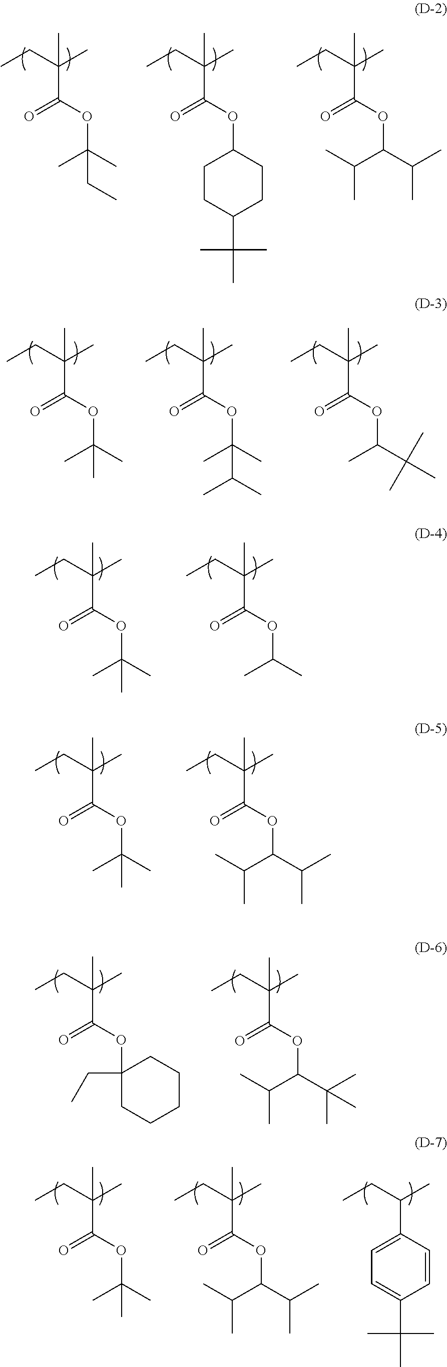

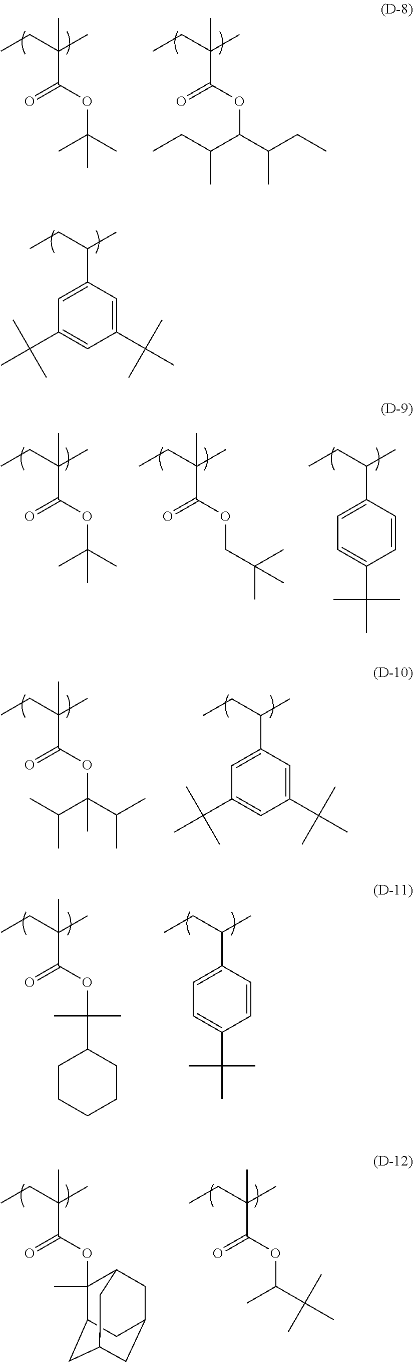

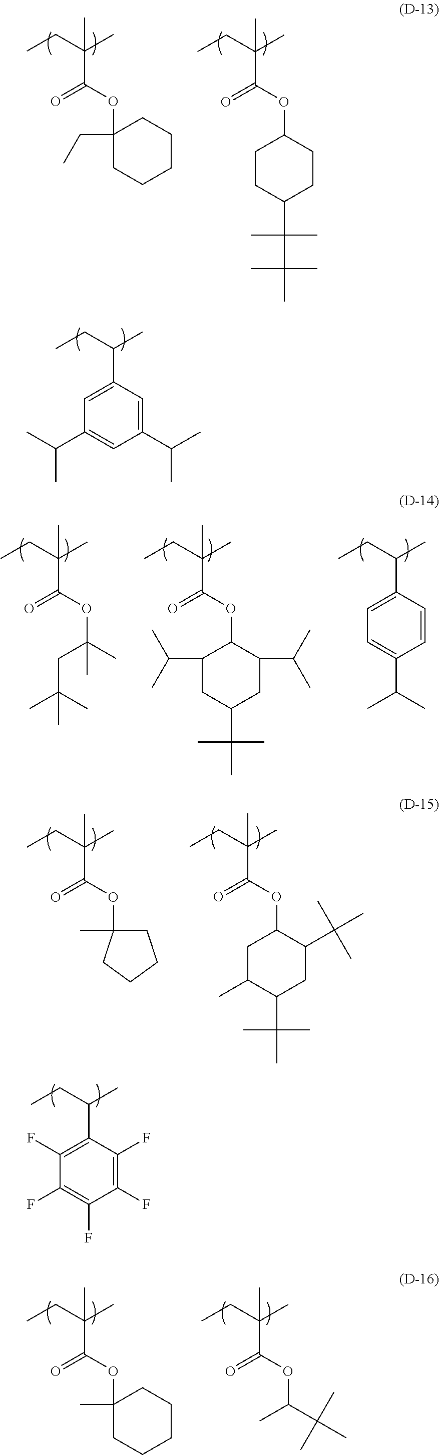

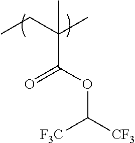

TABLE 4

| Resin | Composition | Mw | Mw/Mn |
|---|---|---|---|
| C-1 | 50/50 | 9600 | 1.74 |
| C-2 | 60/40 | 34500 | 1.43 |
| C-3 | 30/70 | 19300 | 1.69 |
| C-4 | 90/10 | 26400 | 1.41 |
| C-5 | 100 | 27600 | 1.87 |
| C-6 | 80/20 | 4400 | 1.96 |
| C-7 | 100 | 16300 | 1.83 |
| C-8 | 5/95 | 24500 | 1.79 |
| C-9 | 20/80 | 15400 | 1.68 |
| C-10 | 50/50 | 23800 | 1.46 |
| C-11 | 100 | 22400 | 1.57 |
| C-12 | 10/90 | 21600 | 1.52 |
| C-13 | 100 | 28400 | 1.58 |
| C-14 | 50/50 | 16700 | 1.82 |
| C-15 | 100 | 23400 | 1.73 |
| C-16 | 60/40 | 18600 | 1.44 |
| C-17 | 80/20 | 12300 | 1.78 |
| C-18 | 40/60 | 18400 | 1.58 |
| C-19 | 70/30 | 12400 | 1.49 |
| C-20 | 50/50 | 23500 | 1.94 |
| C-21 | 10/90 | 7600 | 1.75 |
| C-22 | 5/95 | 14100 | 1.39 |
| C-23 | 50/50 | 17900 | 1.61 |
| C-24 | 10/90 | 24600 | 1.72 |
| C-25 | 50/40/10 | 23500 | 1.65 |
| C-26 | 60/30/10 | 13100 | 1.51 |
| C-27 | 50/50 | 21200 | 1.84 |
| C-28 | 10/90 | 19500 | 1.66 |

TABLE 5

| Resin | Composition | Mw | Mw/Mn |
|---|---|---|---|
| D-1 | 50/50 | 16500 | 1.72 |
| D-2 | 10/50/40 | 18000 | 1.77 |
| D-3 | 5/50/45 | 27100 | 1.69 |
| D-4 | 20/80 | 26500 | 1.79 |
| D-5 | 10/90 | 24700 | 1.83 |
| D-6 | 10/90 | 15700 | 1.99 |
| D-7 | 5/90/5 | 21500 | 1.92 |
| D-8 | 5/60/35 | 17700 | 2.10 |
| D-9 | 35/35/30 | 25100 | 2.02 |
| D-10 | 70/30 | 19700 | 1.85 |
| D-11 | 75/25 | 23700 | 1.80 |
| D-12 | 10/90 | 20100 | 2.02 |
| D-13 | 5/35/60 | 30100 | 2.17 |
| D-14 | 5/45/50 | 22900 | 2.02 |
| D-15 | 15/75/10 | 28600 | 1.81 |
| D-16 | 25/55/20 | 27400 | 1.87 |

[5-1] Basic Compound or Ammonium Salt Compound (N) Whose Basicity Decreases Upon Irradiation with an Actinic Ray or Radiation

The actinic ray-sensitive or radiation-sensitive resin composition in the present invention may contain a basic compound or an ammonium salt compound (hereinafter, also referred to as a “compound (N)”) whose basicity decreases upon irradiation with an actinic ray or radiation.

The compound (N) is a compound different from the salt (C) having a conjugate base structure of an acid having a pKa of −2 or more in a molecule thereof and substantially not capable of decomposing by an actinic ray or radiation, and particularly, the salt (C) is different from the compound (N) in that the salt (C) does not substantially decompose by an actinic ray or radiation, while the basicity of the compound (N) decreases upon irradiation with an actinic ray or radiation.

The compound (N) is preferably a compound (N-1) having a basic functional group or an ammonium group and a group capable of generating an acidic functional group upon irradiation with an actinic ray or radiation. That is, the compound (N) is preferably a basic compound having a basic functional group and a group capable of generating an acidic functional group upon irradiation with an actinic ray or radiation, or an ammonium salt compound having an ammonium group and a group capable of generating an acidic functional group upon irradiation with an actinic ray or radiation.

Examples of the compounds which is generated by decomposing the compound (N) or (N-1) upon irradiation with an actinic ray or radiation and whose basicity decreases may include compounds represented by the following Formulas (PA-I), (PA-II) or (PA-III), and from the viewpoint of enhancing excellent effects relating to LWR, uniformity of a local pattern dimension and DOF to a high level, the compounds represented by Formula (PA-II) or (PA-III) are particularly preferred.

First, the compounds represented by Formula (PA-I) will be described.

Q-A₁-(X)ₙ—B—R (PA-I)

In Formula (PA-I),

A₁ represents a single bond or a divalent linking group.

Q represents —SO₃H, or —CO₂H. Q corresponds to an acidic functional group generated upon irradiation with an actinic ray or radiation.

X represents —SO₂—, or —CO—.

n represents 0 or 1.

B represents a single bond, an oxygen atom, or —N(Rx)-.

Rx represents a hydrogen atom, or a monovalent organic group.

R represents a monovalent organic group having a basic functional group or a monovalent organic group having an ammonium group.

The divalent linking group in Aₗ is preferably a divalent linking group having 2 to 12 carbon atoms, and examples thereof may include an alkylene group, a phenylene group and the like. An alkylene group having at least one fluorine atom is more preferred, and the carbon number thereof is preferably 2 to 6, and more preferably 2 to 4. The alkylene chain may have a linking group such as an oxygen atom and sulfur atom. The alkylene group is preferably an alkylene group in which 30% to 100% of the number of the hydrogen atom is substituted with a fluorine atom, and more preferably an alkylene group in which the carbon atom bonded to the Q site has a fluorine atom. Further, a perfluoroalkylene group is preferred, and a perfluoroethylene group, a perfluoropropylene group and a perfluorobutylene group are more preferred.

The monovalent organic group in Rx preferably has 4 to 30 carbon atoms, and examples thereof may include an alkyl group, a cycloalkyl group, an aryl group, an aralkyl group, an alkenyl group and the like.

The alkyl group in Rx may have a substituent and is preferably a straight or branched alkyl group having 1 to 20 carbon atoms, and the alkyl chain may have an oxygen atom, a sulfur atom or a nitrogen atom.

Meanwhile, examples of the alkyl group having a substituent may particularly include a group in which a straight or branched alkyl group is substituted with a cycloalkyl group (for example, an adamantylmethyl group, an adamantylethyl group, a cyclohexylethyl group, a camphor residue and the like).

The cycloalkyl group in Rx may have a substituent, and is preferably a cycloalkyl group having 3 to 20 carbon atoms, and may have an oxygen atom in the ring.

The aryl group in Rx may have a substituent, and is preferably an aryl group having 6 to 14 carbon atoms.

The aralkyl group in Rx may have a substituent and is preferably an aralkyl group having 7 to 20 carbon atoms.

The alkenyl group in Rx may have a substituent, and examples thereof may include a group having a double bond at an arbitrary position of the alkyl group exemplified as Rx.

Examples of a preferred partial structure of the basic functional group may include a structure such as crown ether, a primary to tertiary amine, and a nitrogen-containing heterocyclic ring (pyridine, imidazole, pyrazine and the like).

Examples of the preferred partial structure of an ammonium group may include a primary to tertiary ammonium structure, a pyridinium structure, an imidazolinium structure, a pyrazinium structure and the like.

Meanwhile, the basic functional group is preferably a functional group having a nitrogen atom, and more preferably a structure having a primary to tertiary amino group, or a nitrogen-containing heterocyclic structure. In these structures, from the viewpoint of improving basicity, it is preferred that all atoms adjacent to a nitrogen atom included in the structure are a carbon atom or a hydrogen atom. In addition, from the viewpoint of improving basicity, it is preferred that an electron-withdrawing functional group (a carbonyl group, a sulfonyl group, a cyano group, a halogen atom and the like) is not directly connected to the nitrogen atom.

The monovalent organic group in the monovalent organic group (group R) including the structure preferably has 4 to 30 carbon atoms, examples thereof may include an alkyl group, a cycloalkyl group, an aryl group, an aralkyl group, an alkenyl group and the like, and each group may have a substituent.

The alkyl group, the cycloalkyl group, the aryl group, the aralkyl group, and the alkenyl group in the alkyl group, the cycloalkyl group, the aryl group, the aralkyl group and the alkenyl group including a basic functional group or an ammonium group in R are the same as the alkyl group, the cycloalkyl group, the aryl group, the aralkyl group and the alkenyl group exemplified as Rx.

Examples of the substituent which each group may have may include a halogen atom, a hydroxyl group, a nitro group, a cyano group, a carboxyl group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 20 carbon atoms), an acyloxy group (preferably having 2 to 10 carbon atoms), an alkoxycarbonyl group (preferably having 2 to 20 carbon atoms), an aminoacyl group (preferably having 2 to 20 carbon atoms) and the like. Examples of the cyclic structure in the aryl group, the cycloalkyl group and the like may further include an alkyl group (preferably having 1 to 20 carbon atoms) as the substituent. Examples of the aminoacyl group may further include one or two alkyl groups (preferably having 1 to 20 carbon atoms) as the substituent.

When B is —N(Rx)-, R and Rx preferably are bound with each other to form a ring. By forming a ring structure, the stability is improved, and thus storage stability of the composition using the same is improved. The number of carbon atoms forming the ring is preferably 4 to 20, and the ring may be monocyclic or polycyclic and may include an oxygen atom, a sulfur atom or a nitrogen atom therein.

Examples of the monocyclic structure may include a 4- to 8-membered ring including a nitrogen atom and the like. Examples of the polycyclic structure may include a structure composed of a combination of two or three or more monocyclic structures. The monocyclic structure and polycyclic structure may have a substituent, and preferred examples of the substituent may include a halogen atom, a hydroxyl group, a cyano group, a carboxyl group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 15 carbon atoms), an acyloxy group (preferably having 2 to 15 carbon atoms), an alkoxycarbonyl group (preferably having 2 to 15 carbon atoms), an aminoacyl group (preferably having 2 to 20 carbon atoms) and the like. For the cyclic structure in the aryl group, the cycloalkyl group and the like, examples of the substituent thereof may also include an alkyl group (preferably having 1 to 15 carbon atoms). For the aminoacyl group, examples of the substituent thereof may include one or two alkyl groups (preferably having 1 to 15 carbon atoms).

Among the compounds represented by Formula (PA-I), a compound in which the Q site is a sulfonic acid may be synthesized by using a general sulfonamidation reaction. For example, the compound may be obtained by a method of selectively reacting one sulfonyl halide moiety of a bis-sulfonyl halide compound with an amine compound to form a sulfonamide bond and then hydrolyzing the other sulfonyl halide moiety, or a method of ring-opening a cyclic sulfonic acid anhydride through reaction with an amine compound.

Subsequently, compounds represented by Formula (PA-II) will be described.

Q₁-X₁—NH—X₂-Q₂ (PA-II)

In Formula (PA-II),

each of Q₁ and Q₂ independently represents a monovalent organic group. However, either Q₁ or Q₂ has a basic functional group. Q₁ and Q₂ may be bound with each other to form a ring, and the ring formed may have a basic functional group.

Each of X₁ and X₂ independently represents —CO— or —SO₂—.

Meanwhile, —NH— corresponds to an acidic functional group generated upon irradiation with an actinic ray or radiation.

The monovalent organic group as Q₁ and Q2 in Formula (PA-II) preferably has 1 to 40 carbon atoms, and examples thereof may include an alkyl group, a cycloalkyl group, an aryl group, an aralkyl group, an alkenyl group and the like.

The alkyl group in Q₁ and Q2 may have a substituent and is preferably a straight or branched alkyl group having 1 to 30 carbon atoms, and the alkyl chain may have an oxygen atom, a sulfur atom or a nitrogen atom.

The cycloalkyl group in Q₁ and Q2 may have a substituent, is preferably a cycloalkyl group having 3 to 20 carbon atoms, and may have an oxygen atom and a nitrogen atom in the ring.

The aryl group in Q₁ and Q2 may have a substituent, and is preferably an aryl group having 6 to 14 carbon atoms.

The aralkyl group in Q₁ and Q2 may have a substituent and is preferably an aralkyl group having 7 to 20 carbon atoms.

The alkenyl group in Q₁ and Q2 may have a substituent, and examples thereof may include a group having a double bond at an arbitrary position of the alkyl group.

Examples of the substituent which each group may have may include a halogen atom, a hydroxyl group, a nitro group, a cyano group, a carboxyl group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 20 carbon atoms), an acyloxy group (preferably having 2 to 10 carbon atoms), an alkoxycarbonyl group (preferably having 2 to 20 carbon atoms), an aminoacyl group (preferably having 2 to 10 carbon atoms) and the like. For the cyclic structure in the aryl group, the cycloalkyl group and the like, examples of the substituent thereof may further include an alkyl group (preferably having 1 to 10 carbon atoms). For the aminoacyl group, examples of the substituent thereof may further have an alkyl group (preferably having 1 to 10 carbon atoms). Examples of the alkyl group having a substituent may include a perfluoroalkyl group such as a perfluoromethyl group, a perfluoroethyl group, a perfluoropropyl group and a perfluorobutyl group.

Preferred partial structures of the basic functional group that at least one of Q₁ and Q2 has are the same as those described as the basic functional group that R of Formula (PA-I) has.

Examples of the structure in which Q₁ and Q2 are bound with each other to form a ring and the ring formed has a basic functional group may include a structure in which the organic groups of Q₁ and Q2 are further bonded through an alkylene group, an oxy group, an imino group or the like.

In Formula (PA-II), at least one of X₁ and X₂ is preferably —SO₂—.

Subsequently, compounds represented by Formula (PA-III) will be described.

Q₁-X—NH—X₂-A₂-(X₃)ₘ—B-Q₃ (PA-III)

In Formula (PA-III),

each of Q₁ and Q3 independently represents a monovalent organic group. However, either Q₁ or Q3 has a basic functional group. Q1 and Q₃ may be bound with each other to form a ring, and the ring formed may have a basic functional group.

Each of X₁, X₂ and X₃ independently represents —CO— or —SO₂—.

A₂ represents a divalent linking group.

B represents a single bond, an oxygen atom, or —N(Qx)-.

Qx represents a hydrogen atom, or a monovalent organic group.

When B is —N(Qx)-, Q3 and Qx may be bound with each other to form a ring. m represents 0 or 1.

Meanwhile, —NH— corresponds to an acidic functional group generated upon irradiation with an actinic ray or radiation.

Q₁ has the same meaning as Q₁ in Formula (PA-II).

Examples of the organic group of Q₃ are the same as those of the organic groups of Q₁ and Q₂ in Formula (PA-II).

Further, examples of the structure in which Q₁ and Q₃ are bound with each other to form a ring and the ring formed has a basic functional group may include a structure in which the organic groups of Q₁ and Q₃ are further bonded to an alkylene group, an oxy group, an imino group or the like.

The divalent linking group in A₂ is preferably a divalent linking group having 1 to 8 carbon atoms and having a fluorine atom, and examples thereof may include an alkylene group having 1 to 8 carbon atoms and having a fluorine atom, a phenylene group having a fluorine atom and the like. An alkylene group having a fluorine atom is more preferred, and the number of carbon atoms is preferably 2 to 6, and more preferably 2 to 4. The alkylene chain may have a linking group such as an oxygen atom and a sulfur atom. The alkylene group is preferably an alkylene group in which 30% to 100% of the number of the hydrogen atoms is substituted with a fluorine atom, preferably a perfluoroalkylene group, and particularly preferably a perfluoroalkylene group having 2 to 4 carbon atoms.

The monovalent organic group in Qx is preferably an organic group having 4 to 30 carbon atoms, and examples thereof may include an alkyl group, a cycloalkyl group, an aryl group, an aralkyl group, an alkenyl group and the like. Examples of the alkyl group, the cycloalkyl group, the aryl group, the aralkyl group and the alkenyl group are the same as those for Rx in Formula (PA-I).

In Formula (PA-III), X₁, X₂ and X₃ are preferably —SO₂—.

The compound (N) is preferably a sulfonium salt compound of the compound represented by Formula (PA-I), (PA-II) or (PA-III), or an iodonium salt compound of the compound represented by Formula (PA-I), (PA-II) or (PA-III), and more preferably a compound represented by the following Formula (PA1) or (PA2).

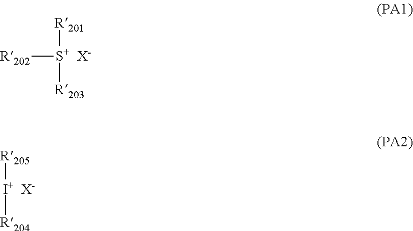

In Formula (PA1),

each of R′₂₀₁, R′₂₀₂ and R′₂₀₃ independently represents an organic group, and specific examples thereof are the same as those for R₂₀₁, R₂₀₂ and R₂₀₃ of Formula ZI in the component (B).

X⁻ represents a sulfonate anion or a carboxylate anion resulting from leaving of a hydrogen atom in the —SO₃H moiety or —COOH moiety of the compound represented by Formula (PA-I), or an anion resulting from leaving of a hydrogen atom from the —NH— moiety of the compound represented by Formula (PA-II) or (PA-III).

In Formula (PA2),

each of R′₂₀₄ and R′₂₀₅ independently represents an aryl group, an alkyl group or a cycloalkyl group, and specific examples thereof are the same as those for R₂₀₄ and R₂₀₅ of Formula ZII in the component (B).

X⁻ represents a sulfonate anion or a carboxylate anion resulting from leaving of a hydrogen atom in the —SO₃H moiety or —COOH moiety of the compound represented by Formula (PA-I), or an anion resulting from leaving of a hydrogen atom from the —NH— moiety of the compound represented by Formula (PA-II) or (PA-III).

The compound (N) decomposes upon irradiation with an actinic ray or radiation to generate, for example, a compound represented by Formula (PA-I), (PA-II) or (PA-III).

The compound represented by Formula (PA-I) is a compound whose basicity decreases, or is lost or changed from basic to acidic by having a sulfonic acid group or a carboxylic acid group together with a basic functional group or an ammonium group, as compared to the compound (N).

The compound represented by Formula (PA-II) or (PA-III) is a compound whose basicity decreases, or is lost or changed from basic to acidic by having an organic sulfonylimino group or an organic carbonylimino group together with a basic functional group, as compared to the compound (N).

In the present invention, decrease in the basicity upon irradiation with an actinic ray or radiation means that the acceptor property for a proton (an acid generated upon irradiation with an actinic ray or radiation) of the compound (N) decreases upon the irradiation with an actinic ray or radiation. The decrease in the acceptor property means that when an equilibrium reaction of producing a non-covalent bond complex as a proton adduct takes place from a basic functional group-containing compound and a proton or when an equilibrium reaction of letting the counter cation of the ammonium group-containing compound be exchanged with a proton takes place, the equilibrium constant in the chemical equilibrium decreases.

In this manner, the compound (N) whose basicity decreases upon irradiation with an actinic ray or radiation is contained in the resist film, so that in the unexposed portion, the acceptor property of the compound (N) may be sufficiently expressed, and thus an unintended reaction of an acid diffused from the exposed portion or the like with the resin (A) may be suppressed, and simultaneously in the exposed portion, the acceptor property of the compound (N) decreases, and thus the intended reaction of an acid with the resin (A) more certainly occurs, and in the degree of contribution of the operation mechanism, it is assumed to be able to obtain a pattern excellent in terms of line width variation (LWR), uniformity of local pattern dimension, depth of focus (DOF) and pattern shape.

Meanwhile, the basicity may be confirmed by measuring the pH, and a calculated value may be calculated by a commercially available software.

Hereinafter, specific examples of the compound (N) capable of generating a compound represented by Formula (PA-I) upon irradiation with an actinic ray or radiation will be described, but the present invention is not limited thereto.

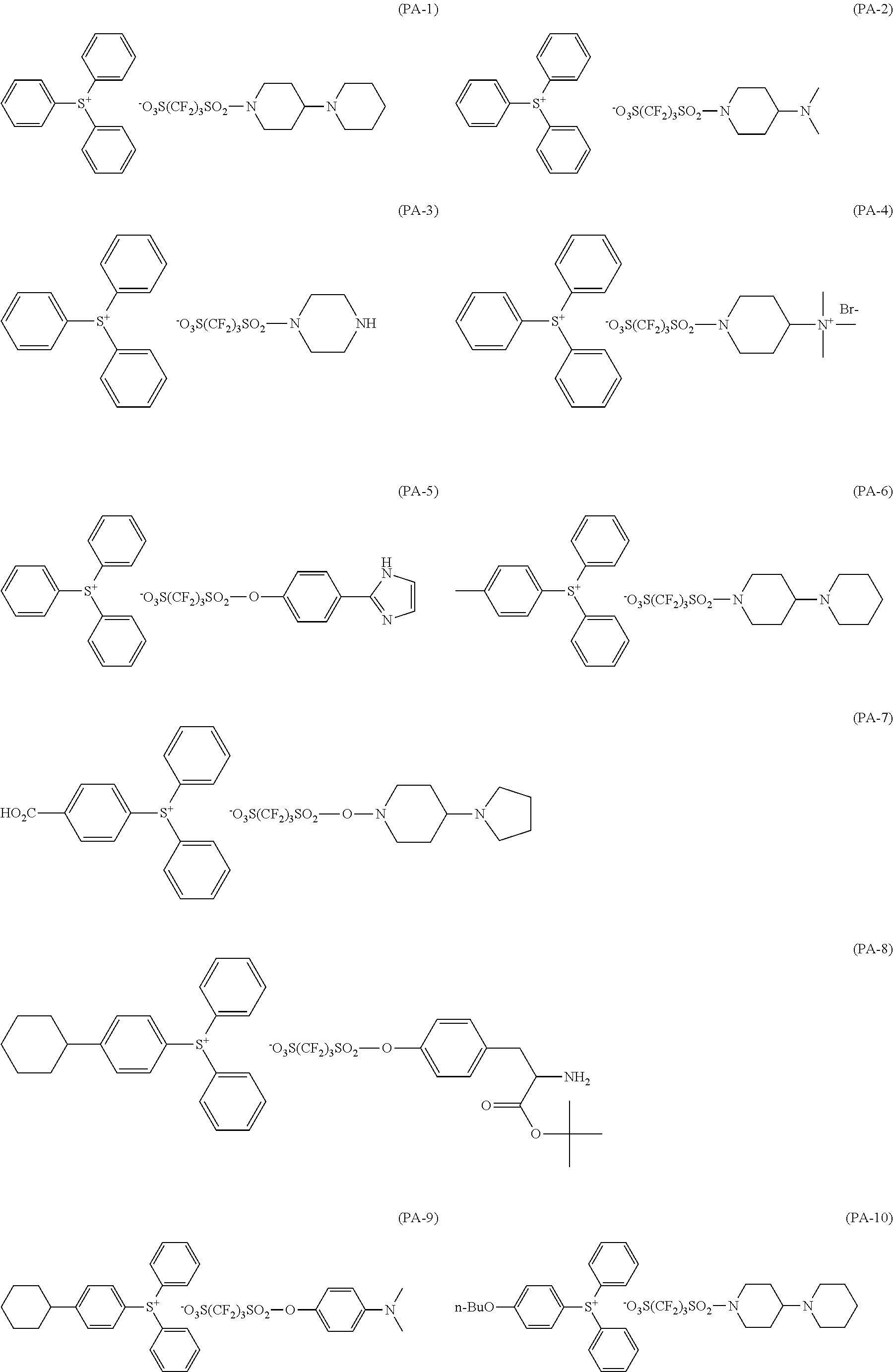

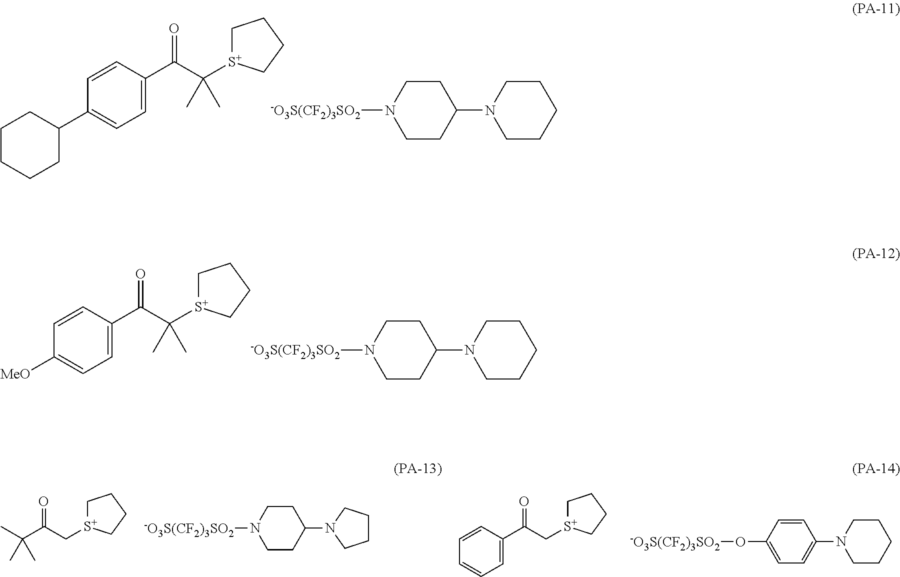

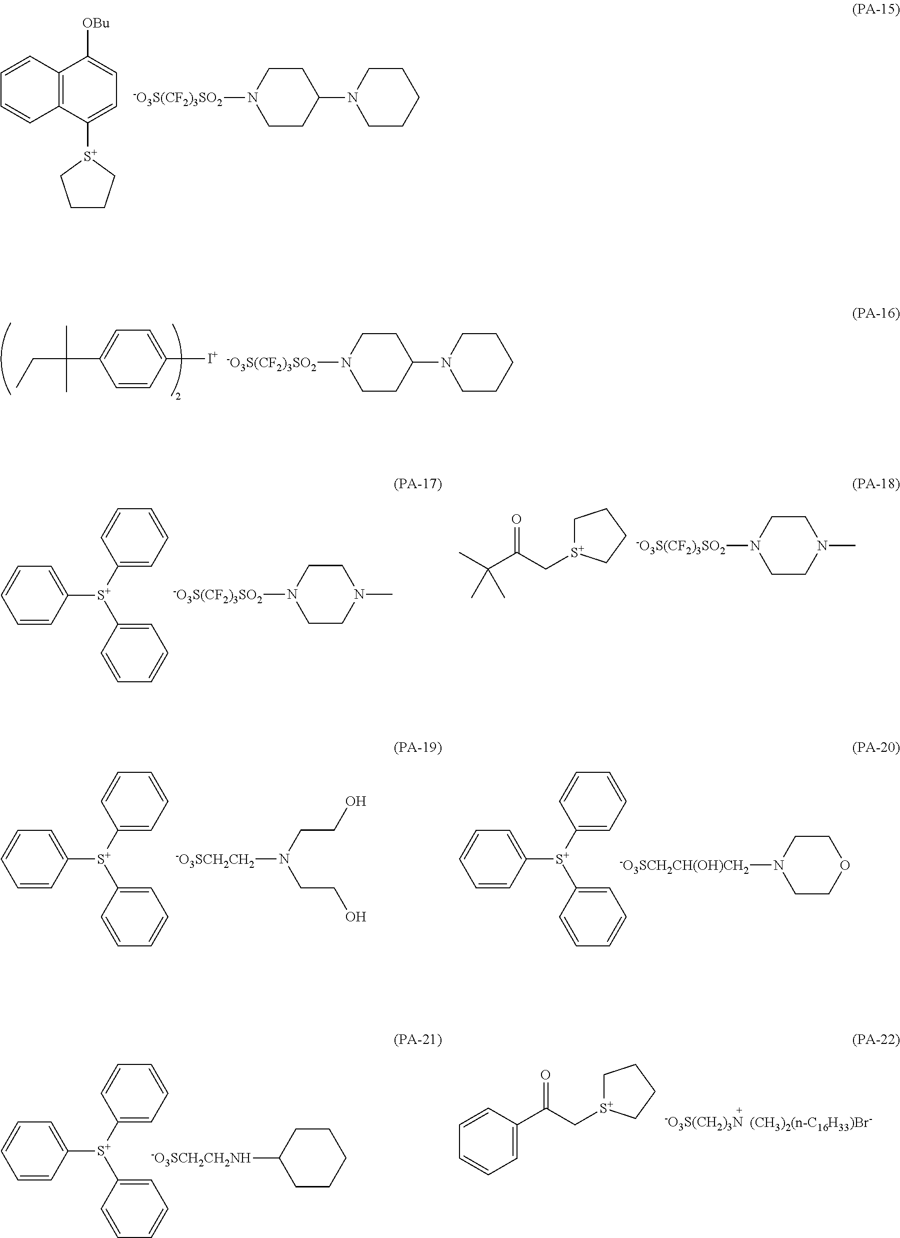

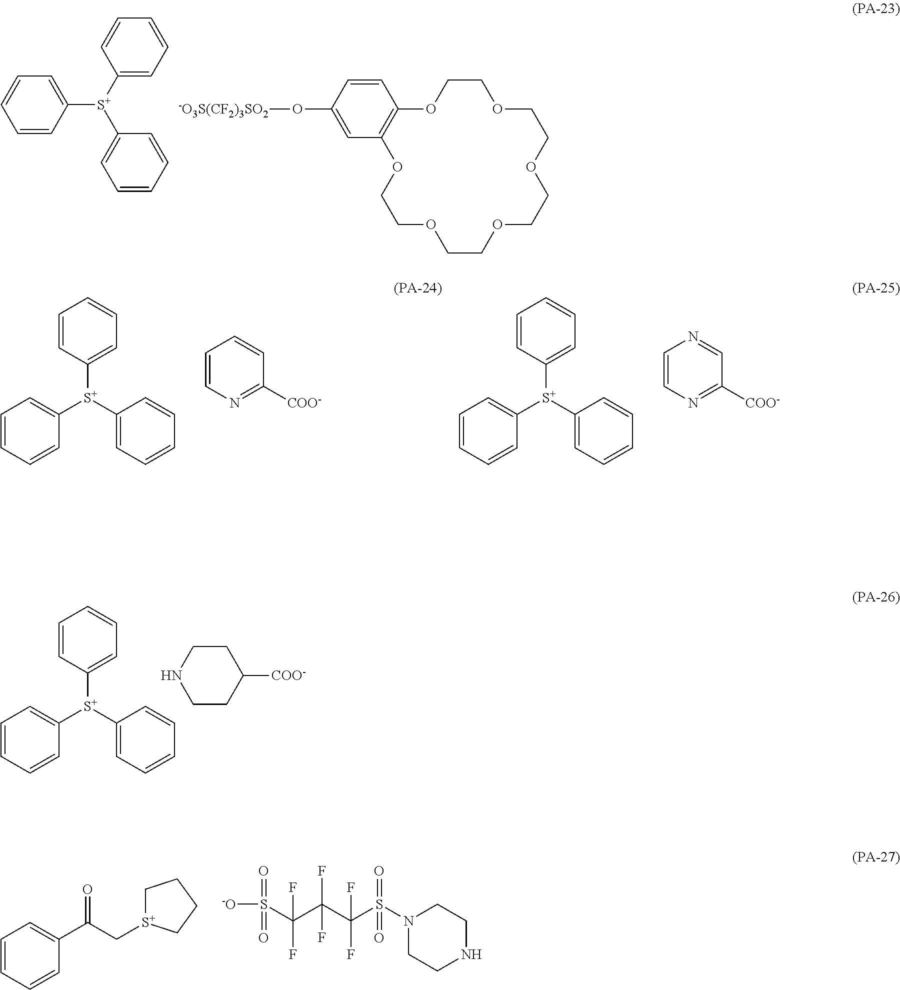

These compounds may be easily synthesized from a compound represented by Formula (PA-I) or a lithium, sodium or potassium salt thereof and a hydroxide, bromide, chloride or the like of iodonium or sulfonium, by using the salt exchange method described in Japanese Patent Application Publication No. H11-501909 or Japanese Patent Application Laid-Open No. 2003-246786. Further, the synthesis may also be performed in accordance with the synthesis method described in Japanese Patent Application Laid-Open No. H7-333851.

Hereinafter, specific examples of the compound (N) capable of generating a compound represented by Formula (PA-II) or (PA-III) upon irradiation with an actinic ray or radiation will be described, but the present invention is not limited thereto.

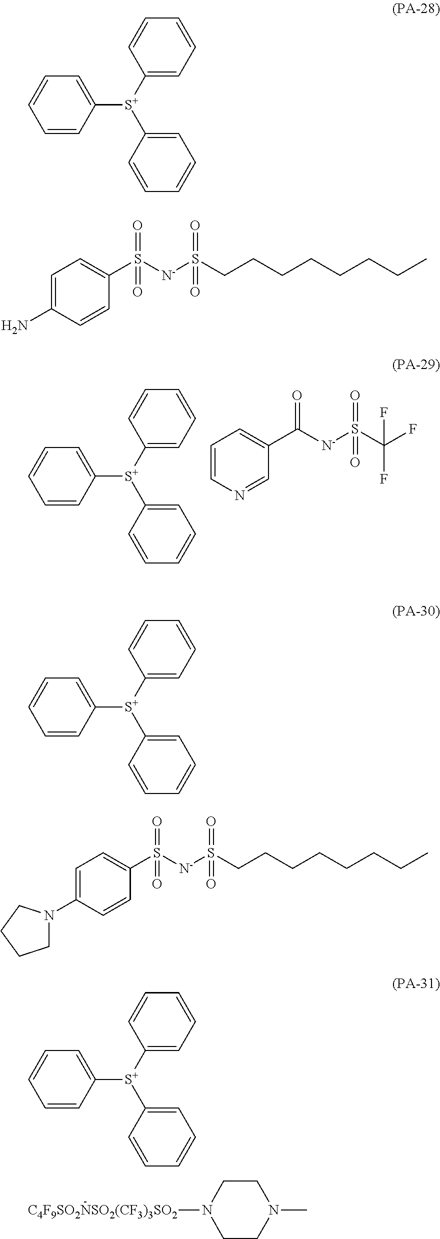

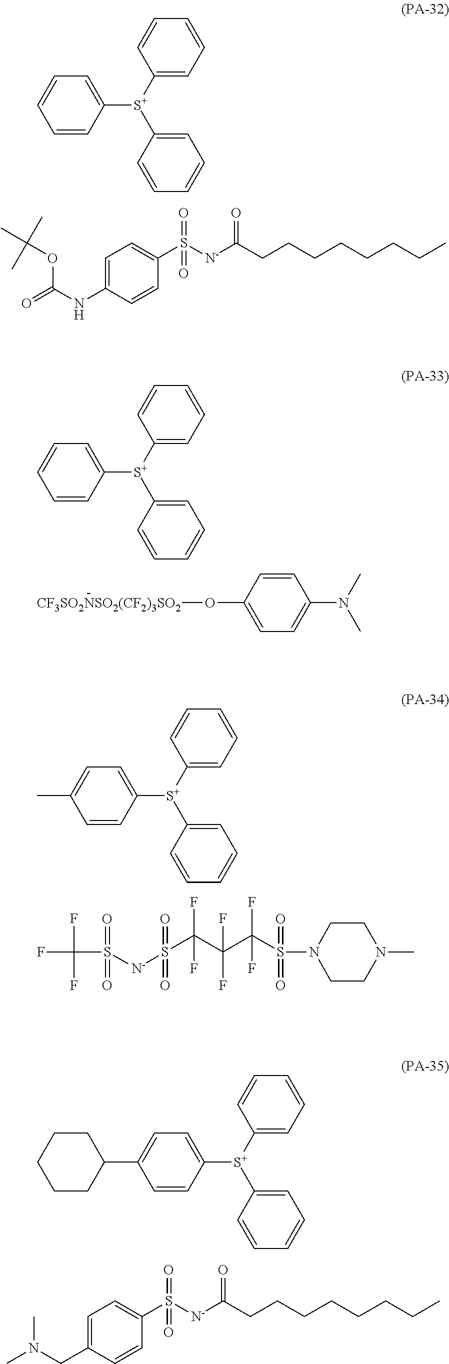

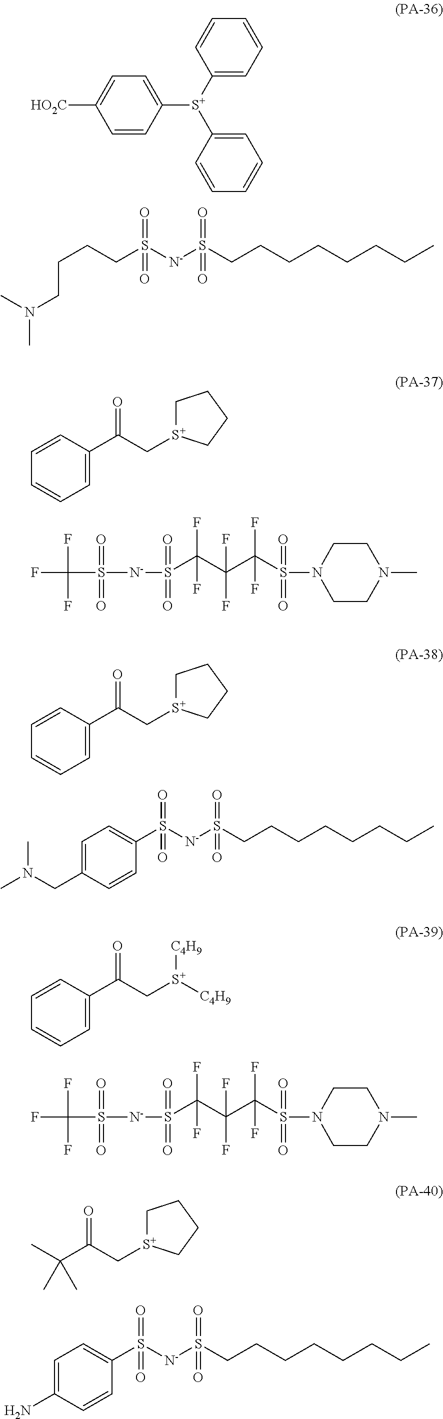

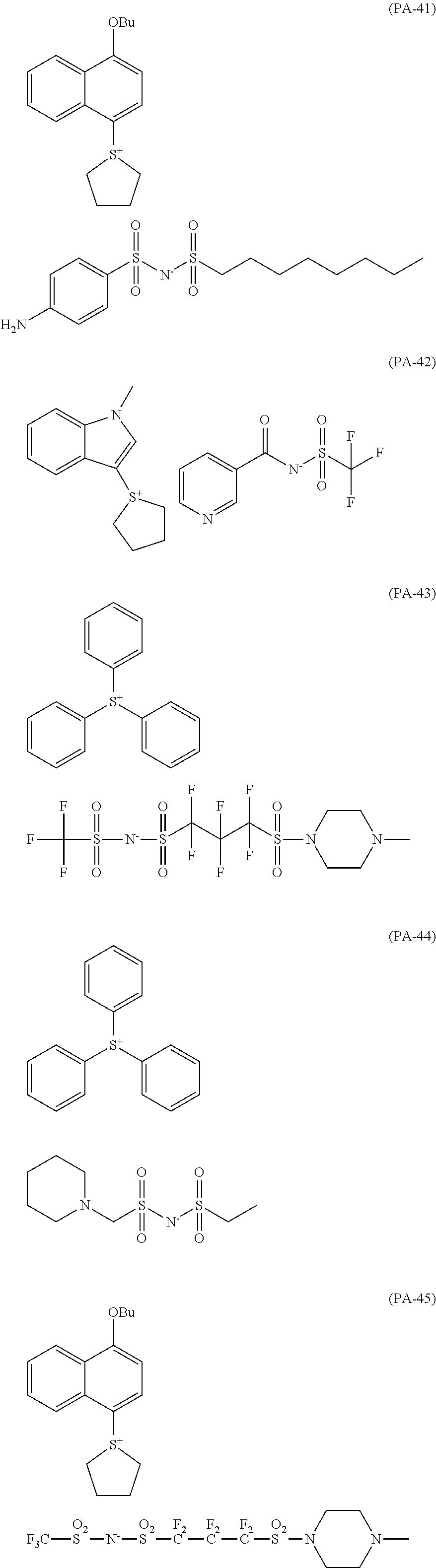

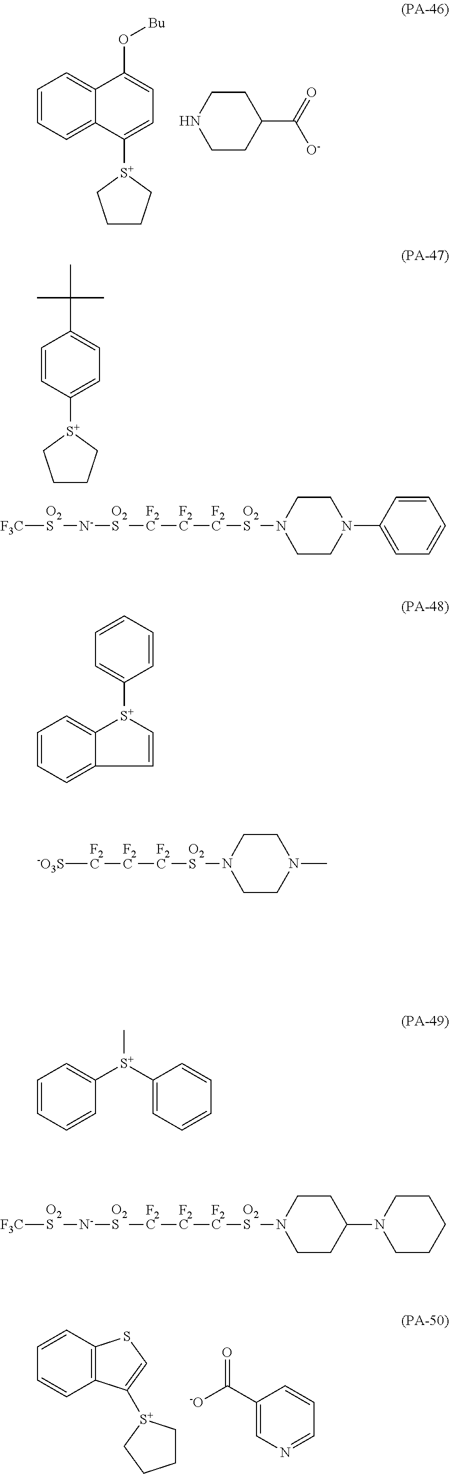

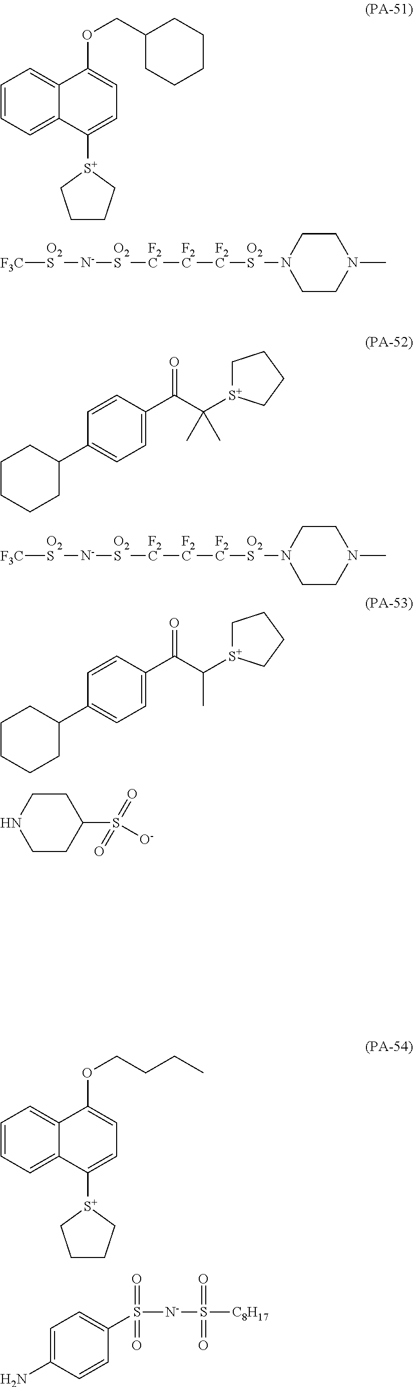

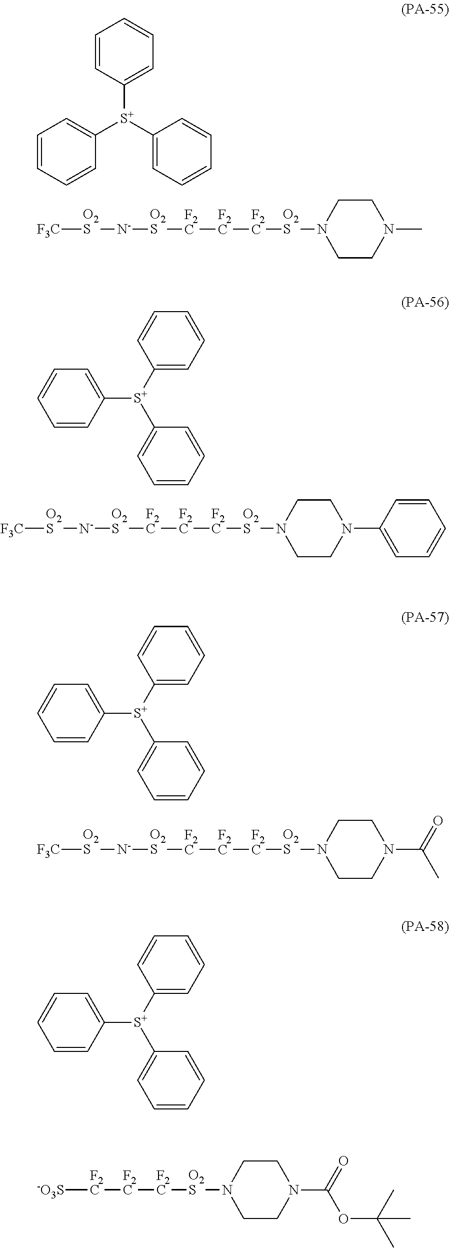

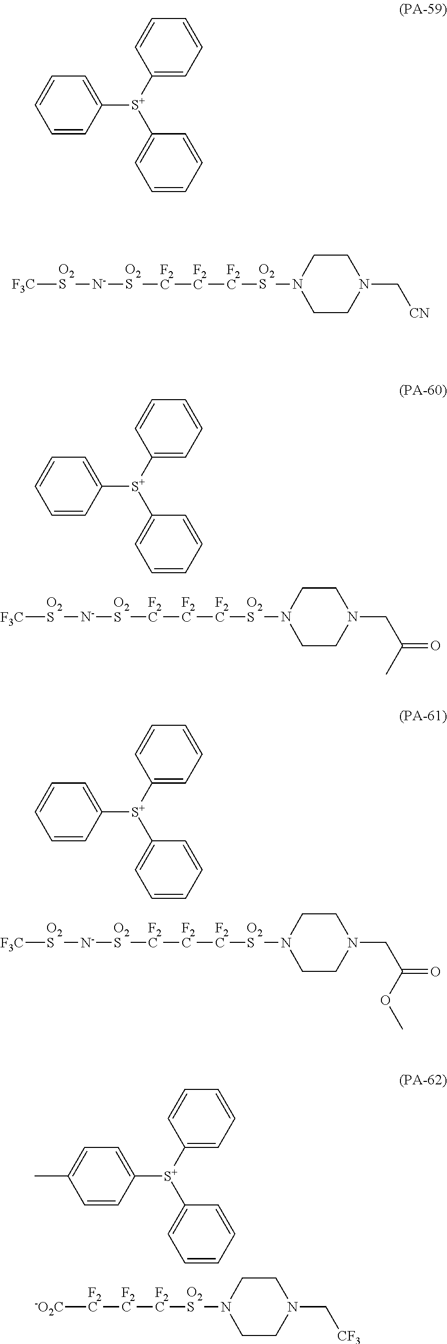

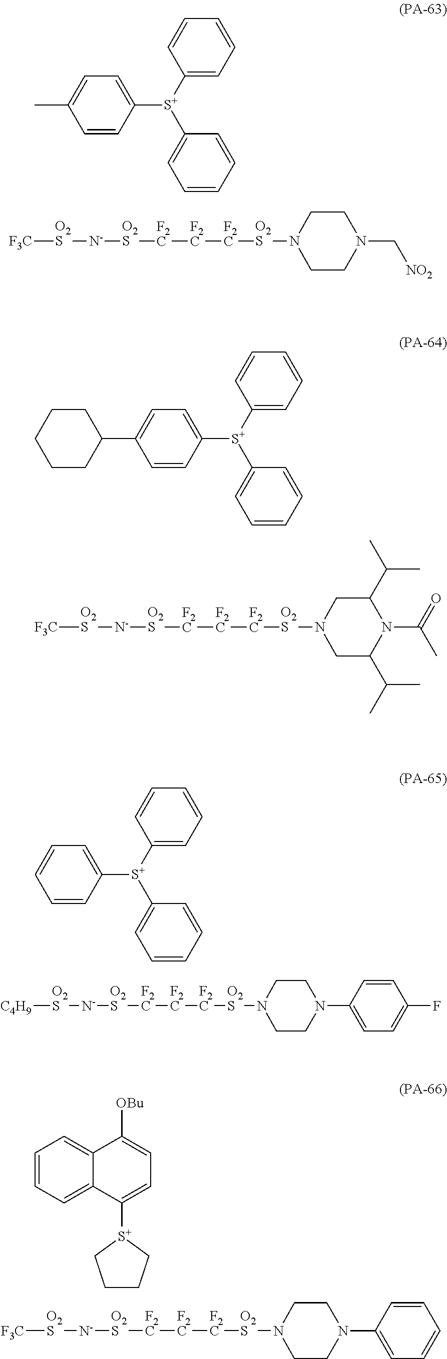

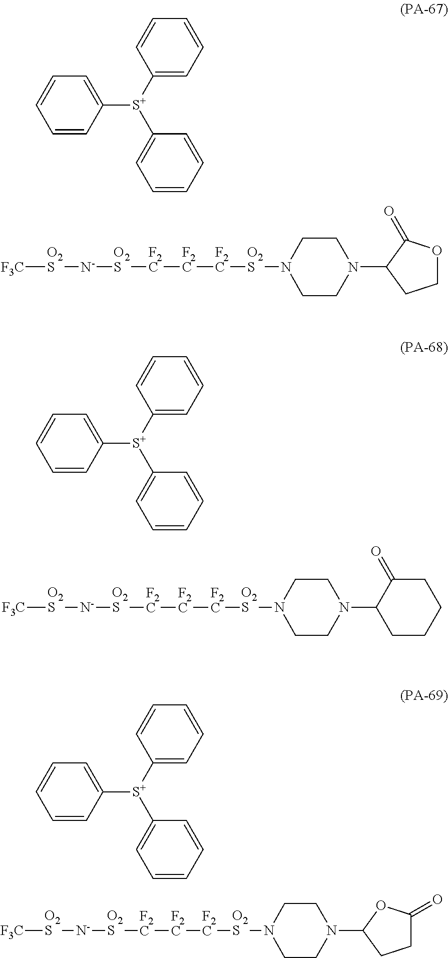 [SMILES: c1ccc([S+](c2ccccc2)c2ccccc2)cc1 ; O=C1OCCC1N1CCN(S(=O)(=O)C(F)(F)C(F)(F)C(F)(F)S(=O)(=O)[N-]S(=O)(=O)C(F)(F)F)CC1 ; c1ccc([S+](c2ccccc2)c2ccccc2)cc1 ; O=C1CCCCC1N1CCN(S(=O)(=O)C(F)(F)C(F)(F)C(F)(F)S(=O)(=O)[N-]S(=O)(=O)C(F)(F)F)CC1 ; c1ccc([S+](c2ccccc2)c2ccccc2)cc1 ; O=C1CCC(N2CCN(S(=O)(=O)C(F)(F)C(F)(F)C(F)(F)S(=O)(=O)[N-]S(=O)(=O)C(F)(F)F)CC2)O1]

These compounds may be easily synthesized by using a general sulfonate esterification reaction or sulfonamidation reaction. For example, the compound may be obtained by a method of selectively reacting one sulfonyl halide moiety of a bis-sulfonyl halide compound with an amine, alcohol or the like including a partial structure represented by Formula (PA-II) or (PA-III) to form a sulfonamide bond or a sulfonate ester bond and then hydrolyzing the other sulfonyl halide moiety, or a method of ring-opening a cyclic sulfonic acid anhydride by an amine or alcohol including a partial structure represented by Formula (PA-II). The amine or alcohol including a partial structure represented by Formula (PA-II) or (PA-III) may be synthesized by reacting an amine or an alcohol with an anhydride such as (R′O₂C)₂O, (R′SO₂)₂O and the like or an acid chloride compound such as R′O₂CCl and R′SO₂Cl (R′ is a methyl group, a n-octyl group or a trifluoromethyl group) under basicity conditions. In particular, the synthesis may be performed in accordance with synthesis examples and the like in Japanese Patent Application Laid-Open No. 2006-330098.

The molecular weight of the compound (N) is preferably 500 to 1,000.

The actinic ray-sensitive or radiation-sensitive resin composition in the present invention may or may not contain the compound (N), but in the case of containing the compound (N), the content of the compound (N) is preferably 0.1% by mass to 20% by mass, and more preferably 0.1% by mass to 10% by mass, based on the solid content of the actinic ray-sensitive or radiation-sensitive resin composition.

[5-2] Basic Compound (N′)

The actinic ray-sensitive or radiation-sensitive resin composition in the present invention may contain a basic compound (N′) different from the resin (A) in order to reduce the change in performance with time from exposure to heating.

Preferred examples of the basic compound (N′) may include compounds having a structure represented by the following Formulas (A′) to (E′).

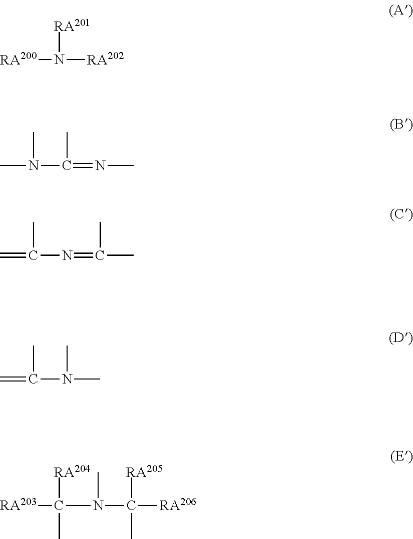

In Formulas (A′) to (E′),

each of RA²⁰⁰, RA²⁰¹ and RA²⁰² may be the same or different and represents a hydrogen atom, an alkyl group (preferably having 1 to 20 carbon atoms), a cycloalkyl group (preferably having 3 to 20 carbon atoms) or an aryl group (having 6 to 20 carbon), and RA²⁰¹ and RA²⁰² may be bound with each other to form a ring. Each of RA²⁰³, RA²⁰⁴, RA²⁰⁵ and RA²⁰⁶ may be the same or different and represents an alkyl group (preferably having 1 to 20 carbon atoms).

The alkyl group may have a substituent, and the alkyl group having a substituent is preferably an aminoalkyl group having 1 to 20 carbon atoms, a hydroxyalkyl group having 1 to 20 carbon atoms or a cyanoalkyl group having 1 to 20 carbon atoms.

The alkyl group in Formulas (A′) to (E′) is more preferably unsubstituted.

Preferred specific examples of the basic compound (N′) may include guanidine, aminopyrrolidine, pyrazole, pyrazoline, piperazine, aminomorpholine, aminoalkylmorpholine, piperidine and the like, and more preferred specific examples thereof may include a compound having an imidazole structure, a diazabicyclo structure, an onium hydroxide structure, an onium carboxylate structure, a trialkylamine structure, an aniline structure or a pyridine structure, an alkylamine derivative having a hydroxyl group and/or an ether bond, an aniline derivative having a hydroxyl group and/or an ether bond and the like.

Examples of the compound having an imidazole structure may include imidazole, 2,4,5-triphenylimidazole, benzimidazole and the like. Examples of the compound having a diazabicyclo structure may include 1,4-diazabicyclo[2,2,2]octane, 1,5-diazabicyclo[4,3,0]non-5-ene, 1,8-diazabicyclo[5,4,0]undec-7-ene and the like. Examples of the compound having an onium hydroxide structure may include triarylsulfonium hydroxide, phenacylsulfonium hydroxide, a sulfonium hydroxide having a 2-oxoalkyl group, specifically, triphenylsulfonium hydroxide, tris(t-butylphenyl)sulfonium hydroxide, bis(t-butylphenyl)iodonium hydroxide, phenacylthiophenium hydroxide, 2-oxopropylthiophenium hydroxide and the like. Examples of the compound having an onium carboxylate structure may include a compound, in which the anion moiety of a compound having an onium hydroxide structure has been converted into carboxylate, such as acetate, adamantane-1-carboxylate and perfluoroalkylcarboxylate. Examples of the compound having a trialkylamine structure may include tri(n-butyl)amine, tri(n-octyl)amine and the like. Examples of the compound having an aniline structure may include 2,6-diisopropylaniline, N,N-dimethylaniline, N,N-dibutylaniline, N,N-dihexylaniline and the like. Examples of the alkylamine derivative having a hydroxyl group and/or an ether bond may include ethanolamine, diethanolamine, triethanolamine, tris(methoxyethoxyethyl)amine and the like. Examples of the aniline derivative having a hydroxyl group and/or an ether bond may include N,N-bis(hydroxyethyl)aniline and the like.

Examples of the preferred basic compound may further include an amine compound having a phenoxy group, an ammonium salt compound having a phenoxy group, an amine compound having a sulfonate ester group, and an ammonium salt compound having a sulfonate ester group.

It is preferred that the amine compound having a phenoxy group, the ammonium salt compound having a phenoxy group, the amine compound having a sulfonate ester group, and the ammonium salt compound having a sulfonate ester group have at least one alkyl group bonded to a nitrogen atom. Further, it is preferred that the alkyl chain has an oxygen atom therein to form an oxyalkylene group. The number of the oxyalkylene groups is one or more, preferably 3 to 9, and more preferably 4 to 6, in the molecule. Among the oxyalkylene groups, the structures of —CH₂CH₂O—, CH(CH₃)CH₂O— or —CH₂CH₂CH₂O— are preferred.

Specific examples of the amine compound having a phenoxy group, the ammonium salt compound having a phenoxy group, the amine compound having a sulfonate ester group, and the ammonium salt compound having a sulfonate ester group may include compounds (C1-1) to (C3-3) as exemplified in paragraph [0066] of US Patent Application Publication No. 2007/0224539, but are not limited thereto.

Further, a nitrogen-containing organic compound having a group capable of leaving by the action of an acid may also be used as a kind of the basic compound. Examples of the compound may include a compound represented by the following Formula (F). Meanwhile, the compound represented by the following Formula (F) exhibits an effective basicity in the system as a result of leaving of the group capable of leaving by the action of an acid.

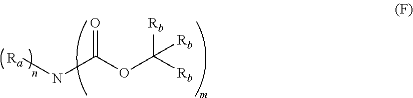

In Formula (F), Rₐ independently represents a hydrogen atom, an alkyl group, a cycloalkyl group, an aryl group or an aralkyl group. Further, when n=2, each of two Rₐ's may be the same or different and two Rₐ's may be bound with each other to form a divalent heterocyclic hydrocarbon group (preferably having 20 or less carbon atoms) or a derivative thereof.

A plurality of R_{b} independently represents a hydrogen atom, an alkyl group, a cycloalkyl group, an aryl group or an aralkyl group, provided that, in —C(R_{b})(R_{b})(R_{b}), when one or more R_{b}'s are a hydrogen atom, at least one of remaining R_{b}'s is a cyclopropyl group or a 1-alkoxy alkyl group.

At least two R_{b}'s may be bound with each other to form an alicyclic hydrocarbon group, an aromatic hydrocarbon group, a heterocyclic hydrocarbon group or a derivative thereof.

n represents an integer of 0 to 2, m represents an integer of 1 to 3, and n+m=3.

In Formula (F), each of the alkyl group, the cycloalkyl group, the aryl group and the aralkyl group represented by Rₐ and R_{b} may be substituted with a functional group such as a hydroxyl group, a cyano group, an amino group, a pyrrolidino group, a piperidino group, a morpholino group and an oxo group, an alkoxy group or a halogen atom.

Examples of the alkyl group, the cycloalkyl group, the aryl group or the aralkyl group (each of the alkyl group, the cycloalkyl group, the aryl group and the aralkyl group may be substituted with the functional group, an alkoxy group or a halogen atom) of the R may include a group derived from a straight or branched alkane such as methane, ethane, propane, butane, pentane, hexane, heptane, octane, nonane, decane, undecane and dodecane, a group in which the group derived from the alkane is substituted with one or more kinds of or one or more of cycloalkyl groups such as, for example, a cyclobutyl group, a cyclopentyl group and a cyclohexyl group,

a group derived from a cycloalkane such as cyclobutane, cyclopentane, cyclohexane, cycloheptane, cyclooctane, norbornane, adamantane and noradamantane, a group in which the group derived from the cycloalkane is substituted with one or more kinds of or one or more of straight or branched alkyl groups such as, for example, a methyl group, an ethyl group, a n-propyl group, an i-propyl group, a n-butyl group, a 2-methylpropyl group, a 1-methylpropyl group and a t-butyl group,

a group derived from an aromatic compound such as benzene, naphthalene and anthracene, a group in which the group derived from the aromatic compound is substituted with one or more kinds of or one or more of straight or branched alkyl groups such as, for example, a methyl group, an ethyl group, a n-propyl group, an i-propyl group, a n-butyl group, a 2-methylpropyl group, a 1-methylpropyl group and a t-butyl group, and

a group derived from a heterocyclic compound such as pyrrolidine, piperidine, morpholine, tetrahydrofuran, tetrahydropyran, indole, indoline, quinoline, perhydroquinoline, indazole and benzimidazole, a group in which the group derived from the heterocyclic compound is substituted with one or more kinds of or one or more of straight or branched alkyl groups or groups derived from aromatic compounds, a group in which the group derived from a straight or branched alkane or the group derived from a cycloalkane is substituted with one or more kinds of or one or more of groups derived from aromatic compounds, such as a phenyl group, a naphthyl group and an anthracenyl group, a group in which the above-described substituent is substituted with a functional group such as a hydroxyl group, a cyano group, an amino group, a pyrrolidino group, a piperidino group, a morpholino group and an oxo group, and the like.

Further, examples of the divalent heterocyclic hydrocarbon group (preferably having 1 to 20 carbon atoms) in which Rₐs are bound with each other to form or a derivative thereof may include a group derived from a heterocyclic compound such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline and 1,5,9-triazacyclododecane, a group in which the group derived from the heterocyclic compound is substituted with one or more kinds of or one or more of straight or branched groups derived from alkane, groups derived from cycloalkane, groups derived from aromatic compounds, groups derived from heterocyclic compounds and functional groups such as a hydroxyl group, a cyano group, an amino group, a pyrrolidino group, a piperidino group, a morpholino group and an oxo group, and the like.

Specific examples of the compound represented by Formula (F) will be described below.

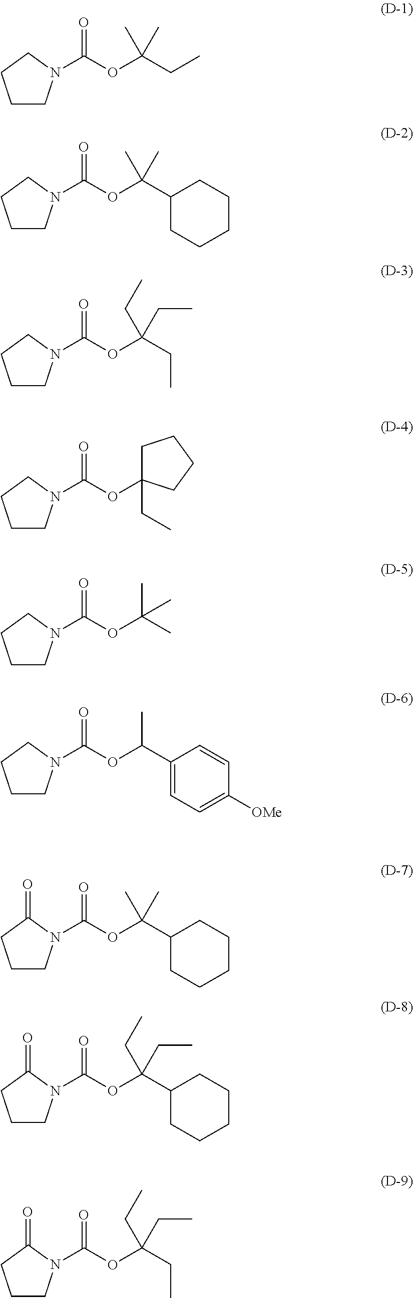

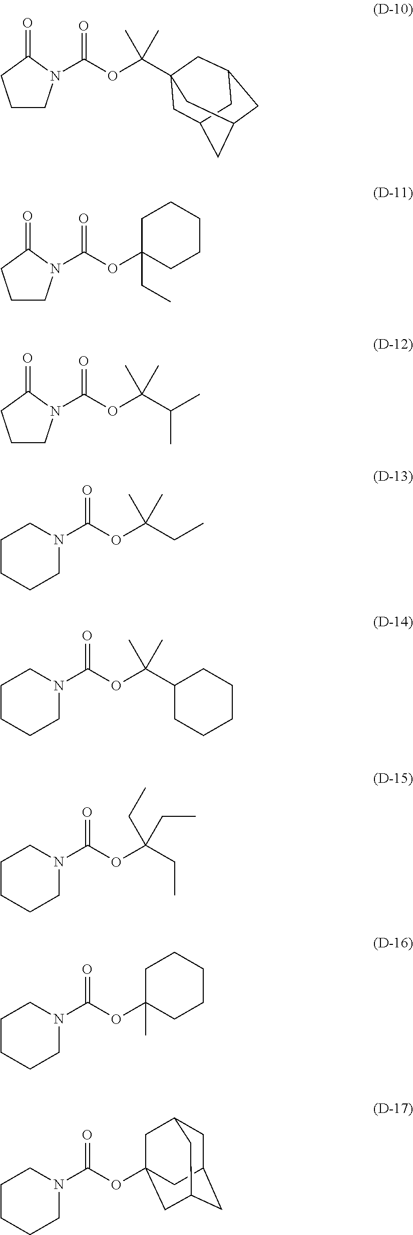

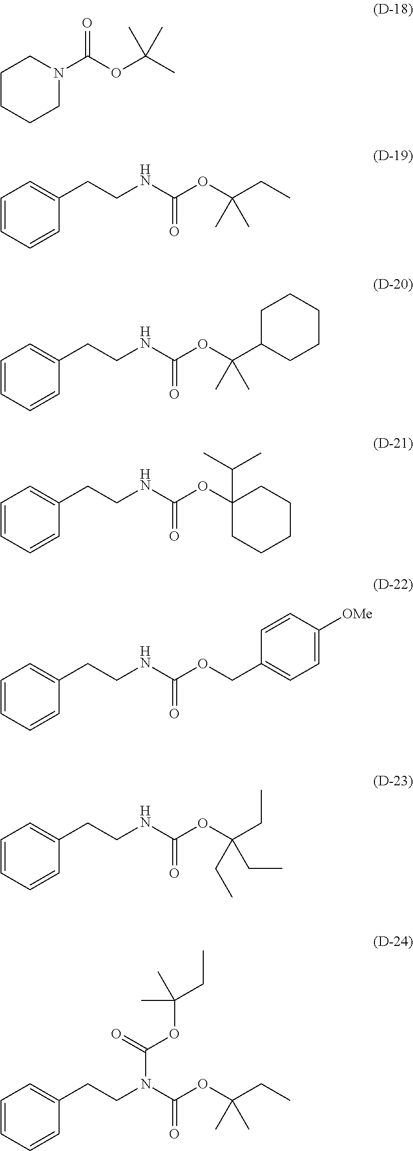

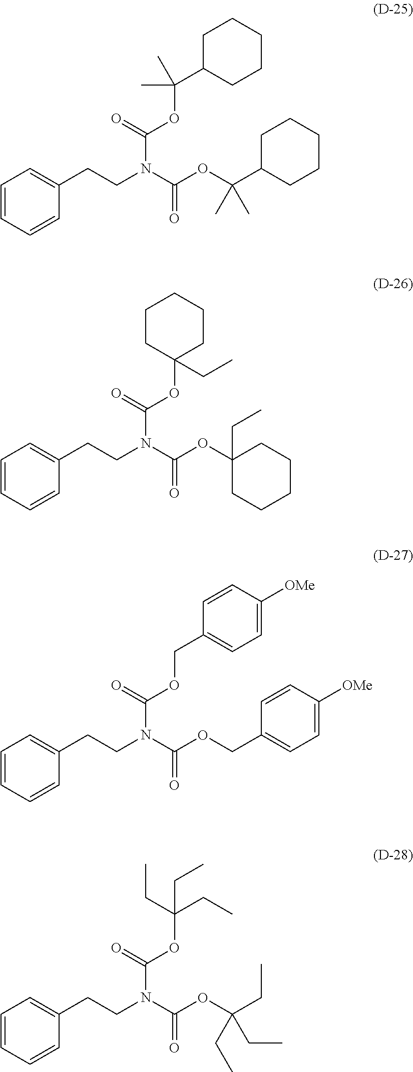 [SMILES: CC(C)(OC(=O)N(CCc1ccccc1)C(=O)OC(C)(C)C1CCCCC1)C1CCCCC1 ; CCC1(OC(=O)N(CCc2ccccc2)C(=O)OC2(CC)CCCCC2)CCCCC1 ; COc1ccc(COC(=O)N(CCc2ccccc2)C(=O)OCc2ccc(OC)cc2)cc1 ; CCC(CC)(CC)OC(=O)N(CCc1ccccc1)C(=O)OC(CC)(CC)CC]

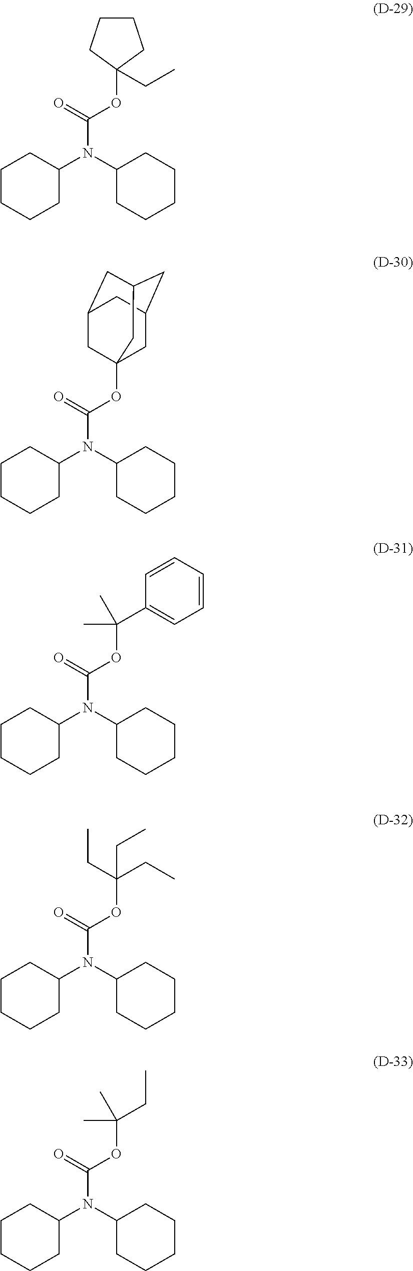

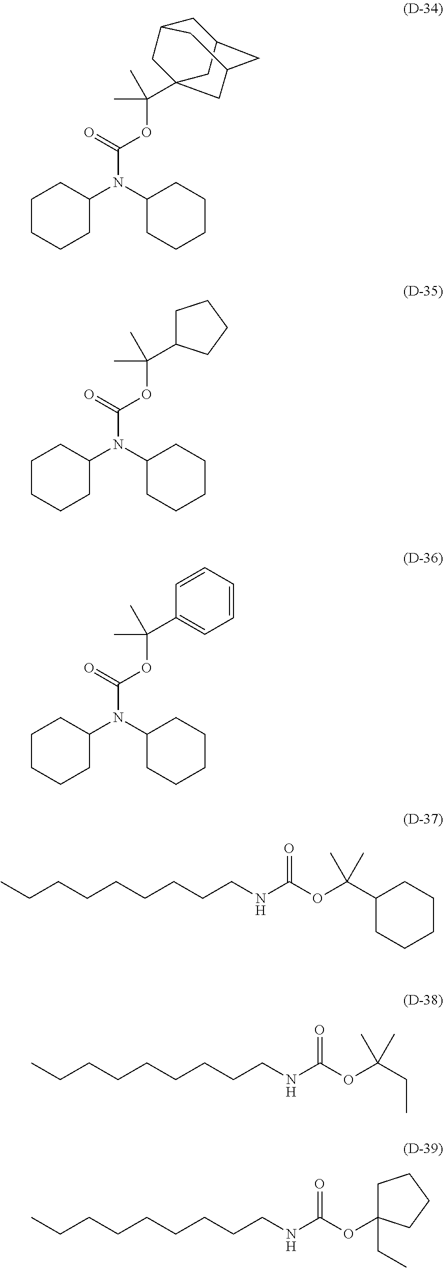

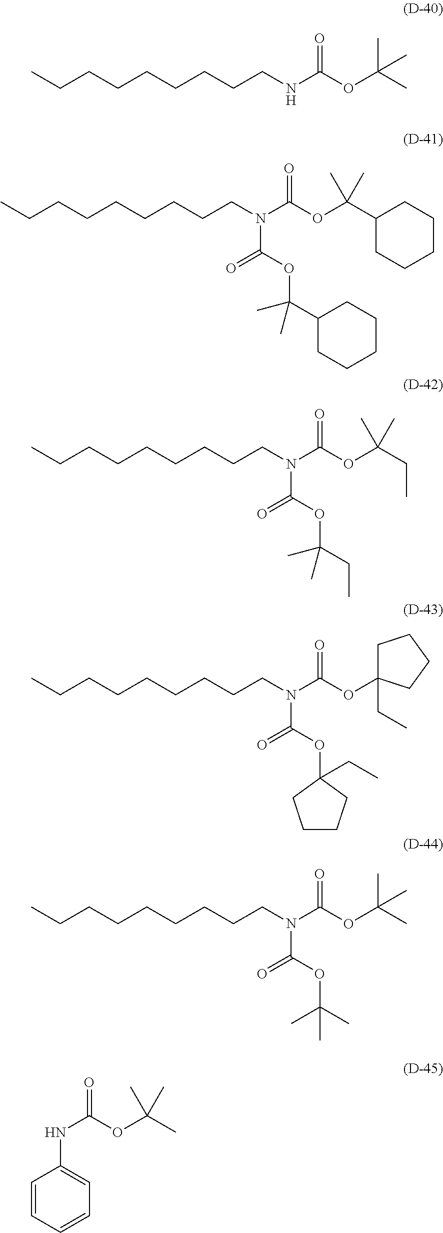

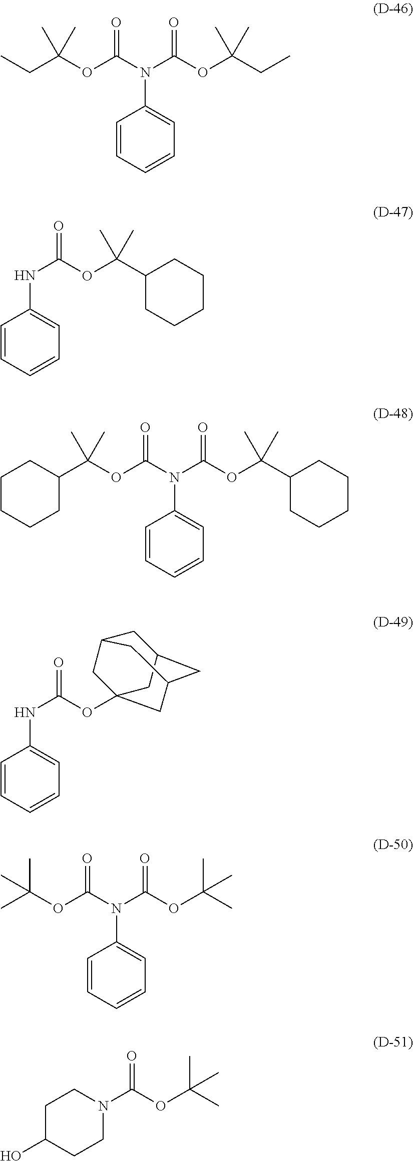

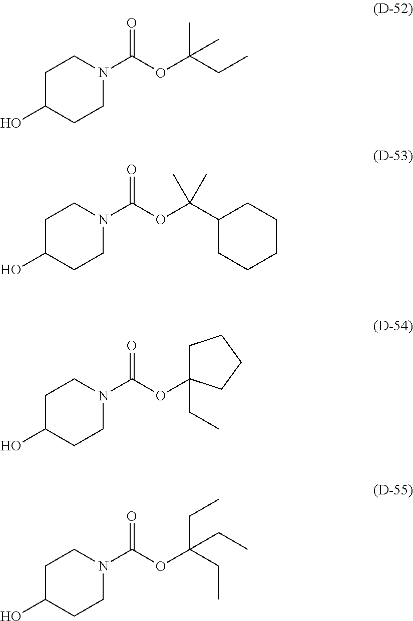 [SMILES: CCC(C)(C)OC(=O)N1CCC(O)CC1 ; CC(C)(OC(=O)N1CCC(O)CC1)C1CCCCC1 ; CCC1(OC(=O)N2CCC(O)CC2)CCCC1 ; CCC(CC)(CC)OC(=O)N1CCC(O)CC1]

As for the compound represented by Formula (F), a commercially available product may be used and the compound may be synthesized from a commercially available amine by the method described in Protective Groups in Organic Synthesis, 4th Edition and the like. The compound may be synthesized in accordance with the method described in, for example, Japanese Patent Application Laid-Open No. 2009-199021, as the most general method.

Further, a compound having an amine oxide structure as the basic compound (N′) may also be used. As specific examples of the compound, triethylamine pyridine N-oxide, tributylamine N-oxide, triethanolamine N-oxide, tris(methoxyethyl)amine N-oxide, tris(2-(methoxymethoxy)ethyl)amine=oxide, 2,2′,2″-nitrilotriethylpropionate N-oxide, N-2-(2-methoxyethoxy)methoxyethylmorpholine N-oxide, and an amine oxide compound exemplified in Japanese Patent Application Laid-Open No. 2008-102383 may be used.

The molecular weight of the basic compound (N′) is preferably 250 to 2,000, and more preferably 400 to 1,000. From the viewpoint of more reduction in LWR and uniformity of local pattern dimension, the molecular weight of the basic compound is preferably 400 or more, more preferably 500 or more, and still more preferably 600 or more.

These basic compounds (N′) may be used in combination with the compound (N), and are used either alone or in combination of two or more thereof.

The actinic ray-sensitive or radiation-sensitive resin composition in the present invention may or may not contain the basic compound (N′), but in the case of containing the basic compound (N′), the amount of the basic compound (N′) used is usually 0.001% by mass to 10% by mass, and preferably 0.01% by mass to 5% by mass, based on the solid content of the actinic ray-sensitive or radiation-sensitive resin composition.

[6] Solvent (E)

Examples of the solvent which may be used at the time of preparing the actinic ray-sensitive or radiation-sensitive resin composition in the present invention may include an organic solvent such as alkylene glycol monoalkyl ether carboxylate, alkylene glycol monoalkyl ether, alkyl ester lactate, alkyl alkoxypropionate, cyclic lactone (preferably having 4 to 10 carbon atoms), a monoketone compound (preferably having 4 to 10 carbon atoms) which may have a ring, alkylene carbonate, alkyl alkoxyacetate and alkyl pyruvate.

Specific examples of these solvents may include those described in paragraphs [0441] to [0455] of U.S. Patent Application Publication No. 2008/0187860.

In the present invention, a mixed solvent in which a solvent containing a hydroxyl group and a solvent containing no hydroxyl group in the structure thereof are mixed may be used as an organic solvent.

As the solvent containing a hydroxyl group and the solvent containing no hydroxyl group, the above-described exemplary compound may be appropriately selected, and the solvent containing a hydroxyl group is preferably alkylene glycol monoalkyl ether, alkyl lactate and the like, and more preferably propylene glycol monomethyl ether (PGME, another name 1-methoxy-2-propanol) and ethyl lactate. Further, the solvent containing no hydroxyl group is preferably alkylene glycol monoalkyl ether acetate, alkyl alkoxypropionate, a monoketone compound which may contain a ring, a cyclic lactone, alkyl acetate and the like, and among them, propylene glycol monomethyl ether acetate (PGMEA, another name 1-methoxy-2-acetoxypropane), ethyl ethoxypropionate, 2-heptanone, γ-butyrolactone, cyclohexanone and butyl acetate are particularly preferred, and propylene glycol monomethyl ether acetate, ethyl ethoxypropionate and 2-heptanone are most preferred.

The mixing ratio (by mass) of the solvent containing a hydroxyl group to the solvent containing no hydroxyl group is 1/99 to 99/1, preferably 10/90 to 90/10, and more preferably 20/80 to 60/40. A mixed solvent in which the solvent containing no hydroxyl group is contained in an amount of 50% by mass or more is particularly preferred from the viewpoint of coating uniformity.

The solvent preferably includes propylene glycol monomethyl ether acetate, and a single solvent of propylene glycol monomethyl ether acetate or a mixed solvent of two or more containing propylene glycol monomethyl ether acetate is preferred.

[7] Surfactant (F)

The actinic ray-sensitive or radiation-sensitive resin composition in the present invention may or may not further contain a surfactant, but in the case of containing a surfactant, it is more preferred that the composition contains any one of fluorine and/or silicon-based surfactants (a fluorine-based surfactant, a silicon-based surfactant and a surfactant having both a fluorine atom and a silicon atom), or two or more thereof.

The actinic ray-sensitive or radiation-sensitive resin composition in the present invention contains a surfactant, thereby imparting a resist pattern with adhesion and reduced development defects due to improved sensitivity and resolution when using an exposure light source with a wavelength of 250 nm or less, particularly 220 nm or less.

Examples of the fluorine-based and/or silicon-based surfactants may include surfactants described in paragraph [0276] of U.S. Patent Application Publication No. 2008/0248425, such as Eftop EF301 and EF303 (manufactured by Shin-Akita Chemical Co., Ltd.), Fluorad FC430, 431 and 4430 (manufactured by Sumitomo 3M Limited), Megafac F171, F173, F176, F189, F113, F110, F177, F120 and R08 (manufactured by DIC Corporation), Surflon S-382, SC101, 102, 103, 104, 105 and 106 and KH-20 (manufactured by Asahi Glass Co., Ltd.), Troysol S-366 (manufactured by Troy Chemical Industries, Inc.), GF-300 and GF-150 (manufactured by Toagosei Chemical Industry Co., Ltd.), Surflon S-393 (manufactured by Seimi Chemical Co., Ltd.), Eftop EF121, EF122A, EF122B, RF122C, EF125M, EF135M, EF351, EF352, EF801, EF802 and EF601 (manufactured by JEMCO Co., Ltd.), PF636, PF656, PF6320 and PF6520 (manufactured by OMNOVA Solutions, Inc.), and FTX-204G, 208G, 218G, 230G, 204D, 208D, 212D, 218D and 222D (manufactured by NEOS Co., Ltd.). In addition, polysiloxane polymer KP-341 (manufactured by Shin-Etsu Chemical Co., Ltd.) may also be used as the silicon-based surfactant.

Further, other than those known surfactants described above, it is possible to use a surfactant using a polymer having a fluoro-aliphatic group derived from a fluoro-aliphatic compound which is prepared by a telomerization method (also referred to as a telomer method) or an oligomerization method (also referred to as an oligomer method) as the surfactant. The fluoro-aliphatic compound may be synthesized by the method described in Japanese Patent Application Laid-Open No. 2002-90991.

Examples of a surfactant corresponding to the above-described surfactant may include Megafac F178, F-470, F-473, F-475, F-476 and F-472 (manufactured by DIC Corporation), a copolymer of an acrylate having a C₆F₁₃ group (or methacrylate) with a (poly(oxyalkylene))acrylate (or methacrylate), a copolymer of an acrylate having a C₃F₇ group (or methacrylate) with a (poly(oxyethylene))acrylate (or methacrylate) and a (poly(oxypropylene))acrylate (or methacrylate), and the like.

Further, in the present invention, it is also possible to use a surfactant other than the fluorine-based and/or silicon-based surfactant, described in paragraph [0280] of U.S. Patent Application Publication No. 2008/0248425.

These surfactants may be used either alone or in combination of several thereof.

When the actinic ray-sensitive or radiation-sensitive resin composition contains a surfactant, the amount of the surfactant used is preferably 0.0001% by mass to 2% by mass, and more preferably 0.0005% by mole to 1% by mole, based on the total amount of the actinic ray-sensitive or radiation-sensitive resin composition (excluding the solvent).

Meanwhile, by adjusting the amount of the surfactant added to 10 ppm or less based on the total amount of the actinic ray-sensitive or radiation-sensitive resin composition (excluding the solvent), the surface uneven distribution of the hydrophobic resin is increased, and accordingly, the surface of the resist film may be made to be more hydrophobic, thereby improving the water follow-up property at the time of immersion exposure.

[8] Other Additives (G)

The actinic ray-sensitive or radiation-sensitive resin composition in the present invention may or may not contain a carboxylic acid onium salt. Examples of the carboxylic acid onium salt may include those described in paragraphs [0605] to [0606] of U.S. Patent Application Publication No. 2008/0187860.

The carboxylic acid onium salt may be synthesized by reacting sulfonium hydroxide, iodonium hydroxide, ammonium hydroxide and carboxylic acid with silver oxide in an appropriate solvent.

When the actinic ray-sensitive or radiation-sensitive resin composition contains a carboxylic acid onium salt, the content thereof is generally 0.1% by mass to 20% by mass, preferably 0.5% by mass to 10% by mass, and more preferably 1% by mass to 7% by mass, based on the total solid content of the composition.

The actinic ray-sensitive or radiation-sensitive resin composition of the present invention may further contain a dye, a plasticizer, a photosensitizer, a light absorber, an alkali-soluble resin, a dissolution inhibitor, a compound for accelerating solubility in a developer (for example, a phenol compound having a molecular weight of 1,000 or less, or an alicyclic or aliphatic compound having a carboxyl group) and the like, if necessary.

The phenol compound having a molecular weight of 1,000 or less may be easily synthesized by a person skilled in the art by referring to the methods described in, for example, Japanese Patent Application Laid-Open No. H4-122938, Japanese Patent Application Laid-Open No. H2-28531, U.S. Pat. No. 4,916,210, European Patent No. 219294 and the like.

Specific examples of the alicyclic or aliphatic compound having a carboxyl group may include a carboxylic acid derivative having a steroid structure, such as cholic acid, deoxycholic acid, lithocholic acid and the like, an adamantanecarboxylic acid derivative, adamantanedicarboxylic acid, cyclohexanecarboxylic acid and cyclohexanedicarboxylic acid, but are not limited thereto.

From the viewpoint of improving the resolution, the actinic ray-sensitive or radiation-sensitive resin composition in the present invention is preferably used in a film thickness of 30 nm to 250 nm, and more preferably in a film thickness of 30 nm to 200 nm. Such a film thickness may be achieved by setting a solid concentration in the composition to an adequate range to have an appropriate viscosity, thereby improving coatability and film-formation property.

The solid content concentration of the actinic ray-sensitive or radiation-sensitive resin composition in the present invention is usually 1.0% by mass to 10% by mass, preferably 2.0% by mass to 5.7% by mass, and more preferably 2.0% by mass to 5.3% by mass. By setting the solid content concentration to the above-described range, the resist solution may be uniformly applied on a substrate and a resist pattern having excellent line width roughness may be formed. The reason is not clear, but it is thought that by setting the solid content concentration to 10% by mass or less and preferably 5.7% by mass or less, aggregation of materials, particularly, a photo-acid generator, in the resist solution is suppressed, and as a result, a uniform resist film may be formed.

The solid content concentration is a weight percentage of the weight of other resist components excluding the solvent, based on the total weight of the actinic ray-sensitive or radiation-sensitive resin composition.

The actinic ray-sensitive or radiation-sensitive resin composition in the present invention is used by dissolving the above-described components in a predetermined organic solvent, preferably in the mixed solvent, filtering the solution through a filter, and then applying the filtered solution on a predetermined support (substrate). The filter used for filtration is preferably a polytetrafluoroethylene-, polyethylene- or nylon-made filter having a pore size of 0.1 μm or less, more preferably 0.05 μm or less, and still more preferably 0.03 μm or less. In the filtration through a filter, as described in, for example, Japanese Patent Application Laid-Open No. 2002-62667, circulating filtration may be performed, or the filtration may be performed by connecting a plurality of kinds of filters in series or in parallel. In addition, the composition may be filtered a plurality of times. Further, a deaeration treatment or the like may be applied to the composition before or after filtration.

[9] Pattern Forming Method

The pattern forming method (negative pattern forming method) of the present invention at least includes

(a) forming a film (resist film) by the above-described actinic ray-sensitive or radiation-sensitive resin composition,

(b) exposing the film, and

(c) performing development using a developer containing an organic solvent to form a negative pattern.

The exposure in the process (b) may be immersion exposure.

It is preferred that the pattern forming method of the present invention includes (d) a heating process after (b) the exposure process.

The pattern forming method of the present invention may further include (e) performing development using an alkali developer.

The pattern forming method of the present invention may include several times of (b) the exposure process.

The pattern forming method of the present invention may include several times of (e) the heating process.

The resist film is formed of the above-described actinic ray-sensitive or radiation-sensitive resin composition of the present invention, and more specifically, it is preferred that the resist film is formed on a substrate. In the pattern forming method of the present invention, the process of forming a film by an actinic ray-sensitive or radiation-sensitive resin composition on a substrate, the process of exposing the film, and the process of performing development may be performed by a generally known method.

It is also preferred that the method includes, after film formation, a pre-baking process (PB) before the exposure process.

Further, it is also preferred that the method includes a post-exposure baking process (PEB) after the exposure process but before the development process.

As for the heating temperature, both PB and PEB are performed preferably at 70° C. to 130° C., and more preferably at 80° C. to 120° C.

The heating time is preferably 30 to 300 seconds, more preferably 30 to 180 seconds, and still more preferably 30 to 90 seconds.

The heating may be performed using a means equipped with a typical exposure/developing machine or may be performed using a hot plate or the like.

By means of baking, the reaction in the exposed portion is accelerated, and thus the sensitivity or pattern profile is improved.

The light source wavelength used in the exposure apparatus in the present invention is not limited, but examples thereof may include an infrared light, visible light, ultraviolet light, far ultraviolet light, an extreme-ultraviolet light, X-ray, an electron beam and the like, but the light source wavelength is preferably far ultraviolet light at a wavelength of preferably 250 nm or less, more preferably 220 nm or less, and particularly preferably 1 nm to 200 nm. Specific examples thereof may include a KrF excimer laser (248 nm), an ArF excimer laser (193 nm), a F₂ excimer laser (157 nm), an X-ray, an EUV (13 nm), an electron beam and the like, and a KrF excimer laser, an ArF excimer laser, an EUV or an electron beam is preferred, and an ArF excimer laser is more preferred.

Further, in the process of performing exposure of the present invention, a immersion exposure method may be applied.

The immersion exposure method is, as the technique to increase the resolution, a technique of performing the exposure by filling a high refractive-index liquid (hereinafter, also referred to as a “liquid for immersion”) between a projection lens and a sample.

As described above, for the “effect of immersion”, assuming that λ₀ is the wavelength of exposure light in air, n is the refractive index of the liquid for immersion for air, θ is the convergence half-angle of beam and NAₒ=sin θ, the resolution and the depth of focus in immersion may be expressed by the following equations. Here, k₁ and k₂ are coefficients related to the process.

(Resolution)=k₁·(λ₀/n)/NA₀

(Depth of focus)=±k₂·(λ₀/n)/NA₀²

That is, the effect of immersion is equivalent to the use of an exposure wavelength having a wavelength of 1/n. In other words, in the case of a projection optical system having the same NA, the depth of focus may be made n times larger by the immersion. This is effective for all pattern shapes and may be combined with the super-resolution technology that is now being currently studied, such as a phase-shift method and a modified illumination method.

In the case of performing immersion exposure, a process of washing the surface of the film with an aqueous chemical solution may be performed (1) after forming the film on a substrate and before the process of performing exposure and/or (2) after the process of exposing the film through a liquid for immersion but before the process of heating the film.

The liquid for immersion is preferably a liquid which is transparent to light at the exposure wavelength and has a temperature coefficient of refractive index as small as possible in order to minimize the distortion of an optical image projected on the film, but particularly, when the exposure light source is an ArF excimer laser (wavelength; 193 nm), water is preferably used from the viewpoint of easy availability and easy handleability in addition to the above-described viewpoint.

When water is used, an additive (liquid) capable of decreasing the surface tension of water and increasing the interfacial activity may be added in a small ratio. It is preferred that the additive does not dissolve the resist layer on the wafer and has only a negligible effect on the optical coat at the undersurface of the lens element.

Such an additive is preferably an aliphatic alcohol having a refractive index almost equal to that of, for example, water, and specific examples thereof may include methyl alcohol, ethyl alcohol, isopropyl alcohol and the like. By adding an alcohol having a refractive index almost equal to that of water, even when the alcohol component in water is evaporated and the content concentration thereof is changed, it is possible to obtain an advantage in that the change in the refractive index of the liquid as a whole may be made very small.

Meanwhile, when a substance opaque to light at 193 nm or an impurity greatly differing from water in the refractive index is incorporated, the incorporation incurs distortion of the optical image projected on the resist, and thus, the water used is preferably distilled water. Further, pure water filtered through an ion exchange filter or the like may also be used.

The electrical resistance of water used as the liquid for immersion is preferably 18.3 MQcm or more, and TOC (organic concentration) is preferably 20 ppb or less and the water is preferably subjected to deaeration treatment.

Further, the lithography performance may be enhanced by raising the refractive index of the liquid for immersion. From this viewpoint, an additive for raising the refractive index may be added to water, or heavy water (D₂O) may be used in place of water.

When a film formed by using the composition of the present invention is exposed through a immersion medium, the above-described hydrophobic resins (D) may be further added if necessary. The hydrophobic resin (D) is added, thereby improving the receding contact angle of the surface. The receding contact angle of the film is preferably 60° to 90°, and more preferably 70° or more.

In the immersion exposure process, the liquid for immersion needs to move on a wafer following the movement of an exposure head that scans on the wafer at a high speed and forms an exposure pattern, and thus the contact angle of the liquid for immersion for the resist film in a dynamic state is important, and a performance of allowing the exposure head to follow the high-speed scanning is required for the resist while a liquid droplet no longer remains.

In order not to cause the film to directly contact the liquid for immersion, a film (hereinafter, also referred to as a “topcoat”) that is sparingly soluble in a liquid for immersion may be formed between the film formed using the composition of the present invention and the liquid for immersion. Examples of a function required for the topcoat may include coating suitability to the upper layer portion of the resist, transparency to radiation, particularly to radiation having a wavelength of 193 nm, and poor solubility in the liquid for immersion. It is preferred that the topcoat may be uniformly coated onto the upper layer of the resist without being mixed with the resist.

The topcoat is preferably a polymer not containing an aromatic group from the viewpoint of the transparency to 193 nm.

Specific examples of the polymer may include a hydrocarbon polymer, an acrylate ester polymer, polymethacrylic acid, polyacrylic acid, polyvinyl ether, a silicon-containing polymer, a fluorine-containing polymer and the like. The described-above hydrophobic resin (D) is also suitable as the topcoat. If impurities are eluted from the topcoat to the liquid for immersion, the optical lens is contaminated, and thus it is preferred that the amounts of residual monomer components of the polymer included in the topcoat are small.

When the topcoat is peeled off, a developer may be used, or another peeling agent may be used. As the peeling agent, a solvent that rarely penetrates the film is preferred. From the viewpoint that the peeling process may be performed simultaneously with the developing treatment process of the film, it is preferred that the topcoat may be peeled off by an alkali developer. From the viewpoint of peeling off the topcoat with an alkali developer, the topcoat is preferably acidic, but from the viewpoint of a non-intermixture property with respect to the film, the topcoat may be neutral or alkaline.

It is preferred that there be no difference or a small difference in the refractive index between the topcoat and the liquid for immersion. In this case, the resolution may be improved. When the exposure light source is an ArF excimer laser (wavelength: 193 nm), it is preferred that water is used as the liquid for immersion, and thus the topcoat for ArF immersion exposure preferably has a refractive index close to the refractive index (1.44) of water. Further, from the viewpoint of transparency and refractive index, the topcoat is preferably a thin film

It is preferred that the topcoat is not mixed with the film and the liquid for immersion. From this viewpoint, when the liquid for immersion is water, it is preferred that the solvent used for the topcoat is sparingly soluble in the solvent used for the composition of the present invention and is a water-insoluble medium. Further, when the liquid for immersion is an organic solvent, the topcoat may be water-soluble or water-insoluble.

In the present invention, the substrate on which the film is formed is not particularly limited, and it is possible to use an inorganic substrate such as silicon, SiN, SiO₂ or SiN, a coating-type inorganic substrate such as SOG, or a substrate generally used in the process of manufacturing a semiconductor such as IC or manufacturing a liquid crystal device or a circuit board such as a thermal head or in the lithography process of other photo-fabrication processes. Further, if necessary, an organic antireflection film may be formed between the film and the substrate.

When the pattern forming method of the present invention further includes performing development using an alkali developer, it is possible to use an alkaline aqueous solution of inorganic alkalis such as sodium hydroxide, potassium hydroxide, sodium carbonate, sodium silicate, sodium metasilicate, aqueous ammonia and the like, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide and tetraethylammonium hydroxide, cyclic amines such as pyrrole and piperidine, and the like, as the alkali developer.

Further, alcohols and a surfactant may be added to the alkaline aqueous solution each in an appropriate amount and the mixture may be used.

The alkali concentration of the alkali developer is usually 0.1% by mass to 20% by mass.

The pH of the alkali developer is usually 10.0 to 15.0.

In particular, an aqueous solution of 2.38% by mass of tetramethylammonium hydroxide is preferred.

As for the rinsing solution in the rinse treatment performed after the alkali development, pure water is used, and an appropriate amount of a surfactant may be added thereto to use the mixture.

Further, after the development treatment or rinse treatment, a treatment of removing the developer or rinsing solution adhering on the pattern by a supercritical fluid may be performed.

As the developer (hereinafter, also referred to as an organic-based developer) in the process of performing developing using a developer containing an organic solvent to form a negative pattern, a polar solvent such as a ketone-based solvent, an ester-based solvent, an alcohol-based solvent, an amide-based solvent and an ether-based solvent, and a hydrocarbon-based solvent may be used.

Examples of the ketone-based solvent may include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, propylene carbonate and the like.

Examples of the ester-based solvent may include methyl acetate, butyl acetate, ethyl acetate, isopropyl acetate, pentyl acetate, isopentyl acetate, amyl acetate, cyclohexyl acetate, isobutyl isobutyrate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate and the like.

Examples of the alcohol-based solvent may include an alcohol such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, n-decanol and the like, a glycol-based solvent such as ethylene glycol, diethylene glycol and triethylene glycol, a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethyl butanol, and the like.

Examples of the ether-based solvent may include, in addition to the glycol ether-based solvents, dioxane, tetrahydrofuran, phenetol, dibutyl ether and the like.

As the amide-based solvent, it is possible to use N-methyl-2-pyrrolidone, N,N-dimethylacetamide, N,N-dimethylformamide, hexamethylphosphoric triamide, 1,3-dimethyl-2-imidazolidinone and the like.

Examples of the hydrocarbon-based solvent may include an aromatic hydrocarbon-based solvent such as toluene and xylene, and an aliphatic hydrocarbon-based solvent such as pentane, hexane, octane and decane.

A plurality of the above-described solvents may be mixed, or the solvents may be used by being mixing with a solvent other than those described above or with water. However, in order to sufficiently exhibit the effects of the present invention, the water content ratio of the entire developer is preferably less than 10% by mass, and it is more preferred that the developer contains substantially no moisture.

That is, the amount of the organic solvent used in the organic-based developer is preferably 90% by mass to 100% by mass, and preferably 95% by mass to 100% by mass, based on the total amount of the developer.

In particular, the organic-based developer is preferably a developer containing at least one of organic solvents selected from the group consisting of a ketone-based solvent, an ester-based solvent, an alcohol-based solvent, an amide-based solvent and an ether-based solvent.

The vapor pressure of the organic-based developer is preferably 5 kPa or less, more preferably 3 kPa or less, and particularly preferably 2 kPa or less, at 20° C. By adjusting the vapor pressure of the organic-based developer to 5 kPa or less, evaporation of the developer on a substrate or in a development cup is suppressed so that temperature uniformity in the wafer plane is improved, and as a result, the dimensional uniformity in the wafer plane is improved.

Specific examples of the solvent having a vapor pressure of 5 kPa or less may include a ketone-based solvent such as 1-octanone, 2-octanone, 1-nonanone, 2-nonanone, 2-heptanone (methyl amyl ketone), 4-heptanone, 2-hexanone, diisobutyl ketone, cyclohexanone, methylcyclohexanone, phenylacetone and methyl isobutyl ketone, an ester-based solvent such as butyl acetate, pentyl acetate, isopentyl acetate, amyl acetate, cyclohexyl acetate, isobutyl isobutyrate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, butyl formate, propyl formate, ethyl lactate, butyl lactate and propyl lactate, an alcohol-based solvent such as n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol and n-decanol, a glycol-based solvent such as ethylene glycol, diethylene glycol and triethylene glycol, a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethylbutanol, an ether-based solvent such as tetrahydrofuran, phenetol and dibutyl ether, an amide-based solvent such as N-methyl-2-pyrrolidone, N,N-dimethylacetamide and N,N-dimethylformamide, an aromatic hydrocarbon-based solvent such as toluene and xylene, and an aliphatic hydrocarbon-based solvent such as octane and decane.

Specific examples of the solvent having a vapor pressure of 2 kPa or less that is in a particularly preferred range may include a ketone-based solvent such as 1-octanone, 2-octanone, 1-nonanone, 2-nonanone, 4-heptanone, 2-hexanone, diisobutyl ketone, cyclohexanone, methylcyclohexanone and phenylacetone, an ester-based solvent such as butyl acetate, amyl acetate, cyclohexyl acetate, isobutyl isobutyrate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, ethyl lactate, butyl lactate and propyl lactate, an alcohol-based solvent such as n-butyl alcohol, sec-butyl alcohol, tert-butyl alcohol, isobutyl alcohol, n-hexyl alcohol, n-heptyl alcohol, n-octyl alcohol and n-decanol, a glycol-based solvent such as ethylene glycol, diethylene glycol and triethylene glycol, a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethylbutanol, an ether-based solvent such as phenetol and dibutyl ether, an amide-based solvent such as N-methyl-2-pyrrolidone, N,N-dimethylacetamide and N,N-dimethylformamide, an aromatic hydrocarbon-based solvent such as xylene, and an aliphatic hydrocarbon-based solvent such as octane and decane.

In the organic-based developer, a surfactant may be added in an appropriate amount, if necessary.

The surfactant is not particularly limited but, for example, ionic or nonionic fluorine-based and/or silicon-based surfactant and the like may be used. Examples of the fluorine and/or silicon-based surfactants may include surfactants described in Japanese Patent Application Laid-Open Nos. S62-36663, S61-226746, S61-226745, S62-170950, S63-34540, H7-230165, H8-62834, H9-54432, and H9-5988 and U.S. Pat. Nos. 5,405,720, 5,360,692, 5,529,881, 5,296,330, 5,436,098, 5,576,143, 5,294,511 and 5,824,451, and a nonionic surfactant is preferred. The nonionic surfactant is not particularly limited, but a fluorine-based surfactant or a silicon-based surfactant is more preferably used.

The amount of the surfactant used is usually 0.001% by mass to 5% by mass, preferably 0.005% by mass to 2% by mass, and more preferably 0.01% by mass to 0.5% by mass, based on the total amount of the developer.

As for the developing method, it is possible to apply, for example, a method of dipping a substrate in a bath filled with a developer for a predetermined time (a dipping method), a method of raising a developer on a substrate surface sufficiently by the effect of a surface tension and keeping the substrate still for a predetermined time, thereby performing development (a puddle method), a method of spraying a developer on a substrate surface (a spray method), a method of continuously ejecting a developer on a substrate spinning at a constant speed while scanning a developer ejecting nozzle at a constant rate (a dynamic dispense method) and the like.

When the above-described various developing methods include ejecting a developer toward a resist film from a development nozzle of a developing apparatus, the ejection pressure of the developer ejected (the flow velocity per unit area of the developer ejected) is preferably 2 mL/sec/mm² or less, more preferably 1.5 mL/sec/mm² or less, and still more preferably 1 mL/sec/mm² or less. The flow velocity has no particular lower limit, but is preferably 0.2 mL/sec/mm² or more in consideration of throughput.

By setting the ejection pressure of the ejected developer to the above-described range, pattern defects resulting from the resist scum after development may be significantly reduced. Details on the mechanism are not clear, but it is thought that it is because the resist film•resist pattern is suppressed from being inadvertently cut or collapsing by setting the ejection pressure to the above-described range, the pressure imposed on the resist film by the developer is decreased.

Meanwhile, the ejection pressure (mL/sec/mm²) of the developer is the value at the outlet of the development nozzle in the developing apparatus.

Examples of the method for adjusting the ejection pressure of the developer may include a method of adjusting the ejection pressure by a pump or the like, a method of supplying a developer from a pressurized tank and adjusting the pressure to change the ejection pressure and the like.

In addition, after the process of performing development using a developer containing an organic solvent, a process of stopping the development while replacing the solvent with another solvent may be performed.

A process of rinsing a film using a rinsing solution is preferably included after the process of performing development using a developer containing an organic solvent.

The rinsing solution used in the rinse process after the process of performing development using a developer containing an organic solvent is not particularly limited as long as the rinsing solution does not dissolve the resist pattern, and a solution including a general organic solvent may be used. As for the rinsing solution, a rinsing solution containing at least one of organic solvents selected from the group consisting of a hydrocarbon-based solvent, a ketone-based solvent, an ester-based solvent, an alcohol-based solvent, an amide-based solvent and an ether-based solvent is preferably used.

Specific examples of the hydrocarbon-based solvent, the ketone-based solvent, the ester-based solvent, the alcohol-based solvent, the amide-based solvent and the ether-based solvent are the same as those described above for the developer containing an organic solvent.

After the process of performing development using a developer containing an organic solvent, a process of performing rinsing using a rinsing solution containing at least one of organic solvents selected from the group consisting of a ketone-based solvent, an ester-based solvent, an alcohol-based solvent and an amide-based solvent is more preferably performed, a process of performing rinsing using a rinsing solution containing an alcohol-based solvent or an ester-based solvent is still more preferably performed, a process of performing rinsing using a rinsing solution containing a monohydric alcohol is particularly preferably performed, and a process of performing rinsing using a rinsing solution containing a monohydric alcohol having 5 or more carbon atoms is most preferably performed.

Here, examples of the monohydric alcohol used in the rinsing process may includes a straight, branched or cyclic monohydric alcohol, and specifically, it is possible to use 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, 4-octanol and the like, and as the particularly preferred monohydric alcohol having 5 or more carbon atoms, it is possible to use 1-hexanol, 2-hexanol, 4-methyl-2-pentanol, 1-pentanol, 3-methyl-1-butanol and the like.

A plurality of the components may be mixed, or the solvent may be used by being mixed with an organic solvent other than those described above.

The water content ratio in the rinsing solution is preferably 10% by mass or less, more preferably 5% by mass or less, and particularly preferably 3% by mass or less. By setting the water content ratio to 10% by mass or less, good development characteristics may be obtained.

The vapor pressure of the rinsing solution used after the process of performing development using a developer containing an organic solvent is preferably 0.05 kPa to 5 kPa, still more preferably 0.1 kPa to 5 kPa, and most preferably 0.12 kPa to 3 kPa, at 20° C. By setting the vapor pressure of the rinsing solution to 0.05 kPa to 5 kPa, the temperature uniformity in the wafer plane is improved. Further, swelling caused by permeation of the rinsing solution is suppressed. As a result, the dimensional uniformity in the wafer plane is improved.

The rinsing solution may also be used by adding an appropriate amount of a surfactant thereto.

In the rinsing process, the wafer subjected to development using a developer containing an organic solvent is rinsed by using the above-described rinsing solution including an organic solvent. The method of rinse treatment is not particularly limited, but it is possible to apply, for example, a method of continuously ejecting a rinsing solution on a substrate spinning at a constant speed (spin coating method), a method of dipping a substrate in a bath filled with a rinsing solution for a predetermined time (dipping method), a method of spraying a rinsing solution on a substrate surface (spraying method), and the like, and among them, it is preferred that the rinse treatment is performed by the spin coating method and after the rinsing, the substrate is spun at a rotational speed of 2,000 rpm to 4,000 rpm to remove the rinsing solution from the substrate. Further, it is also preferred that a heating process (post bake) is included after the rinsing process. The developer and rinsing solution remaining between patterns and in the inside of the pattern are removed by the bake. The heating process after the rinsing process is performed at usually 40° C. to 160° C., and preferably 70° C. to 95° C., for usually 10 seconds to 3 minutes, and preferably 30 to 90 seconds.

Further, the present invention also relates to a method for manufacturing an electronic device, including the above-described pattern forming method of the present invention, and an electronic device manufactured by this manufacturing method.

The electronic device of the present invention is suitably mounted on electric electronic devices (such as home appliances, OA-media-related devices, optical devices and communication devices).

### EXAMPLES

### Synthesis of Resin (P-1)

27.9 g of cyclohexanone was placed in a 3-neck flask, and heated at 80° C. under nitrogen flow. Subsequently, the following monomer 1 (14.8 g) and monomer 2 (12.6 g) were dissolved in cyclohexanone (51.9 g) to prepare a monomer solution, and a solution prepared by adding 0.55 g (2.0 mol % based on the total amount of the monomers) of a polymerization initiator V-601 (manufactured by Wako Pure Chemical Industries, Ltd.) thereto was added dropwise to the flask over 6 hours. After the completion of dropwise addition, the solution was also allowed to react at 80° C. for 2 hours. The reaction solution was allowed to cool, and then added dropwise to a mixed solvent of 670 g of heptane/74.5 g of ethyl acetate, and a precipitated powder was obtained by filtration and dried to obtain 21.8 g of Resin (P-1). The weight average molecular weight obtained from the GPC (carrier: tetrahydrofuran (THF)) of the obtained Resin (P-1) was 21,500, the polydispersity Mw/Mn was 1.68, and the composition ratio (molar ratio) measured by ¹³C-NMR was 50/50.

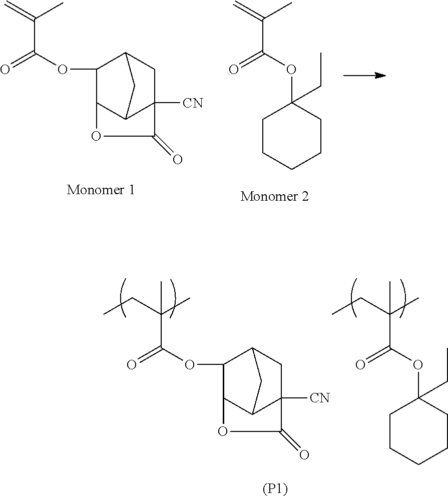

Hereinafter, Resins (P-2) to (P-14) were synthesized in the same manner as in Resin (P-1).

The structure of the synthesized resin, the composition ratio (molar ratio), and the mass average molecular weight and the polydispersity of the repeating unit will be described below.

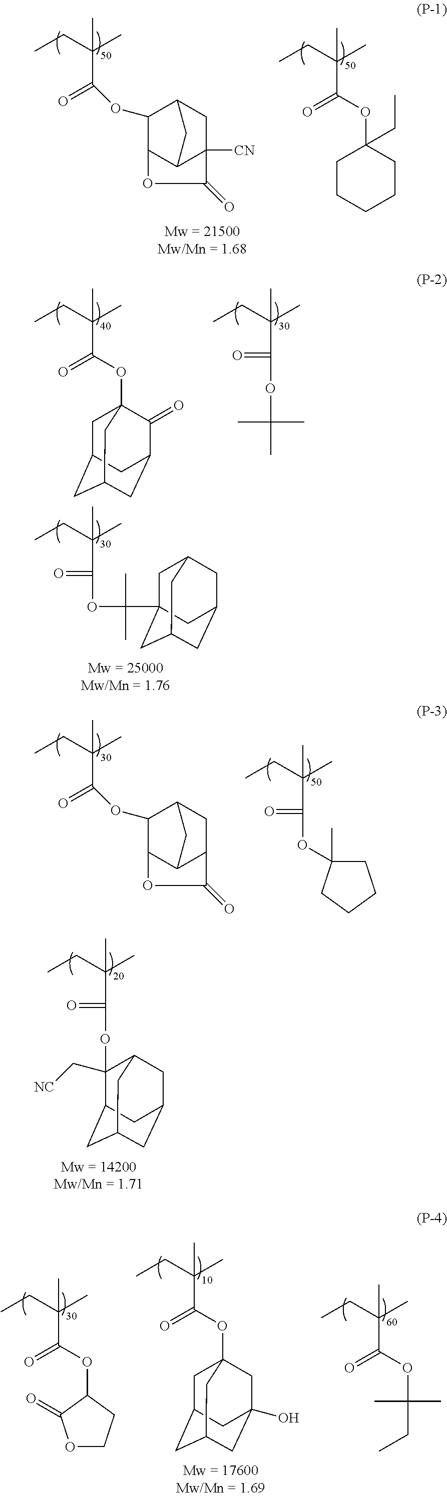

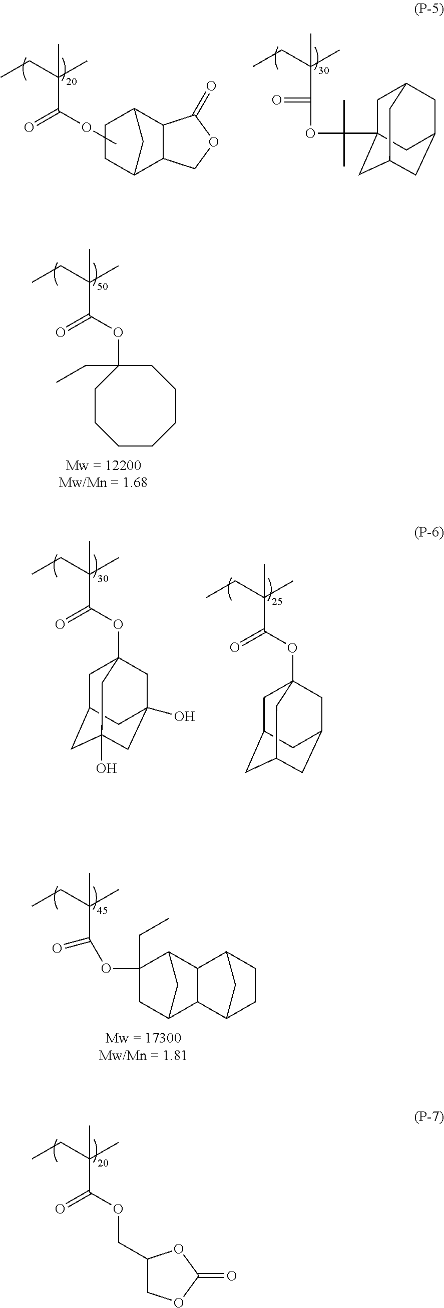

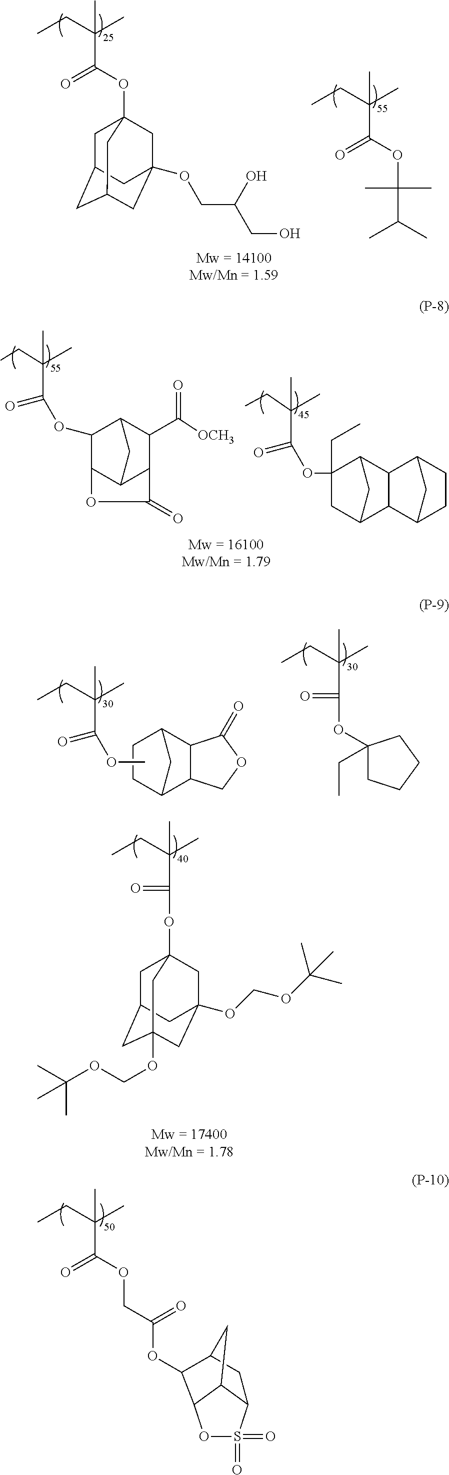

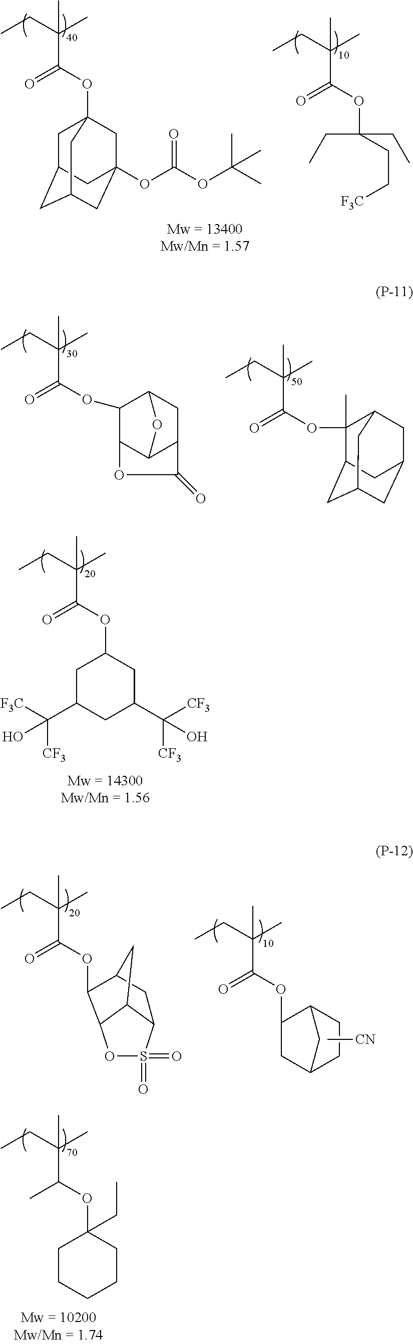

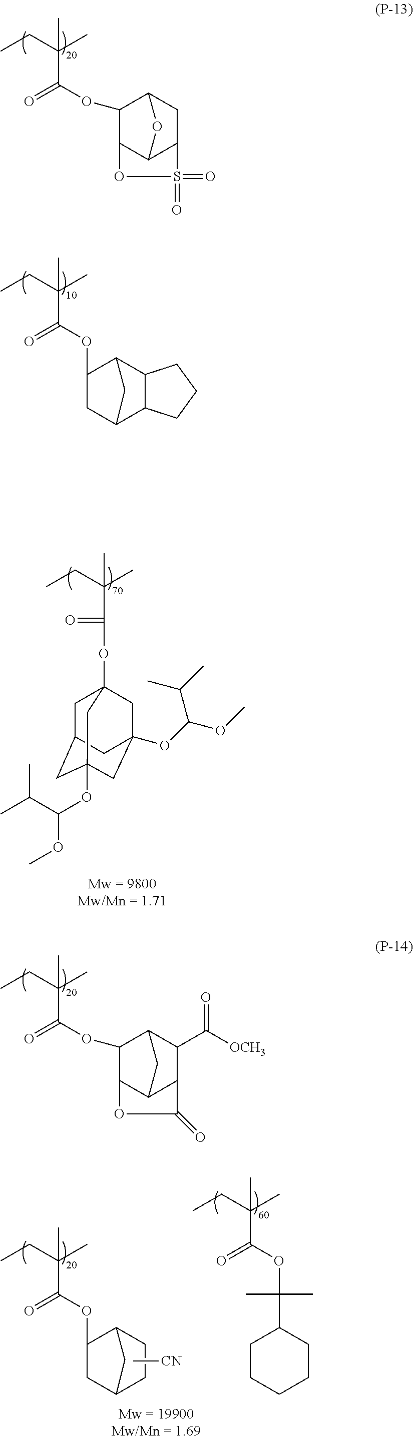

<Salt (C) Having Conjugate Base Structure of an Acid Having pKa of −2 or More in the Molecule Thereof and Substantially not Capable of Decomposing by Actinic Ray or Radiation>

As the salt (C) having a conjugate base structure of an acid having a pKa of −2 or more in a molecule thereof and substantially not capable of decomposing by an actinic ray or radiation, the following salt was used.

(The Following pKa Represents a pKa of a Conjugate Acid of an Anionic Part)

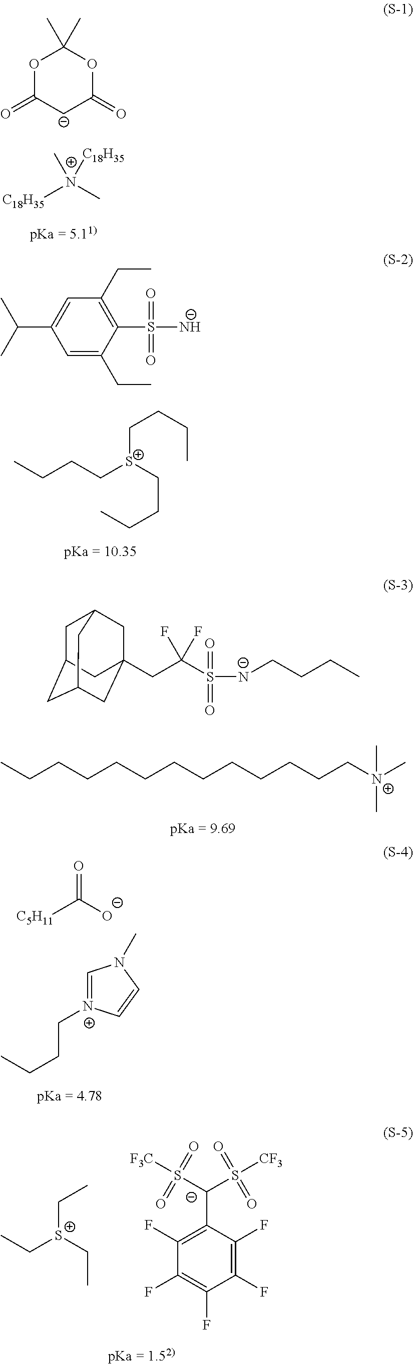

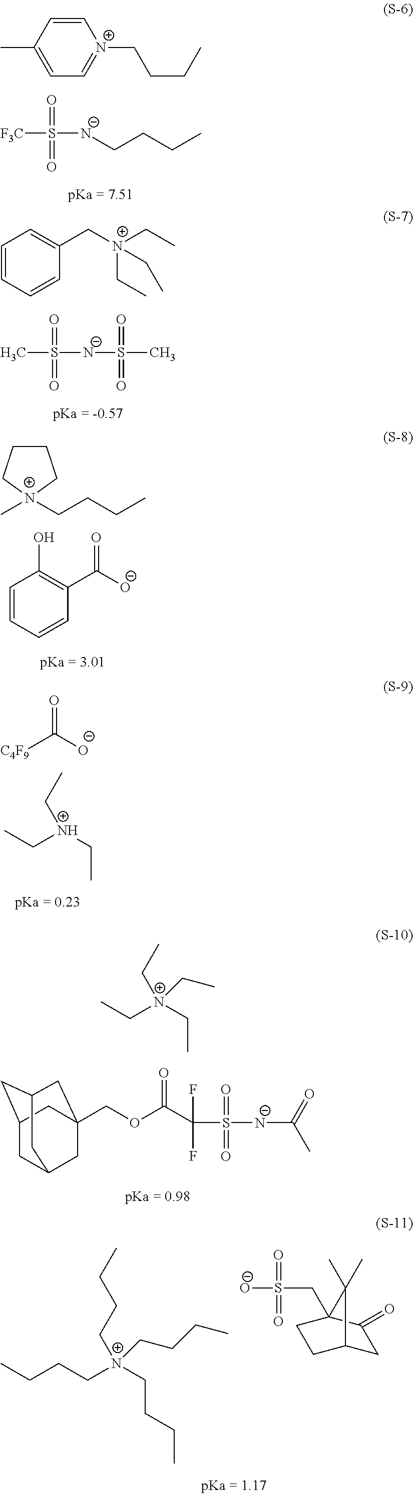

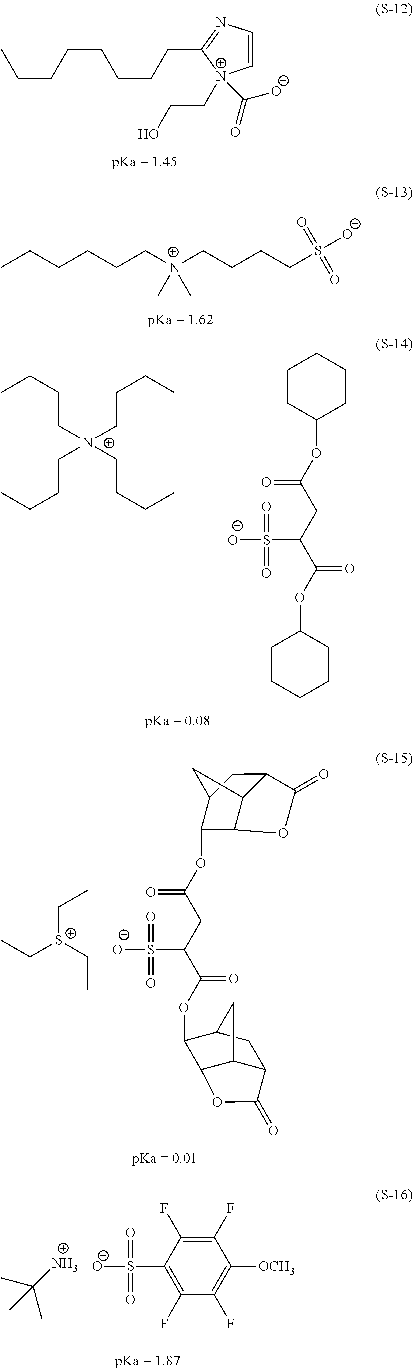

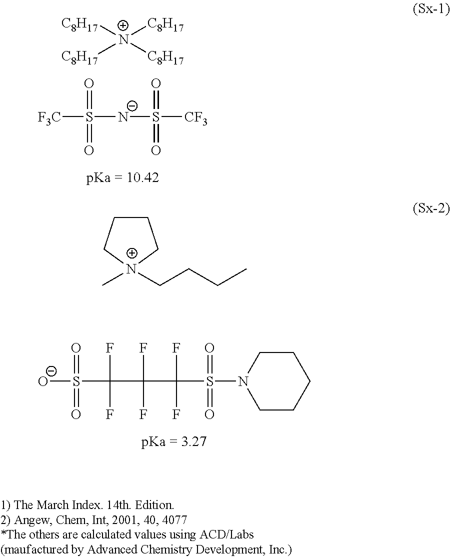

The above-described salt (C) having a conjugate base structure of an acid having a pKa of −2 or more in a molecule thereof and substantially not capable of decomposing by an actinic ray or radiation was synthesized using a method described in “Hiroshi Horiguchi, Synthetic Surfactants <augmented edition>, Sankyo Publishing Co., Ltd., 1969”.

<Acid Generator>

The following compounds were used as the acid generator.

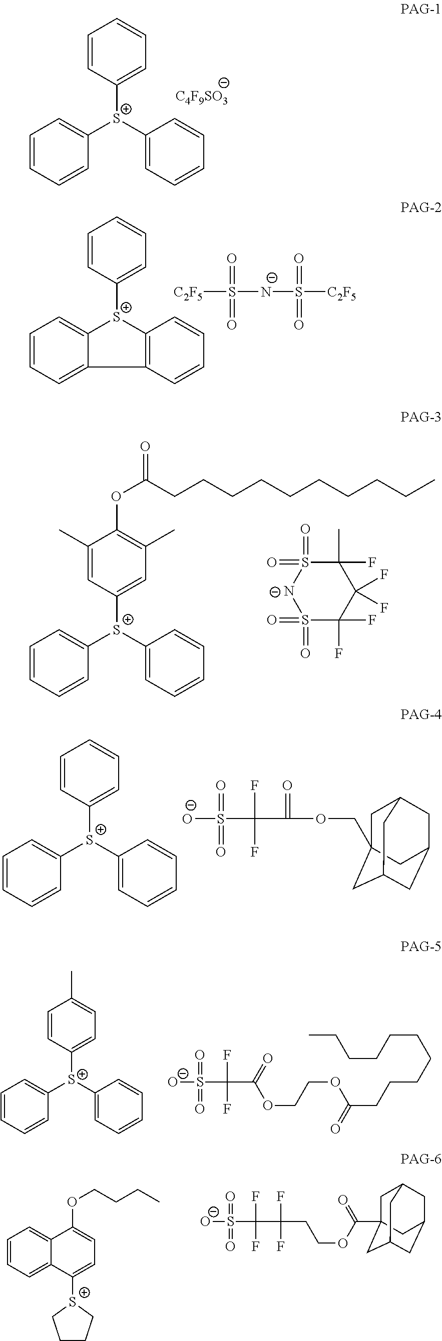

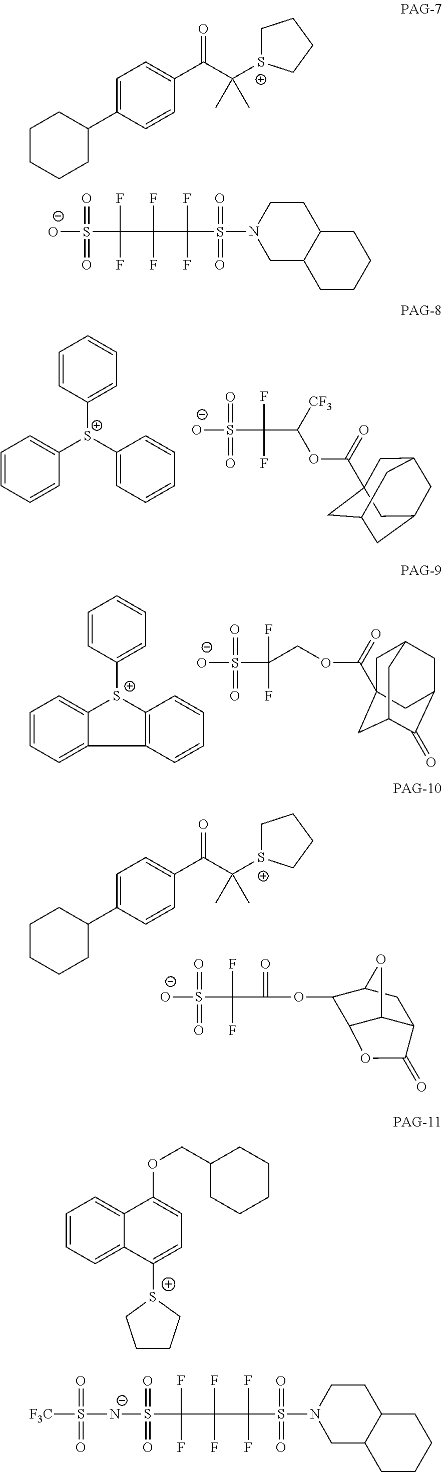

<Basic Compound (N) Whose Basicity Decreases Upon Irradiation with Actinic Ray or Radiation, and Basic Compound (N′)>

The following compounds were used as the basic compound whose basicity decreases upon irradiation with an actinic ray or radiation, or the basic compound.

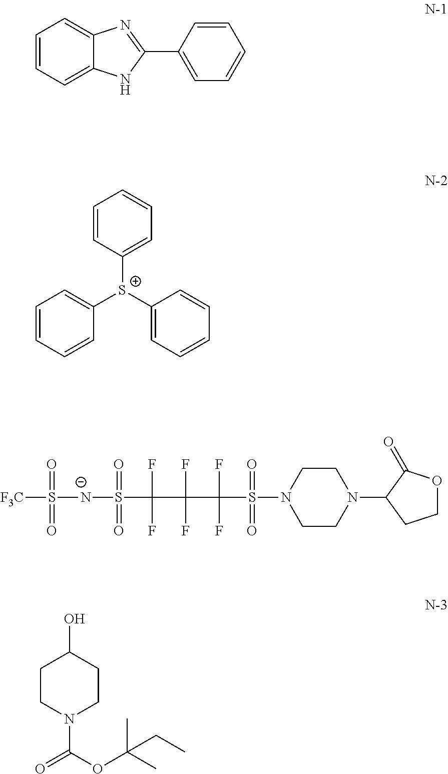 [SMILES: c1ccc(-c2nc3ccccc3[nH]2)cc1 ; c1ccc([S+](c2ccccc2)c2ccccc2)cc1 ; O=C1OCCC1N1CCN(S(=O)(=O)C(F)(F)C(F)(F)C(F)(F)S(=O)(=O)[N-]S(=O)(=O)C(F)(F)F)CC1 ; CCC(C)(C)OC(=O)N1CCC(O)CC1]

<Hydrophobic Resin>

A hydrophobic resin was appropriately selected from Resins (HR-1) to (HR-84), (C−1) to (C-28), and (D−1) to (D-16) previously exemplified, and then was used.

<Surfactant>

The followings were used as the surfactant.

W-1: Megafac F176 (manufactured by DIC Corporation; fluorine-based)

W-2: PolyFox PF-6320 (manufactured by OMNOVA Solutions Inc.; fluorine-based)

W-3: Polysiloxane Polymer KP-341 (manufactured by Shin-Etsu Chemical Co., Ltd.; silicon-based)

W-4: Troysol S-366 (manufactured by Troy Chemical Industries, Inc.)

W-5: KH-20 (manufactured by Asahi Glass Co., Ltd.)

<Solvent>

The followings were used as the solvent.

(Group a)

SL-1: Propylene glycol monomethyl ether acetate (PGMEA)

SL-2: Propylene glycol monomethyl ether propionate

SL-3: 2-Heptanone

(Group b)

SL-4: Ethyl lactate

SL-5: Propylene glycol monomethyl ether (PGME)

SL-6: Cyclohexanone

(Group c)

SL-7: γ-Butyrolactone

SL-8: Propylene carbonate

<Developer>

The followings were used as the developer.

SG-1: 2-Nonanone

SG-2: Diisobutyl ketone

SG-3: Cyclohexyl acetate

SG-4: Isobutyl isobutyrate

SG-5: Isopentyl acetate

SG-6: Phenetol

SG-7: Dibutyl ether

SG-8: Butyl acetate

<Rinsing Solution>

The followings were used as the rinsing solution.

SR-1: 4-methyl-2-pentanol

SR-2: 1-hexanol

### Examples 1 to 20, Comparative Examples 1 to 3

### ArF Immersion Exposure

(Preparation of Resist)

The components shown in the following Table 6 were dissolved in the solvent shown in the same Table to have a total solid content of 3.8% by mass, and each was filtered through a polyethylene filter having a pore size of 0.03 μm to prepare an actinic ray-sensitive or radiation-sensitive resin composition (resist composition). An organic antireflection film ARC29SR (manufactured by Nissan Chemical Industries, Ltd.) was applied on a silicon wafer (12 inch 300 mmΦ) and baked at 205° C. for 60 seconds to form an antireflection film having a thickness of 95 nm. The actinic ray-sensitive or radiation-sensitive resin composition was applied thereon and baked (PB: prebake) at 100° C. over 60 seconds to form a resist film having a thickness of 100 nm.

The obtained wafer was subjected to pattern exposure by using an ArF excimer laser immersion scanner (manufactured by ASML Co., Ltd.; XT1700i, NA 1.20, C-Quad, outer sigma 0.900, inner sigma 0.812, XY deflection) through a halftone mask having a square arrangement in which a hole portion was 60 nm and a pitch between holes was 90 nm (here, a portion corresponding to the hole is light-shielded in order to form a negative image). As the liquid for immersion, ultrapure water was used. Thereafter, heating (PEB: post exposure bake) was performed at 105° C. for 60 seconds. Subsequently, the wafer was developed by performing puddling using the organic solvent-based developer shown in the following Table 6 for 30 seconds, and then rinsed by performing puddling using the rinsing solution shown in the following Table 6 for 30 seconds while spinning the wafer at a rotational speed of 1,000 rpm. Subsequently, a contact hole pattern having a pore diameter of 45 nm was obtained by spinning the wafer at a rotational speed of 4,000 rpm for 30 seconds.

[Exposure Latitude (EL, %)]

A hole size was observed by a Critical Dimension scanning electron microscope (SEM) (manufactured by Hitachi, Ltd., S-938011), and an optimal exposure amount at the time of resolving a contact hole pattern having an average hole portion of 45 nm was defined as the sensitivity (Eₒₚₜ)(mJ/cm²). An exposure amount was obtained when the obtained optimal exposure amount (Eₒₚₜ) was used as a reference and subsequently, the hole size become 45 nm±10% (that is, 40.5 nm and 49.5 nm) which was a target value. Further, an exposure latitude (EL, %) defined as the following equation was calculated. The larger EL value, the smaller the change in performance caused by a change in exposure amount was, indicating that EL was good.

[EL(%)]=[(an exposure amount when the hole portion is 40.5 nm)−(an exposure amount when the hole portion is 49.5 nm)]/Eₒₚₜ×100

[Uniformity of Local Pattern Dimension (Local CDU, Nm)]

Within one shot exposed as the optimal exposure amount in the exposure latitude evaluation, in twenty regions having an interval of 1 μm therebetween, hole sizes at arbitrary 25 points in each region (that is, 500 points in total) were measured and a standard deviation thereof was obtained to calculate 3a. The smaller the value, the smaller the variation in dimension was, indicating that the performance was good.

[Scum]

The obtained wafer was exposed through a 6% halftone mask of a pattern (line: space=1:1) having a line width of 45 nm using an ArF excimer laser immersion scanner (manufactured by ASML, XT1700i, NA 1.20). As the liquid for immersion, ultrapure water was used. Thereafter, the wafer was heated at 105° C. for 60 seconds, and subsequently, developed by performing puddling using an organic solvent-based developer described in the following Table 6 for 30 seconds, and then rinsed by performing puddling using the rinsing solution described in the following Table 6 for 30 seconds while spinning the wafer at a rotational speed of 1,000 rpm.

The development scum (scum) in the resist pattern (line: space=1:1) having a line width of 45 nm, which was obtained in this manner, was observed using a scanning electron microscope (manufactured by Hitachi, Ltd., S-4800), and those with no scum occurring, those with scum severely occurring, and those with scum occurring in-between were defined as A, C, and B, respectively.

TABLE 6
Immersion exposure

| | | | Compound | | Compound | | Compound | | Hydrophobic | |
|---|---|---|---|---|---|---|---|---|---|---|
| Ex | Resin | (g) | (B) | (g) | (C) | (g) | (N), (N′) | (g) | resin (D) | (g) |
| Ex. 1 | P-1 | 10 | PAG-4 | 1.32 | S-13 | 0.54 | | | D-12 | 0.06 |
| Ex. 2 | P-2 | 10 | PAG-2 | 1.14 | S-4 | 0.54 | | | HR-16 | 0.06 |
| Ex. 3 | P-3 | 10 | PAG-11 | 1.45 | S-12 | 0.70 | | | D-4 | 0.06 |
| Ex. 4 | P-4 | 10 | PAG-7 | 1.33 | S-3 | 0.64 | | | HR-59 | 0.06 |
| Ex. 5 | P-5 | 10 | PAG-5 | 1.04 | S-7 | 0.64 | | | C-10 | 0.06 |
| Ex. 6 | P-6 | 10 | PAG-8 | 2.39 | S-1 | 0.55 | | | C-14 | 0.06 |
| Ex. 7 | P-7 | 10 | PAG-6 | 1.28 | S-8 | 0.48 | | | HR-39 | 0.06 |
| Ex. 8 | P-8 | 10 | PAG-9 | 1.18 | S-2 | 0.69 | | | HR-83 | 0.06 |
| Ex. 9 | P-9 | 10 | PAG-7 | 1.19 | S-11 | 0.41 | N-2 | 0.22 | HR-84 | 0.06 |
| Ex. 10 | P-10 | 10 | PAG-3 | 2.22 | S-10 | 0.76 | | | HR-51 | 0.06 |
| Ex. 11 | P-11 | 10 | PAG-4 | 1.50 | S-2 | 0.58 | N-3 | 0.14 | D-1 | 0.06 |
| Ex. 12 | P-12 | 10 | PAG-1/PAG-9 | 0.66/0.70 | S-12 | 0.25 | N-1 | 0.25 | D-4/C-10 | 0.04/0.02 |
| Ex. 13 | P-13 | 10 | PAG-10 | 2.22 | S-9 | 0.62 | | | HR-81 | 0.060 |
| Ex. 14 | P-14 | 10 | PAG-1 | 1.14 | S-11 | 0.59 | | | HR-24/C-14 | 0.03/0.03 |
| Ex. 15 | P-1/P-13 | 5/5 | PAG-5 | 1.33 | S-6 | 0.44 | | | C-1 | 0.06 |
| Ex. 16 | P-3 | 10 | PAG-9 | 1.45 | S-13/S-8 | 0.38/0.28 | | | HR-26 | 0.06 |
| Ex. 17 | P-5 | 10 | PAG-10 | 1.56 | S-5 | 0.64 | | | HR-83 | 0.06 |
| Ex. 18 | P-1 | 10 | PAG-8 | 1.44 | S-14 | 0.45 | | | HR-59 | 0.06 |
| Ex. 19 | P-2 | 10 | PAG-6 | 1.23 | S-15 | 0.62 | | | C-10 | 0.06 |
| Ex. 20 | P-3 | 10 | PAG-9 | 1.28 | S-16 | 0.65 | | | C-14 | 0.06 |
| C. Ex. 1 | P-1 | 10 | PAG-4 | 1.32 | Sx-1 | 0.54 | | | D-12 | 0.06 |
| C. Ex. 2 | P-2 | 10 | PAG-4 | 1.32 | None | None | N-1 | 0.25 | D-12 | 0.06 |
| C. Ex. 3 | P-3 | 10 | PAG-2 | 1.14 | Sx-2 | 0.54 | | | HR-16 | 0.06 |

| | | Mass | | | | Mass | Rinsing | | EL | Local CDU | |
|---|---|---|---|---|---|---|---|---|---|---|---|
| Ex | Solvent | ratio | Surfactant | (g) | Developer | ratio | solution | Mass ratio | (%) | (nm) | Scum |
| Ex. 1 | SL-1/SL-7 | 60/40 | W-3 | 0.003 | SG-6 | 100 | SR-1 | 100 | 18.3 | 5.0 | A |
| Ex. 2 | SL-1/SL-3 | 80/20 | None | None | SG-8 | 100 | SR-1 | 100 | 18.0 | 4.9 | A |
| Ex. 3 | SL-1/SL-8 | 70/30 | None | None | SG-2 | 100 | SR-1 | 100 | 18.1 | 4.9 | A |
| Ex. 4 | SL-1/SL-7 | 60/40 | None | None | SG-8 | 100 | SR-1 | 100 | 17.5 | 4.8 | A |
| Ex. 5 | SL-1/SL-5 | 60/40 | W-5 | 0.003 | SG-8 | 100 | SR-2 | 100 | 18.5 | 5.0 | A |
| Ex. 6 | SL-1/SL-5 | 60/40 | W-4 | 0.003 | SG-5 | 100 | SR-1 | 100 | 18.2 | 5.0 | A |
| Ex. 7 | SL-1/SL-5 | 60/40 | None | None | SG-8 | 100 | SR-1 | 100 | 17.3 | 5.3 | A |
| Ex. 8 | SL-1/SL-2 | 90/10 | None | None | SG-8 | 100 | SR-1 | 100 | 18.1 | 4.9 | A |
| Ex. 9 | SL-1/SL-5 | 60/40 | W-1 | 0.003 | SG-7 | 100 | SR-1 | 100 | 17.8 | 4.8 | A |
| Ex. 10 | SL-1/SL-5 | 60/40 | None | None | SG-3 | 100 | SR-1/SR-2 | 90/10 | 17.7 | 5.1 | A |
| Ex. 11 | SL-1/SL-2 | 90/10 | W-3 | 0.003 | SG-8 | 100 | SR-1 | 100 | 17.9 | 5.0 | A |
| Ex. 12 | SL-1/SL-5 | 60/40 | None | None | SG-1/SG-7 | 50/50 | SR-1 | 100 | 18.2 | 4.4 | A |
| Ex. 13 | SL-1/SL-4 | 60/40 | None | None | SG-4 | 100 | SR-1 | 100 | 17.5 | 4.6 | A |
| Ex. 14 | SL-1/SL-5 | 60/40 | None | None | SG-4 | 100 | SR-2 | 100 | 17.5 | 4.8 | A |
| Ex. 15 | SL-5/SL-6 | 30/70 | None | None | SG-6 | 100 | SR-1 | 100 | 18.1 | 5.2 | A |
| Ex. 16 | SL-5/SL-6 | 30/70 | W-2 | 0.003 | SG-1 | 100 | SR-1 | 100 | 17.3 | 5.0 | A |
| Ex. 17 | SL-1/SL-4 | 60/40 | W-4 | 0.003 | SG-6 | 100 | SR-1 | 100 | 17.9 | 5.2 | A |
| Ex. 18 | SL-1/SL-5 | 60/40 | None | None | SG-8 | 100 | None | — | 18.0 | 5.3 | A |
| Ex. 19 | SL-1/SL-2 | 90/10 | W-2 | 0.003 | SG-8 | 100 | SR-1 | 100 | 17.5 | 5.2 | A |
| Ex. 20 | SL-1/SL-5 | 60/40 | W-4 | 0.003 | SG-5 | 100 | SR-2 | 100 | 17.1 | 5.5 | A |
| C. Ex. 1 | SL-1/SL-7 | 60/40 | W-3 | 0.003 | SG-6 | 100 | SR-1 | 100 | 8.6 | 7.3 | B |
| C. Ex. 2 | SL-1/SL-7 | 60/40 | W-3 | 0.003 | SG-6 | 100 | SR-1 | 100 | 14.9 | 6.1 | C |
| C. Ex. 3 | SL-1/SL-3 | 80/20 | None | None | SG-8 | 100 | SR-1 | 100 | 11.3 | 6.6 | C |

As apparent from the result shown in Table 6, it can be known that Comparative Examples 1 and 3, in which salts having a conjugate base structure of acids having a pKa less than −2 (pKa: −10.42, pKa: −3.27, respectively) in the molecule thereof are used, are inferior in any of exposure latitude and uniformity of local pattern dimension, and also have a little large scum generation.

It can be known that Comparative Example 2, in which the salt (C) having a conjugate base structure of an acid having a pKa of −2 or more in the molecule thereof and substantially not capable of decomposing by an actinic ray or radiation is not used and only a basic compound is used, is slightly inferior in any of exposure latitude and uniformity of local pattern dimension, and has a large scum generation.

Meanwhile, it can be known that Examples 1 to 20, in which a salt (C) having a conjugate base structure of an acid having a pKa of −2 or more in the molecule thereof and substantially not capable of decomposing by an actinic ray or radiation is used, are excellent in any of exposure latitude and uniformity of local pattern dimension, and also have no scum generation.

### INDUSTRIAL APPLICABILITY

According to the present invention, in forming a fine pattern such as a hole pattern having a pore diameter of 45 nm or less by an organic-based developer, it is possible to provide a pattern forming method having excellent uniformity of local pattern dimension and exposure latitude and excellent reduction in scum generation, an actinic ray-sensitive or radiation-sensitive resin composition and a resist film used therefor, and an electronic device manufacturing method and an electronic device using the same.

This application is based on Japanese patent application No. 2012-134190 filed on Jun. 13, 2012, the entire content of which is hereby incorporated by reference, the same as if set forth at length.

What is claimed is:

1. A pattern forming method comprising:
(a) forming a film by an actinic ray-sensitive or radiation-sensitive resin composition containing (A) to (C),
(A) a resin capable of increasing polarity by the action of an acid to decrease solubility in a developer containing an organic solvent,
(B) a compound capable of generating acid upon irradiation with an actinic ray or radiation, and
(C) a salt having a conjugate base structure of an acid having a pKa of −2 or more in a molecule thereof and substantially not capable of decomposing by an actinic ray or radiation,
(b) exposing the film, and
(c) developing the exposed film using a developer containing an organic solvent to form a negative pattern.

2. The pattern forming method according to claim 1,
wherein the salt (C) is represented by Formula (I):
A^{⊖}B^{⊕} (I)
wherein in Formula (I), A⁻ represents an organic anion having a conjugate base structure of an acid having a pKa of −2 or more, and
B⁺ represents an organic cation, and
A⁻ and B⁺ may be bonded to each other through a covalent bond.

3. The pattern forming method according to claim 2,
wherein the organic cation B⁺ is an organic cation having no aromatic structure.

4. The pattern forming method according to claim 2,
wherein the organic cation B⁺ is an ammonium cation or a sulfonium cation.

5. The pattern forming method according to claim 1,
wherein the resin (A) is a resin capable of increasing polrality by generating an alcoholic hydroxyl group by the action of an acid so as to decrease solubility in a developer containing an organic solvent.

6. The pattern forming method according to claim 1,
wherein the compound (B) is a compound capable of generating an organic acid represented by Formula (V) or Formula (VI) upon irradiation with an actinic ray or radiation: 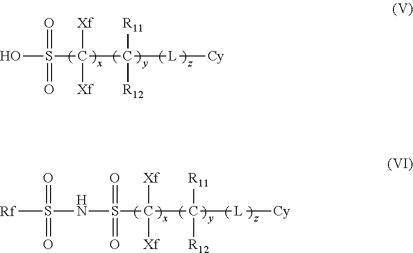
wherein a plurality of Xf each independently represents a fluorine atom or an alkyl group substituted with at least one fluorine atom,
each of R₁₁ and R₁₂ independently represents a hydrogen atom, a fluorine atom or an alkyl group,
L each independently represents a divalent linking group,
Cy represents a cyclic organic group,
Rf is a group including a fluorine atom,
x represents an integer of 1 to 20,
y represents an integer of 0 to 10, and
z represents an integer of 0 to 10.

7. The pattern forming method according to claim 1,
wherein the actinic ray-sensitive or radiation-sensitive resin composition further contains a hydrophobic resin (D) different from the resin (A).

8. The pattern forming method according to claim 1,
wherein the developer is a developer containing at least one organic solvent selected from the group consisting of a ketone-based solvent, an ester-based solvent, an alcohol-based solvent, an amide-based solvent and an ether-based solvent.

9. The pattern forming method according to claim 1,
wherein the exposure in the process (b) is immersion exposure.

10. An actinic ray-sensitive or radiation-sensitive resin composition, comprising:
(A) a resin capable of increasing polarity by the action of an acid to decrease solubility in a developer containing an organic solvent,
(B) a compound capable of generating acid upon irradiation with an actinic ray or radiation, and
(C) a salt having a conjugate base structure of an acid having a pKa of −2 or more in a molecule thereof and substantially not capable of decomposing by an actinic ray or radiation,

11. The actinic ray-sensitive or radiation-sensitive resin composition according to claim 10,
wherein the salt (C) is represented by Formula (I):
A^{⊖}B^{⊕} (I)
wherein in Formula (I), A⁻ represents an organic anion having a conjugate base structure of an acid having a pKa of −2 or more,
B⁺ represents an organic cation, and
A⁻ and B⁺ may be bonded to each other through a covalent bond.

12. The actinic ray-sensitive or radiation-sensitive resin composition according to claim 11,
wherein the organic cation B⁺ is an organic cation having no aromatic structure.

13. The actinic ray-sensitive or radiation-sensitive resin composition according to claim 11,
wherein the organic cation 13⁺ is an ammonium cation or a sulfonium cation.

14. The actinic ray-sensitive or radiation-sensitive resin composition according to claim 10,
wherein the resin (A) is a resin capable of increasing polrality by generating an alcoholic hydroxyl group by the action of an acid so as to decrease solubility in a developer containing an organic solvent.

15. The actinic ray-sensitive or radiation-sensitive resin composition according to claim 10,
wherein the compound (B) is a compound capable of generating an organic acid represented by Formula (V) or Formula (VI) upon irradiation with an actinic ray or radiation: 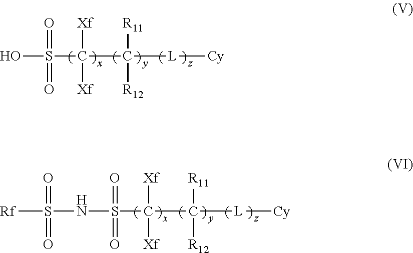
wherein a plurality of Xf each independently represents a fluorine atom or an alkyl group substituted with at least one fluorine atom,
each of R₁₁ and R₁₂ independently represents a hydrogen atom, a fluorine atom or an alkyl group,
L each independently represents a divalent linking group,
Cy represents a cyclic organic group,
Rf is a group including a fluorine atom,
x represents an integer of 1 to 20,
y represents an integer of 0 to 10, and
z represents an integer of 0 to 10.

16. The actinic ray-sensitive or radiation-sensitive resin composition according to claim 10,
wherein the actinic ray-sensitive or radiation-sensitive resin composition further contains a hydrophobic resin (D) different from the resin (A).

17. A resist film formed by the actinic ray-sensitive or radiation-sensitive resin composition according to claim 10.

18. An electronic device manufacturing method comprising the pattern forming method according to claim 1.

19. An electronic device manufactured by the electronic device manufacturing method according to claim 18.
